(19) United States
(12) Patent Application Publication
(10) Pub. No.: US 2025/0221307 A1
(43) Pub. Date: Jul. 3, 2025

(54) LIGHT EMITTING ELEMENT, FUSED POLYCYCLIC COMPOUND FOR THE SAME AND DISPLAY DEVICE INCLUDING THE SAME

(71) Applicant: Samsung Display Co., Ltd., Yongin-si (KR)

(72) Inventors: MUN-KI SIM, Yongin-si (KR); Hirokazu MIYASHITA, Yongin-si (KR); TAEIL KIM, Yongin-si (KR); SUN YOUNG PAK, Yongin-si (KR); JUNHA PARK, Yongin-si (KR); Chihyun RYOO, Yongin-si (KR); Giwoong HAN, Yongin-si (KR)

(73) Assignee: Samsung Display Co., Ltd., Yongin-si (KR)

(21) Appl. No.: 18/945,852

(22) Filed: Nov. 13, 2024

(30) Foreign Application Priority Data
Jan. 2, 2024 (KR) 10-2024-0000501

(51) Int. Cl. H10K 85/60; C07F 5/02; C09K 11/02; C09K 11/06; H10K 50/12; H10K 85/30

(52) U.S. Cl. CPC H10K 85/658; C07F 5/027; C09K 11/02; C09K 11/06; H10K 85/346; H10K 85/654; H10K 85/6572; C09K 2211/1007; C09K 2211/1044; C09K 2211/185; H10K 50/12

(57) ABSTRACT

Embodiments provide a fused polycyclic compound and a light emitting element. The light emitting element includes a first electrode, a second electrode disposed on the first electrode, and an emission layer disposed between the first electrode and the second electrode and including the fused polycyclic compound. The fused polycyclic compound is represented by Formula 1, which is explained in the specification:

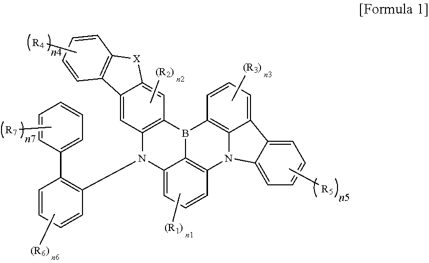

### CROSS-REFERENCE TO RELATED APPLICATION(S)

This application claims priority to and benefits of Korean Patent Application No. 10-2024-0000501 under 35 U.S.C. § 119, filed on Jan. 2, 2024, in the Korean Intellectual Property Office the entire contents of which are incorporated herein by reference.

### BACKGROUND

### 1. Technical Field

The disclosure relates to a light emitting element, a fused polycyclic compound used for the same, and a display device including the same.

### 2. Description of the Related Art

Ongoing development continues for an organic electroluminescence display as an image display. An organic electroluminescence display is different from a liquid crystal display in that it is a so-called self-luminescent display in which holes and electrons respectively injected from a first electrode and a second electrode recombine in an emission layer. Thus, a light emitting material including an organic compound in the emission layer emits light to achieve display.

In the application of an organic electroluminescence device to a display device, there is a constant demand for a lower driving voltage, increased emission efficiency, and a longer lifetime of the organic electroluminescence device. Continuous development is required on materials for an organic electroluminescence device that are capable of stably achieving such characteristics.

In order to implement an organic electroluminescence device with high efficiency, technologies pertaining to phosphorescence emission that uses energy in a triplet state, or to fluorescence emission in which singlet excitons are generated by the collision of triplet excitons (triplet-triplet annihilation, TTA) are being developed. Development is presently directed to a thermally activated delayed fluorescence (TADF) material that utilizes delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An embodiment provides a light emitting element having improved emission efficiency and element lifetime.

Another embodiment provides a fused polycyclic compound which is capable of improving the emission efficiency and element lifetime of a light emitting element.

Another embodiment provides a display device having excellent display quality by including a light emitting element having improved emission efficiency and lifetime.

According to an embodiment, a light emitting element may include a first electrode, a second electrode disposed on the first electrode, and an emission layer disposed between the first electrode and the second electrode, wherein the emission layer may include a first compound represented by Formula 1.

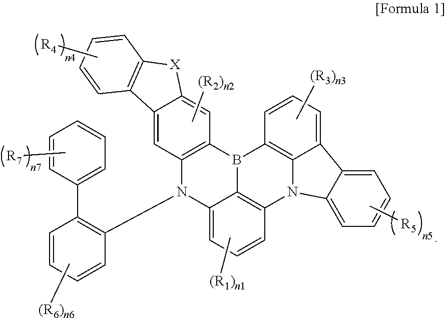

In Formula 1, X may be O, S, or N(R₈); R₁ to R₇ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; R₈ may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; n1 and n3 may each independently be an integer from 0 to 3; n2 may be an integer from 0 to 2; n4 to n6 may each independently be an integer from 0 to 4; and n7 may be an integer from 0 to 5.

In an embodiment, the first compound may be represented by one of Formula 2-1 to Formula 2-3.

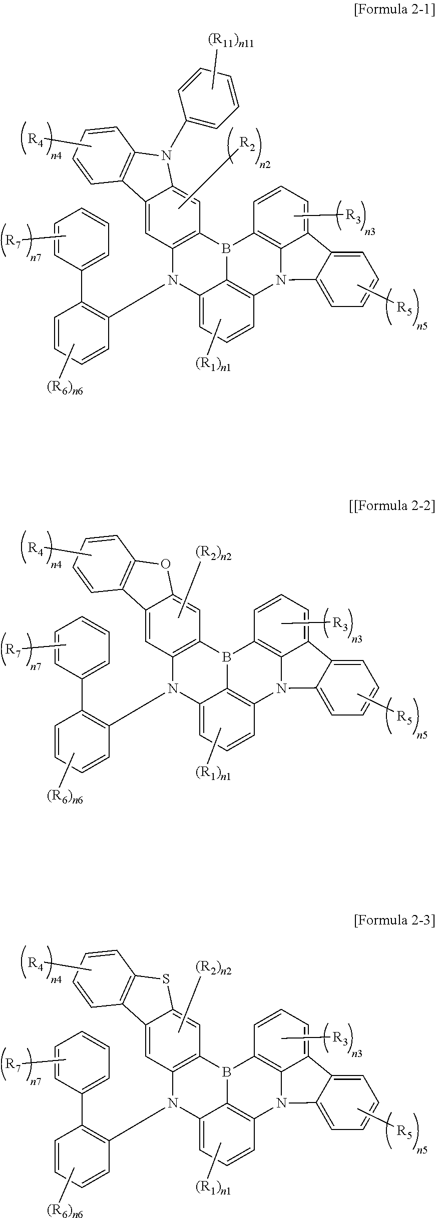

In Formula 2-1 to Formula 2-3, Rn may be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; and n11 may be an integer from 0 to 5.

In Formula 2-1 to Formula 2-3, R₁ to R₇ and n1 to n7 are the same as defined in Formula 1.

In an embodiment, the first compound may be represented by Formula 3-1 or Formula 3-2.

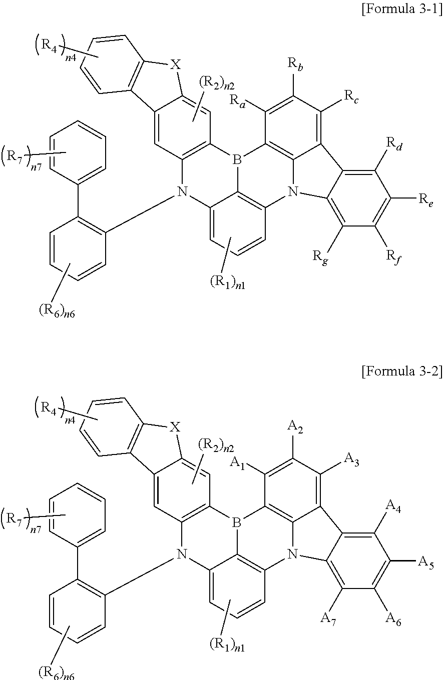

In Formula 3-1 and Formula 3-2, Rₐ to R_{g} may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
provided that: at least one of Rₐ to R_{g} may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; or at least one pair of adjacent groups among Rₐ to R_{g} may be positions where a moiety represented by Formula 4 is fused, and
A₁ to A₇ may each independently be a hydrogen atom or a deuterium atom.

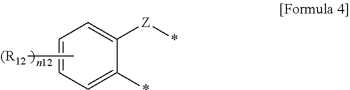

In Formula 4, -* are positions which may be fused with a pair of adjacent groups among Rₐ to R_{g} in Formula 3-1; Z may be O, S, N(R₁₃), or C(R₁₄)(R₁₅); R₁₂ to R₁₅ may each independently be a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; and n12 may be an integer from 0 to 4.

In Formula 3-1 and Formula 3-2, X, R₁, R₂, R₄, R₆, R₇, n1, n2, n4, n6, and n7 are the same as defined in Formula 1.

In an embodiment, in Formula 3-1, at least one of Rₐ to R_{g} may be a substituted or unsubstituted t-butyl group, a substituted or unsubstituted phenyl group, or a substituted or unsubstituted biphenyl group.

In an embodiment, the first compound may be represented by Formula 5.

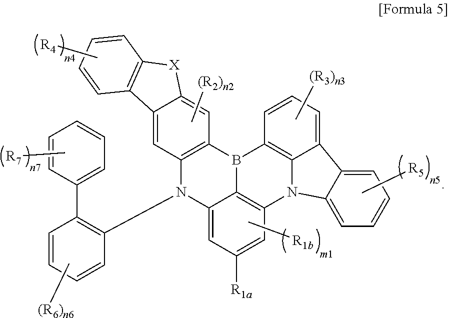

In Formula 5, R₁ₐ may be a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; Rib may be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; and m1 may be an integer from 0 to 2.

In Formula 5, X, R₂ to R₇, and n2 to n7 are the same as defined in Formula 1.

In an embodiment, in Formula 5, R₁ₐ may be a substituted or unsubstituted isopropyl group, a substituted or unsubstituted t-butyl group, a substituted or unsubstituted diphenylamine group, a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted fluorenyl group, a substituted or unsubstituted pyridine group, a substituted or unsubstituted triazine group, a substituted or unsubstituted carbazole group, a substituted or unsubstituted dibenzofuran group, a substituted or unsubstituted dibenzothiophene group, or a substituted or unsubstituted xanthene group.

In an embodiment, the first compound may be represented by Formula 6.

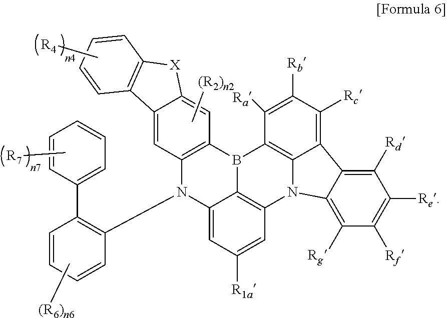

In Formula 6, Rₐ′ to R_{g}′ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,

provided that: at least one of Rₐ′ to R_{c}′ and at least one of R_{d}′ to R_{g}′ may each independently be a substituted or unsubstituted alkyl group of 1 to 10 carbon atoms, or a substituted or unsubstituted aryl group of 6 to 15 ring-forming carbon atoms; or a pair of adjacent groups among Rₐ′ to R_{g}′ may be positions where a moiety represented by Formula 7 is fused, and

R₁ₐ′ may be a substituted or unsubstituted alkyl group of 1 to 10 carbon atoms, or a group represented by one of Formula A-1 to Formula A-11.

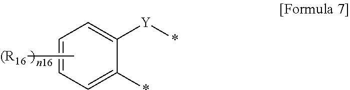

In Formula 7, -* are positions which may be fused with a pair of adjacent groups among Rₐ′ to R_{g}′ in Formula 6; Y may be O, S, N(R₁₇), or C(R₁₈)(R₁₉); R₁₆ to R₁₉ may each independently be a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; and n16 may be an integer from 0 to 4.

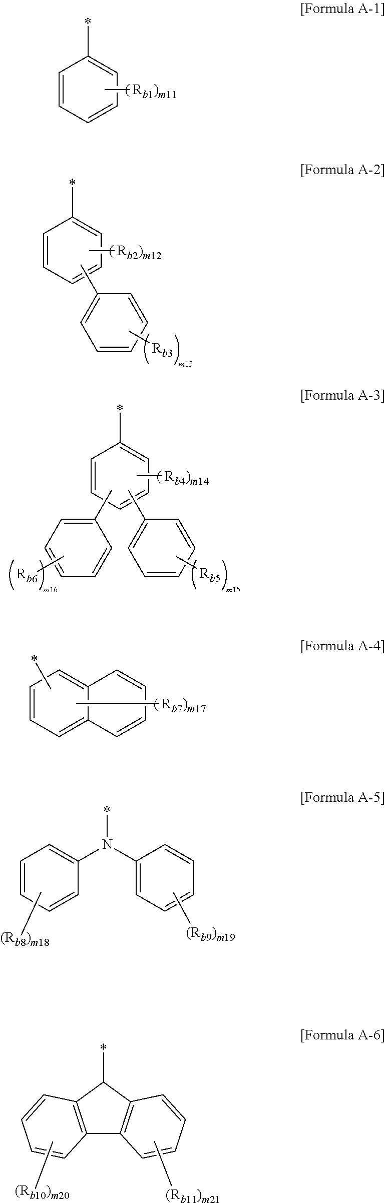

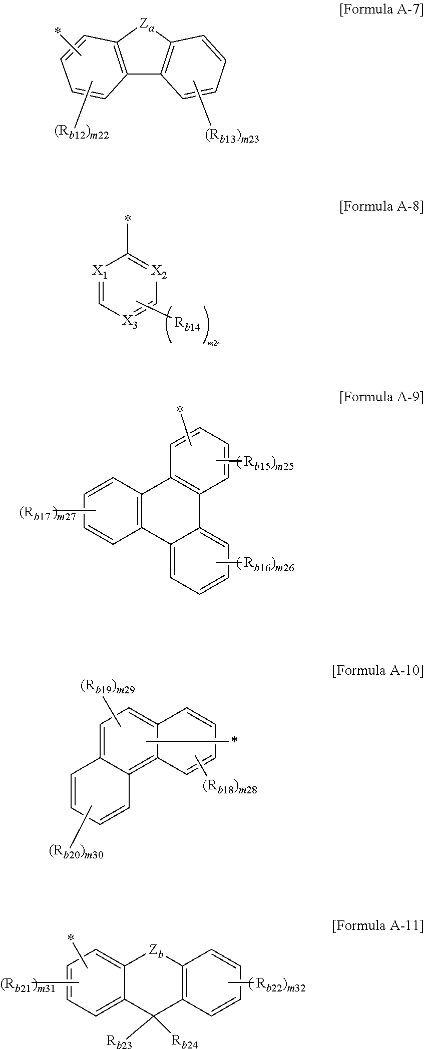

In Formula A-1 to Formula A-11, Zₐ and Z_{b} may each independently be O, S, or N(R_{b25}); at least one of X₁ to X₃ may each be N, the remainder of X₁ to X₃ may each independently be C(R_{b26}); R_{b1} to R_{b26} may each independently be a hydrogen atom, a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; m11, m13, m15, m16, m18, and m19 may each independently be an integer from 0 to 5; m12, m20, m21, m23, m26, m27, m28, m30, and m32 may each independently be an integer from 0 to 4; m14, m22, m25, and m31 may each independently be an integer from 0 to 3; m17 may be an integer from 0 to 7; m24 and m29 may each independently be an integer from 0 to 2; a sum of m28 and m29 may be 5 or less; and -* is a position connected with Formula 6.

In Formula 6, X, R₂, R₄, R₆, R₇, n2, n4, n6, and n7 are the same as defined in Formula 1.

In an embodiment, the first compound may be represented by Formula 8.

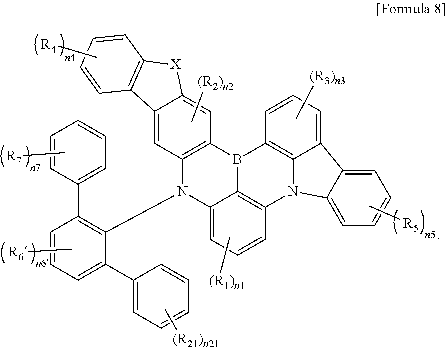

In Formula 8, R₆′ and R₂₁ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; n6′ may be an integer from 0 to 3; and n21 may be an integer from 0 to 5.

In Formula 8, X, R₁ to R₅, R₇, n1 to n5, and n7 are the same as defined in Formula 1.

In an embodiment, the emission layer may emit green light.

In an embodiment, the emission layer may further include at least one of a second compound represented by Formula HT-1, a third compound represented by Formula ET-1, and a fourth compound represented by Formula D-1.

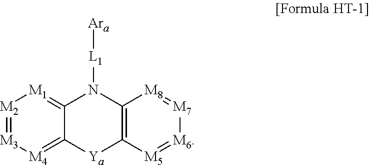

In Formula HT-1, M₁ to M₈ may each independently be N or C(R₅₁); L₁ may be a direct linkage, a substituted or unsubstituted arylene group of 6 to 30 ring-forming carbon atoms, or a substituted or unsubstituted heteroarylene group of 2 to 30 ring-forming carbon atoms; Yₐ may be a direct linkage, C(R₅₂)(R₅₃), or Si(R₅₄)(R₅₅); Arₐ may be a substituted or unsubstituted aryl group of 6 to 30 ring-forming carbon atoms, or a substituted or unsubstituted heteroaryl group of 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring.

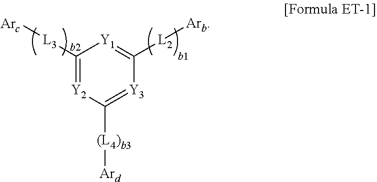

In Formula ET-1, at least one of Y₁ to Y₃ may each be N; the remainder of Y₁ to Y₃ may each independently be C(R₅₆); R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; b1 to b3 may each independently be an integer from 0 to 10; Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; and L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms.

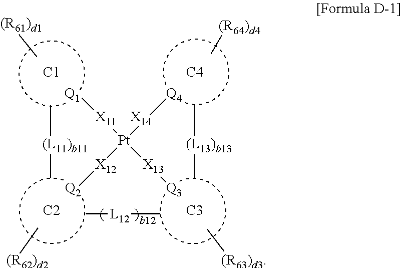

In Formula D-1, Q₁ to Q₄ may each independently C or N; C1 to C4 may each independently be a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms; X₁₁ to X₁₄ may each independently be a direct linkage or *—O—*; L₁₁ to L₁₃ may each independently be a direct linkage, *—O—*, *—S—*,

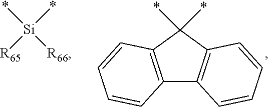

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms; and d1 to d4 may each independently be an integer from 0 to 4.

According to an embodiment, a display device may include a circuit layer disposed on a base layer, and a display element layer disposed on the circuit layer and including a light emitting element, wherein
the light emitting element may include a first electrode, a second electrode disposed on the first electrode, and an emission layer disposed between the first electrode and the second electrode; and the emission layer may include the first compound represented by Formula 1.

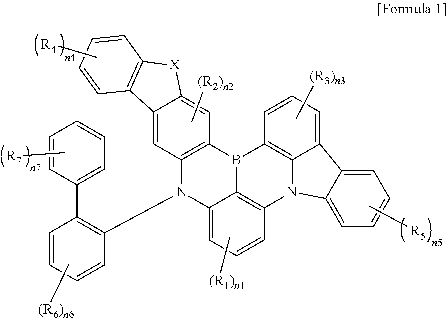

In Formula 1, X may be O, S, or N(R₈); R₁ to R₇ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; R₈ may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring; n1 and n3 may each independently be an integer from 0 to 3; n2 may be an integer from 0 to 2; n4 to n6 may each independently be an integer from 0 to 4; and n7 may be an integer from 0 to 5.

In an embodiment, the light emitting element may further include a capping layer disposed on the second electrode; and the capping layer may have a refractive index equal to or greater than about 1.6, with respect to light in a wavelength range of about 550 nm to about 660 nm.

In an embodiment, the display device may further include a light controlling layer disposed on the display element layer, the light controlling layer including a quantum dot; the light emitting element may emit first color light; and the light controlling layer may include a first light controlling part including a first quantum dot that converts the first color light into second color light, which has a longer wavelength range than the first color light, a second light controlling part including a second quantum dot that converts the first color light into third color light, which has a longer wavelength range than the first color light and the second color light, and a third light controlling part that transmits the first color light.

In an embodiment, the display device may further include a color filter layer disposed on the light controlling layer; and the color filter layer may include a first filter that transmits the second color light, a second filter that transmits the third color light, and a third filter that transmits the first color light.

According to an embodiment, a fused polycyclic compound may be represented by Formula 1, which is explained herein.

In an embodiment, the fused polycyclic compound represented by Formula 1 may be represented by Formula 3-1 or Formula 3-2, which are explained herein.

In an embodiment, the fused polycyclic compound represented by Formula 1 may be represented by Formula 5, which is explained herein.

In an embodiment, the fused polycyclic compound represented by Formula 1 may be represented by Formula 6, which is explained herein.

In an embodiment, the fused polycyclic compound represented by Formula 1 may be represented by Formula 8, which is explained herein.

In an embodiment, the fused polycyclic compound represented by Formula 1 may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic diagram of a vehicle including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “combined with an adjacent group to form a ring” may be interpreted as a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being combined with each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be combined with each other to form a spiro structure. Examples of a substituted fluorenyl group may include the groups shown below. However, embodiments are not limited thereto.

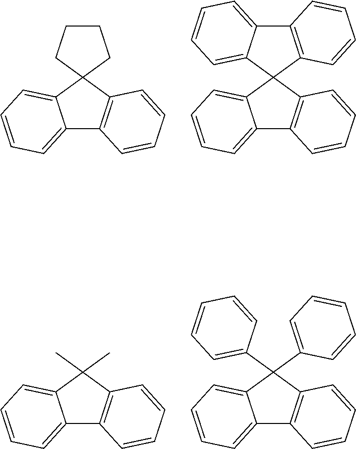

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 60, 2 to 50, 2 to 40, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

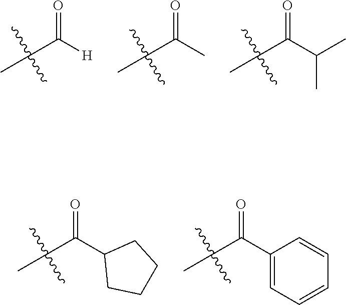

In the specification, the number of carbon atoms in a sulfinyl group or in a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

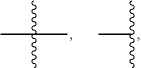

and -* each represent a bond to a neighboring atom in a corresponding formula or moiety.

Hereinafter, embodiments will be described with reference to the accompanying drawings.

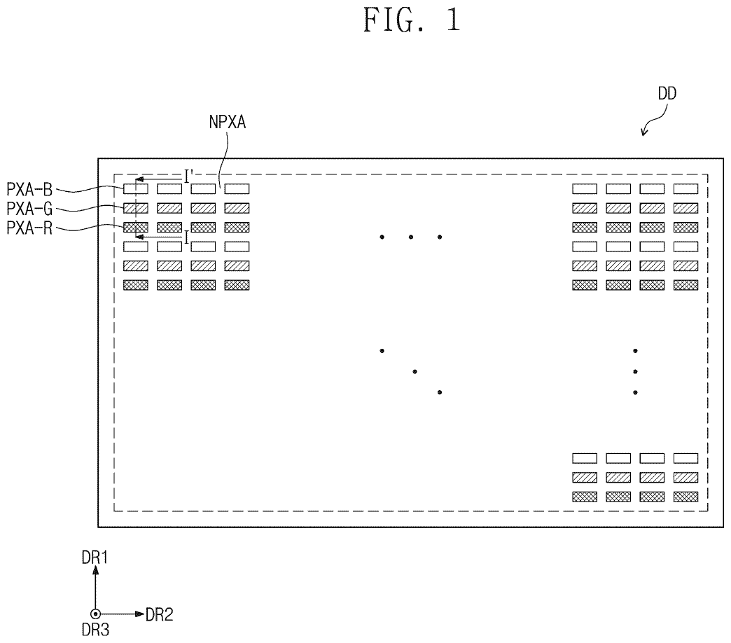

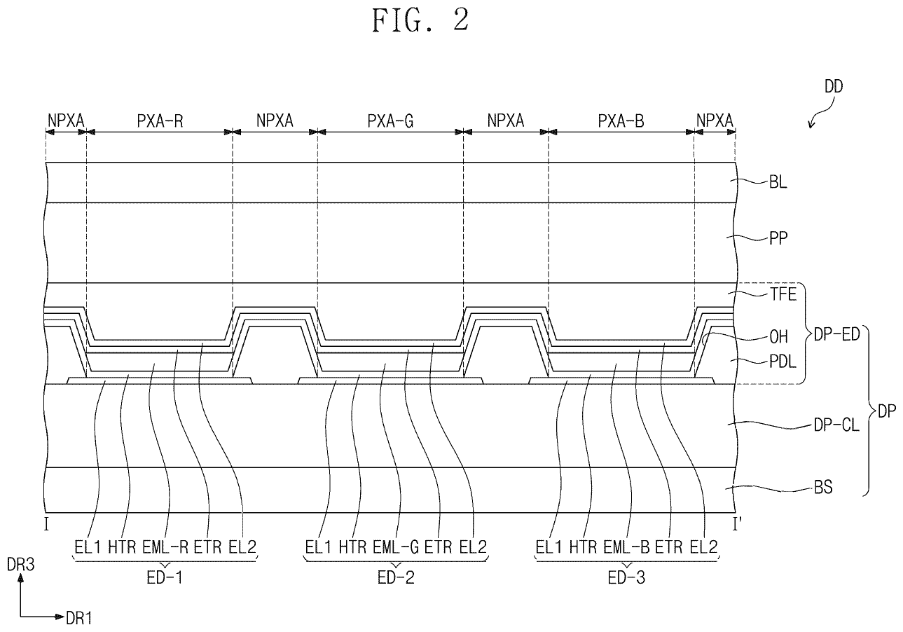

FIG. 1 is a schematic plan view of a display device DD according to an embodiment. FIG. 2 is a schematic cross-sectional view of a display device DD according to an embodiment. FIG. 2 is a schematic cross-sectional view illustrating a part taken along virtual line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

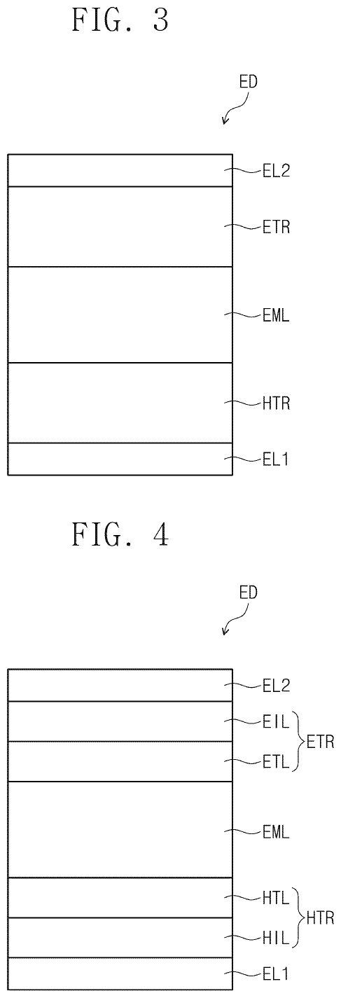

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3, respectively.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. Embodiments provide a light emitting element ED which may include a first electrode EL1, a second electrode EL2 oppositely disposed to the first electrode EL1, and at least one functional layer disposed between the first electrode EL1 and the second electrode EL2. The light emitting element ED may include a fused polycyclic compound according to an embodiment, which will be explained later, in the at least one functional layer.

In an embodiment, the light emitting element ED may include a hole transport region HTR, an emission layer EML, an electron transport region ETR, or the like, as the at least one functional layer. In an embodiment shown in FIG. 3, a light emitting element ED may include a first electrode EL1, a hole transport region HTR, an emission layer EML, an electron transport region ETR, and a second electrode EL2.

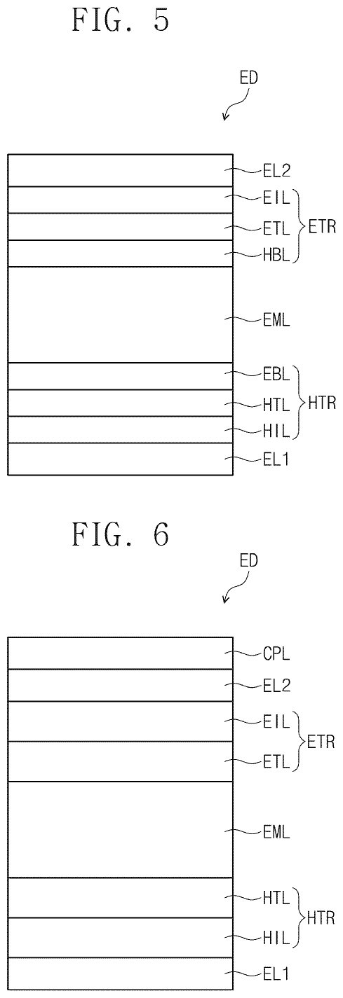

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

A light emitting element ED according to an embodiment may include a fused polycyclic compound according to an embodiment, which will be explained later, in the at least one functional layer. In the light emitting element ED, at least one of the hole transport region HTR, the emission layer EML, and the electron transport region ETR may include the fused polycyclic compound according to an embodiment. For example, in the light emitting element ED, the emission layer EML may include the fused polycyclic compound.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

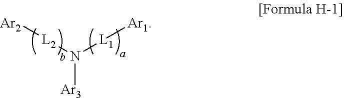

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

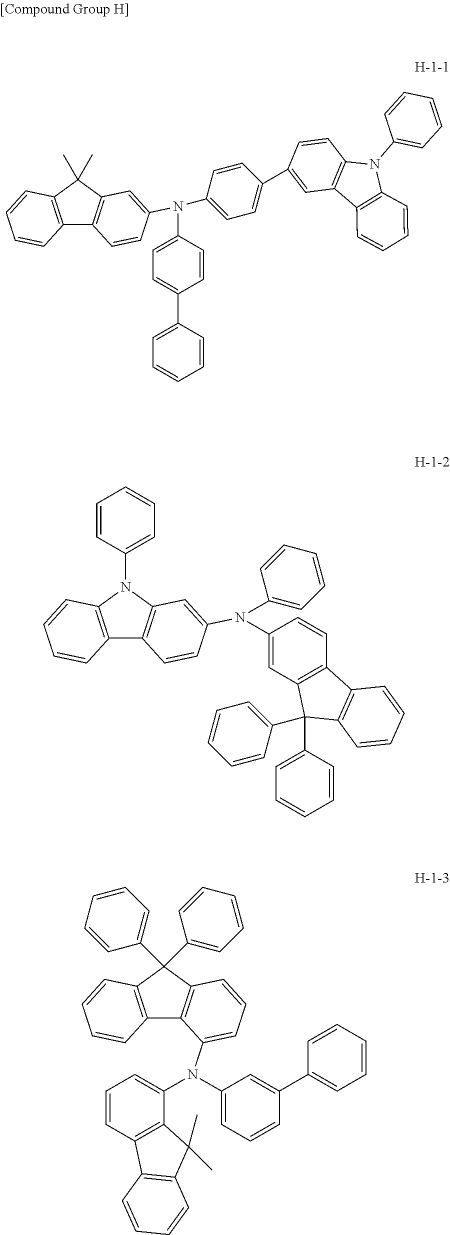 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

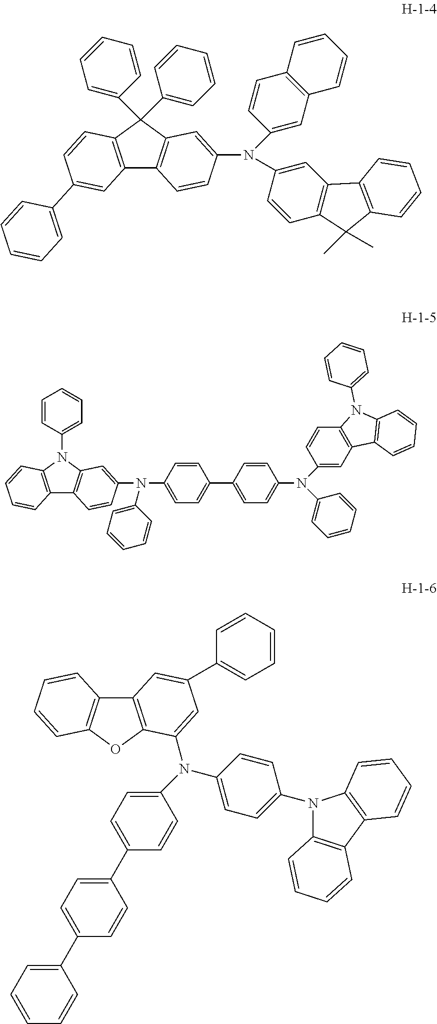 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

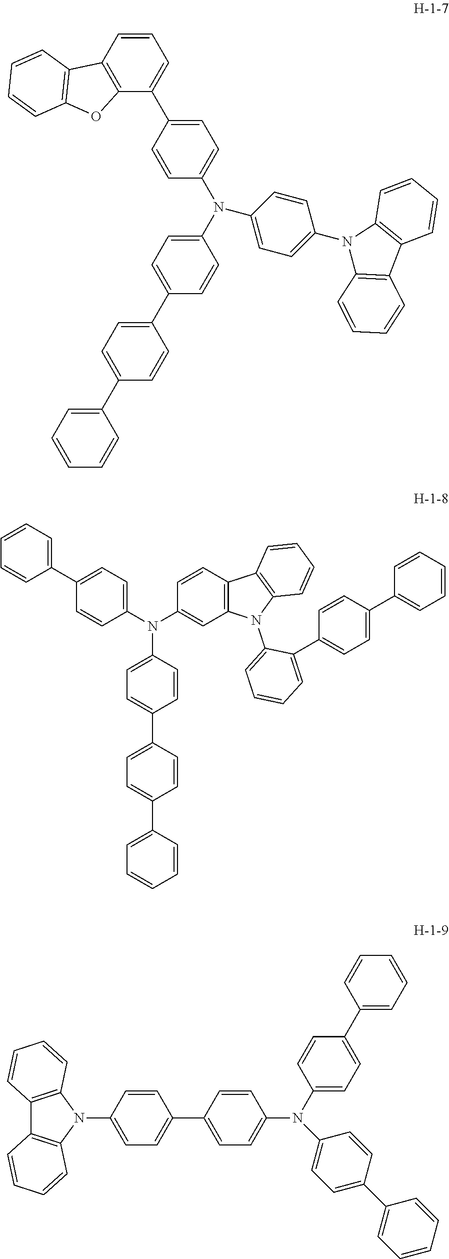 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

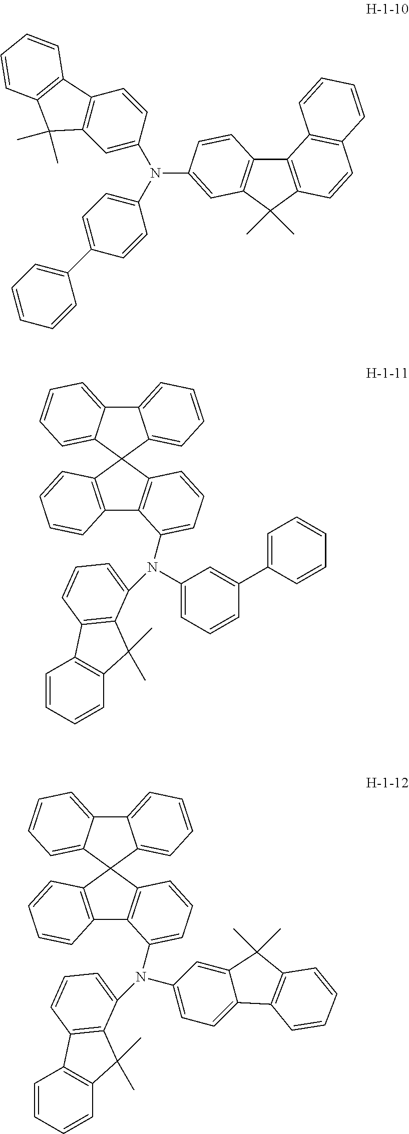 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

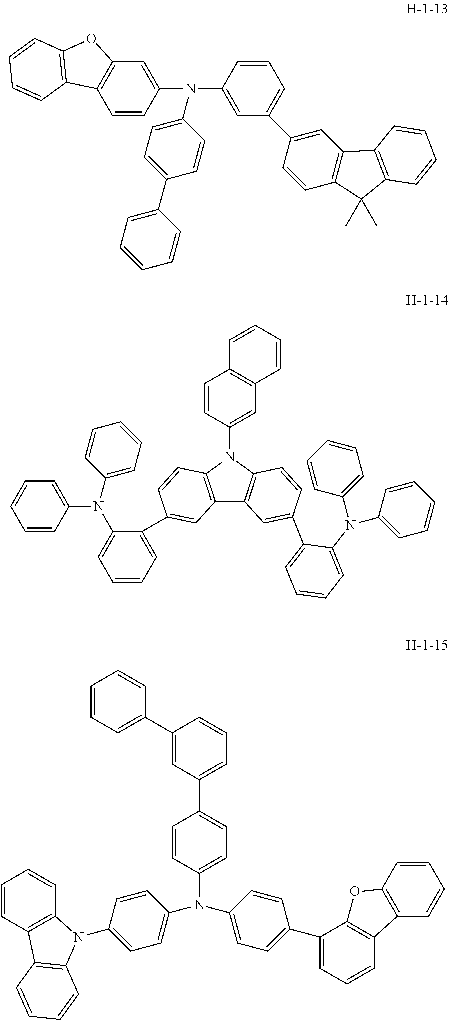 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

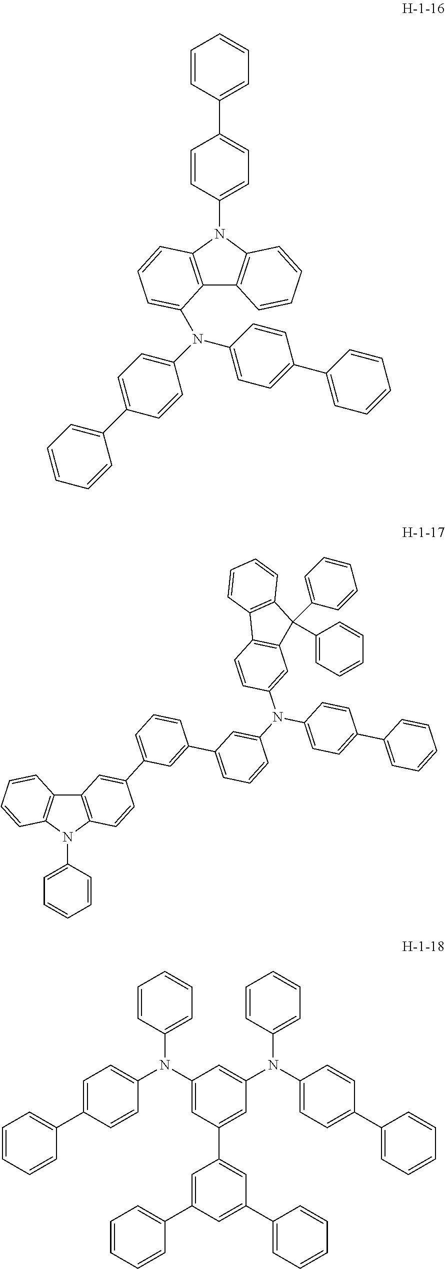 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

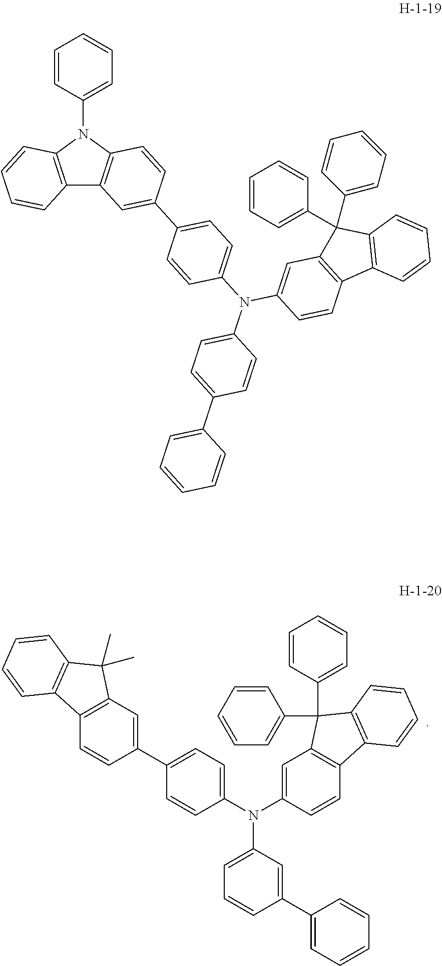 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphe)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

The light emitting element ED according to an embodiment may include a fused polycyclic compound represented by Formula 1 in at least one functional layer disposed between the first electrode EL1 and the second electrode EL2. In the light emitting element ED, the emission layer EML may include the fused polycyclic compound according to an embodiment. In an embodiment, the emission layer EML may include the fused polycyclic compound as a dopant. The fused polycyclic compound may be a dopant material of the emission layer EML. In the specification, the fused polycyclic compound according to an embodiment may be referred to as a first compound.

The fused polycyclic compound may include a fused ring core in which five rings are fused together, wherein the fused ring core includes a boron atom and first and second nitrogen atoms, and may have a structure in which two aromatic hydrocarbon rings are connected with the fused ring core. In the fused polycyclic compound, two aromatic hydrocarbon rings are connected with the fused ring core to form four additional fused rings.

In an embodiment, the fused ring core of the fused polycyclic compound may form five rings according to the connection of three benzene rings via the boron atom, the first nitrogen atom, and the second nitrogen atom. In the fused ring core, the three benzene rings may be connected with the boron atom at the center, a first benzene ring and a second benzene ring among the three benzene rings may be connected via the first nitrogen atom, and the remaining third benzene ring may be connected with the first benzene ring via the second nitrogen atom. The boron atom and the first and second nitrogen atoms may each be connected with the first benzene ring.

In an embodiment, two aromatic hydrocarbon rings included in the fused polycyclic compound may be connected with the fused ring core to form additional fused rings. The fused polycyclic compound according to an embodiment may have a structure such that a fourth benzene ring, which is one of the two aromatic hydrocarbon rings, is connected with the second benzene ring of the fused ring core, and a first heteroatom may be disposed as a connecting group between the second benzene ring and the fourth benzene ring. For example, the first heteroatom may be connected with the second benzene ring among three benzene rings included in the fused ring core, and the fourth benzene ring may be connected with the second benzene ring via the first heteroatom. The first heteroatom may be connected with a carbon atom of the second benzene ring at a para position to the first nitrogen atom of the fused ring core. Through the connection of the fourth benzene ring to the fused ring core, a tricyclic heterocycle including the second benzene ring, the first heteroatom, and the fourth benzene ring may be formed. The second benzene ring, a five-membered heterocycle including the first heteroatom, and the fourth benzene ring may be fused to form a tricyclic fused heterocycle. In an embodiment, the first heteroatom may be a nitrogen (N) atom, an oxygen (O) atom, or a sulfur (S) atom.

A fifth benzene ring among the two aromatic hydrocarbon rings may be connected with the third benzene ring and the second nitrogen atom of the fused ring core to form an additional fused ring. The fifth benzene ring may be connected with the second nitrogen atom of the fused ring core. The fifth benzene ring may also be connected such that a bond is formed between a carbon atom of the third benzene ring at an ortho position to the second nitrogen atom, and a carbon atom of the fifth benzene ring at an ortho position to the second nitrogen. The fifth benzene ring may be fused with the fused ring core, thereby forming a carbazone ring that includes the third benzene ring, the second nitrogen atom, and the fifth benzene ring.

The fused polycyclic compound according to an embodiment may include a first substituent connected with the fused ring core. The first substituent may be connected with the first nitrogen atom of the fused ring core in the fused polycyclic compound. The first substituent may include a benzene moiety, and a first sub-substituent that is bonded to a carbon atom at a specific position of the benzene moiety. The first substituent may include the benzene moiety connected with the first nitrogen atom of the fused ring core, and the first substituent may have a structure in which the first sub-substituent is connected at an ortho position to the first nitrogen atom. The first sub-substituent may be a substituted or unsubstituted aryl group of 6 to 30 ring-forming carbon atoms. For example, the first sub-substituent may be a substituted or unsubstituted phenyl group.

The light emitting element ED according to an embodiment may include the fused polycyclic compound according to an embodiment. The fused polycyclic compound according to an embodiment may be represented by Formula 1:

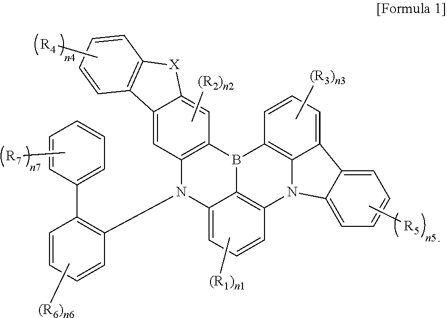

The fused polycyclic compound according to an embodiment, which is represented by Formula 1, may include a fused ring core formed by five rings that are fused together with a first boron atom and first and second nitrogen atoms, and the fused polycyclic compound may have a structure in which two aromatic hydrocarbon rings are connected with the fused ring core. In Formula 1, the benzene ring that includes a substituent represented by R₁ may correspond to the above-described first benzene ring, the benzene ring that includes a substituent represented by R₂ may correspond to the above-described second benzene ring, and the benzene ring that includes a substituent represented by R₃ is substituted may correspond to the above-described third benzene ring. In Formula 1, the benzene ring that includes a substituent represented by R₄ may correspond to the above-described fourth benzene ring, and the benzene ring that includes a substituent represented by R₅ may correspond to the above-described fifth benzene ring. In Formula 1, a biphenyl group that includes substituents represented by R₆ and R₇ may correspond to the above-described first substituent.

In Formula 1, X may be O, S, or N(R₈).

In Formula 1, R₁ to R₇ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R₁ to R₇ may each independently be a hydrogen atom, a substituted or unsubstituted methyl group, a substituted or unsubstituted isopropyl group, a substituted or unsubstituted t-butyl group, a substituted or unsubstituted diphenylamine group, a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted fluorenyl group, a substituted or unsubstituted pyridine group, a substituted or unsubstituted triazine group, a substituted or unsubstituted carbazole group, a substituted or unsubstituted dibenzofuran group, a substituted or unsubstituted dibenzothiophene group, or a substituted or unsubstituted xanthene group.

In an embodiment, at least one of R₁ to R₇ may be a group selected from Substituent Group 1.

In Formula 1, R₈ may be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. In an embodiment, R₈ may be a substituted or unsubstituted aryl group of 6 to 30 ring-forming carbon atoms. For example, R₈ may be a substituted or unsubstituted phenyl group.

In Formula 1, n1 and n3 may each independently be an integer from 0 to 3. If n1 and n3 are each 0, the fused polycyclic compound may not be substituted with R₁ and R₃, respectively. A case where n1 and n3 are each 3 and three groups of each of R₁ and R₃ are all hydrogen atoms may be the same as a case where n1 and n3 are each 0. If n1 and n3 are each 2 or more, multiple groups of each of R₁ and R₃ may all be the same, or at least one thereof may be different from the remainder.

In Formula 1, n2 may be an integer from 0 to 2. If n2 is 0, the fused polycyclic compound may not be substituted with R₂. A case where n2 is 2 and two R₂ groups are all hydrogen atoms may be the same as a case where n2 is 0. If n2 is 2, multiple R₂ groups may all be the same, or at least one thereof may be different from the remainder.

In Formula 1, n4 to n6 may each independently be an integer from 0 to 4. If n4 to n6 are each 0, the fused polycyclic compound may not be substituted with R₄ to R₆, respectively. A case where n4 to n6 are each 4 and four groups of each of R₄ to R₆ are all hydrogen atoms may be the same as a case where n4 to n6 are each 0. If n4 to n6 are each 2 or more, multiple groups of each of R₄ to R₆ may all be the same, or at least one thereof may be different from the remainder.

In Formula 1, n7 may be an integer from 0 to 5. If n7 is 0, the fused polycyclic compound may not be substituted with R₇. A case where n7 is 5 and five R₇ groups are all hydrogen atoms may be the same as a case where n7 is 0. If n7 is 2 or more, multiple R₇ groups may all be the same, or at least one thereof may be different from the remainder.

In an embodiment, the fused polycyclic compound represented by Formula 1 may be represented by one of Formula 2-1 to Formula 2-3:

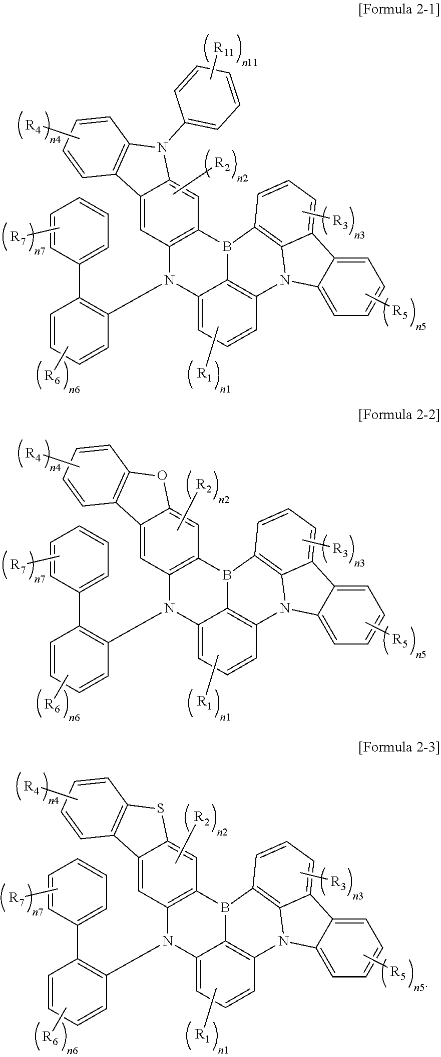

Formula 2-1 to Formula 2-3 each represent a case where X in Formula 1 is further defined.

In Formula 2-1, R₁₁ may be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R₁₁ may be a hydrogen atom.

In Formula 2-1, n11 may be an integer from 0 to 5. If n11 is 0, the fused polycyclic compound may not be substituted with Rn. A case where n11 is 5 and five R₁₁ groups are all hydrogen atoms may be the same as a case where n11 is 0. If n11 is 2 or more, multiple R₁₁ groups may all be the same, or at least one thereof may be different from the remainder.

In Formula 2-1 to Formula 2-3, R₁ to R₇ and n1 to n7 are the same as defined in Formula 1.

In an embodiment, the fused polycyclic compound represented by Formula 1 may be represented by Formula 3-1 or Formula 3-2:

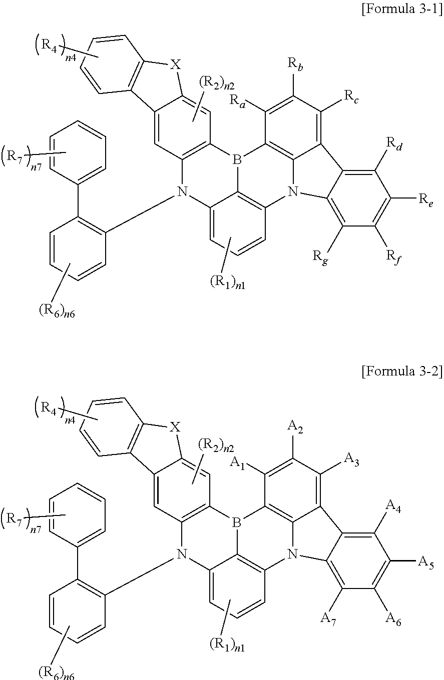

Formula 3-1 and Formula 3-2 each represent a case where R₃ and R₅ in Formula 1 are further defined.

In Formula 3-1, Rₐ to R_{g} may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
provided that: at least one of Rₐ to R_{g} may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; or at least one pair of adjacent groups among Rₐ to R_{g} may be positions where a substituent represented by Formula 4 is fused.

In an embodiment, in Formula 3-1, at least one of Rₐ to R_{g} may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, two of Rₐ to R_{g} may be substituted or unsubstituted t-butyl groups, substituted or unsubstituted phenyl groups, or substituted or unsubstituted biphenyl groups, and the remainder may be each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, the moiety represented by Formula 4 may be fused with at least one pair of adjacent groups among Rₐ to R_{g}. For example, the substituent represented by Formula 4 may be fused with any pair of adjacent groups among Rₐ to R_{g}, and the remainder of Rₐ to R_{g} may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, in Formula 3-1, at least one of Rₐ to R_{g} may each independently be a substituted or unsubstituted t-butyl group, a substituted or unsubstituted phenyl group, or a substituted or unsubstituted biphenyl group; or at least one pair of adjacent groups among Rₐ to R_{g} may be positions where the moiety represented by Formula 4 is fused.

In an embodiment, in Formula 3-1, at least one of Rₐ to R_{g} may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and the remainder may be hydrogen atoms. For example, two of Rₐ to R_{g} may be substituted or unsubstituted t-butyl groups, substituted or unsubstituted phenyl groups, or substituted or unsubstituted biphenyl groups, and the remainder may be hydrogen atoms.

In an embodiment, in Formula 3-1, the moiety represented by Formula 4 may be fused with any pair of adjacent groups among Rₐ to R_{g}, and the remainder of Rₐ to R_{g} that are not fused with the moiety represented by Formula 4 may each be a hydrogen atom.

In Formula 3-2, A₁ to A₇ may each independently be a hydrogen atom or a deuterium atom. For example, A₁ to A₇ may each be a hydrogen atom.

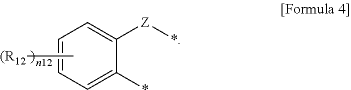

In Formula 4, -* may be positions fused with a pair of adjacent groups among Rₐ to R_{g} in Formula 3-1.

In Formula 4, Z may be O, S, N(R₁₃), or C(R₁₄)(R₁₅).

In Formula 4, R₁₂ to R₁₅ may each independently be a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R₁₂ may be a hydrogen atom, or a substituted or unsubstituted phenyl group, and R₁₃ to R₁₅ may each independently be a substituted or unsubstituted methyl group or a substituted or unsubstituted phenyl group.

In Formula 4, n12 may be an integer from 0 to 4. If n12 is 0, the fused polycyclic compound may not be substituted with R₁₂. A case where n12 is 4 and four R₁₂ groups are all hydrogen atoms may be the same as a case where n12 is 0. If n12 is 2 or more, multiple R₁₂ groups may all be the same, or at least one thereof may be different from the remainder.

In Formula 3-1 and Formula 3-2, X, R₁, R₂, R₄, R₆, R₇, n1, n2, n4, n6, and n7 are the same as defined in Formula 1.

In an embodiment, the fused polycyclic compound represented by Formula 1 may be represented by Formula 5:

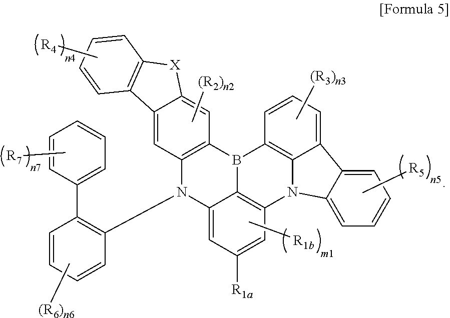

Formula 5 represents a case where R₁ in Formula 1 is further defined.

In Formula 5, R₁ₐ may be a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In an embodiment, in Formula 5, R₁ₐ may be a substituted or unsubstituted isopropyl group, a substituted or unsubstituted t-butyl group, a substituted or unsubstituted diphenylamine group, a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted fluorenyl group, a substituted or unsubstituted pyridine group, a substituted or unsubstituted triazine group, a substituted or unsubstituted carbazole group, a substituted or unsubstituted dibenzofuran group, a substituted or unsubstituted dibenzothiophene group, or a substituted or unsubstituted xanthene group.

In Formula 5, R_{1b} may be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R_{1b} may be a hydrogen atom.

In Formula 5, m1 may be an integer from 0 to 2. If m1 is 0, the fused polycyclic compound may not be substituted with R_{1b}. A case where m1 is 2 and two R_{1b} groups are hydrogen atoms may be the same as a case where m1 is 0. If m1 is 2, multiple R_{1b} groups may be the same, or at least one thereof may be different from the remainder.

In Formula 5, X, R₂ to R₇, and n2 to n7 are the same as defined in Formula 1.

In an embodiment, the fused polycyclic compound represented by Formula 1 may be represented by Formula 6:

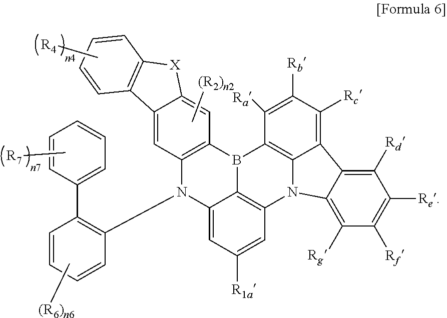

In Formula 6, Rₐ′ to R_{g}′ may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,

provided that: at least one of Rₐ′ to R_{c}′ and at least one of R_{d}′ to R_{g}′ may each independently be a substituted or unsubstituted alkyl group of 1 to 10 carbon atoms or a substituted or unsubstituted aryl group of 6 to 15 ring-forming carbon atoms; or a pair of adjacent groups among Rₐ′ to R_{g}′ may be positions where a moiety represented by Formula 7 is fused.

In an embodiment, in Formula 6, at least one of Rₐ′ to R_{c}′ and at least one of R_{d}′ to R_{g}′ may each independently be a substituted or unsubstituted t-butyl group, a substituted or unsubstituted phenyl group, or a substituted or unsubstituted biphenyl group; or a pair of adjacent groups among Rₐ′ to R_{g}′ may be positions where the moiety represented by Formula 7 is fused.

In Formula 6, R₁ₐ′ may be a substituted or unsubstituted alkyl group of 1 to 10 carbon atoms, or a group represented by one of Formula A-1 to Formula A-11. For example, R₁ₐ′ may be a substituted or unsubstituted methyl group, a substituted or unsubstituted isopropyl group, or a substituted or unsubstituted t-butyl group, or a groups represented by one of Formula A-1 to Formula A-11.

In an embodiment, in Formula 6, R₁ₐ′ may be a group selected from Substituent Group 1.

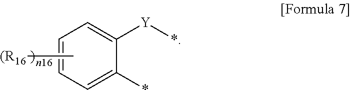

In Formula 7, -* may be positions which are fused with a pair of adjacent groups among Rₐ′ to R_{g}′ in Formula 6.

In Formula 7, Y may be O, S, N(R₁₇), or C(R₁₈)(R₁₉).

In Formula 7, R₁₆ to R₁₉ may each independently be a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R₁₆ may be a hydrogen atom, or a substituted or unsubstituted phenyl group, and R₁₇ to R₁₉ may each independently be a substituted or unsubstituted methyl group or a substituted or unsubstituted phenyl group.

In Formula 7, n16 may be an integer from 0 to 4. If n16 is 0, the fused polycyclic compound may not be substituted with R₁₆. A case where n16 is 4 and four R₁₆ groups are all hydrogen atoms may be the same as a case where n16 is 0. If n16 is 2 or more, multiple R₁₆ groups may all be the same, or at least one thereof may be different from the remainder.

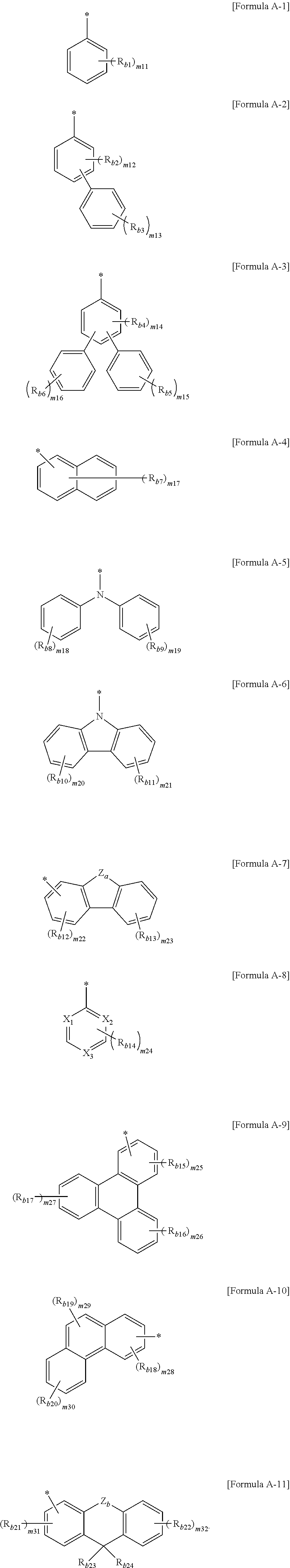

In Formula A-7 and Formula A-11, Zₐ and Z_{b} may each independently be O, S, or N(R_{b25}).

In Formula A-8, at least one of X₁ to X₃ may each be N, and the remainder of X₁ to X₃ may each independently be C(R_{b26}). For example, one of X₁ to X₃ may be N, and the remainder of X₁ to X₃ may each independently be C(R_{b26}), such that the group represented by Formula A-8 may include a pyridine moiety. As another example, two of X₁ to X₃ may each be N, and the remainder of X₁ to X₃ may be C(R_{b26}), such that the group represented by Formula A-8 may include a pyrimidine moiety. As yet another example, X₁ to X₃ may each be N, such that the group represented by Formula A-8 may include a triazine moiety.

In Formula A-1 to Formula A-11, R_{b1} to R_{b26} may each independently be a hydrogen atom, a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{b1} to R_{b26} may each independently be a hydrogen atom, a substituted or unsubstituted methyl group, a substituted or unsubstituted t-butyl group, or a substituted or unsubstituted phenyl group.

In Formula A-1 to Formula A-11, m11, m13, m15, m16, m18, and m19 may each independently be an integer from 0 to 5; m12, m20, m21, m23, m26, m27, m28, m30, and m32 may each independently be an integer from 0 to 4; m14, m22, m25, and m31 may each independently be an integer from 0 to 3; m17 may be an integer from 0 to 7; m24 and m29 may each independently be an integer from 0 to 2; and a sum of m28 and m29 may be 5 or less.

If m11 to m32 are each 0, the fused polycyclic compound may not be substituted with R_{b1} to R_{b22}, respectively. A case where m11, m13, m15, m16, m18, and m19 are each 5 and five groups of each of R_{b1}, R_{b3}, R_{b5}, R_{b6}, R_{b8}, and R_{b9} are all hydrogen atoms may be the same as a case where m1, m13, m15, m16, m18, and m19 are each 0. A case where m12, m20, m21, m23, m26, m27, m28, m30, and m32 are each 4 and four groups of each of R_{b2}, R_{b10}, R_{b11}, R_{b13}, R_{b16}, R_{b17}, R_{b18}, R_{b20}, and R_{b22} are all hydrogen atoms may be the same as a case where m12, m20, m21, m23, m26, m27, m28, m30, and m32 are each 0. A case where m14, m22, m25, and m31 are each 3 and three groups of each of R_{b4}, R_{b12}, R_{b15}, and R_{b21} are all hydrogen atoms may be the same as a case where m14, m22, m25, and m31 are each 0. A case where m17 is 7 and seven groups of R_{b7} are all hydrogen atoms may be the same as a case where m17 is 0. A case where m24 and m29 are each 2 and two groups of each of R_{b14} and R_{b19} are all hydrogen atoms may be the same as a case where m24 and m29 are each 0. If m11 to m32 are each 2 or more, multiple groups of each of R_{b1} to R_{b22} may all be the same, or at least one thereof may be different from the remainder.

In Formula A-1 to Formula A-11, -* may be a position connected with Formula 6.

In Formula 6, X, R₂, R₄, R₆, R₇, n2, n4, n6, and n7 are the same as defined in Formula 1.

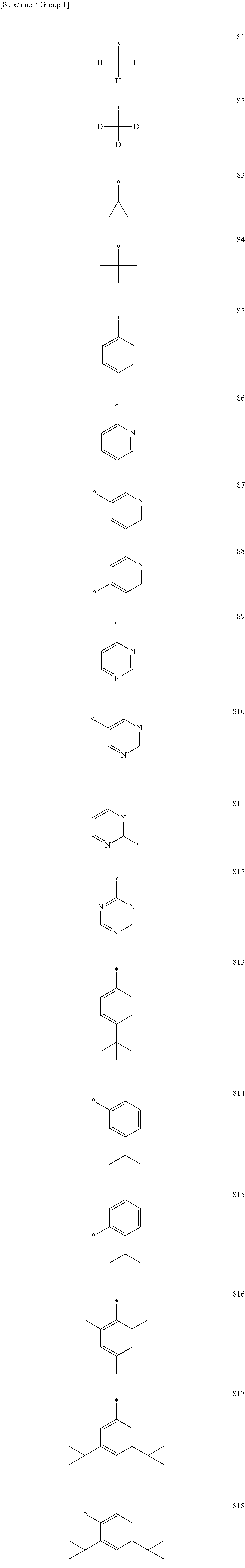

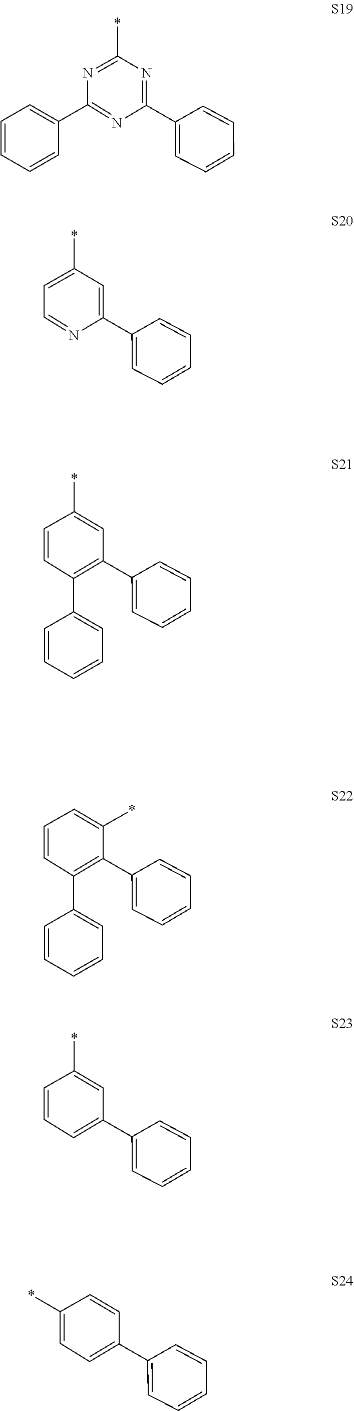 [SMILES: *c1nc(-c2ccccc2)nc(-c2ccccc2)n1 ; *c1ccnc(-c2ccccc2)c1 ; *c1ccc(-c2ccccc2)c(-c2ccccc2)c1 ; *c1cccc(-c2ccccc2)c1-c1ccccc1 ; *c1cccc(-c2ccccc2)c1 ; *c1ccc(-c2ccccc2)cc1]

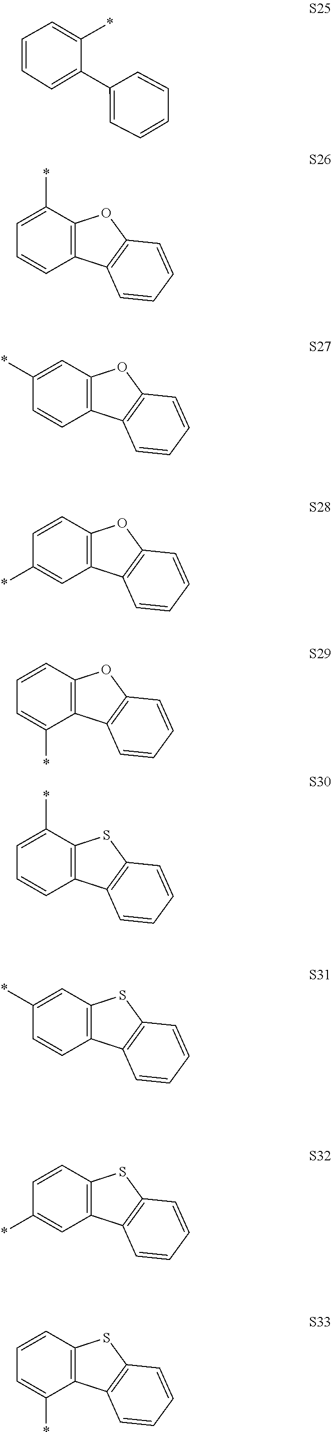

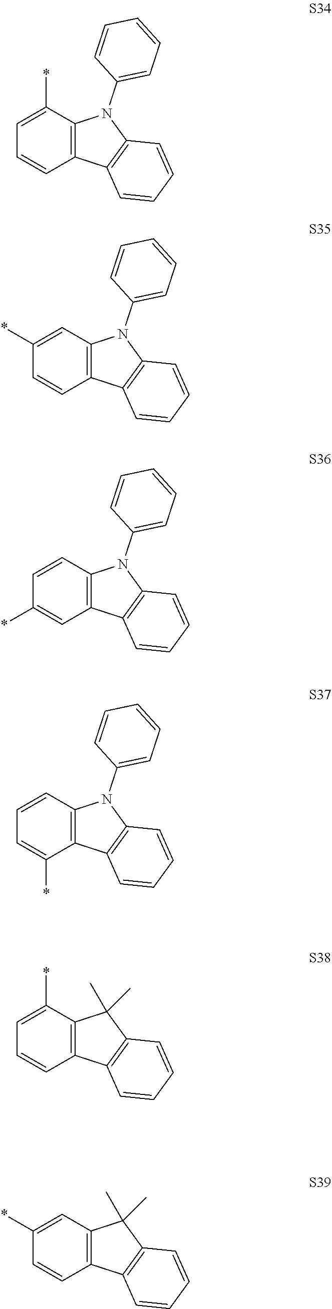

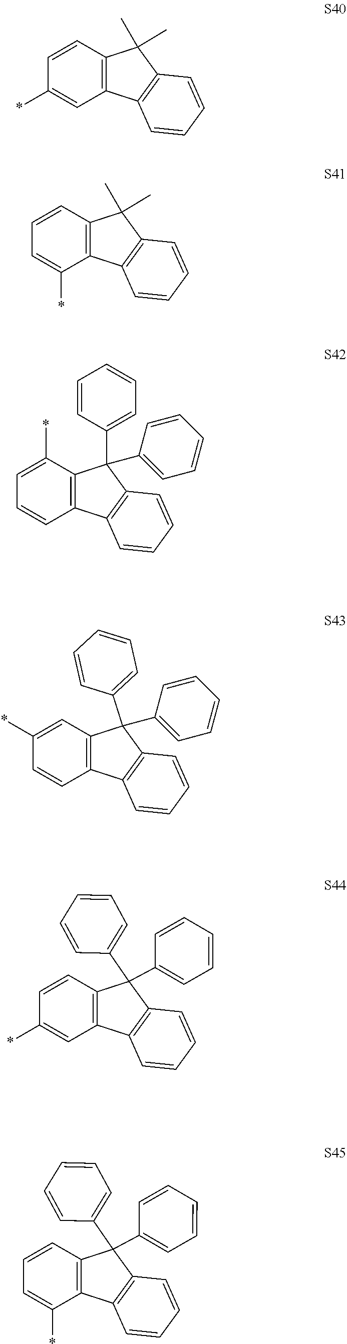 [SMILES: *c1ccc2c(c1)-c1ccccc1C2(C)C ; *c1cccc2c1-c1ccccc1C2(C)C ; *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1]

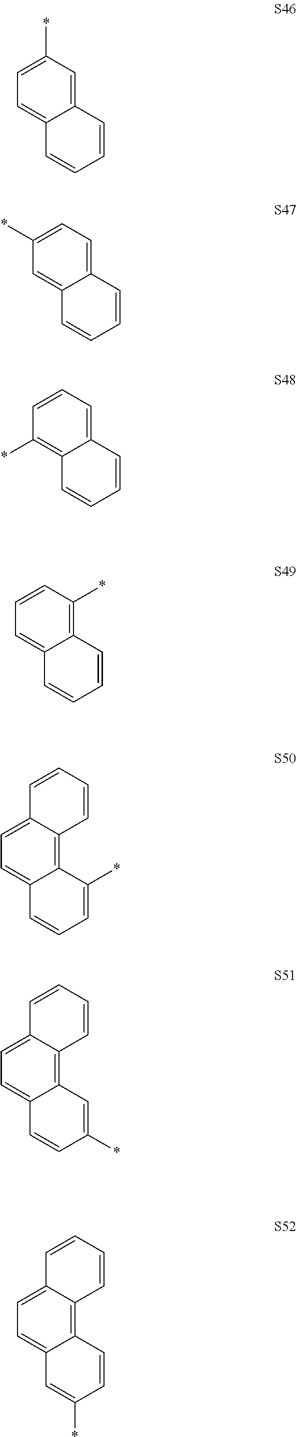

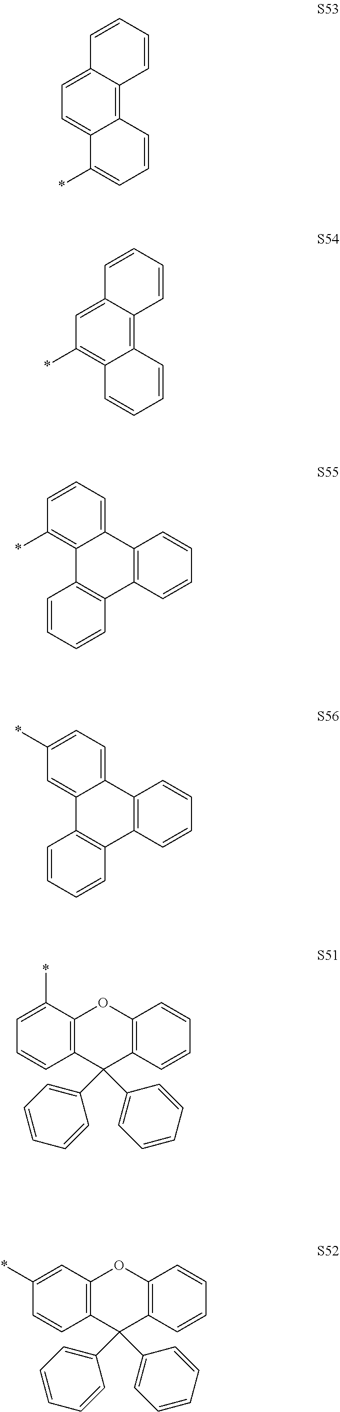 [SMILES: *c1cccc2c1ccc1ccccc12 ; *c1cc2ccccc2c2ccccc12 ; *c1cccc2c3ccccc3c3ccccc3c12 ; *c1ccc2c3ccccc3c3ccccc3c2c1 ; *c1cccc2c1Oc1ccccc1C2(c1ccccc1)c1ccccc1 ; *c1ccc2c(c1)Oc1ccccc1C2(c1ccccc1)c1ccccc1]

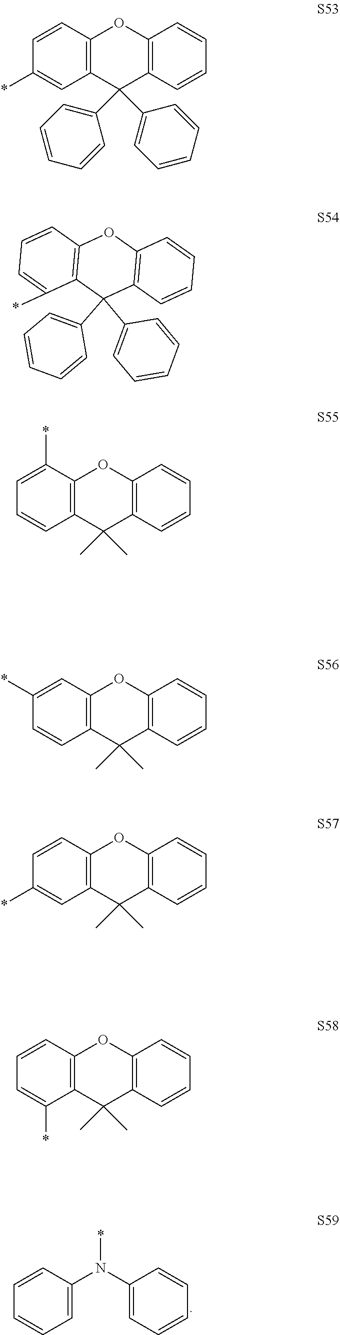

In an embodiment, the fused polycyclic compound represented by Formula 1 may include at least one deuterium atom as a substituent. The fused polycyclic compound represented by Formula 1 according to an embodiment may have a structure in which at least one hydrogen atom is substituted with a deuterium atom.

In an embodiment, the fused polycyclic compound may be any compound selected from Compound Group 1. In an embodiment, in the light emitting element ED, the at least one functional layer (for example, an emission layer EML) may include at least one fused polycyclic compound selected from Compound Group 1:

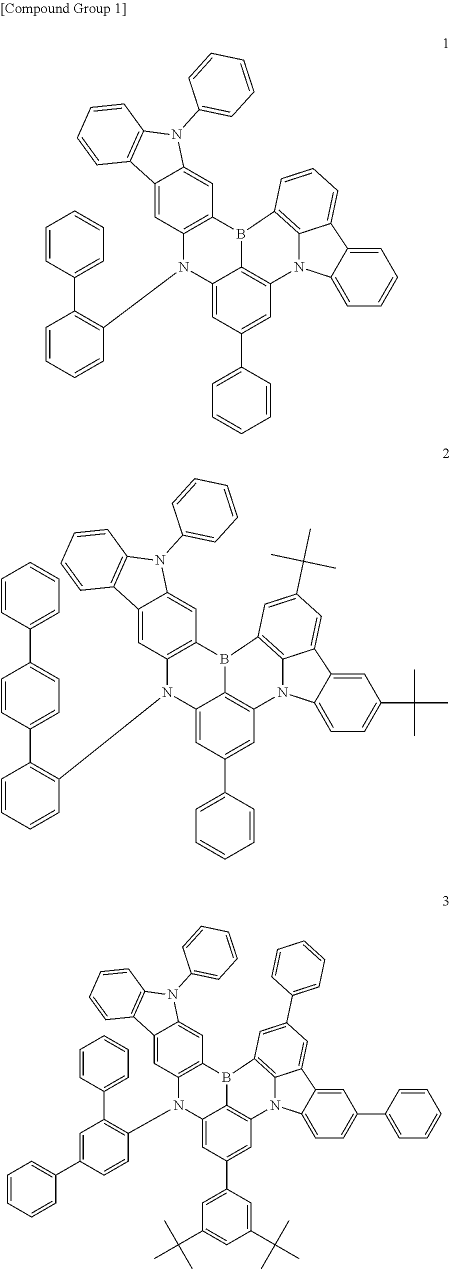 [SMILES: c1ccc(-c2cc3c4c(c2)-n2c5ccccc5c5cccc(c52)B4c2cc4c(cc2N3c2ccccc2-c2ccccc2)c2ccccc2n4-c2ccccc2)cc1 ; CC(C)(C)c1ccc2c(c1)c1cc(C(C)(C)C)cc3c1n2-c1cc(-c2ccccc2)cc2c1B3c1cc3c(cc1N2c1ccccc1-c1ccc(-c2ccccc2)cc1)c1ccccc1n3-c1ccccc1 ; CC(C)(C)c1cc(-c2cc3c4c(c2)-n2c5ccc(-c6ccccc6)cc5c5cc(-c6ccccc6)cc(c52)B4c2cc4c(cc2N3c2ccc(-c3ccccc3)cc2-c2ccccc2)c2ccccc2n4-c2ccccc2)cc(C(C)(C)C)c1]

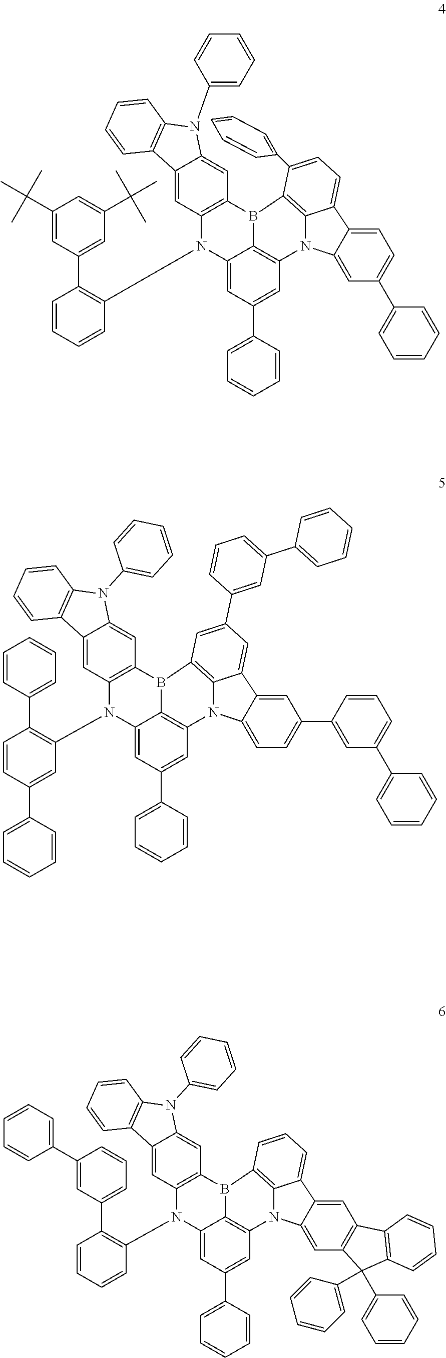 [SMILES: CC(C)(C)c1cc(-c2ccccc2N2c3cc4c5ccccc5n(-c5ccccc5)c4cc3B3c4c2cc(-c2ccccc2)cc4-n2c4cc(-c5ccccc5)ccc4c4ccc(-c5ccccc5)c3c42)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3cc(-c4ccccc4)ccc3-c3ccccc3)c3ccccc3n5-c3ccccc3)c2)cc1 ; c1ccc(-c2cccc(-c3ccccc3N3c4cc5c6ccccc6n(-c6ccccc6)c5cc4B4c5c3cc(-c3ccccc3)cc5-n3c5cc6c(cc5c5cccc4c53)-c3ccccc3C6(c3ccccc3)c3ccccc3)c2)cc1]

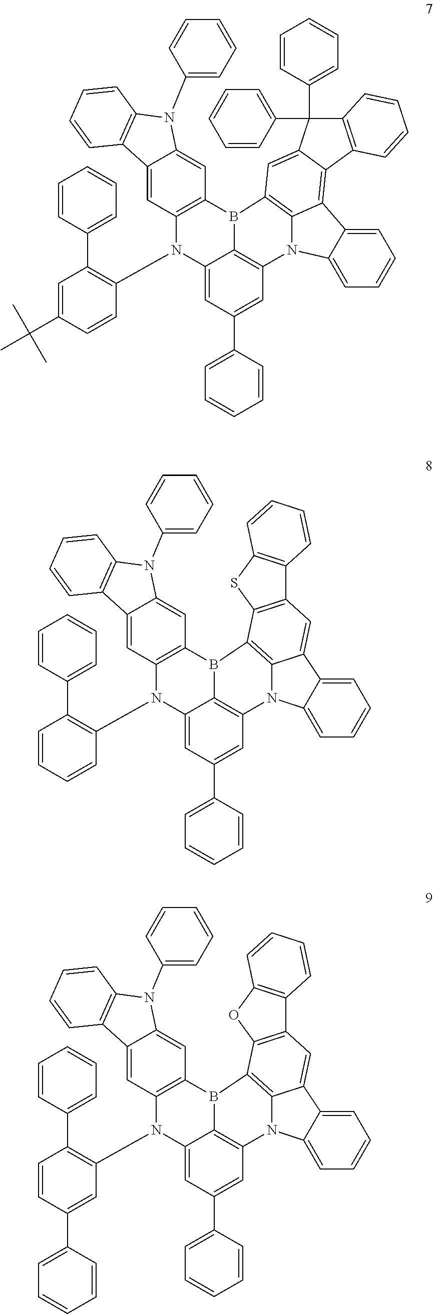

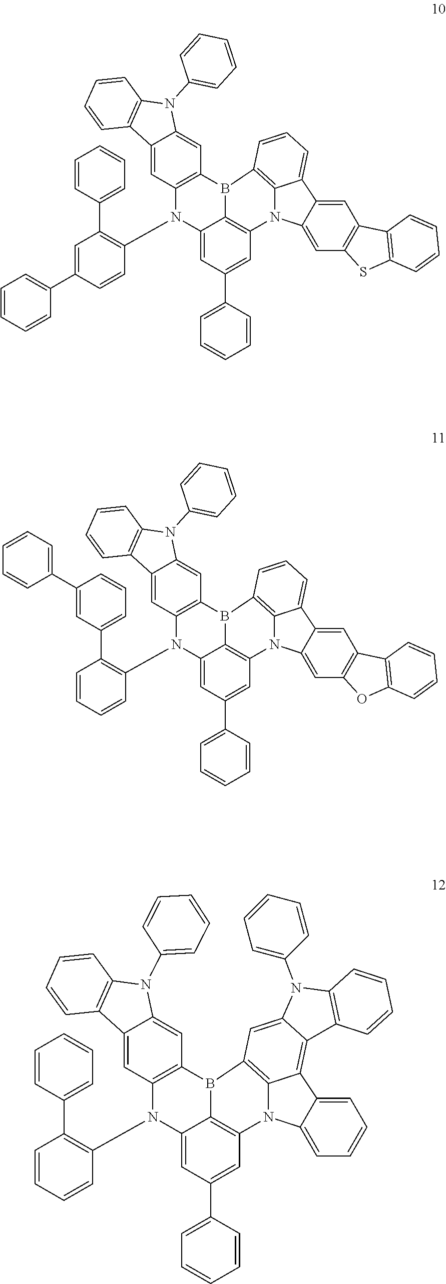 [SMILES: c1ccc(-c2ccc(N3c4cc5c6ccccc6n(-c6ccccc6)c5cc4B4c5c3cc(-c3ccccc3)cc5-n3c5cc6sc7ccccc7c6cc5c5cccc4c53)c(-c3ccccc3)c2)cc1 ; c1ccc(-c2cccc(-c3ccccc3N3c4cc5c6ccccc6n(-c6ccccc6)c5cc4B4c5c3cc(-c3ccccc3)cc5-n3c5cc6oc7ccccc7c6cc5c5cccc4c53)c2)cc1 ; c1ccc(-c2cc3c4c(c2)-n2c5ccccc5c5c6c7ccccc7n(-c7ccccc7)c6cc(c52)B4c2cc4c(cc2N3c2ccccc2-c2ccccc2)c2ccccc2n4-c2ccccc2)cc1]

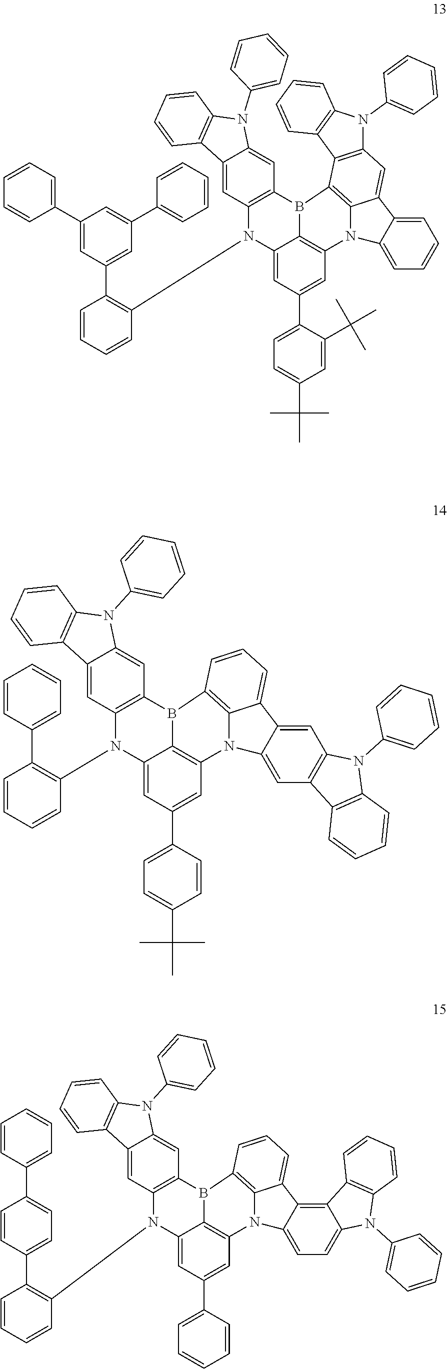 [SMILES: CC(C)(C)c1ccc(-c2cc3c4c(c2)-n2c5ccccc5c5cc6c(c(c52)B4c2cc4c(cc2N3c2ccccc2-c2cc(-c3ccccc3)cc(-c3ccccc3)c2)c2ccccc2n4-c2ccccc2)c2ccccc2n6-c2ccccc2)c(C(C)(C)C)c1 ; CC(C)(C)c1ccc(-c2cc3c4c(c2)-n2c5cc6c7ccccc7n(-c7ccccc7)c6cc5c5cccc(c52)B4c2cc4c(cc2N3c2ccccc2-c2ccccc2)c2ccccc2n4-c2ccccc2)cc1 ; c1ccc(-c2ccc(-c3ccccc3N3c4cc5c6ccccc6n(-c6ccccc6)c5cc4B4c5c3cc(-c3ccccc3)cc5-n3c5ccc6c(c7ccccc7n6-c6ccccc6)c5c5cccc4c53)cc2)cc1]

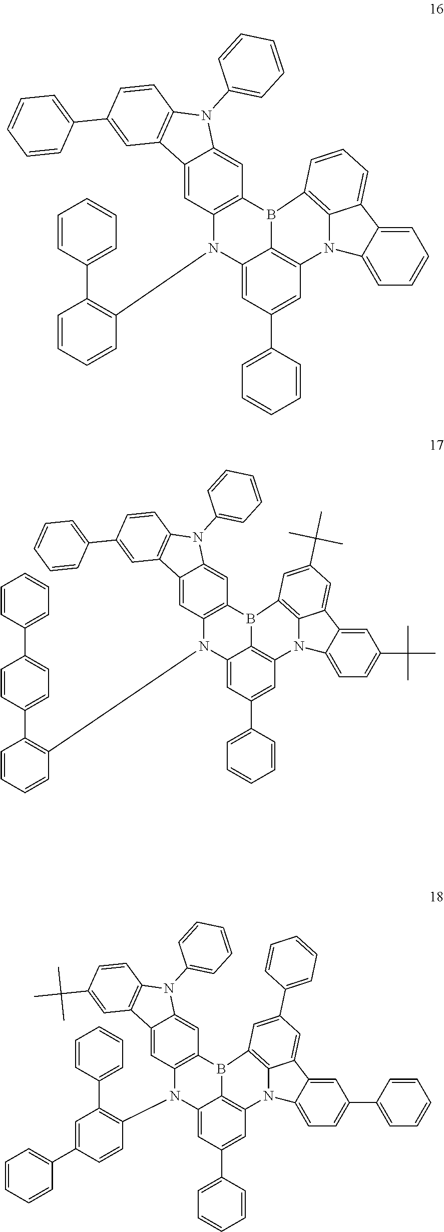 [SMILES: c1ccc(-c2cc3c4c(c2)-n2c5ccccc5c5cccc(c52)B4c2cc4c(cc2N3c2ccccc2-c2ccccc2)c2cc(-c3ccccc3)ccc2n4-c2ccccc2)cc1 ; CC(C)(C)c1ccc2c(c1)c1cc(C(C)(C)C)cc3c1n2-c1cc(-c2ccccc2)cc2c1B3c1cc3c(cc1N2c1ccccc1-c1ccc(-c2ccccc2)cc1)c1cc(-c2ccccc2)ccc1n3-c1ccccc1 ; CC(C)(C)c1ccc2c(c1)c1cc3c(cc1n2-c1ccccc1)B1c2c(cc(-c4ccccc4)cc2-n2c4ccc(-c5ccccc5)cc4c4cc(-c5ccccc5)cc1c42)N3c1ccc(-c2ccccc2)cc1-c1ccccc1]

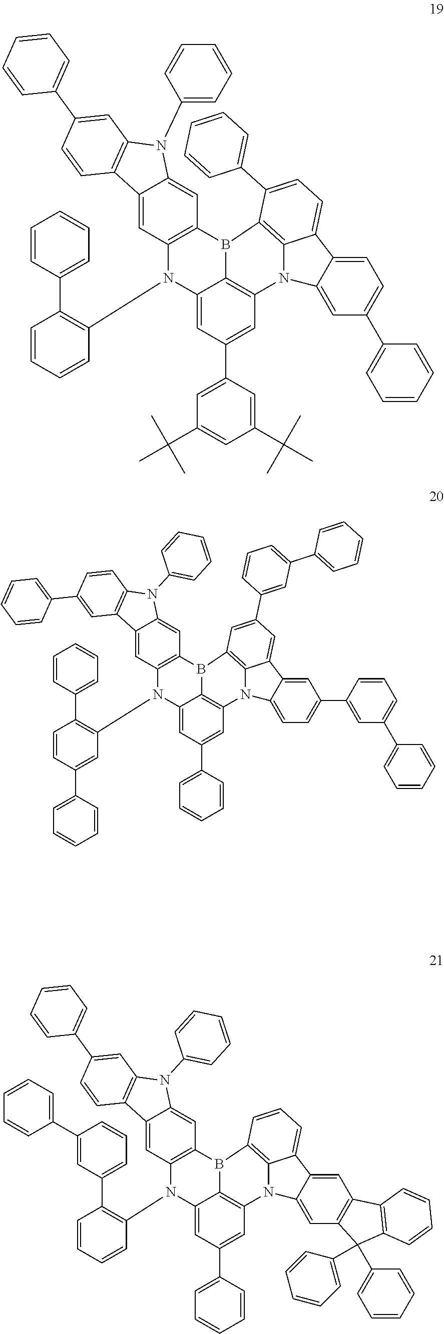 [SMILES: CC(C)(C)c1cc(-c2cc3c4c(c2)-n2c5cc(-c6ccccc6)ccc5c5ccc(-c6ccccc6)c(c52)B4c2cc4c(cc2N3c2ccccc2-c2ccccc2)c2ccc(-c3ccccc3)cc2n4-c2ccccc2)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3cc(-c4ccccc4)ccc3-c3ccccc3)c3cc(-c4ccccc4)ccc3n5-c3ccccc3)c2)cc1 ; c1ccc(-c2cccc(-c3ccccc3N3c4cc5c6ccc(-c7ccccc7)cc6n(-c6ccccc6)c5cc4B4c5c3cc(-c3ccccc3)cc5-n3c5cc6c(cc5c5cccc4c53)-c3ccccc3C6(c3ccccc3)c3ccccc3)c2)cc1]

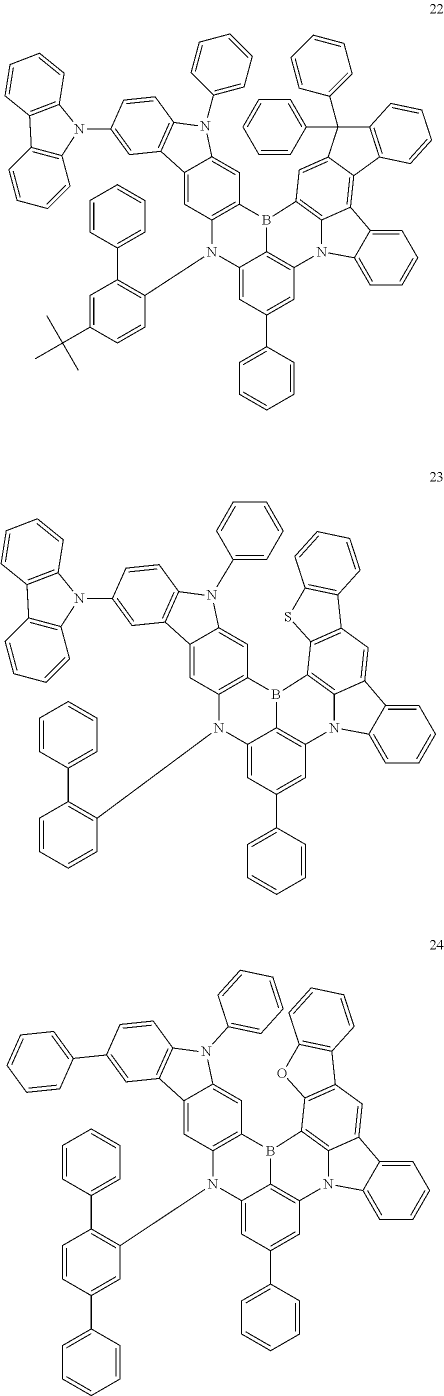 [SMILES: CC(C)(C)c1ccc(N2c3cc4c5cc(-n6c7ccccc7c7ccccc76)ccc5n(-c5ccccc5)c4cc3B3c4c2cc(-c2ccccc2)cc4-n2c4ccccc4c4c5c(cc3c42)C(c2ccccc2)(c2ccccc2)c2ccccc2-5)c(-c2ccccc2)c1 ; c1ccc(-c2cc3c4c(c2)-n2c5ccccc5c5cc6c(sc7ccccc76)c(c52)B4c2cc4c(cc2N3c2ccccc2-c2ccccc2)c2cc(-n3c5ccccc5c5ccccc53)ccc2n4-c2ccccc2)cc1 ; c1ccc(-c2ccc(-c3ccccc3)c(N3c4cc5c6cc(-c7ccccc7)ccc6n(-c6ccccc6)c5cc4B4c5c3cc(-c3ccccc3)cc5-n3c5ccccc5c5cc6c(oc7ccccc76)c4c53)c2)cc1]

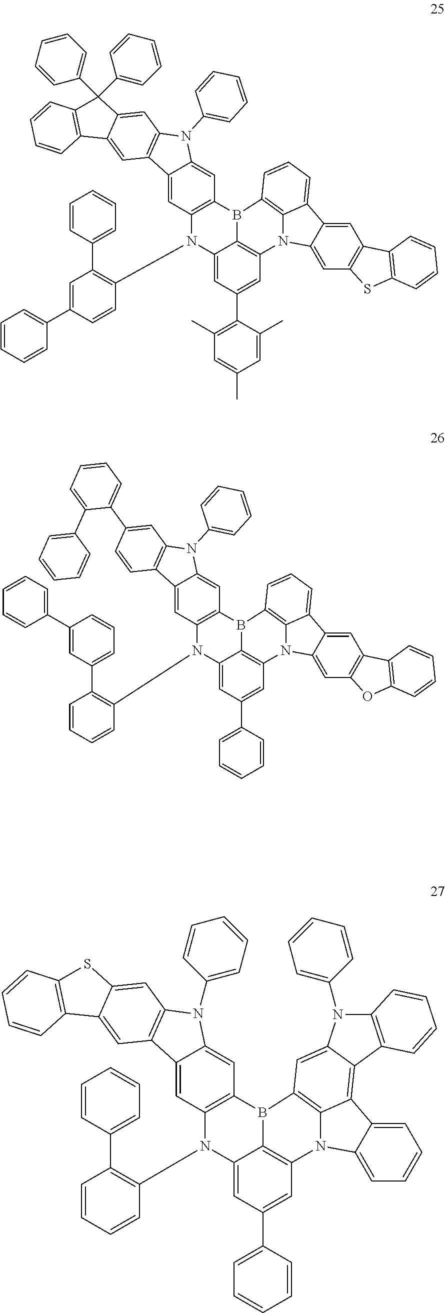 [SMILES: Cc1cc(C)c(-c2cc3c4c(c2)-n2c5cc6sc7ccccc7c6cc5c5cccc(c52)B4c2cc4c(cc2N3c2ccc(-c3ccccc3)cc2-c2ccccc2)c2cc3c(cc2n4-c2ccccc2)C(c2ccccc2)(c2ccccc2)c2ccccc2-3)c(C)c1 ; c1ccc(-c2cccc(-c3ccccc3N3c4cc5c6ccc(-c7ccccc7-c7ccccc7)cc6n(-c6ccccc6)c5cc4B4c5c3cc(-c3ccccc3)cc5-n3c5cc6oc7ccccc7c6cc5c5cccc4c53)c2)cc1 ; c1ccc(-c2cc3c4c(c2)-n2c5ccccc5c5c6c7ccccc7n(-c7ccccc7)c6cc(c52)B4c2cc4c(cc2N3c2ccccc2-c2ccccc2)c2cc3c(cc2n4-c2ccccc2)sc2ccccc23)cc1]

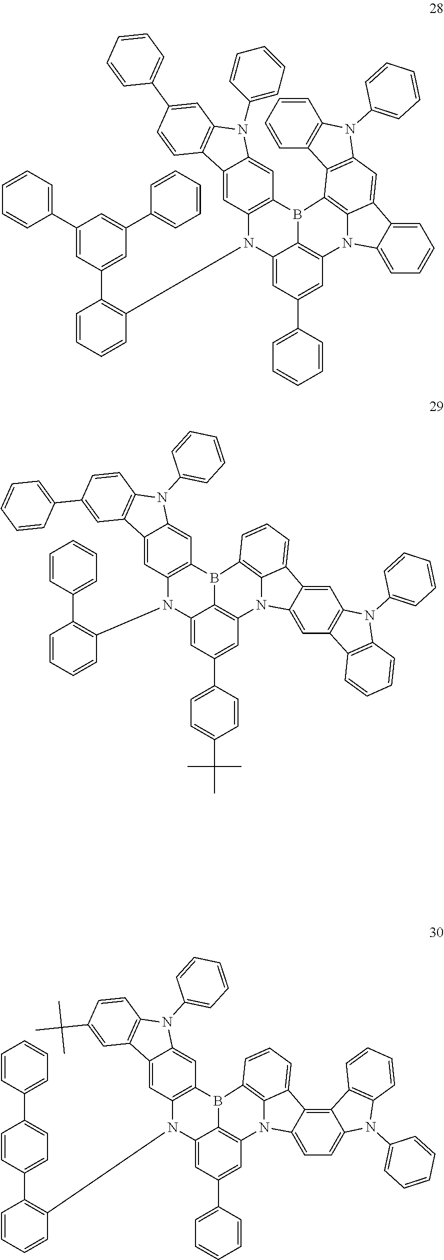 [SMILES: c1ccc(-c2cc(-c3ccccc3)cc(-c3ccccc3N3c4cc5c6ccc(-c7ccccc7)cc6n(-c6ccccc6)c5cc4B4c5c3cc(-c3ccccc3)cc5-n3c5ccccc5c5cc6c(c4c53)c3ccccc3n6-c3ccccc3)c2)cc1 ; CC(C)(C)c1ccc(-c2cc3c4c(c2)-n2c5cc6c7ccccc7n(-c7ccccc7)c6cc5c5cccc(c52)B4c2cc4c(cc2N3c2ccccc2-c2ccccc2)c2cc(-c3ccccc3)ccc2n4-c2ccccc2)cc1 ; CC(C)(C)c1ccc2c(c1)c1cc3c(cc1n2-c1ccccc1)B1c2c(cc(-c4ccccc4)cc2-n2c4ccc5c(c6ccccc6n5-c5ccccc5)c4c4cccc1c42)N3c1ccccc1-c1ccc(-c2ccccc2)cc1]

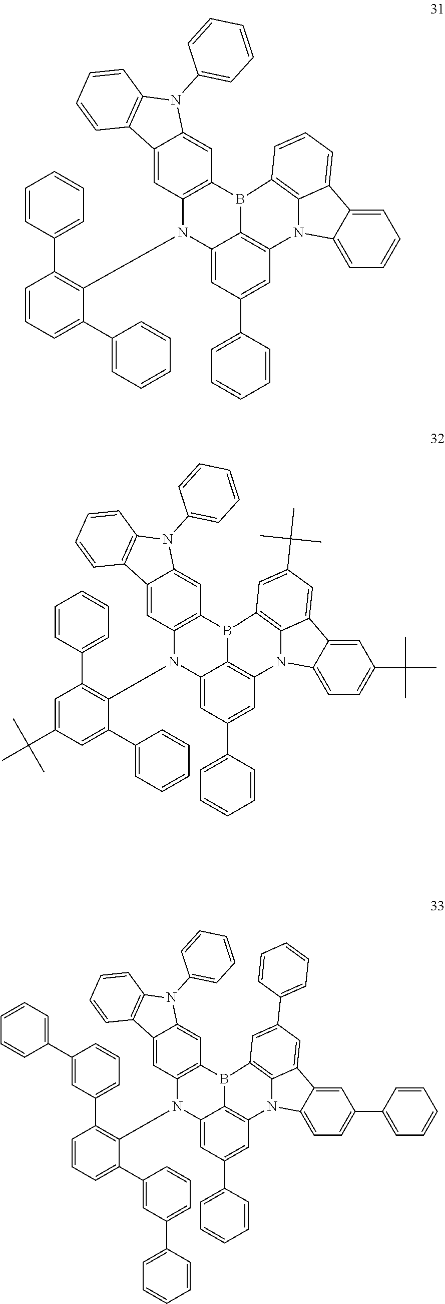 [SMILES: c1ccc(-c2cc3c4c(c2)-n2c5ccccc5c5cccc(c52)B4c2cc4c(cc2N3c2c(-c3ccccc3)cccc2-c2ccccc2)c2ccccc2n4-c2ccccc2)cc1 ; CC(C)(C)c1cc(-c2ccccc2)c(N2c3cc4c5ccccc5n(-c5ccccc5)c4cc3B3c4c2cc(-c2ccccc2)cc4-n2c4ccc(C(C)(C)C)cc4c4cc(C(C)(C)C)cc3c42)c(-c2ccccc2)c1 ; c1ccc(-c2cccc(-c3cccc(-c4cccc(-c5ccccc5)c4)c3N3c4cc5c6ccccc6n(-c6ccccc6)c5cc4B4c5c3cc(-c3ccccc3)cc5-n3c5ccc(-c6ccccc6)cc5c5cc(-c6ccccc6)cc4c53)c2)cc1]

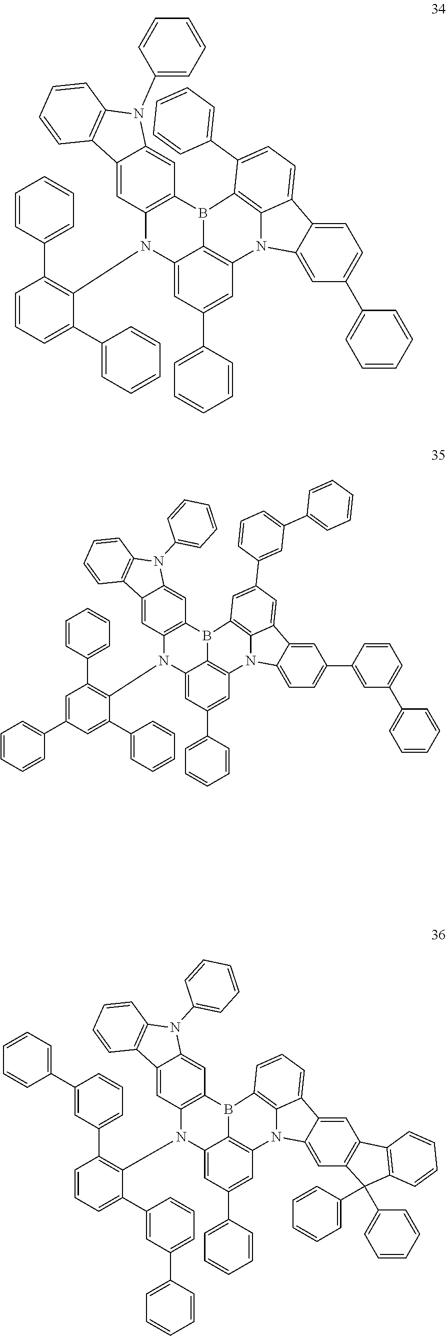 [SMILES: c1ccc(-c2cc3c4c(c2)-n2c5cc(-c6ccccc6)ccc5c5ccc(-c6ccccc6)c(c52)B4c2cc4c(cc2N3c2c(-c3ccccc3)cccc2-c2ccccc2)c2ccccc2n4-c2ccccc2)cc1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3c(-c4ccccc4)cc(-c4ccccc4)cc3-c3ccccc3)c3ccccc3n5-c3ccccc3)c2)cc1 ; c1ccc(-c2cccc(-c3cccc(-c4cccc(-c5ccccc5)c4)c3N3c4cc5c6ccccc6n(-c6ccccc6)c5cc4B4c5c3cc(-c3ccccc3)cc5-n3c5cc6c(cc5c5cccc4c53)-c3ccccc3C6(c3ccccc3)c3ccccc3)c2)cc1]

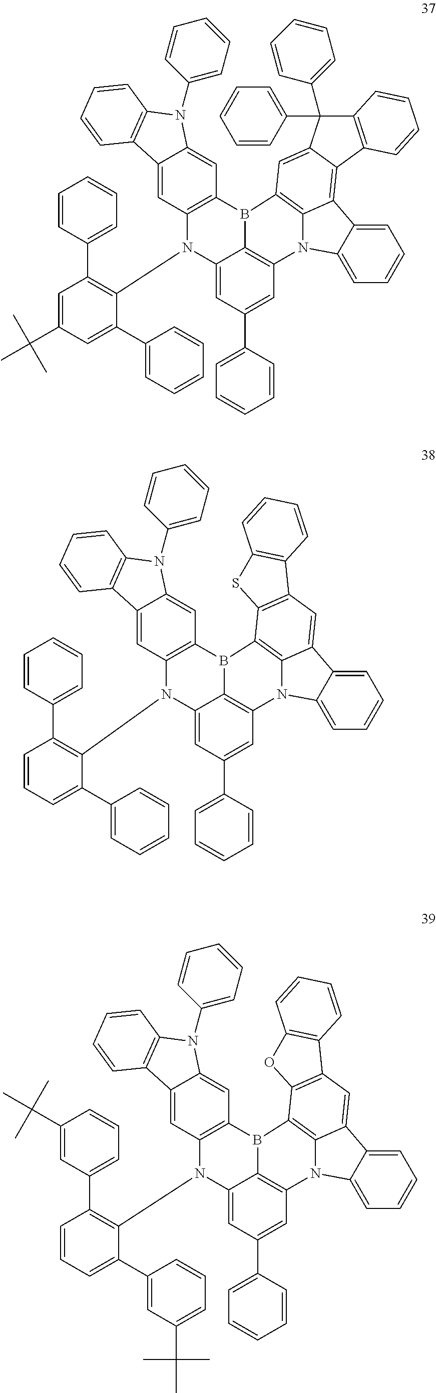 [SMILES: CC(C)(C)c1cc(-c2ccccc2)c(N2c3cc4c5ccccc5n(-c5ccccc5)c4cc3B3c4c2cc(-c2ccccc2)cc4-n2c4ccccc4c4c5c(cc3c42)C(c2ccccc2)(c2ccccc2)c2ccccc2-5)c(-c2ccccc2)c1 ; c1ccc(-c2cc3c4c(c2)-n2c5ccccc5c5cc6c(sc7ccccc76)c(c52)B4c2cc4c(cc2N3c2c(-c3ccccc3)cccc2-c2ccccc2)c2ccccc2n4-c2ccccc2)cc1 ; CC(C)(C)c1cccc(-c2cccc(-c3cccc(C(C)(C)C)c3)c2N2c3cc4c5ccccc5n(-c5ccccc5)c4cc3B3c4c2cc(-c2ccccc2)cc4-n2c4ccccc4c4cc5c(oc6ccccc65)c3c42)c1]

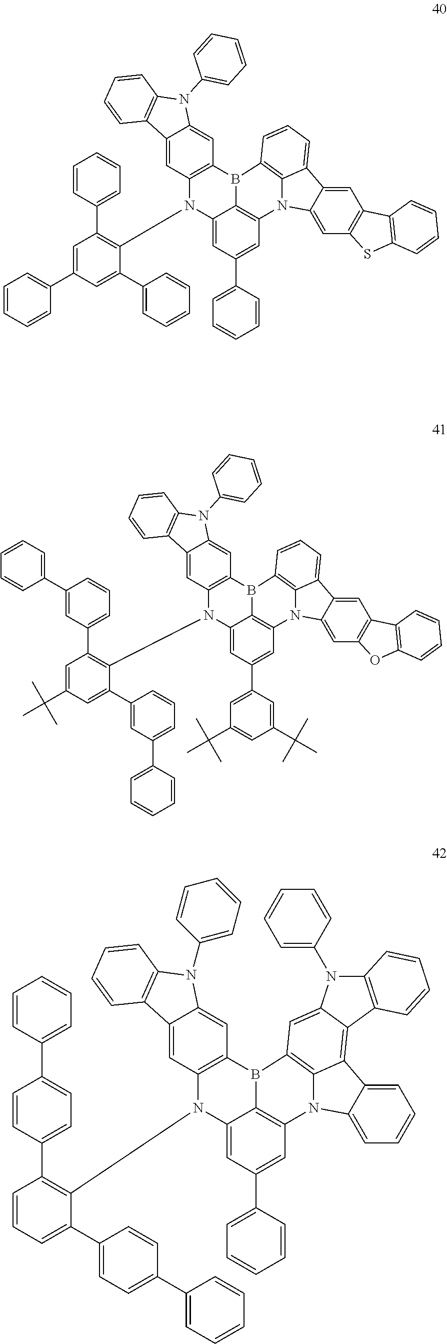 [SMILES: c1ccc(-c2cc(-c3ccccc3)c(N3c4cc5c6ccccc6n(-c6ccccc6)c5cc4B4c5c3cc(-c3ccccc3)cc5-n3c5cc6sc7ccccc7c6cc5c5cccc4c53)c(-c3ccccc3)c2)cc1 ; CC(C)(C)c1cc(-c2cc3c4c(c2)-n2c5cc6oc7ccccc7c6cc5c5cccc(c52)B4c2cc4c(cc2N3c2c(-c3cccc(-c5ccccc5)c3)cc(C(C)(C)C)cc2-c2cccc(-c3ccccc3)c2)c2ccccc2n4-c2ccccc2)cc(C(C)(C)C)c1 ; c1ccc(-c2ccc(-c3cccc(-c4ccc(-c5ccccc5)cc4)c3N3c4cc5c6ccccc6n(-c6ccccc6)c5cc4B4c5c3cc(-c3ccccc3)cc5-n3c5ccccc5c5c6c7ccccc7n(-c7ccccc7)c6cc4c53)cc2)cc1]

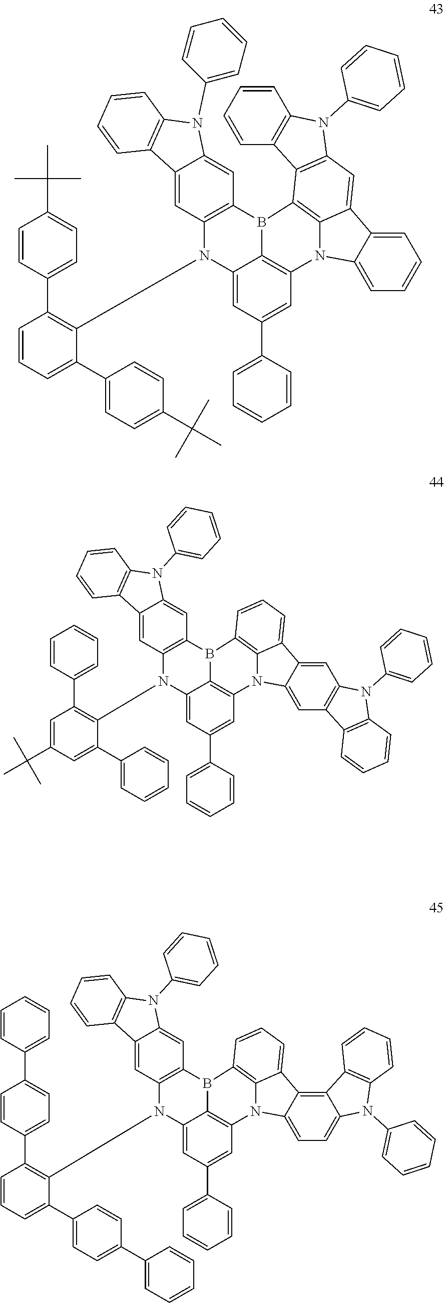 [SMILES: CC(C)(C)c1ccc(-c2cccc(-c3ccc(C(C)(C)C)cc3)c2N2c3cc4c5ccccc5n(-c5ccccc5)c4cc3B3c4c2cc(-c2ccccc2)cc4-n2c4ccccc4c4cc5c(c3c42)c2ccccc2n5-c2ccccc2)cc1 ; CC(C)(C)c1cc(-c2ccccc2)c(N2c3cc4c5ccccc5n(-c5ccccc5)c4cc3B3c4c2cc(-c2ccccc2)cc4-n2c4cc5c6ccccc6n(-c6ccccc6)c5cc4c4cccc3c42)c(-c2ccccc2)c1 ; c1ccc(-c2ccc(-c3cccc(-c4ccc(-c5ccccc5)cc4)c3N3c4cc5c6ccccc6n(-c6ccccc6)c5cc4B4c5c3cc(-c3ccccc3)cc5-n3c5ccc6c(c7ccccc7n6-c6ccccc6)c5c5cccc4c53)cc2)cc1]

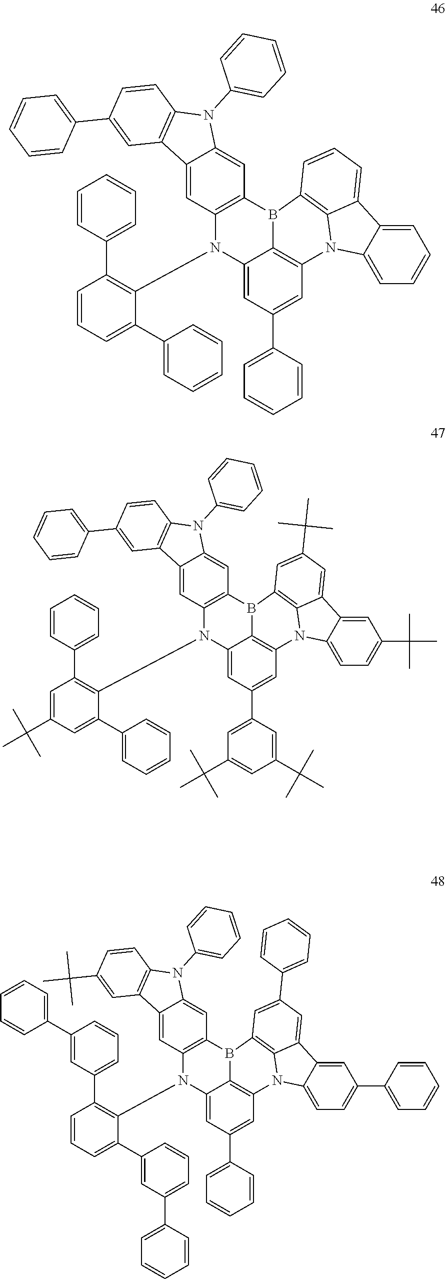 [SMILES: c1ccc(-c2cc3c4c(c2)-n2c5ccccc5c5cccc(c52)B4c2cc4c(cc2N3c2c(-c3ccccc3)cccc2-c2ccccc2)c2cc(-c3ccccc3)ccc2n4-c2ccccc2)cc1 ; CC(C)(C)c1cc(-c2cc3c4c(c2)-n2c5ccc(C(C)(C)C)cc5c5cc(C(C)(C)C)cc(c52)B4c2cc4c(cc2N3c2c(-c3ccccc3)cc(C(C)(C)C)cc2-c2ccccc2)c2cc(-c3ccccc3)ccc2n4-c2ccccc2)cc(C(C)(C)C)c1 ; CC(C)(C)c1ccc2c(c1)c1cc3c(cc1n2-c1ccccc1)B1c2c(cc(-c4ccccc4)cc2-n2c4ccc(-c5ccccc5)cc4c4cc(-c5ccccc5)cc1c42)N3c1c(-c2cccc(-c3ccccc3)c2)cccc1-c1cccc(-c2ccccc2)c1]

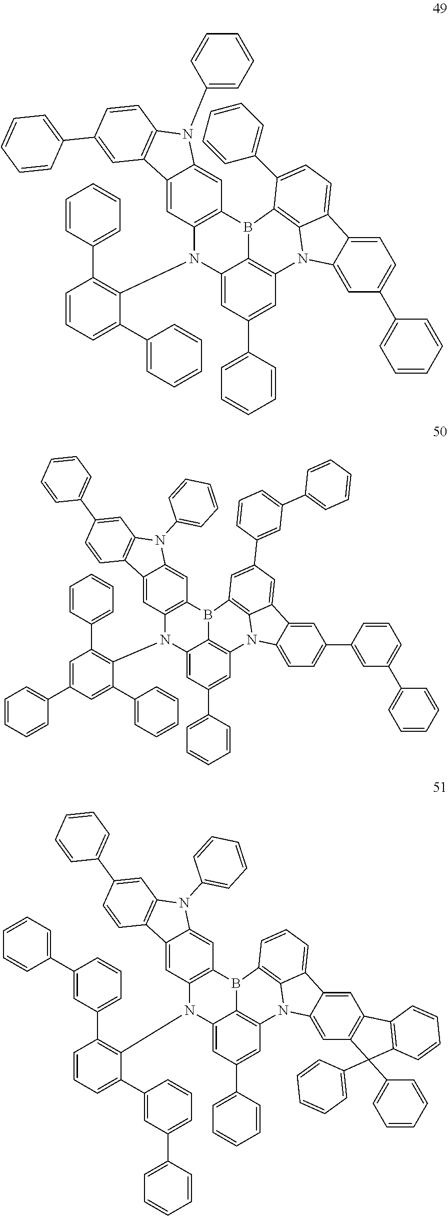 [SMILES: c1ccc(-c2cc3c4c(c2)-n2c5cc(-c6ccccc6)ccc5c5ccc(-c6ccccc6)c(c52)B4c2cc4c(cc2N3c2c(-c3ccccc3)cccc2-c2ccccc2)c2cc(-c3ccccc3)ccc2n4-c2ccccc2)cc1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3c(-c4ccccc4)cc(-c4ccccc4)cc3-c3ccccc3)c3ccc(-c4ccccc4)cc3n5-c3ccccc3)c2)cc1 ; c1ccc(-c2cccc(-c3cccc(-c4cccc(-c5ccccc5)c4)c3N3c4cc5c6ccc(-c7ccccc7)cc6n(-c6ccccc6)c5cc4B4c5c3cc(-c3ccccc3)cc5-n3c5cc6c(cc5c5cccc4c53)-c3ccccc3C6(c3ccccc3)c3ccccc3)c2)cc1]

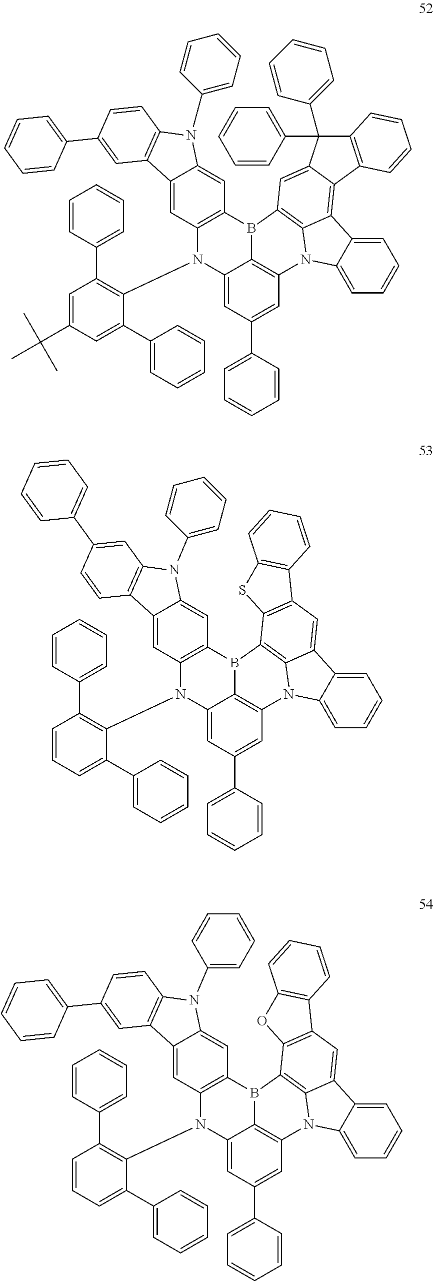 [SMILES: CC(C)(C)c1cc(-c2ccccc2)c(N2c3cc4c5cc(-c6ccccc6)ccc5n(-c5ccccc5)c4cc3B3c4c2cc(-c2ccccc2)cc4-n2c4ccccc4c4c5c(cc3c42)C(c2ccccc2)(c2ccccc2)c2ccccc2-5)c(-c2ccccc2)c1 ; c1ccc(-c2cc3c4c(c2)-n2c5ccccc5c5cc6c(sc7ccccc76)c(c52)B4c2cc4c(cc2N3c2c(-c3ccccc3)cccc2-c2ccccc2)c2ccc(-c3ccccc3)cc2n4-c2ccccc2)cc1 ; c1ccc(-c2cc3c4c(c2)-n2c5ccccc5c5cc6c(oc7ccccc76)c(c52)B4c2cc4c(cc2N3c2c(-c3ccccc3)cccc2-c2ccccc2)c2cc(-c3ccccc3)ccc2n4-c2ccccc2)cc1]

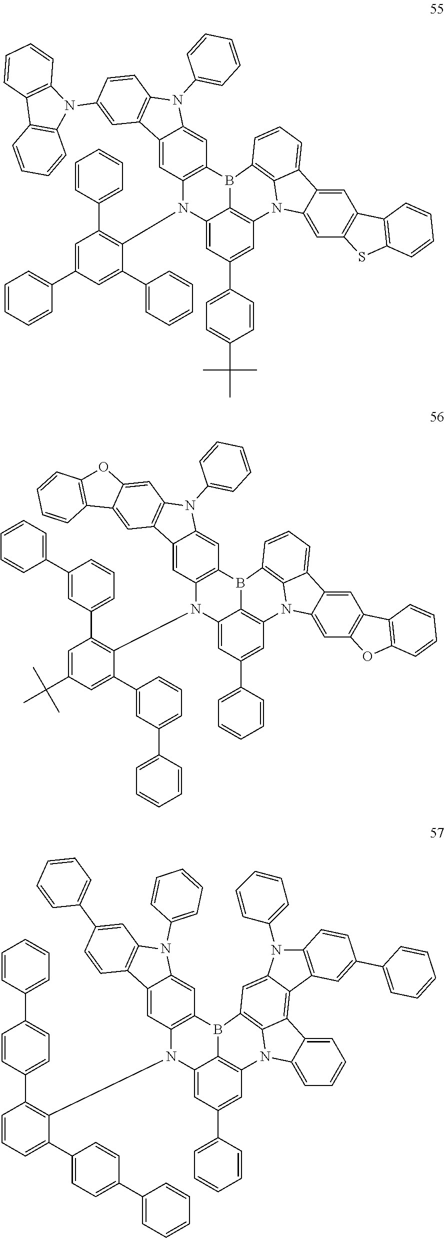 [SMILES: CC(C)(C)c1ccc(-c2cc3c4c(c2)-n2c5cc6sc7ccccc7c6cc5c5cccc(c52)B4c2cc4c(cc2N3c2c(-c3ccccc3)cc(-c3ccccc3)cc2-c2ccccc2)c2cc(-n3c5ccccc5c5ccccc53)ccc2n4-c2ccccc2)cc1 ; CC(C)(C)c1cc(-c2cccc(-c3ccccc3)c2)c(N2c3cc4c5cc6c(cc5n(-c5ccccc5)c4cc3B3c4c2cc(-c2ccccc2)cc4-n2c4cc5oc7ccccc7c5cc4c4cccc3c42)oc2ccccc26)c(-c2cccc(-c3ccccc3)c2)c1 ; c1ccc(-c2ccc(-c3cccc(-c4ccc(-c5ccccc5)cc4)c3N3c4cc5c6ccc(-c7ccccc7)cc6n(-c6ccccc6)c5cc4B4c5c3cc(-c3ccccc3)cc5-n3c5ccccc5c5c6c7cc(-c8ccccc8)ccc7n(-c7ccccc7)c6cc4c53)cc2)cc1]

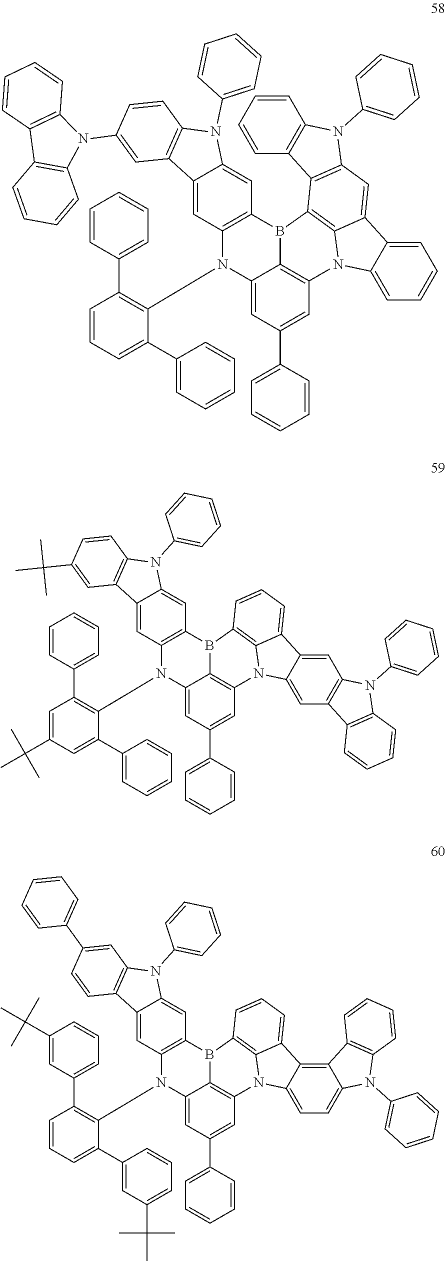 [SMILES: c1ccc(-c2cc3c4c(c2)-n2c5ccccc5c5cc6c(c(c52)B4c2cc4c(cc2N3c2c(-c3ccccc3)cccc2-c2ccccc2)c2cc(-n3c5ccccc5c5ccccc53)ccc2n4-c2ccccc2)c2ccccc2n6-c2ccccc2)cc1 ; CC(C)(C)c1cc(-c2ccccc2)c(N2c3cc4c5cc(C(C)(C)C)ccc5n(-c5ccccc5)c4cc3B3c4c2cc(-c2ccccc2)cc4-n2c4cc5c6ccccc6n(-c6ccccc6)c5cc4c4cccc3c42)c(-c2ccccc2)c1 ; CC(C)(C)c1cccc(-c2cccc(-c3cccc(C(C)(C)C)c3)c2N2c3cc4c5ccc(-c6ccccc6)cc5n(-c5ccccc5)c4cc3B3c4c2cc(-c2ccccc2)cc4-n2c4ccc5c(c6ccccc6n5-c5ccccc5)c4c4cccc3c42)c1]

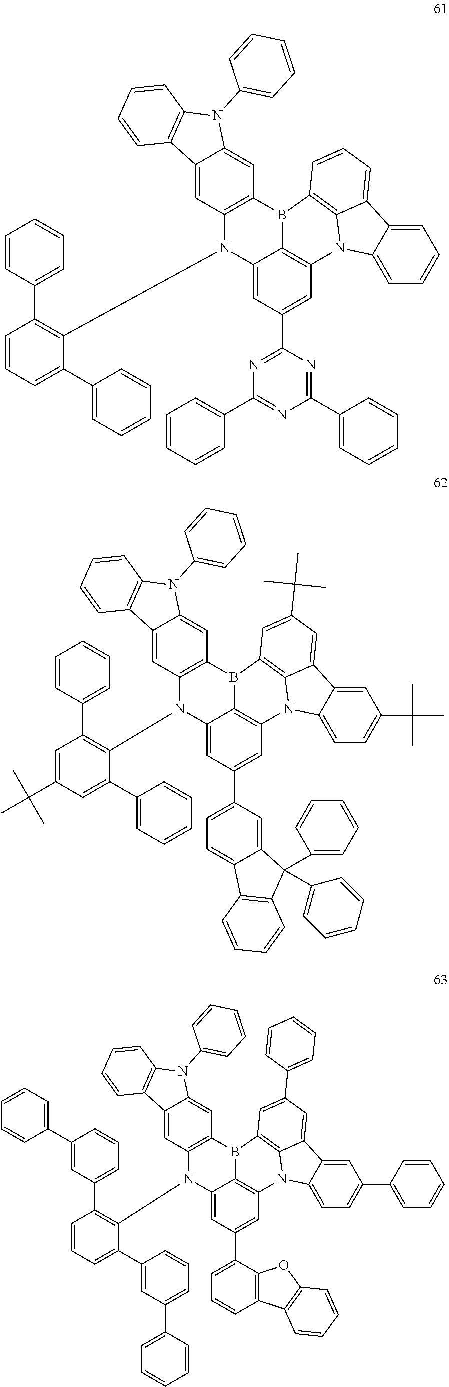 [SMILES: c1ccc(-c2nc(-c3ccccc3)nc(-c3cc4c5c(c3)-n3c6ccccc6c6cccc(c63)B5c3cc5c(cc3N4c3c(-c4ccccc4)cccc3-c3ccccc3)c3ccccc3n5-c3ccccc3)n2)cc1 ; CC(C)(C)c1cc(-c2ccccc2)c(N2c3cc4c5ccccc5n(-c5ccccc5)c4cc3B3c4c2cc(-c2ccc5c(c2)C(c2ccccc2)(c2ccccc2)c2ccccc2-5)cc4-n2c4ccc(C(C)(C)C)cc4c4cc(C(C)(C)C)cc3c42)c(-c2ccccc2)c1 ; c1ccc(-c2cccc(-c3cccc(-c4cccc(-c5ccccc5)c4)c3N3c4cc5c6ccccc6n(-c6ccccc6)c5cc4B4c5c3cc(-c3cccc6c3oc3ccccc36)cc5-n3c5ccc(-c6ccccc6)cc5c5cc(-c6ccccc6)cc4c53)c2)cc1]

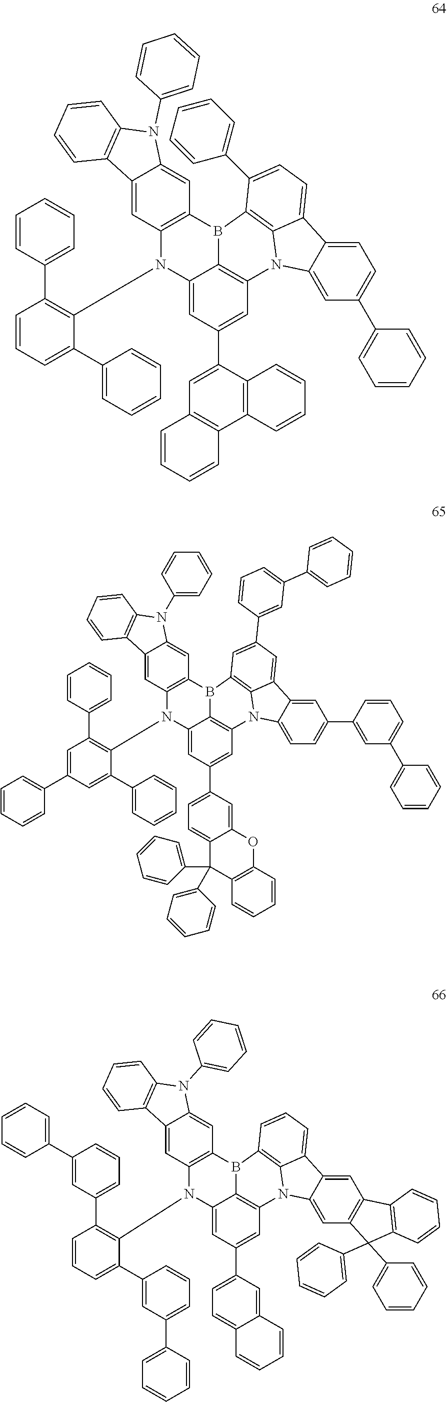

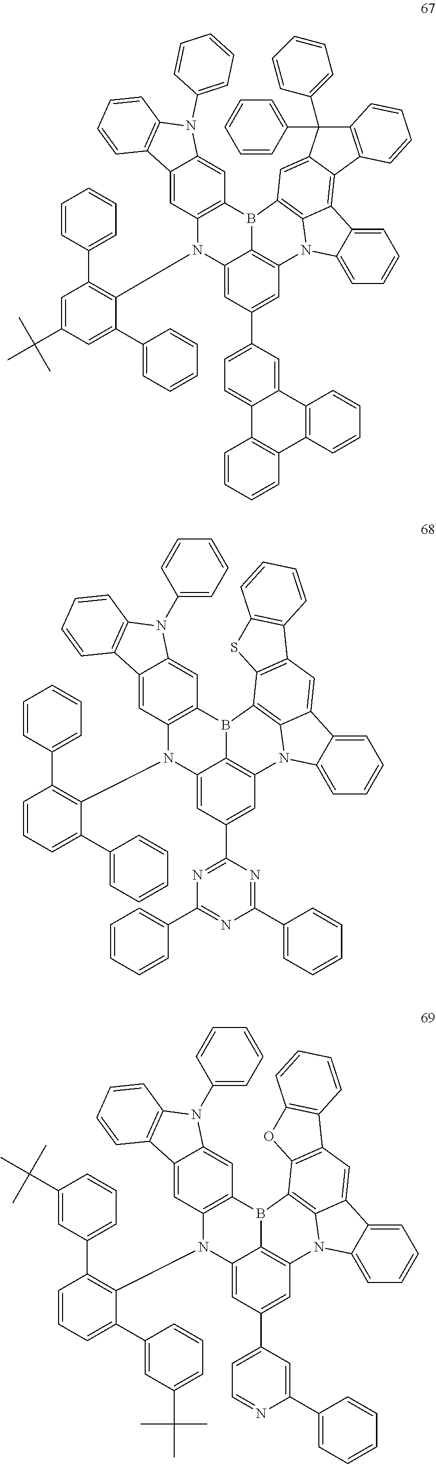 [SMILES: CC(C)(C)c1cc(-c2ccccc2)c(N2c3cc4c5ccccc5n(-c5ccccc5)c4cc3B3c4c2cc(-c2ccc5c6ccccc6c6ccccc6c5c2)cc4-n2c4ccccc4c4c5c(cc3c42)C(c2ccccc2)(c2ccccc2)c2ccccc2-5)c(-c2ccccc2)c1 ; c1ccc(-c2nc(-c3ccccc3)nc(-c3cc4c5c(c3)-n3c6ccccc6c6cc7c(sc8ccccc87)c(c63)B5c3cc5c(cc3N4c3c(-c4ccccc4)cccc3-c3ccccc3)c3ccccc3n5-c3ccccc3)n2)cc1 ; CC(C)(C)c1cccc(-c2cccc(-c3cccc(C(C)(C)C)c3)c2N2c3cc4c5ccccc5n(-c5ccccc5)c4cc3B3c4c2cc(-c2ccnc(-c5ccccc5)c2)cc4-n2c4ccccc4c4cc5c(oc6ccccc65)c3c42)c1]

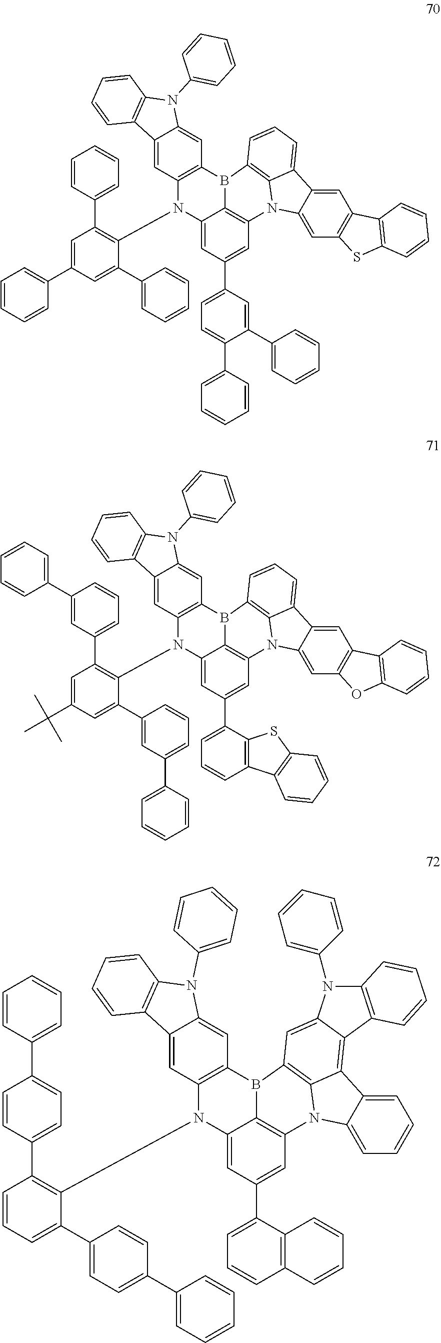 [SMILES: c1ccc(-c2cc(-c3ccccc3)c(N3c4cc5c6ccccc6n(-c6ccccc6)c5cc4B4c5c3cc(-c3ccc(-c6ccccc6)c(-c6ccccc6)c3)cc5-n3c5cc6sc7ccccc7c6cc5c5cccc4c53)c(-c3ccccc3)c2)cc1 ; CC(C)(C)c1cc(-c2cccc(-c3ccccc3)c2)c(N2c3cc4c5ccccc5n(-c5ccccc5)c4cc3B3c4c2cc(-c2cccc5c2sc2ccccc25)cc4-n2c4cc5oc6ccccc6c5cc4c4cccc3c42)c(-c2cccc(-c3ccccc3)c2)c1 ; c1ccc(-c2ccc(-c3cccc(-c4ccc(-c5ccccc5)cc4)c3N3c4cc5c6ccccc6n(-c6ccccc6)c5cc4B4c5c3cc(-c3cccc6ccccc36)cc5-n3c5ccccc5c5c6c7ccccc7n(-c7ccccc7)c6cc4c53)cc2)cc1]

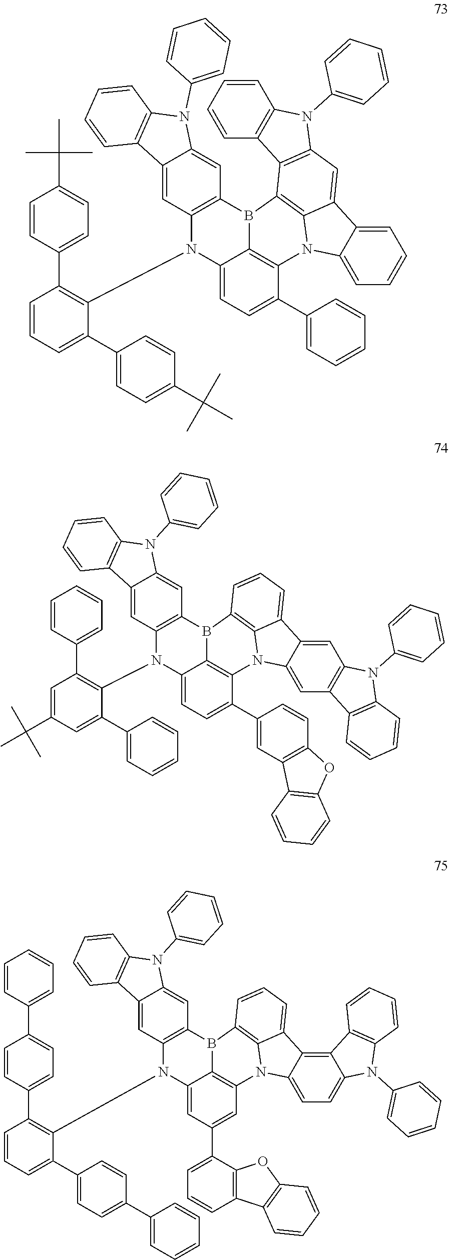 [SMILES: CC(C)(C)c1ccc(-c2cccc(-c3ccc(C(C)(C)C)cc3)c2N2c3cc4c5ccccc5n(-c5ccccc5)c4cc3B3c4c2ccc(-c2ccccc2)c4-n2c4ccccc4c4cc5c(c3c42)c2ccccc2n5-c2ccccc2)cc1 ; CC(C)(C)c1cc(-c2ccccc2)c(N2c3cc4c5ccccc5n(-c5ccccc5)c4cc3B3c4c2ccc(-c2ccc5oc6ccccc6c5c2)c4-n2c4cc5c6ccccc6n(-c6ccccc6)c5cc4c4cccc3c42)c(-c2ccccc2)c1 ; c1ccc(-c2ccc(-c3cccc(-c4ccc(-c5ccccc5)cc4)c3N3c4cc5c6ccccc6n(-c6ccccc6)c5cc4B4c5c3cc(-c3cccc6c3oc3ccccc36)cc5-n3c5ccc6c(c7ccccc7n6-c6ccccc6)c5c5cccc4c53)cc2)cc1]

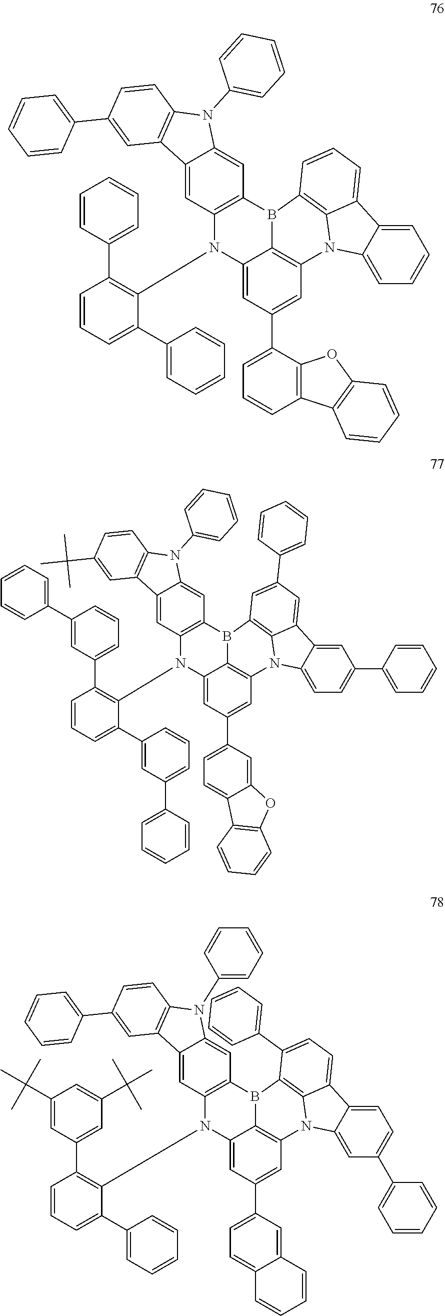 [SMILES: c1ccc(-c2ccc3c(c2)c2cc4c(cc2n3-c2ccccc2)B2c3c(cc(-c5cccc6c5oc5ccccc56)cc3-n3c5ccccc5c5cccc2c53)N4c2c(-c3ccccc3)cccc2-c2ccccc2)cc1 ; CC(C)(C)c1ccc2c(c1)c1cc3c(cc1n2-c1ccccc1)B1c2c(cc(-c4ccc5c(c4)oc4ccccc45)cc2-n2c4ccc(-c5ccccc5)cc4c4cc(-c5ccccc5)cc1c42)N3c1c(-c2cccc(-c3ccccc3)c2)cccc1-c1cccc(-c2ccccc2)c1 ; CC(C)(C)c1cc(-c2cccc(-c3ccccc3)c2N2c3cc4c5cc(-c6ccccc6)ccc5n(-c5ccccc5)c4cc3B3c4c2cc(-c2ccc5ccccc5c2)cc4-n2c4cc(-c5ccccc5)ccc4c4ccc(-c5ccccc5)c3c42)cc(C(C)(C)C)c1]

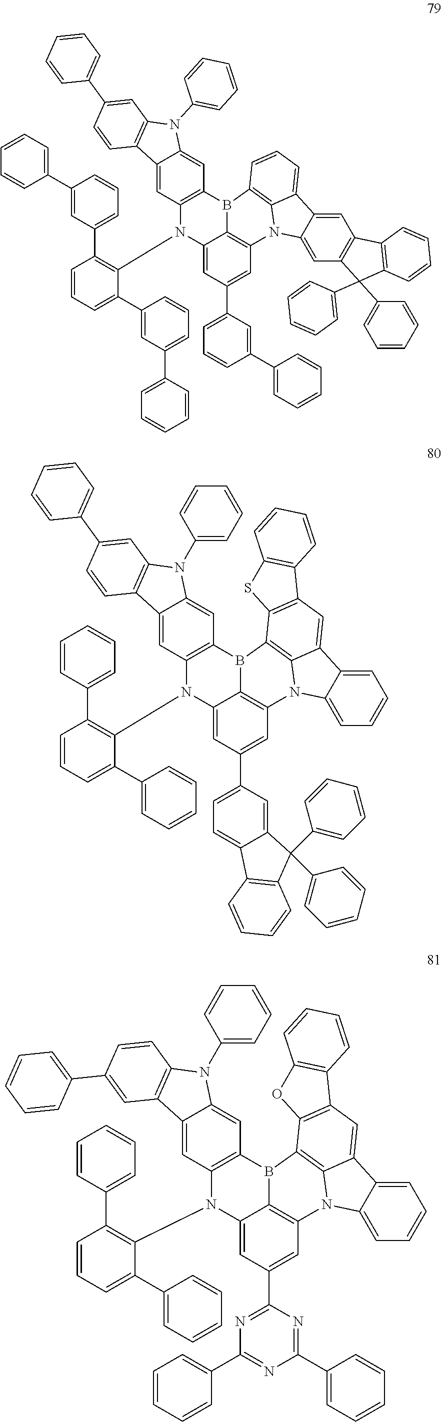

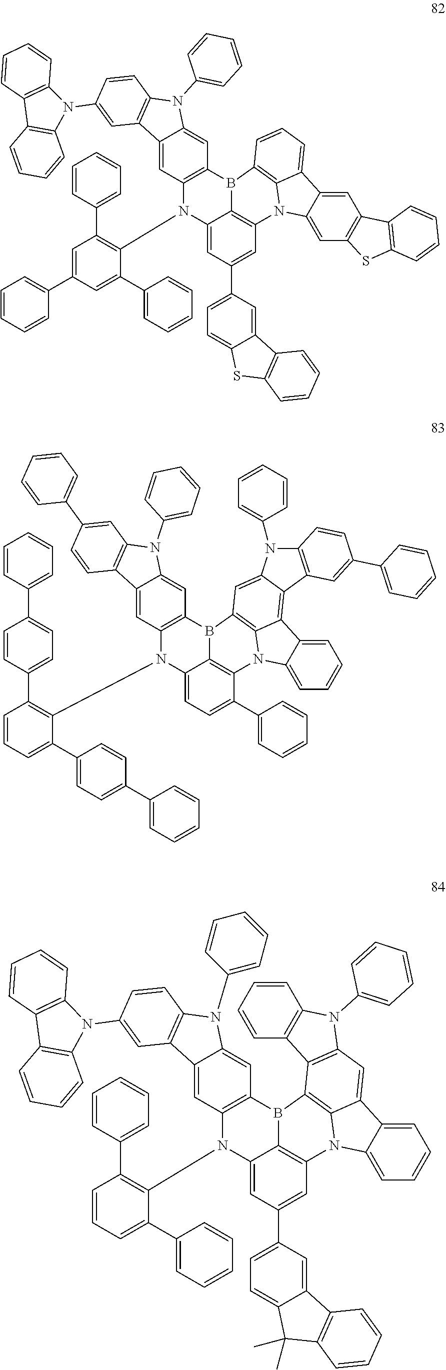

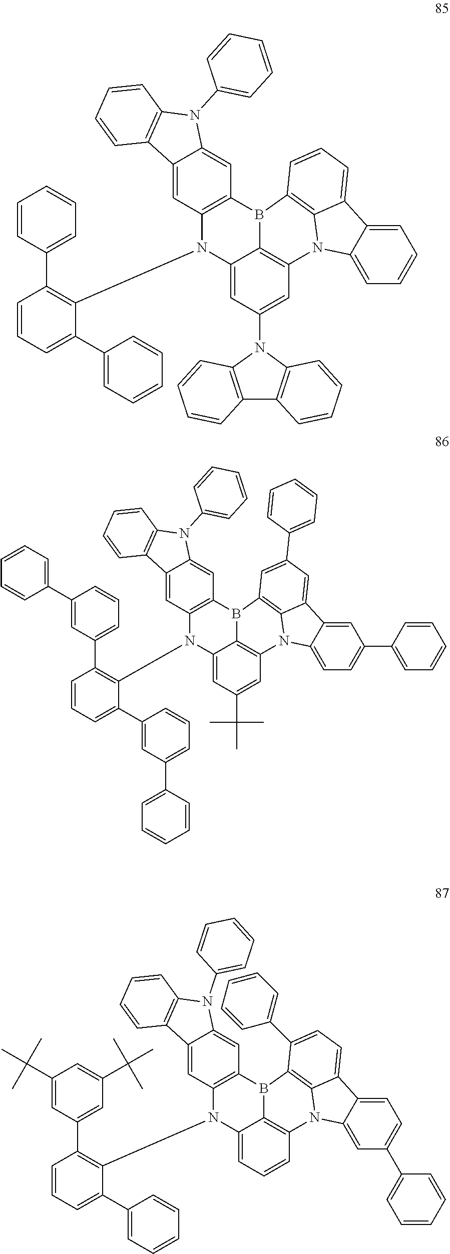 [SMILES: c1ccc(-c2cccc(-c3ccccc3)c2N2c3cc4c5ccccc5n(-c5ccccc5)c4cc3B3c4c2cc(-n2c5ccccc5c5ccccc52)cc4-n2c4ccccc4c4cccc3c42)cc1 ; CC(C)(C)c1cc2c3c(c1)-n1c4ccc(-c5ccccc5)cc4c4cc(-c5ccccc5)cc(c41)B3c1cc3c(cc1N2c1c(-c2cccc(-c4ccccc4)c2)cccc1-c1cccc(-c2ccccc2)c1)c1ccccc1n3-c1ccccc1 ; CC(C)(C)c1cc(-c2cccc(-c3ccccc3)c2N2c3cc4c5ccccc5n(-c5ccccc5)c4cc3B3c4c2cccc4-n2c4cc(-c5ccccc5)ccc4c4ccc(-c5ccccc5)c3c42)cc(C(C)(C)C)c1]

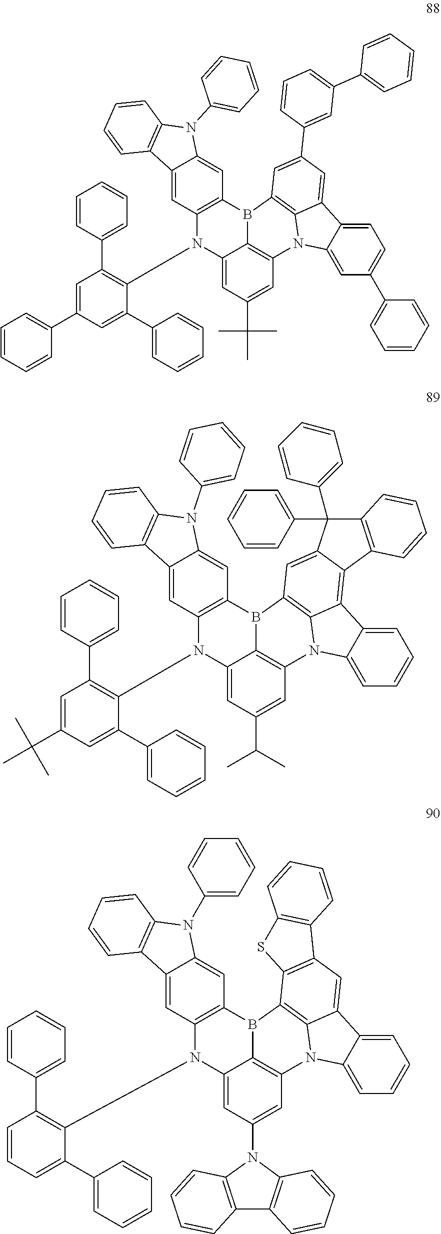 [SMILES: CC(C)(C)c1cc2c3c(c1)-n1c4cc(-c5ccccc5)ccc4c4cc(-c5cccc(-c6ccccc6)c5)cc(c41)B3c1cc3c(cc1N2c1c(-c2ccccc2)cc(-c2ccccc2)cc1-c1ccccc1)c1ccccc1n3-c1ccccc1 ; CC(C)c1cc2c3c(c1)-n1c4ccccc4c4c5c(cc(c41)B3c1cc3c(cc1N2c1c(-c2ccccc2)cc(C(C)(C)C)cc1-c1ccccc1)c1ccccc1n3-c1ccccc1)C(c1ccccc1)(c1ccccc1)c1ccccc1-5 ; c1ccc(-c2cccc(-c3ccccc3)c2N2c3cc4c5ccccc5n(-c5ccccc5)c4cc3B3c4c2cc(-n2c5ccccc5c5ccccc52)cc4-n2c4ccccc4c4cc5c(sc6ccccc65)c3c42)cc1]

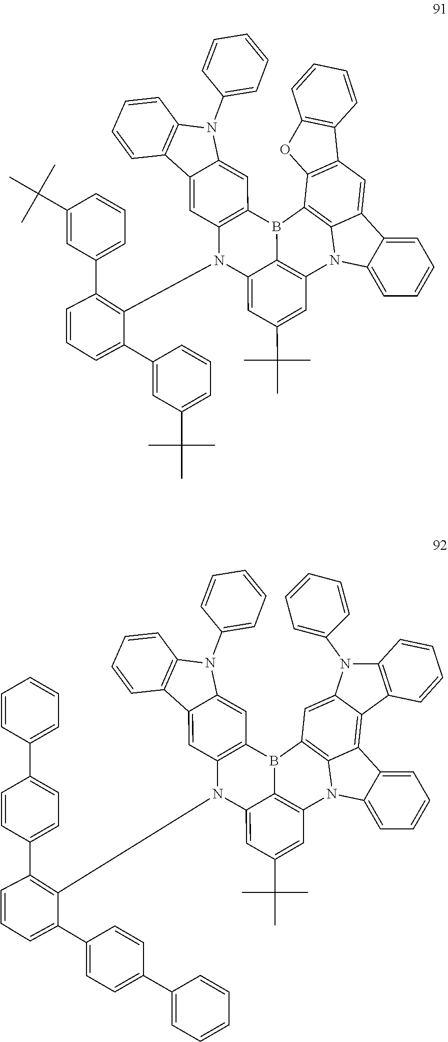 [SMILES: CC(C)(C)c1cccc(-c2cccc(-c3cccc(C(C)(C)C)c3)c2N2c3cc4c5ccccc5n(-c5ccccc5)c4cc3B3c4c2cc(C(C)(C)C)cc4-n2c4ccccc4c4cc5c(oc6ccccc65)c3c42)c1 ; CC(C)(C)c1cc2c3c(c1)-n1c4ccccc4c4c5c6ccccc6n(-c6ccccc6)c5cc(c41)B3c1cc3c(cc1N2c1c(-c2ccc(-c4ccccc4)cc2)cccc1-c1ccc(-c2ccccc2)cc1)c1ccccc1n3-c1ccccc1]

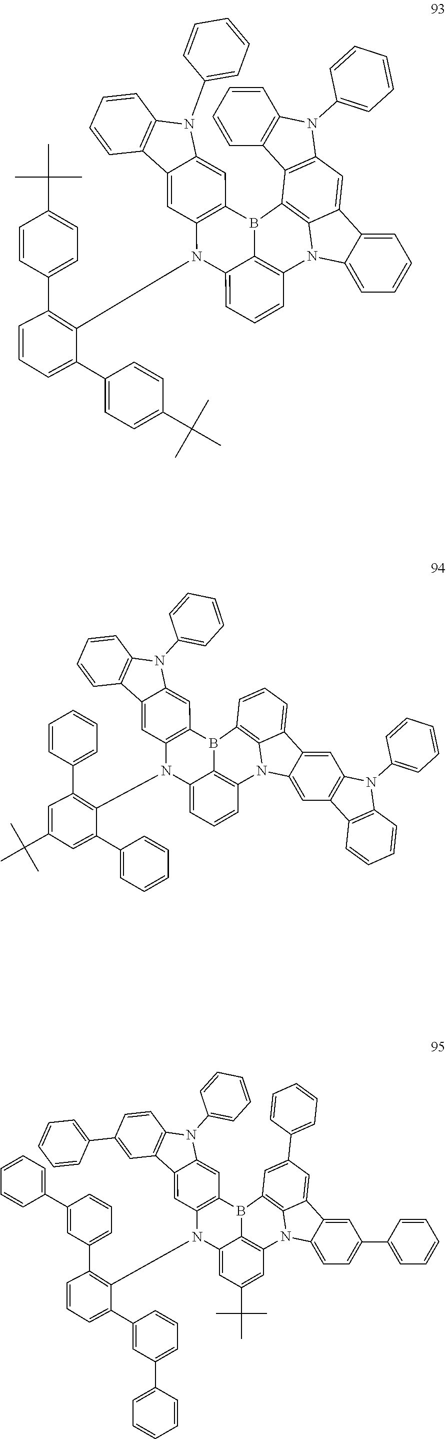 [SMILES: CC(C)(C)c1ccc(-c2cccc(-c3ccc(C(C)(C)C)cc3)c2N2c3cc4c5ccccc5n(-c5ccccc5)c4cc3B3c4c2cccc4-n2c4ccccc4c4cc5c(c3c42)c2ccccc2n5-c2ccccc2)cc1 ; CC(C)(C)c1cc(-c2ccccc2)c(N2c3cc4c5ccccc5n(-c5ccccc5)c4cc3B3c4c2cccc4-n2c4cc5c6ccccc6n(-c6ccccc6)c5cc4c4cccc3c42)c(-c2ccccc2)c1 ; CC(C)(C)c1cc2c3c(c1)-n1c4ccc(-c5ccccc5)cc4c4cc(-c5ccccc5)cc(c41)B3c1cc3c(cc1N2c1c(-c2cccc(-c4ccccc4)c2)cccc1-c1cccc(-c2ccccc2)c1)c1cc(-c2ccccc2)ccc1n3-c1ccccc1]

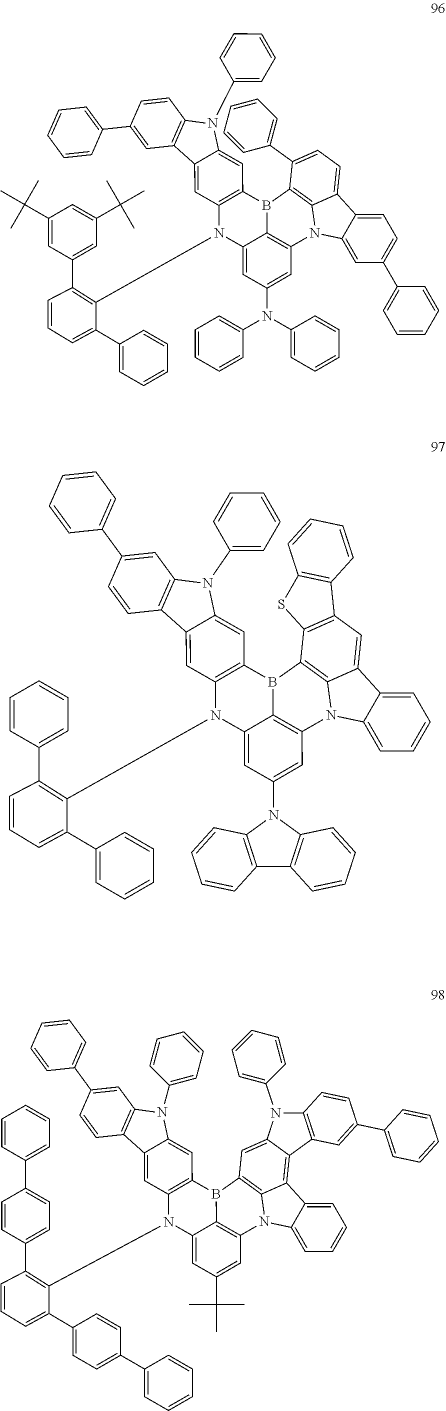 [SMILES: CC(C)(C)c1cc(-c2cccc(-c3ccccc3)c2N2c3cc4c5cc(-c6ccccc6)ccc5n(-c5ccccc5)c4cc3B3c4c2cc(N(c2ccccc2)c2ccccc2)cc4-n2c4cc(-c5ccccc5)ccc4c4ccc(-c5ccccc5)c3c42)cc(C(C)(C)C)c1 ; c1ccc(-c2ccc3c4cc5c(cc4n(-c4ccccc4)c3c2)B2c3c(cc(-n4c6ccccc6c6ccccc64)cc3-n3c4ccccc4c4cc6c(sc7ccccc76)c2c43)N5c2c(-c3ccccc3)cccc2-c2ccccc2)cc1 ; CC(C)(C)c1cc2c3c(c1)-n1c4ccccc4c4c5c6cc(-c7ccccc7)ccc6n(-c6ccccc6)c5cc(c41)B3c1cc3c(cc1N2c1c(-c2ccc(-c4ccccc4)cc2)cccc1-c1ccc(-c2ccccc2)cc1)c1ccc(-c2ccccc2)cc1n3-c1ccccc1]

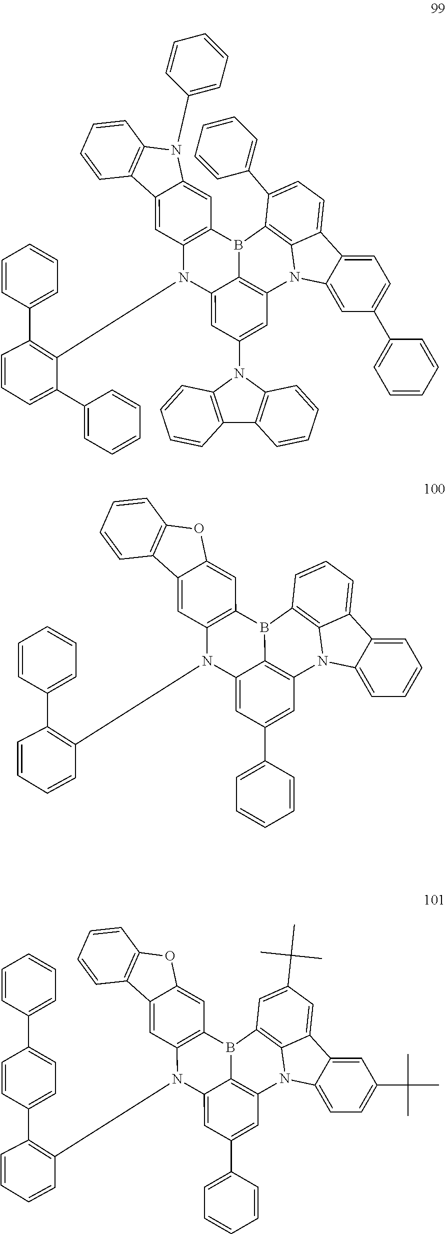 [SMILES: c1ccc(-c2ccc3c4ccc(-c5ccccc5)c5c4n(c3c2)-c2cc(-n3c4ccccc4c4ccccc43)cc3c2B5c2cc4c(cc2N3c2c(-c3ccccc3)cccc2-c2ccccc2)c2ccccc2n4-c2ccccc2)cc1 ; c1ccc(-c2cc3c4c(c2)-n2c5ccccc5c5cccc(c52)B4c2cc4oc5ccccc5c4cc2N3c2ccccc2-c2ccccc2)cc1 ; CC(C)(C)c1ccc2c(c1)c1cc(C(C)(C)C)cc3c1n2-c1cc(-c2ccccc2)cc2c1B3c1cc3oc4ccccc4c3cc1N2c1ccccc1-c1ccc(-c2ccccc2)cc1]

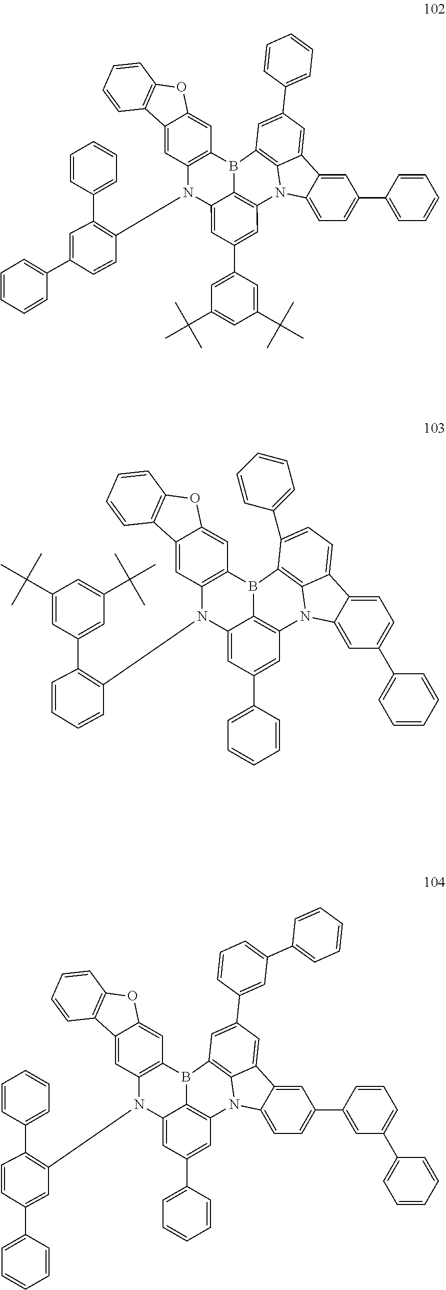 [SMILES: CC(C)(C)c1cc(-c2cc3c4c(c2)-n2c5ccc(-c6ccccc6)cc5c5cc(-c6ccccc6)cc(c52)B4c2cc4oc5ccccc5c4cc2N3c2ccc(-c3ccccc3)cc2-c2ccccc2)cc(C(C)(C)C)c1 ; CC(C)(C)c1cc(-c2ccccc2N2c3cc4c(cc3B3c5c2cc(-c2ccccc2)cc5-n2c5cc(-c6ccccc6)ccc5c5ccc(-c6ccccc6)c3c52)oc2ccccc24)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5oc6ccccc6c5cc3N4c3cc(-c4ccccc4)ccc3-c3ccccc3)c2)cc1]

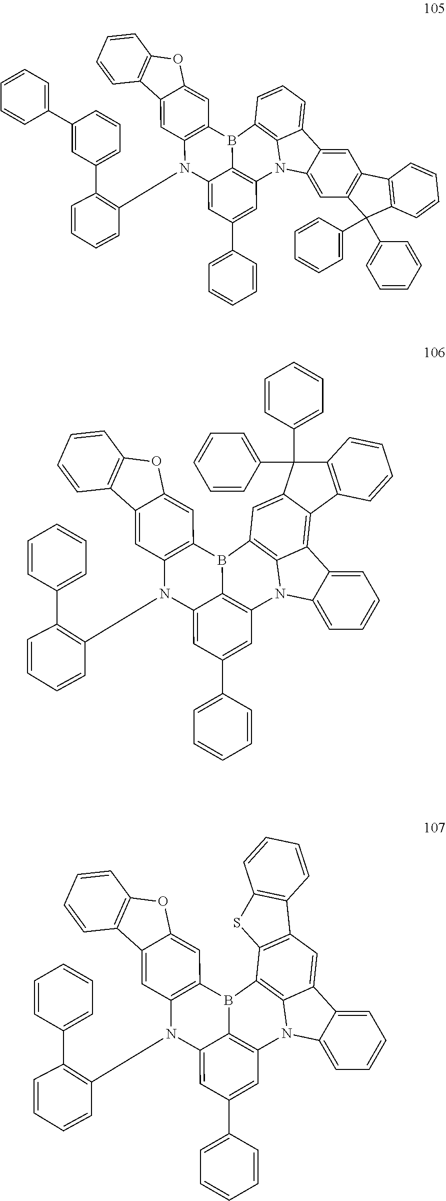 [SMILES: c1ccc(-c2cccc(-c3ccccc3N3c4cc5c(cc4B4c6c3cc(-c3ccccc3)cc6-n3c6cc7c(cc6c6cccc4c63)-c3ccccc3C7(c3ccccc3)c3ccccc3)oc3ccccc35)c2)cc1 ; c1ccc(-c2cc3c4c(c2)-n2c5ccccc5c5c6c(cc(c52)B4c2cc4oc5ccccc5c4cc2N3c2ccccc2-c2ccccc2)C(c2ccccc2)(c2ccccc2)c2ccccc2-6)cc1 ; c1ccc(-c2cc3c4c(c2)-n2c5ccccc5c5cc6c(sc7ccccc76)c(c52)B4c2cc4oc5ccccc5c4cc2N3c2ccccc2-c2ccccc2)cc1]

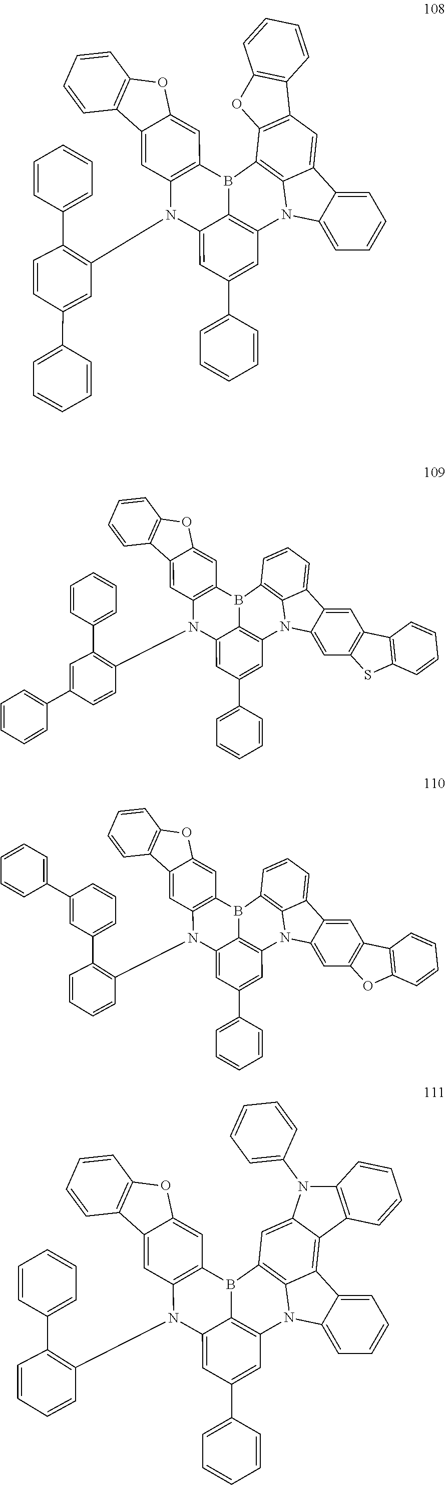

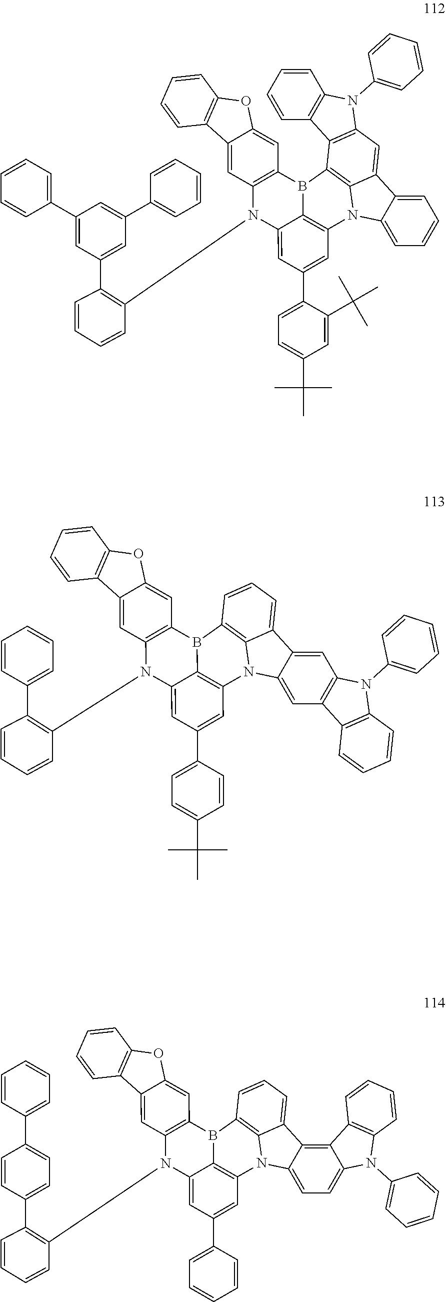 [SMILES: CC(C)(C)c1ccc(-c2cc3c4c(c2)-n2c5ccccc5c5cc6c(c(c52)B4c2cc4oc5ccccc5c4cc2N3c2ccccc2-c2cc(-c3ccccc3)cc(-c3ccccc3)c2)c2ccccc2n6-c2ccccc2)c(C(C)(C)C)c1 ; CC(C)(C)c1ccc(-c2cc3c4c(c2)-n2c5cc6c7ccccc7n(-c7ccccc7)c6cc5c5cccc(c52)B4c2cc4oc5ccccc5c4cc2N3c2ccccc2-c2ccccc2)cc1 ; c1ccc(-c2ccc(-c3ccccc3N3c4cc5c(cc4B4c6c3cc(-c3ccccc3)cc6-n3c6ccc7c(c8ccccc8n7-c7ccccc7)c6c6cccc4c63)oc3ccccc35)cc2)cc1]

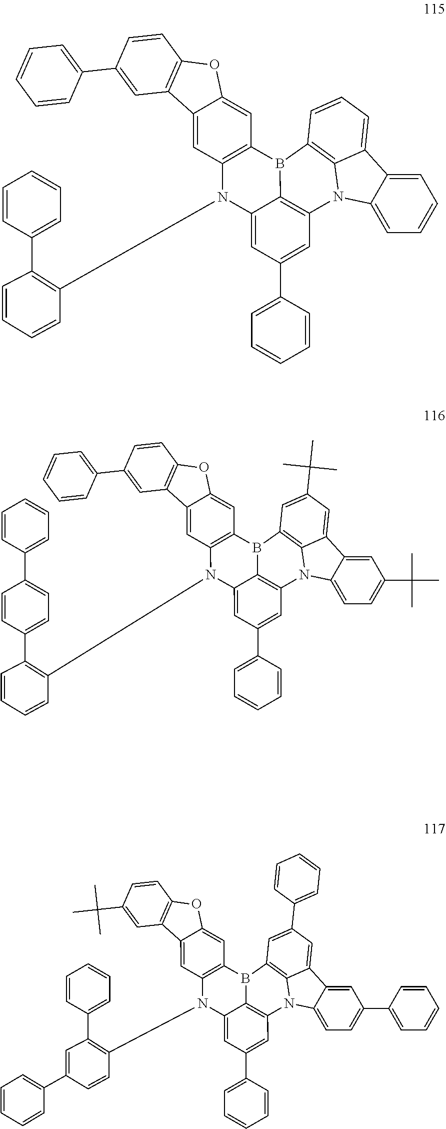 [SMILES: c1ccc(-c2cc3c4c(c2)-n2c5ccccc5c5cccc(c52)B4c2cc4oc5ccc(-c6ccccc6)cc5c4cc2N3c2ccccc2-c2ccccc2)cc1 ; CC(C)(C)c1ccc2c(c1)c1cc(C(C)(C)C)cc3c1n2-c1cc(-c2ccccc2)cc2c1B3c1cc3oc4ccc(-c5ccccc5)cc4c3cc1N2c1ccccc1-c1ccc(-c2ccccc2)cc1 ; CC(C)(C)c1ccc2oc3cc4c(cc3c2c1)N(c1ccc(-c2ccccc2)cc1-c1ccccc1)c1cc(-c2ccccc2)cc2c1B4c1cc(-c3ccccc3)cc3c4cc(-c5ccccc5)ccc4n-2c13]

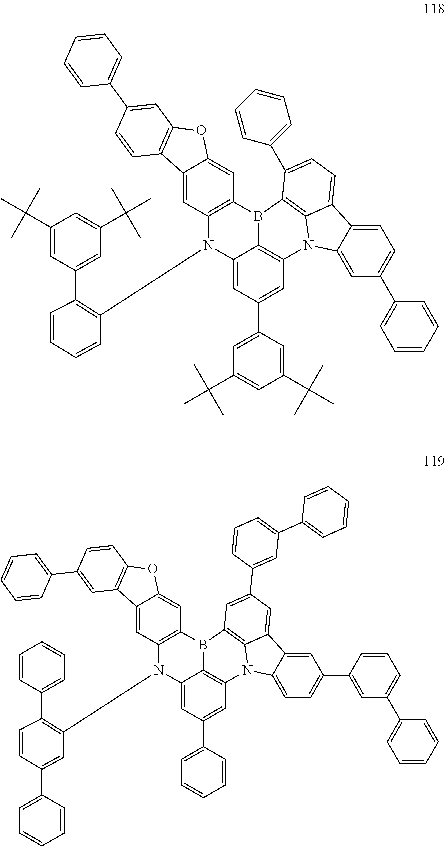 [SMILES: CC(C)(C)c1cc(-c2cc3c4c(c2)-n2c5cc(-c6ccccc6)ccc5c5ccc(-c6ccccc6)c(c52)B4c2cc4oc5cc(-c6ccccc6)ccc5c4cc2N3c2ccccc2-c2cc(C(C)(C)C)cc(C(C)(C)C)c2)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5oc6ccc(-c7ccccc7)cc6c5cc3N4c3cc(-c4ccccc4)ccc3-c3ccccc3)c2)cc1]

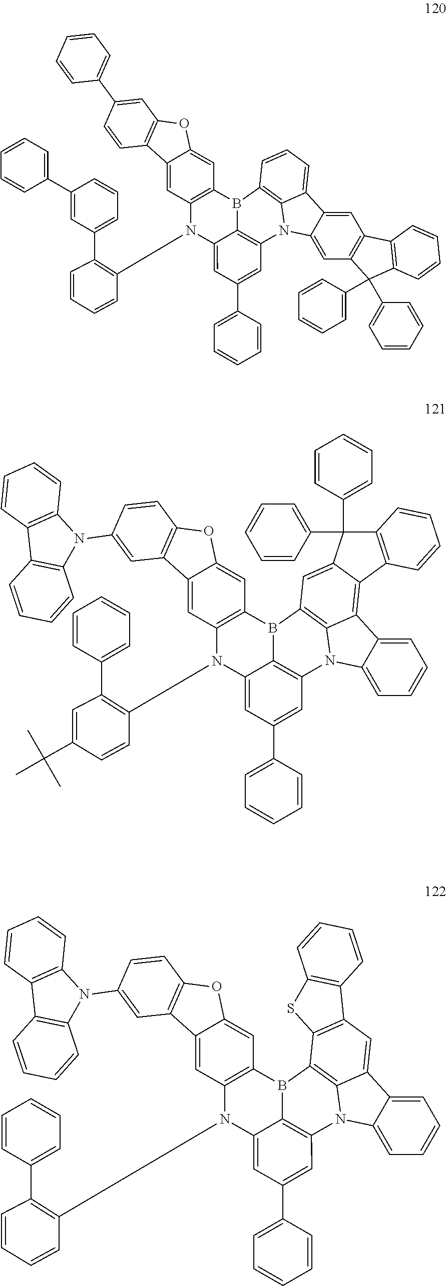 [SMILES: c1ccc(-c2cccc(-c3ccccc3N3c4cc5c(cc4B4c6c3cc(-c3ccccc3)cc6-n3c6cc7c(cc6c6cccc4c63)-c3ccccc3C7(c3ccccc3)c3ccccc3)oc3cc(-c4ccccc4)ccc35)c2)cc1 ; CC(C)(C)c1ccc(N2c3cc4c(cc3B3c5c2cc(-c2ccccc2)cc5-n2c5ccccc5c5c6c(cc3c52)C(c2ccccc2)(c2ccccc2)c2ccccc2-6)oc2ccc(-n3c5ccccc5c5ccccc53)cc24)c(-c2ccccc2)c1 ; c1ccc(-c2cc3c4c(c2)-n2c5ccccc5c5cc6c(sc7ccccc76)c(c52)B4c2cc4oc5ccc(-n6c7ccccc7c7ccccc76)cc5c4cc2N3c2ccccc2-c2ccccc2)cc1]

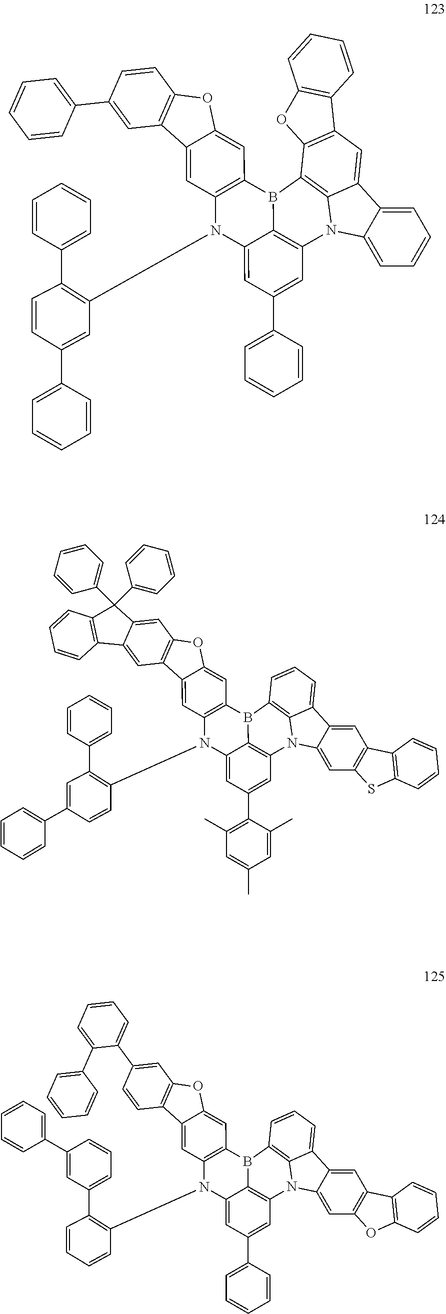 [SMILES: c1ccc(-c2ccc(-c3ccccc3)c(N3c4cc5c(cc4B4c6c3cc(-c3ccccc3)cc6-n3c6ccccc6c6cc7c(oc8ccccc87)c4c63)oc3ccc(-c4ccccc4)cc35)c2)cc1 ; Cc1cc(C)c(-c2cc3c4c(c2)-n2c5cc6sc7ccccc7c6cc5c5cccc(c52)B4c2cc4oc5cc6c(cc5c4cc2N3c2ccc(-c3ccccc3)cc2-c2ccccc2)-c2ccccc2C6(c2ccccc2)c2ccccc2)c(C)c1 ; c1ccc(-c2cccc(-c3ccccc3N3c4cc5c(cc4B4c6c3cc(-c3ccccc3)cc6-n3c6cc7oc8ccccc8c7cc6c6cccc4c63)oc3cc(-c4ccccc4-c4ccccc4)ccc35)c2)cc1]

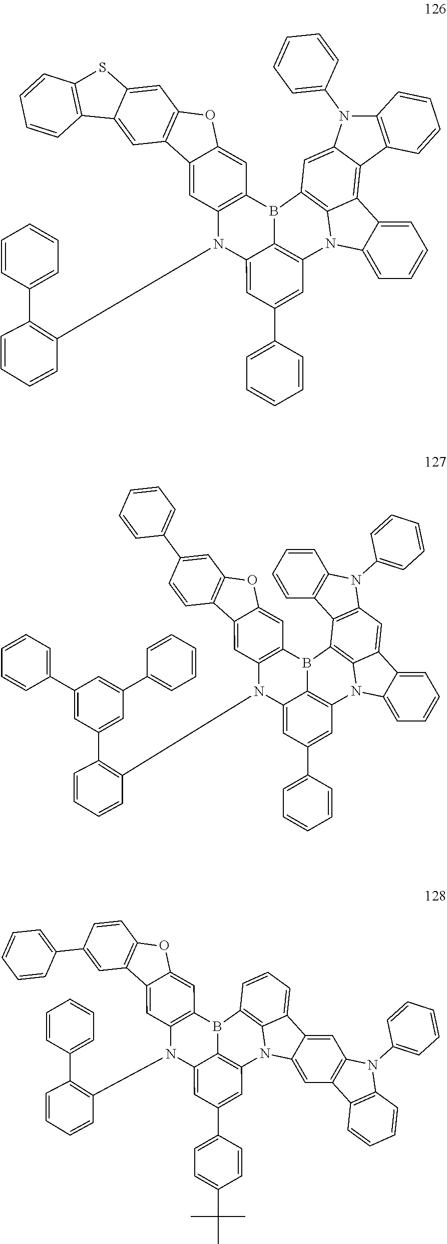 [SMILES: c1ccc(-c2cc3c4c(c2)-n2c5ccccc5c5c6c7ccccc7n(-c7ccccc7)c6cc(c52)B4c2cc4oc5cc6sc7ccccc7c6cc5c4cc2N3c2ccccc2-c2ccccc2)cc1 ; c1ccc(-c2cc(-c3ccccc3)cc(-c3ccccc3N3c4cc5c(cc4B4c6c3cc(-c3ccccc3)cc6-n3c6ccccc6c6cc7c(c4c63)c3ccccc3n7-c3ccccc3)oc3cc(-c4ccccc4)ccc35)c2)cc1 ; CC(C)(C)c1ccc(-c2cc3c4c(c2)-n2c5cc6c7ccccc7n(-c7ccccc7)c6cc5c5cccc(c52)B4c2cc4oc5ccc(-c6ccccc6)cc5c4cc2N3c2ccccc2-c2ccccc2)cc1]

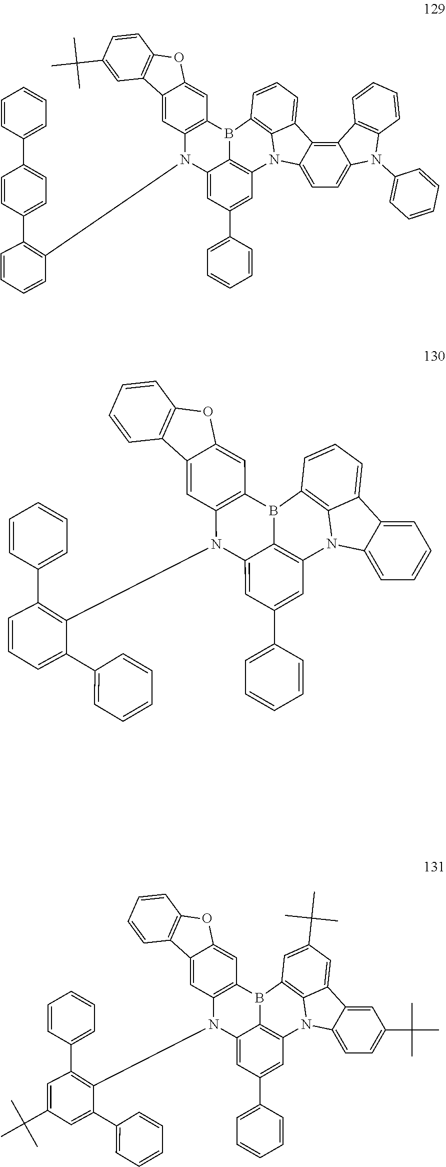 [SMILES: CC(C)(C)c1ccc2oc3cc4c(cc3c2c1)N(c1ccccc1-c1ccc(-c2ccccc2)cc1)c1cc(-c2ccccc2)cc2c1B4c1cccc3c4c5c6ccccc6n(-c6ccccc6)c5ccc4n-2c13 ; c1ccc(-c2cc3c4c(c2)-n2c5ccccc5c5cccc(c52)B4c2cc4oc5ccccc5c4cc2N3c2c(-c3ccccc3)cccc2-c2ccccc2)cc1 ; CC(C)(C)c1cc(-c2ccccc2)c(N2c3cc4c(cc3B3c5c2cc(-c2ccccc2)cc5-n2c5ccc(C(C)(C)C)cc5c5cc(C(C)(C)C)cc3c52)oc2ccccc24)c(-c2ccccc2)c1]

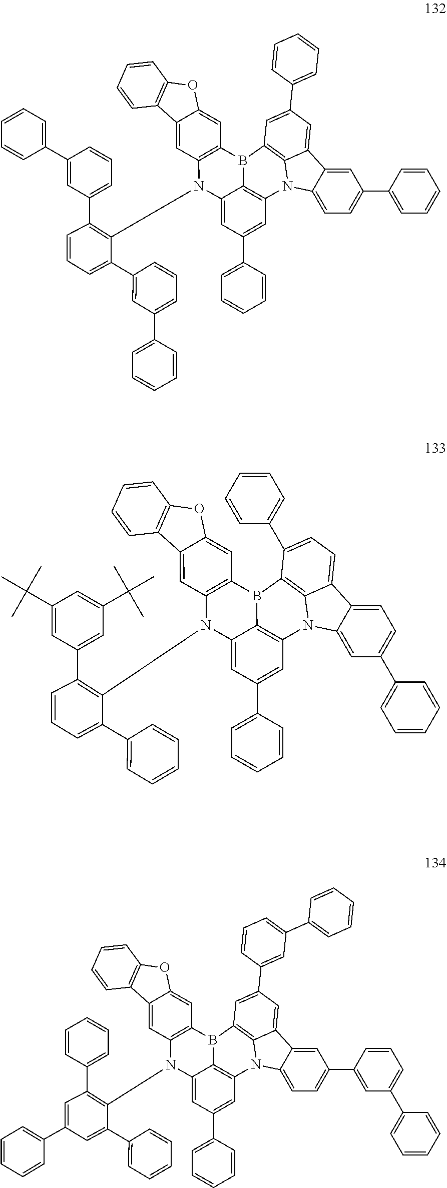 [SMILES: c1ccc(-c2cccc(-c3cccc(-c4cccc(-c5ccccc5)c4)c3N3c4cc5c(cc4B4c6c3cc(-c3ccccc3)cc6-n3c6ccc(-c7ccccc7)cc6c6cc(-c7ccccc7)cc4c63)oc3ccccc35)c2)cc1 ; CC(C)(C)c1cc(-c2cccc(-c3ccccc3)c2N2c3cc4c(cc3B3c5c2cc(-c2ccccc2)cc5-n2c5cc(-c6ccccc6)ccc5c5ccc(-c6ccccc6)c3c52)oc2ccccc24)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5oc6ccccc6c5cc3N4c3c(-c4ccccc4)cc(-c4ccccc4)cc3-c3ccccc3)c2)cc1]

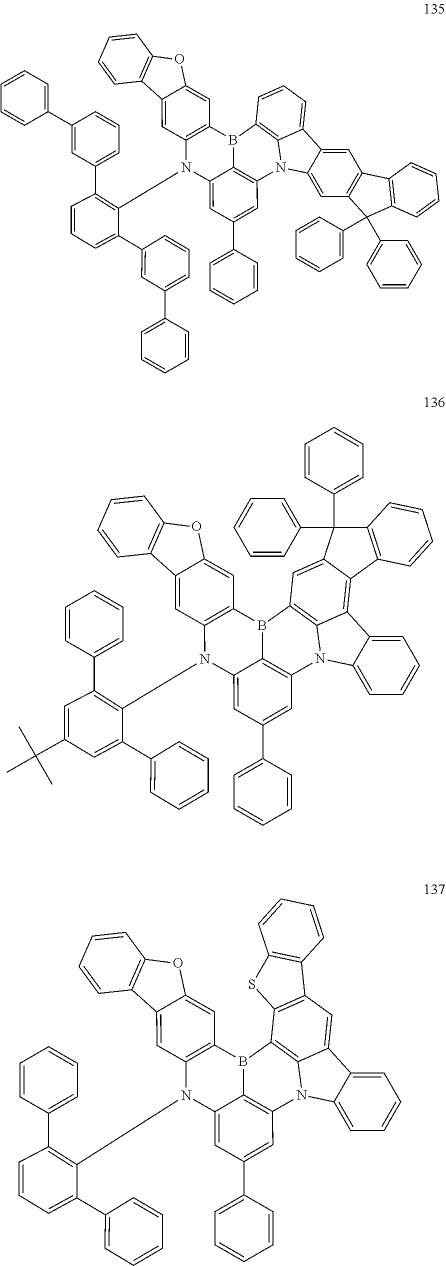 [SMILES: c1ccc(-c2cccc(-c3cccc(-c4cccc(-c5ccccc5)c4)c3N3c4cc5c(cc4B4c6c3cc(-c3ccccc3)cc6-n3c6cc7c(cc6c6cccc4c63)-c3ccccc3C7(c3ccccc3)c3ccccc3)oc3ccccc35)c2)cc1 ; CC(C)(C)c1cc(-c2ccccc2)c(N2c3cc4c(cc3B3c5c2cc(-c2ccccc2)cc5-n2c5ccccc5c5c6c(cc3c52)C(c2ccccc2)(c2ccccc2)c2ccccc2-6)oc2ccccc24)c(-c2ccccc2)c1 ; c1ccc(-c2cc3c4c(c2)-n2c5ccccc5c5cc6c(sc7ccccc76)c(c52)B4c2cc4oc5ccccc5c4cc2N3c2c(-c3ccccc3)cccc2-c2ccccc2)cc1]

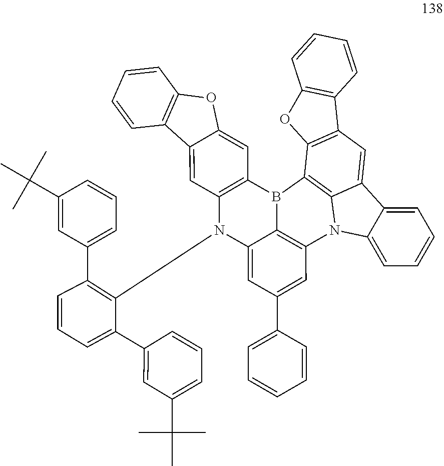 [SMILES: CC(C)(C)c1cccc(-c2cccc(-c3cccc(C(C)(C)C)c3)c2N2c3cc4c(cc3B3c5c2cc(-c2ccccc2)cc5-n2c5ccccc5c5cc6c(oc7ccccc76)c3c52)oc2ccccc24)c1]

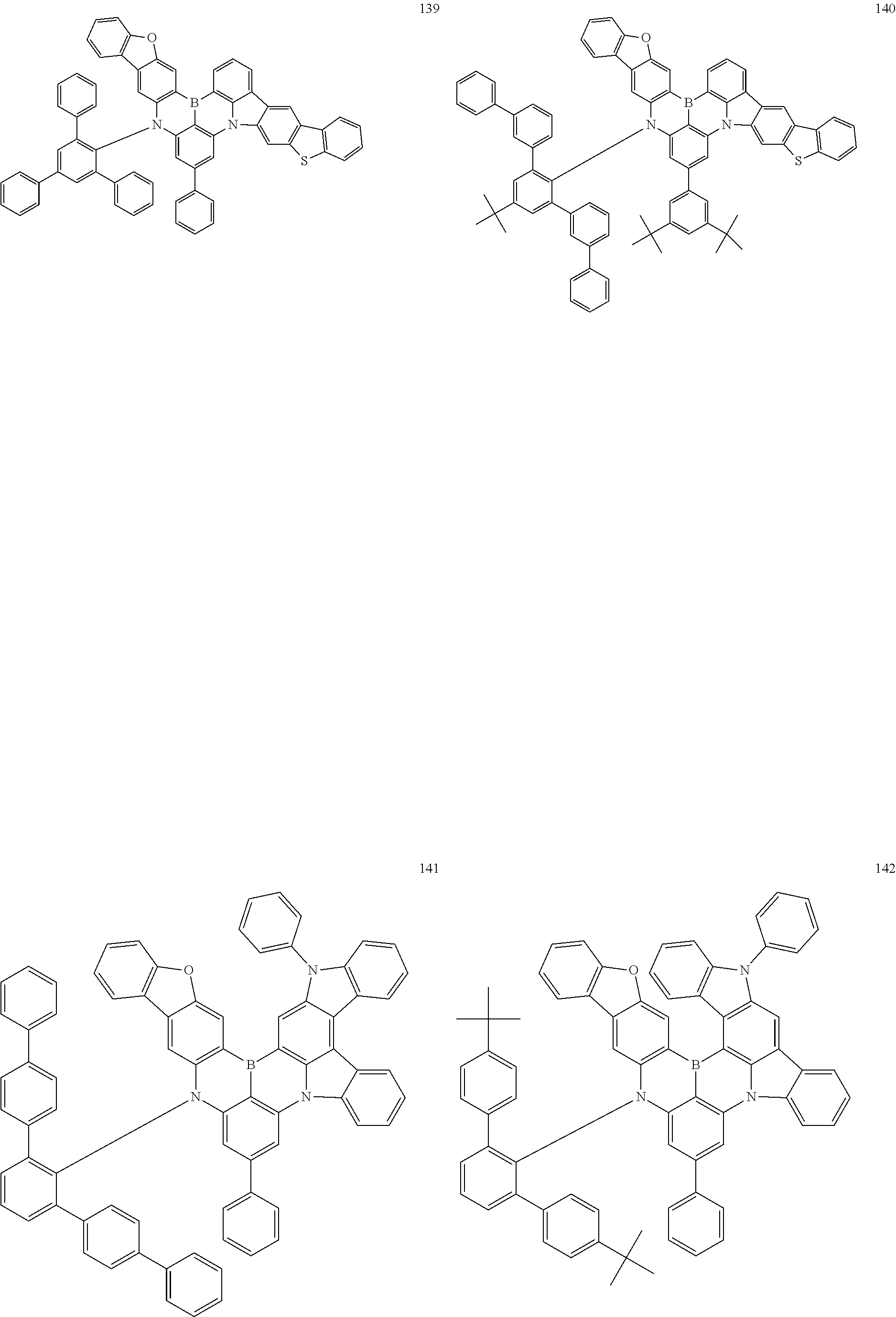

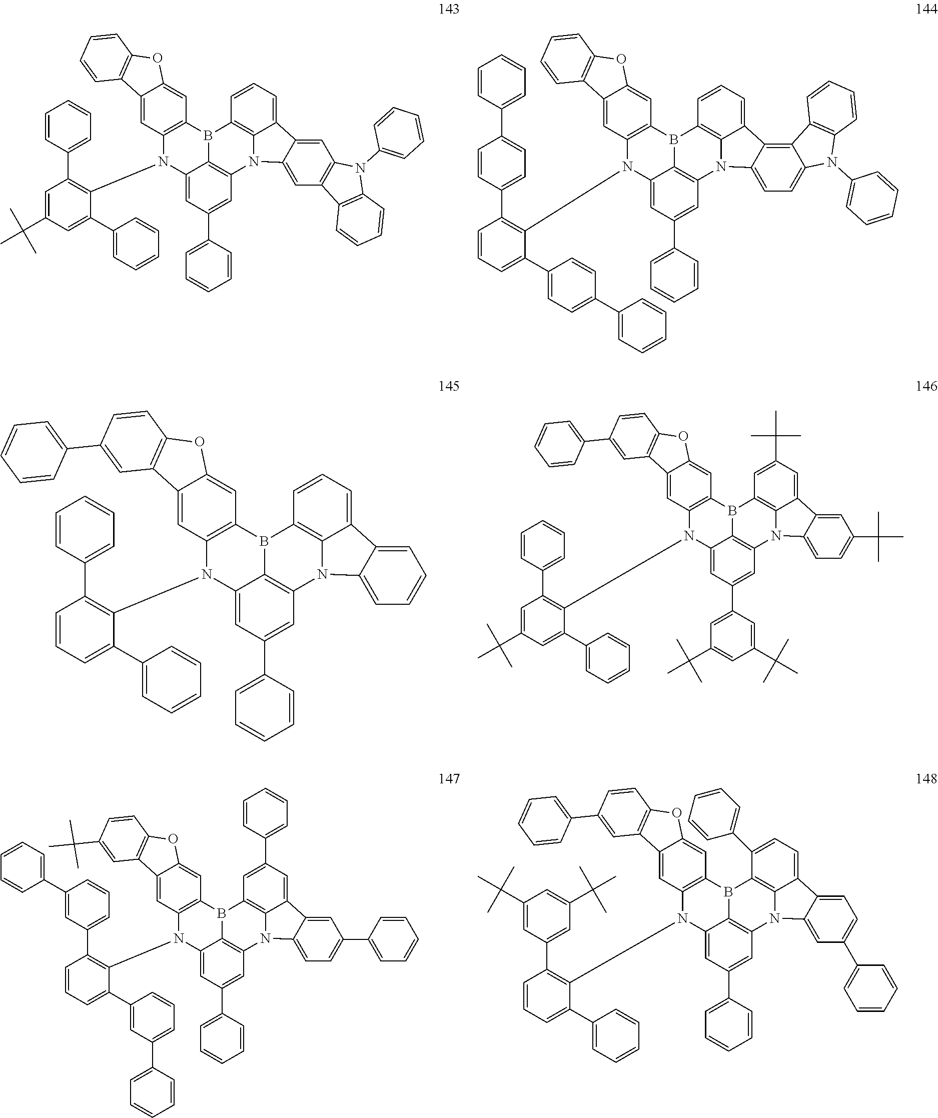

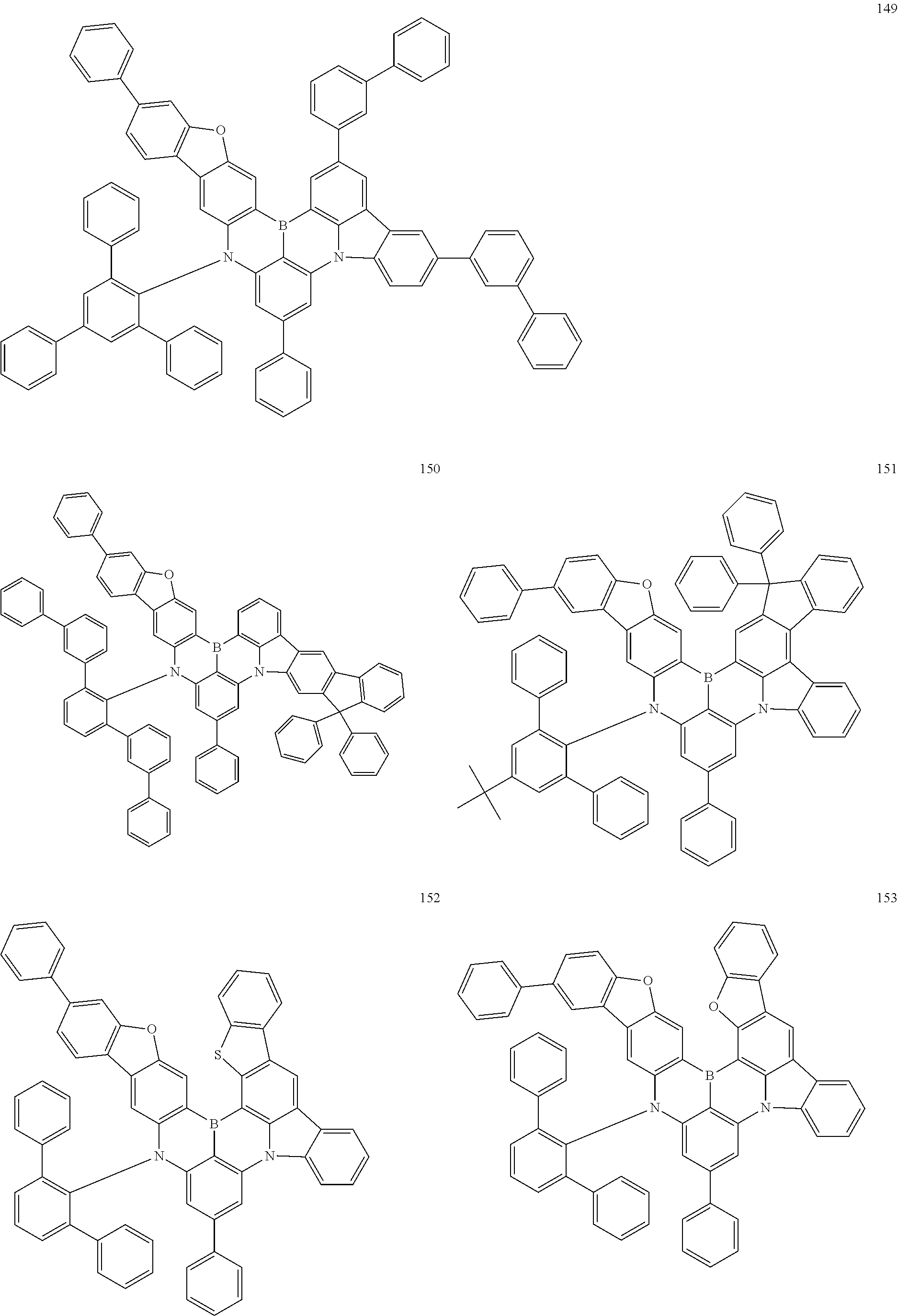

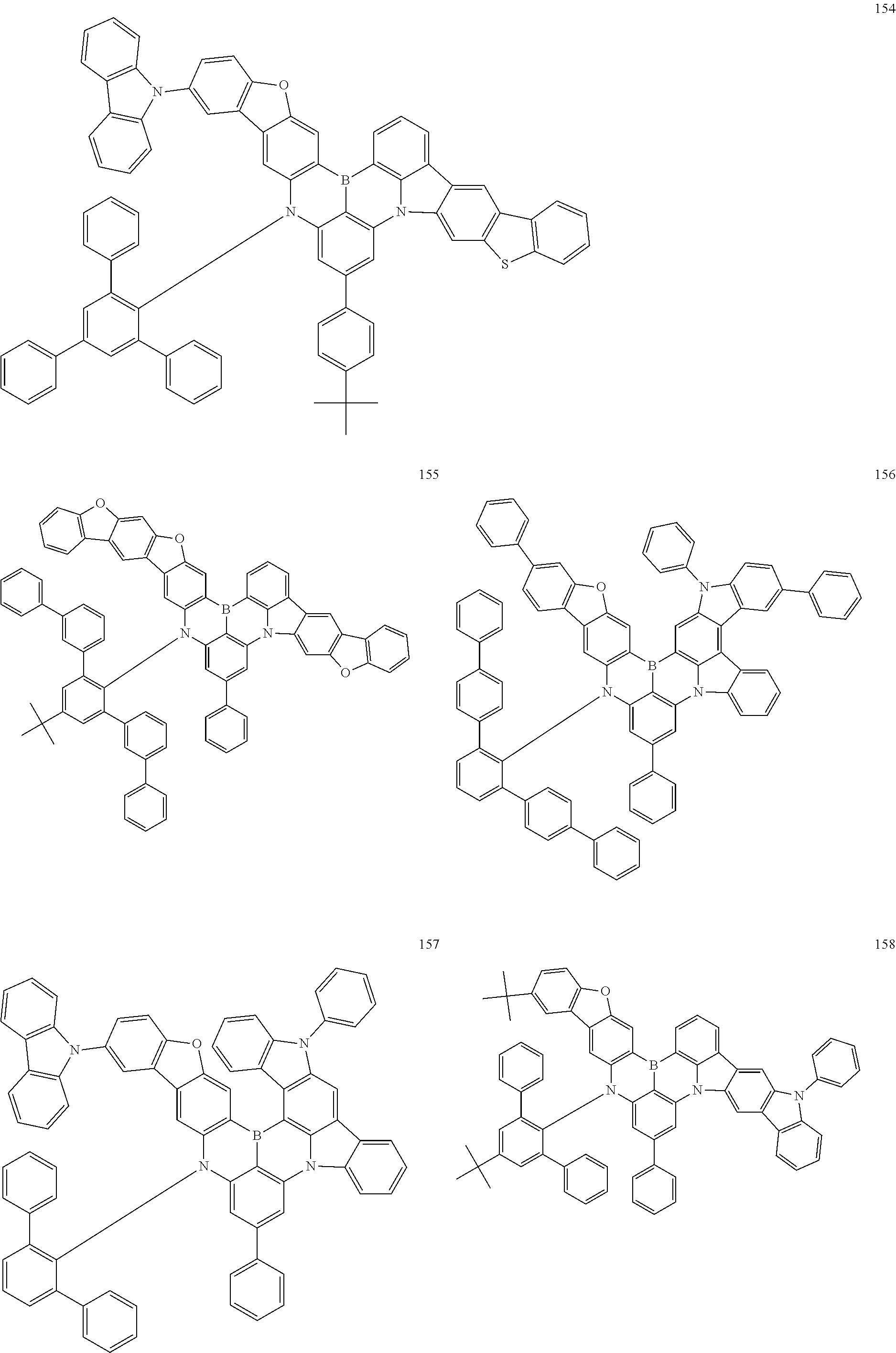

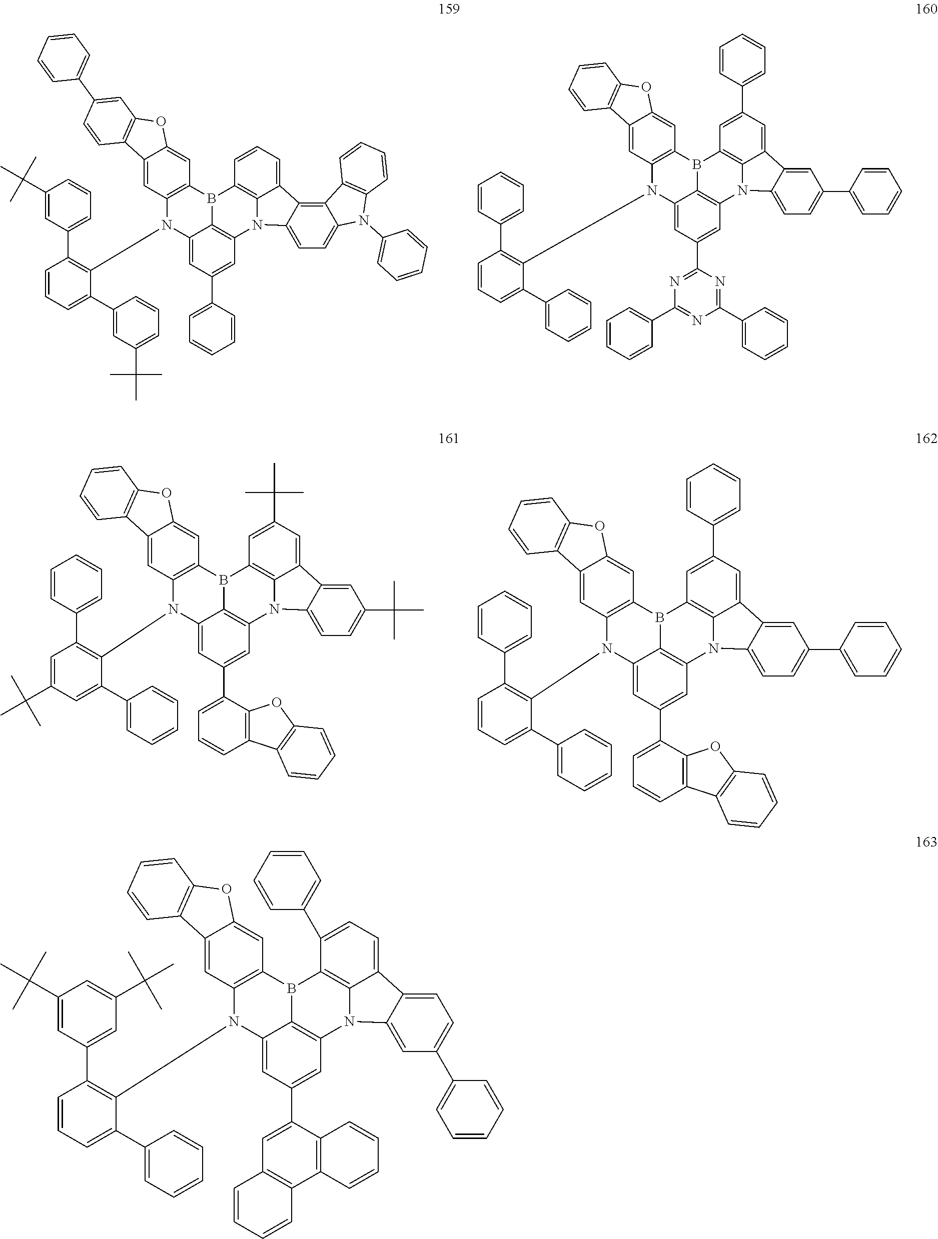

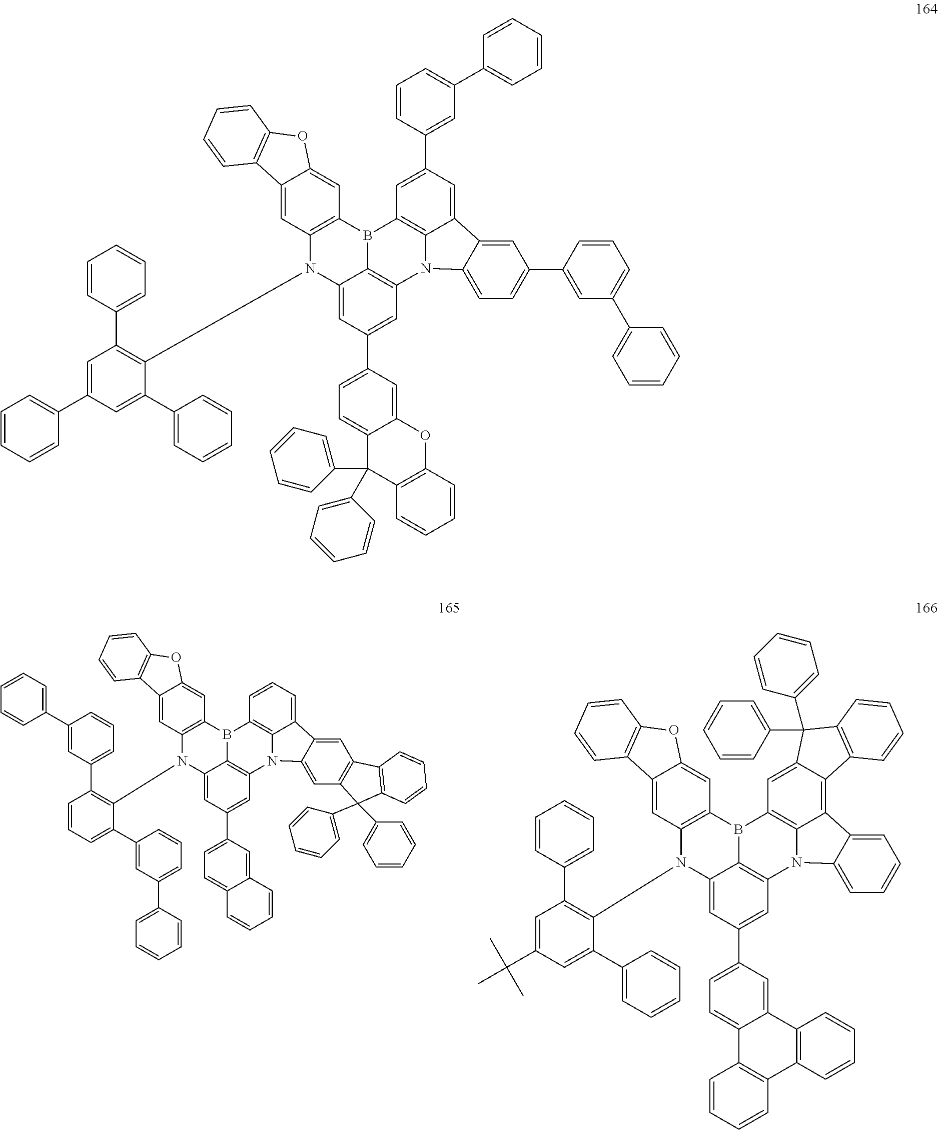

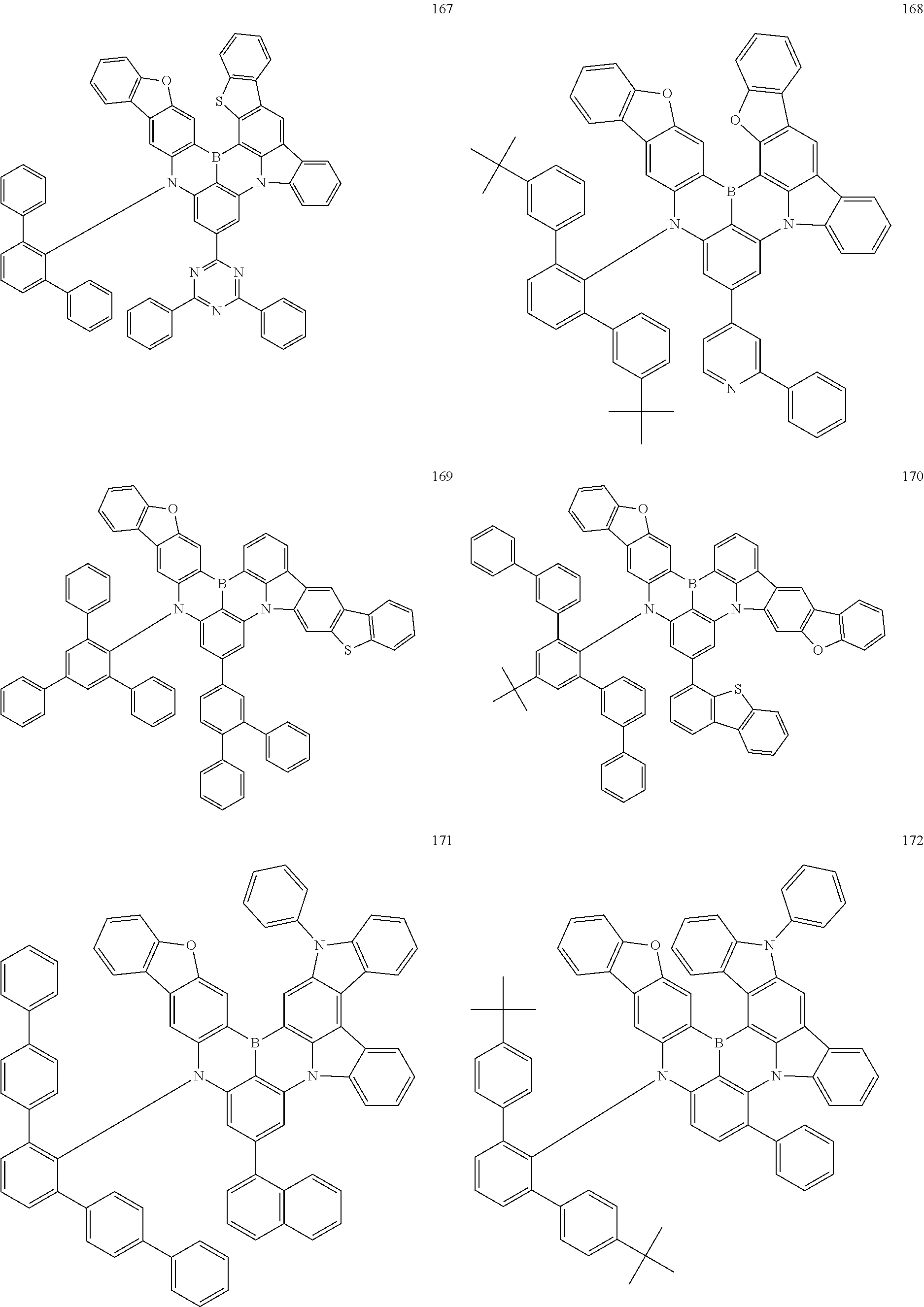

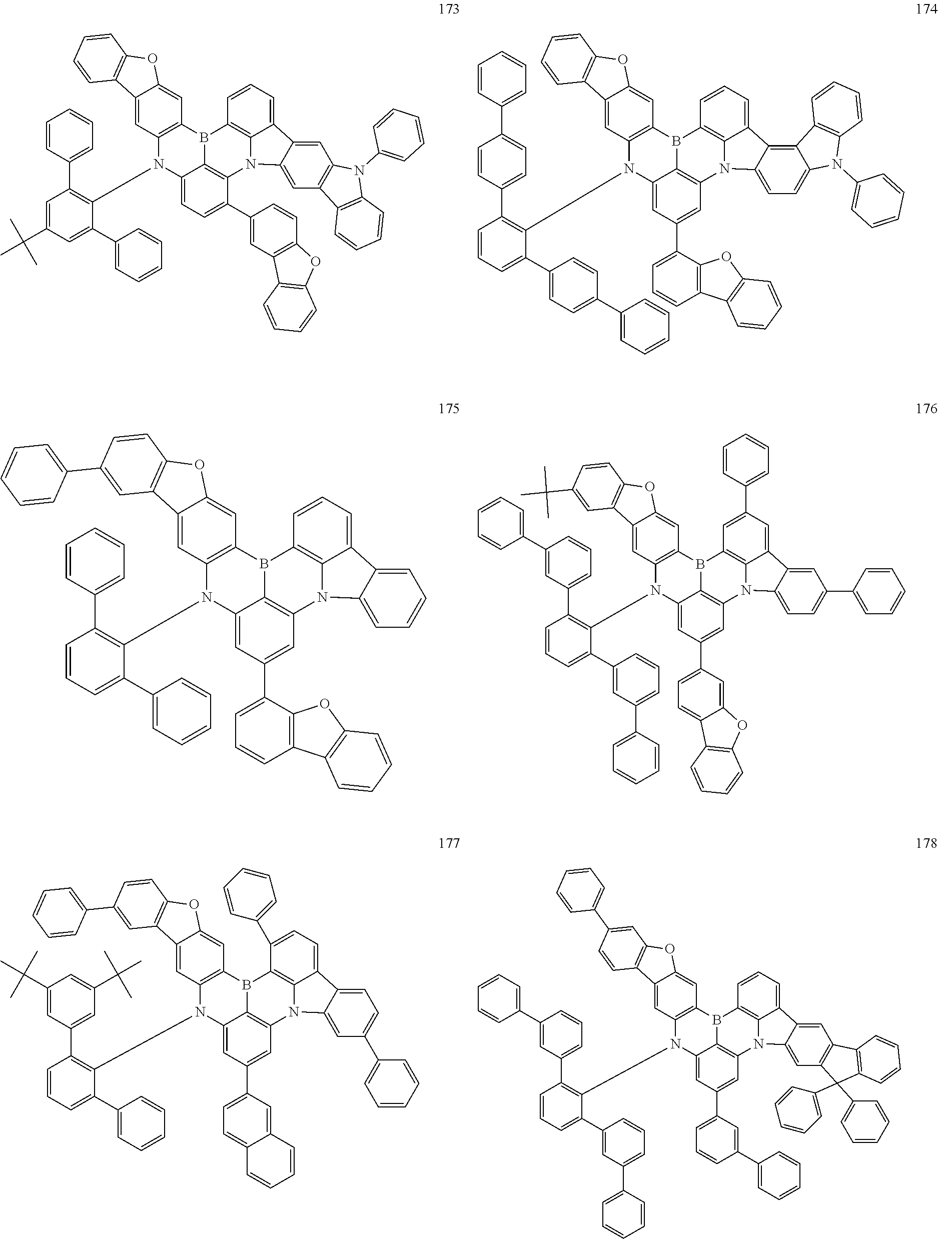

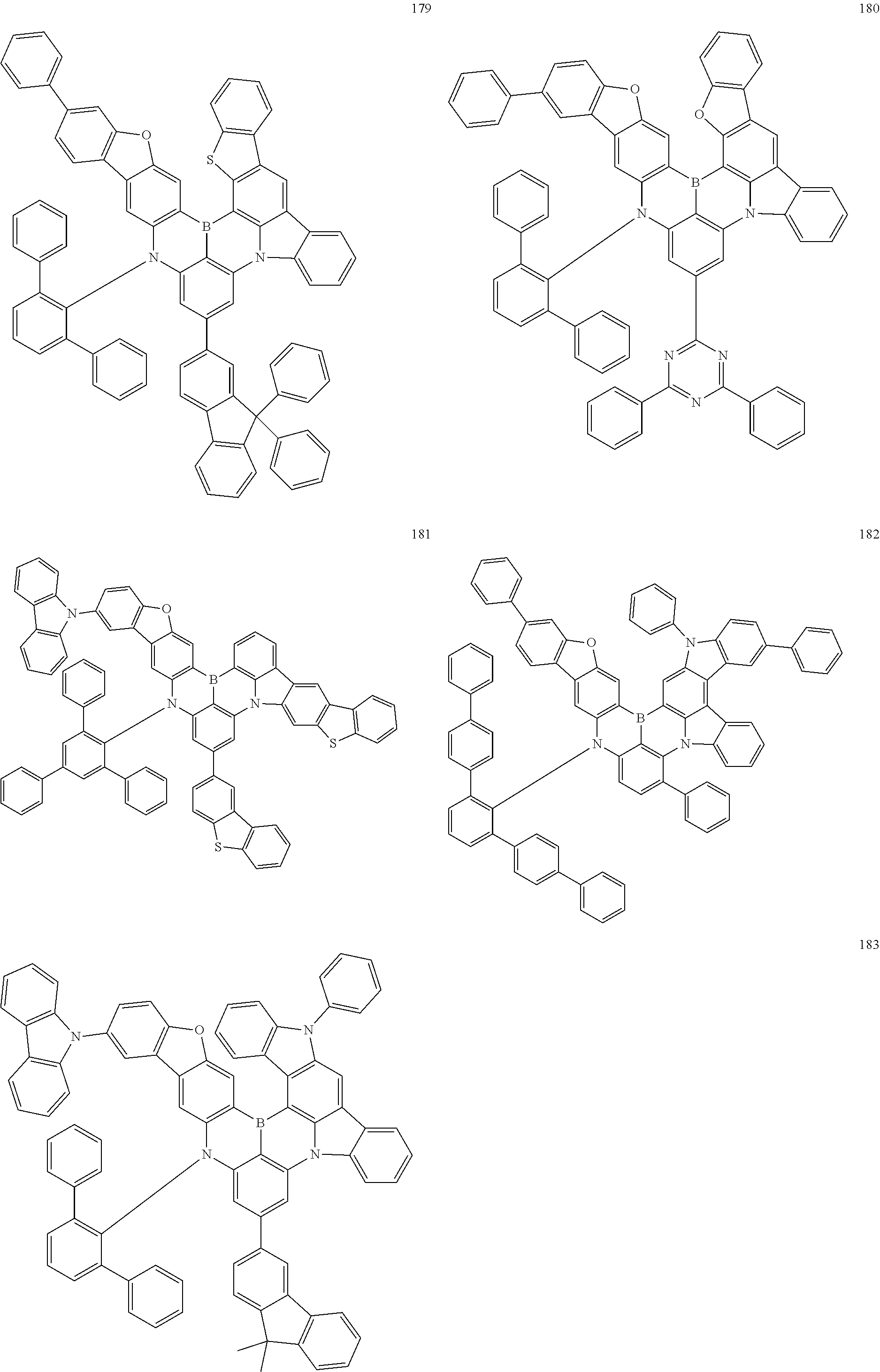

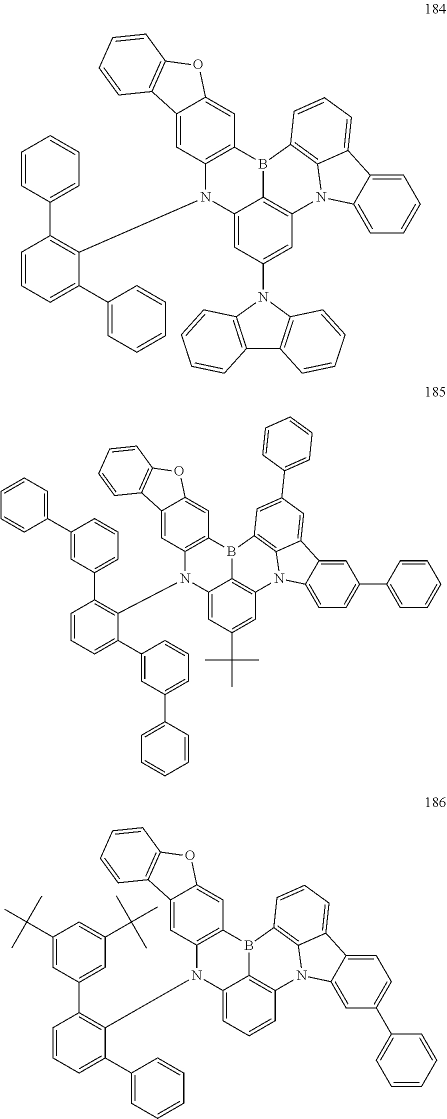 [SMILES: c1ccc(-c2cccc(-c3ccccc3)c2N2c3cc4c(cc3B3c5c2cc(-n2c6ccccc6c6ccccc62)cc5-n2c5ccccc5c5cccc3c52)oc2ccccc24)cc1 ; CC(C)(C)c1cc2c3c(c1)-n1c4ccc(-c5ccccc5)cc4c4cc(-c5ccccc5)cc(c41)B3c1cc3oc4ccccc4c3cc1N2c1c(-c2cccc(-c3ccccc3)c2)cccc1-c1cccc(-c2ccccc2)c1 ; CC(C)(C)c1cc(-c2cccc(-c3ccccc3)c2N2c3cc4c(cc3B3c5c2cccc5-n2c5cc(-c6ccccc6)ccc5c5cccc3c52)oc2ccccc24)cc(C(C)(C)C)c1]

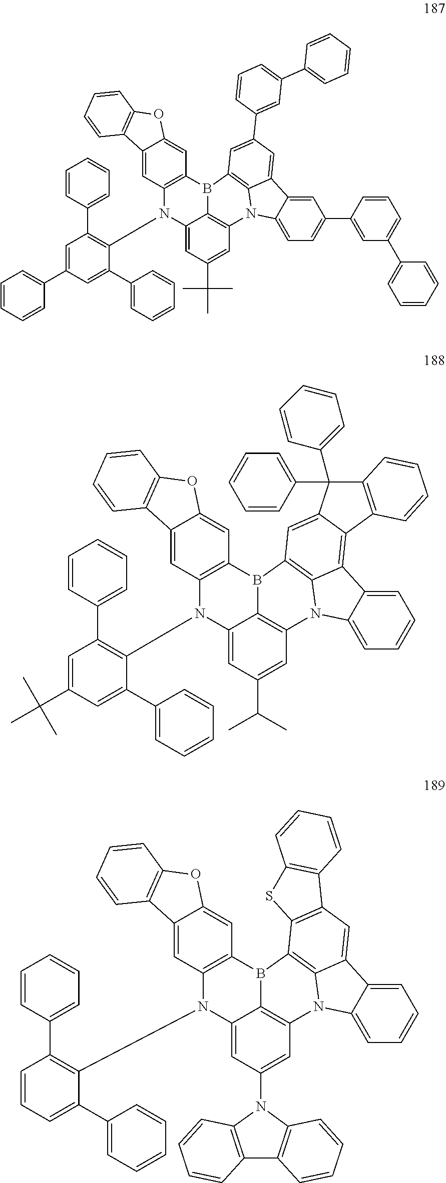 [SMILES: CC(C)(C)c1cc2c3c(c1)-n1c4ccc(-c5cccc(-c6ccccc6)c5)cc4c4cc(-c5cccc(-c6ccccc6)c5)cc(c41)B3c1cc3oc4ccccc4c3cc1N2c1c(-c2ccccc2)cc(-c2ccccc2)cc1-c1ccccc1 ; CC(C)c1cc2c3c(c1)-n1c4ccccc4c4c5c(cc(c41)B3c1cc3oc4ccccc4c3cc1N2c1c(-c2ccccc2)cc(C(C)(C)C)cc1-c1ccccc1)C(c1ccccc1)(c1ccccc1)c1ccccc1-5 ; c1ccc(-c2cccc(-c3ccccc3)c2N2c3cc4c(cc3B3c5c2cc(-n2c6ccccc6c6ccccc62)cc5-n2c5ccccc5c5cc6c(sc7ccccc76)c3c52)oc2ccccc24)cc1]

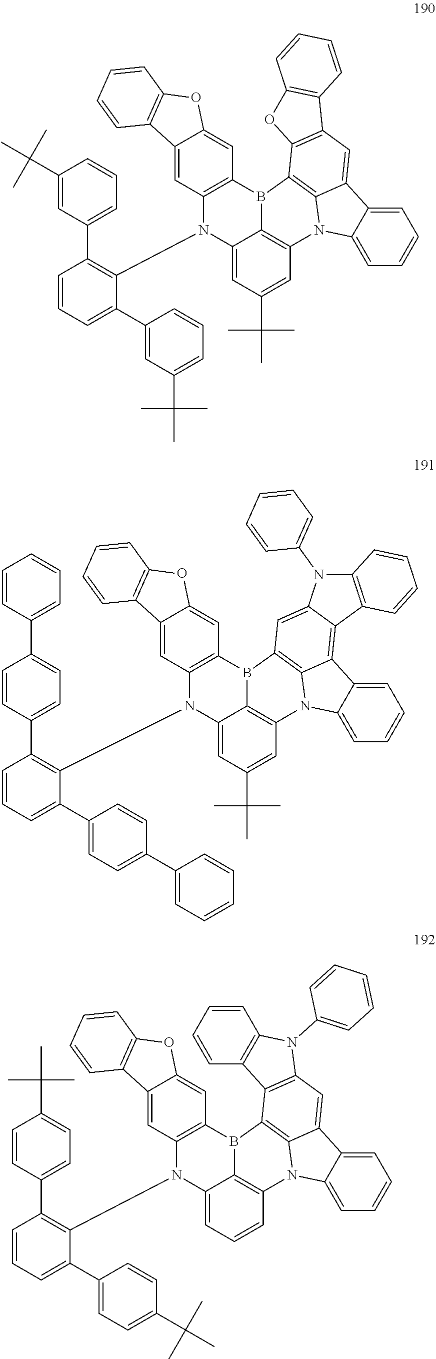 [SMILES: CC(C)(C)c1cccc(-c2cccc(-c3cccc(C(C)(C)C)c3)c2N2c3cc4c(cc3B3c5c2cc(C(C)(C)C)cc5-n2c5ccccc5c5cc6c(oc7ccccc76)c3c52)oc2ccccc24)c1 ; CC(C)(C)c1cc2c3c(c1)-n1c4ccccc4c4c5c6ccccc6n(-c6ccccc6)c5cc(c41)B3c1cc3oc4ccccc4c3cc1N2c1c(-c2ccc(-c3ccccc3)cc2)cccc1-c1ccc(-c2ccccc2)cc1 ; CC(C)(C)c1ccc(-c2cccc(-c3ccc(C(C)(C)C)cc3)c2N2c3cc4c(cc3B3c5c2cccc5-n2c5ccccc5c5cc6c(c3c52)c2ccccc2n6-c2ccccc2)oc2ccccc24)cc1]

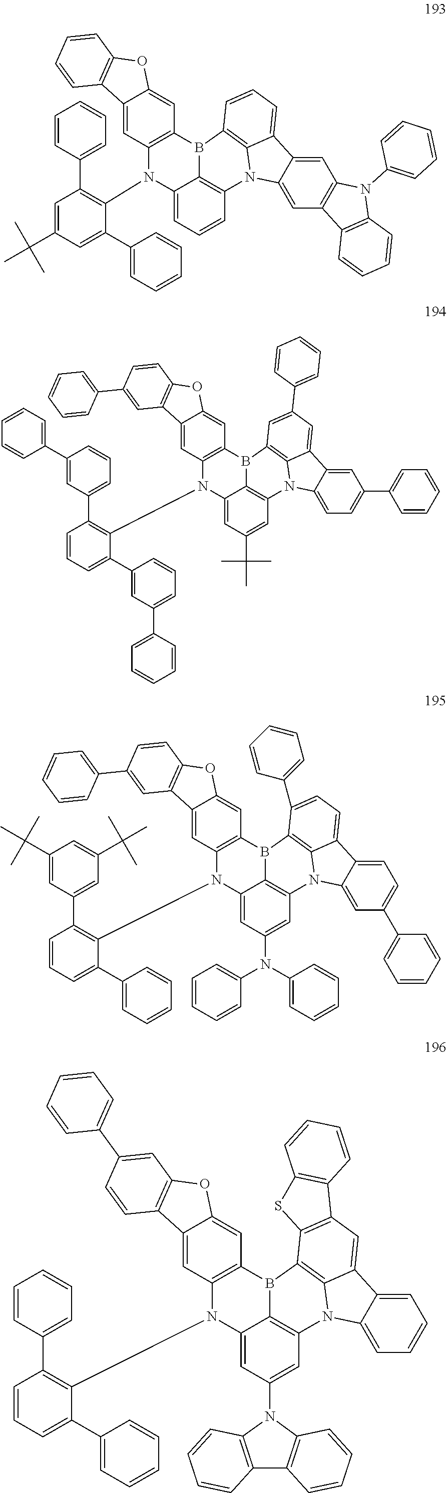

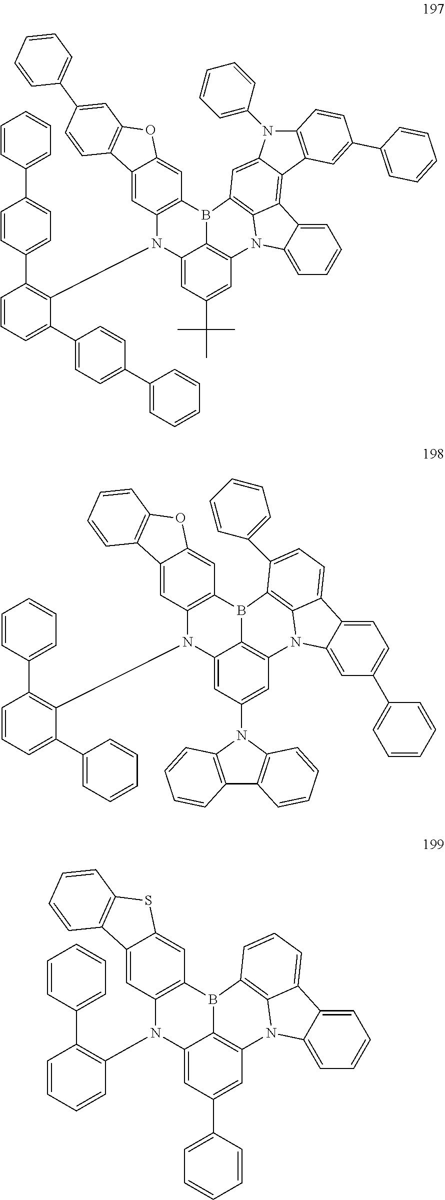 [SMILES: CC(C)(C)c1cc2c3c(c1)-n1c4ccccc4c4c5c6cc(-c7ccccc7)ccc6n(-c6ccccc6)c5cc(c41)B3c1cc3oc4cc(-c5ccccc5)ccc4c3cc1N2c1c(-c2ccc(-c3ccccc3)cc2)cccc1-c1ccc(-c2ccccc2)cc1 ; c1ccc(-c2ccc3c4ccc(-c5ccccc5)c5c4n(c3c2)-c2cc(-n3c4ccccc4c4ccccc43)cc3c2B5c2cc4oc5ccccc5c4cc2N3c2c(-c3ccccc3)cccc2-c2ccccc2)cc1 ; c1ccc(-c2cc3c4c(c2)-n2c5ccccc5c5cccc(c52)B4c2cc4sc5ccccc5c4cc2N3c2ccccc2-c2ccccc2)cc1]

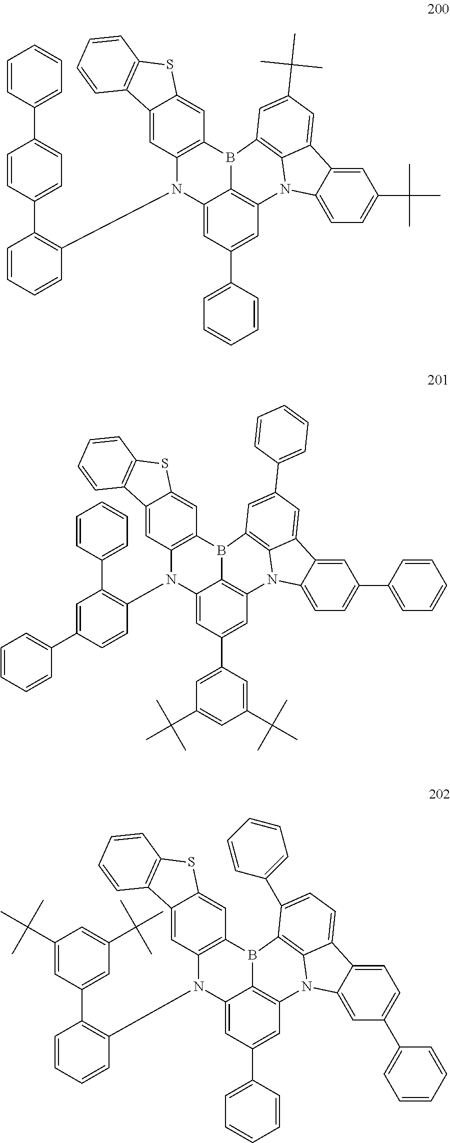

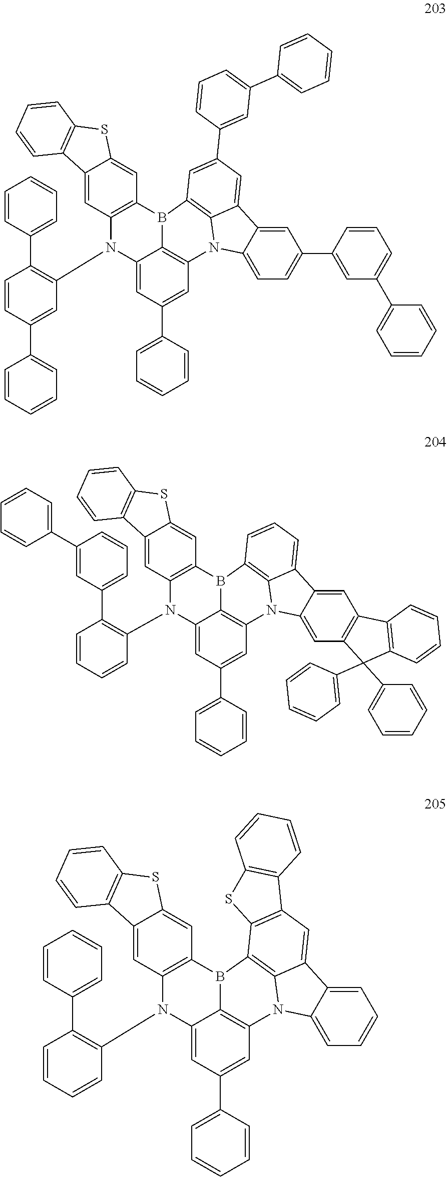 [SMILES: c1ccc(-c2cccc(-c3ccc4c(c3)c3cc(-c5cccc(-c6ccccc6)c5)cc5c3n4-c3cc(-c4ccccc4)cc4c3B5c3cc5sc6ccccc6c5cc3N4c3cc(-c4ccccc4)ccc3-c3ccccc3)c2)cc1 ; c1ccc(-c2cccc(-c3ccccc3N3c4cc5c(cc4B4c6c3cc(-c3ccccc3)cc6-n3c6cc7c(cc6c6cccc4c63)-c3ccccc3C7(c3ccccc3)c3ccccc3)sc3ccccc35)c2)cc1 ; c1ccc(-c2cc3c4c(c2)-n2c5ccccc5c5cc6c(sc7ccccc76)c(c52)B4c2cc4sc5ccccc5c4cc2N3c2ccccc2-c2ccccc2)cc1]

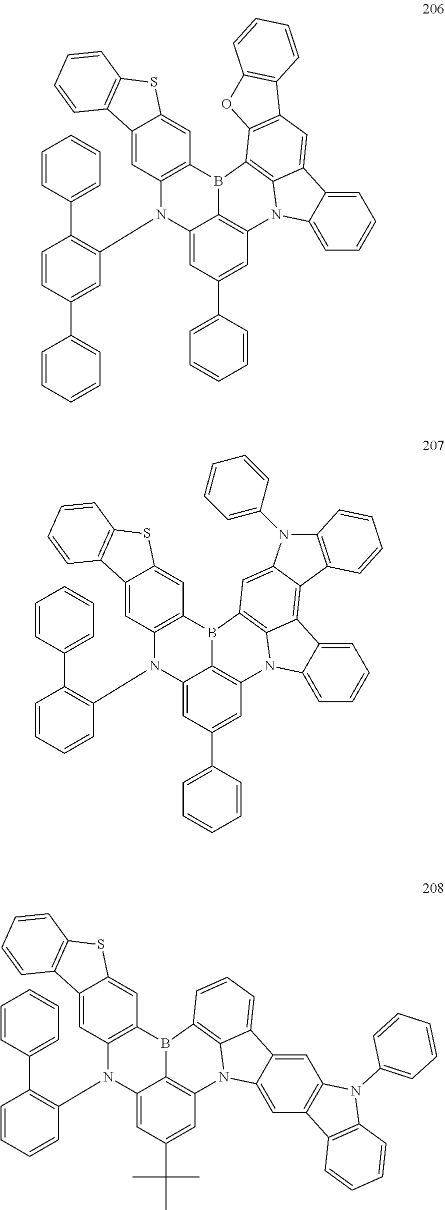 [SMILES: c1ccc(-c2ccc(-c3ccccc3)c(N3c4cc5c(cc4B4c6c3cc(-c3ccccc3)cc6-n3c6ccccc6c6cc7c(oc8ccccc87)c4c63)sc3ccccc35)c2)cc1 ; c1ccc(-c2cc3c4c(c2)-n2c5ccccc5c5c6c7ccccc7n(-c7ccccc7)c6cc(c52)B4c2cc4sc5ccccc5c4cc2N3c2ccccc2-c2ccccc2)cc1 ; CC(C)(C)c1cc2c3c(c1)-n1c4cc5c6ccccc6n(-c6ccccc6)c5cc4c4cccc(c41)B3c1cc3sc4ccccc4c3cc1N2c1ccccc1-c1ccccc1]

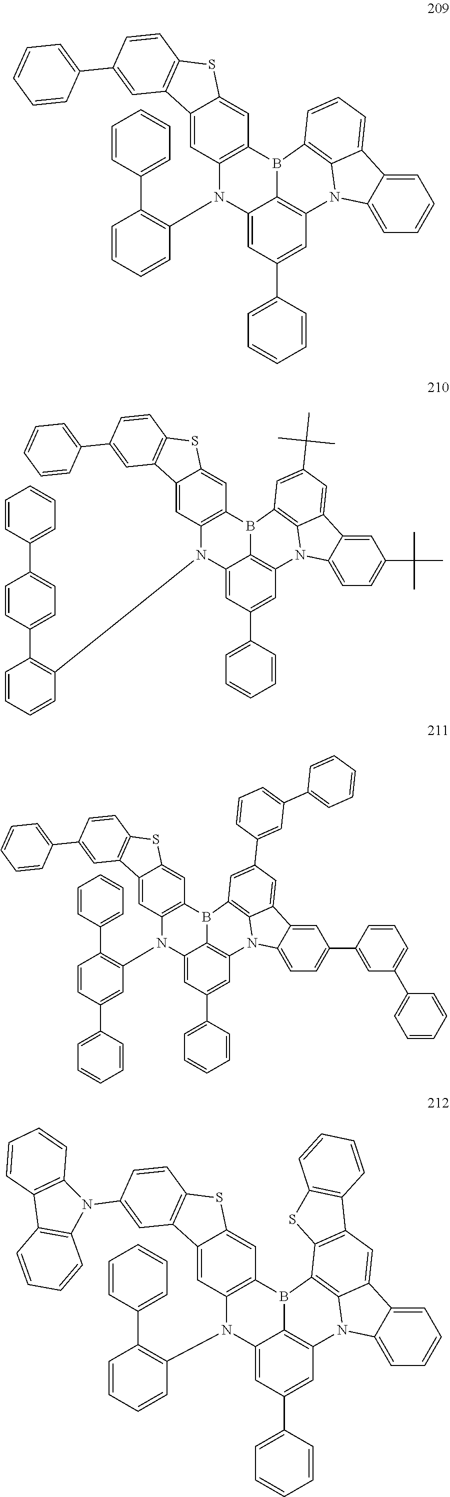 [SMILES: c1ccc(-c2cc3c4c(c2)-n2c5ccccc5c5cccc(c52)B4c2cc4sc5ccc(-c6ccccc6)cc5c4cc2N3c2ccccc2-c2ccccc2)cc1 ; CC(C)(C)c1ccc2c(c1)c1cc(C(C)(C)C)cc3c1n2-c1cc(-c2ccccc2)cc2c1B3c1cc3sc4ccc(-c5ccccc5)cc4c3cc1N2c1ccccc1-c1ccc(-c2ccccc2)cc1 ; c1ccc(-c2cccc(-c3ccc4c(c3)c3cc(-c5cccc(-c6ccccc6)c5)cc5c3n4-c3cc(-c4ccccc4)cc4c3B5c3cc5sc6ccc(-c7ccccc7)cc6c5cc3N4c3cc(-c4ccccc4)ccc3-c3ccccc3)c2)cc1 ; c1ccc(-c2cc3c4c(c2)-n2c5ccccc5c5cc6c(sc7ccccc76)c(c52)B4c2cc4sc5ccc(-n6c7ccccc7c7ccccc76)cc5c4cc2N3c2ccccc2-c2ccccc2)cc1]

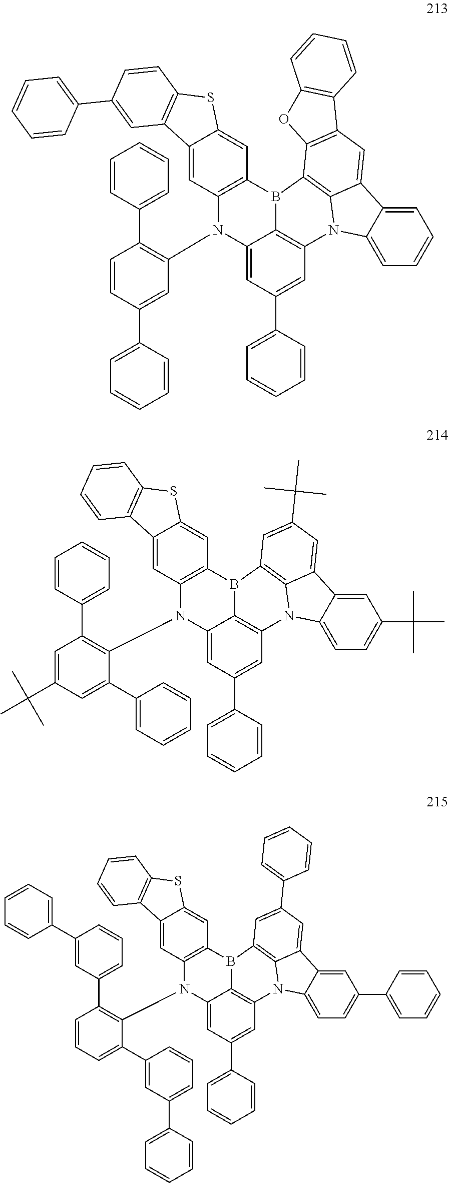 [SMILES: c1ccc(-c2ccc(-c3ccccc3)c(N3c4cc5c(cc4B4c6c3cc(-c3ccccc3)cc6-n3c6ccccc6c6cc7c(oc8ccccc87)c4c63)sc3ccc(-c4ccccc4)cc35)c2)cc1 ; CC(C)(C)c1cc(-c2ccccc2)c(N2c3cc4c(cc3B3c5c2cc(-c2ccccc2)cc5-n2c5ccc(C(C)(C)C)cc5c5cc(C(C)(C)C)cc3c52)sc2ccccc24)c(-c2ccccc2)c1 ; c1ccc(-c2cccc(-c3cccc(-c4cccc(-c5ccccc5)c4)c3N3c4cc5c(cc4B4c6c3cc(-c3ccccc3)cc6-n3c6ccc(-c7ccccc7)cc6c6cc(-c7ccccc7)cc4c63)sc3ccccc35)c2)cc1]

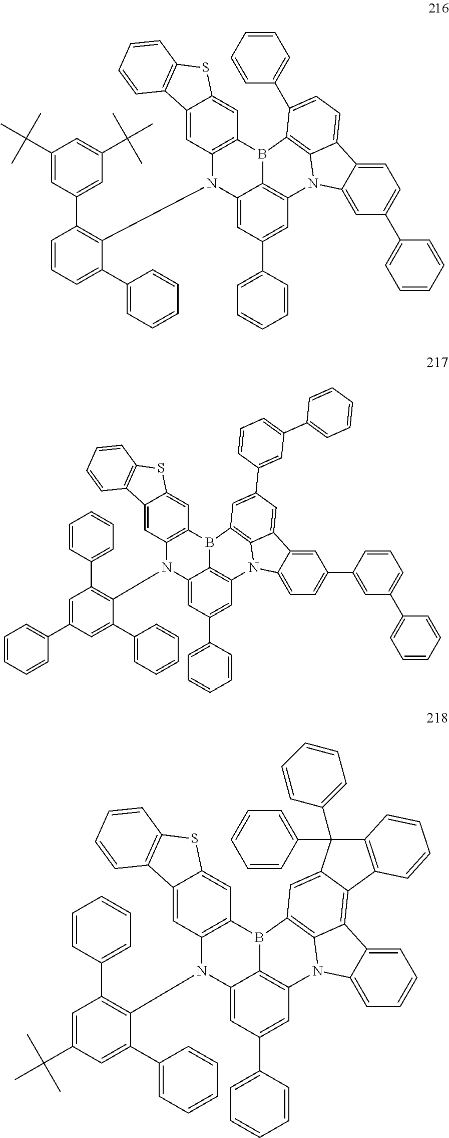 [SMILES: CC(C)(C)c1cc(-c2cccc(-c3ccccc3)c2N2c3cc4c(cc3B3c5c2cc(-c2ccccc2)cc5-n2c5cc(-c6ccccc6)ccc5c5ccc(-c6ccccc6)c3c52)sc2ccccc24)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5sc6ccccc6c5cc3N4c3c(-c4ccccc4)cc(-c4ccccc4)cc3-c3ccccc3)c2)cc1 ; CC(C)(C)c1cc(-c2ccccc2)c(N2c3cc4c(cc3B3c5c2cc(-c2ccccc2)cc5-n2c5ccccc5c5c6c(cc3c52)C(c2ccccc2)(c2ccccc2)c2ccccc2-6)sc2ccccc24)c(-c2ccccc2)c1]

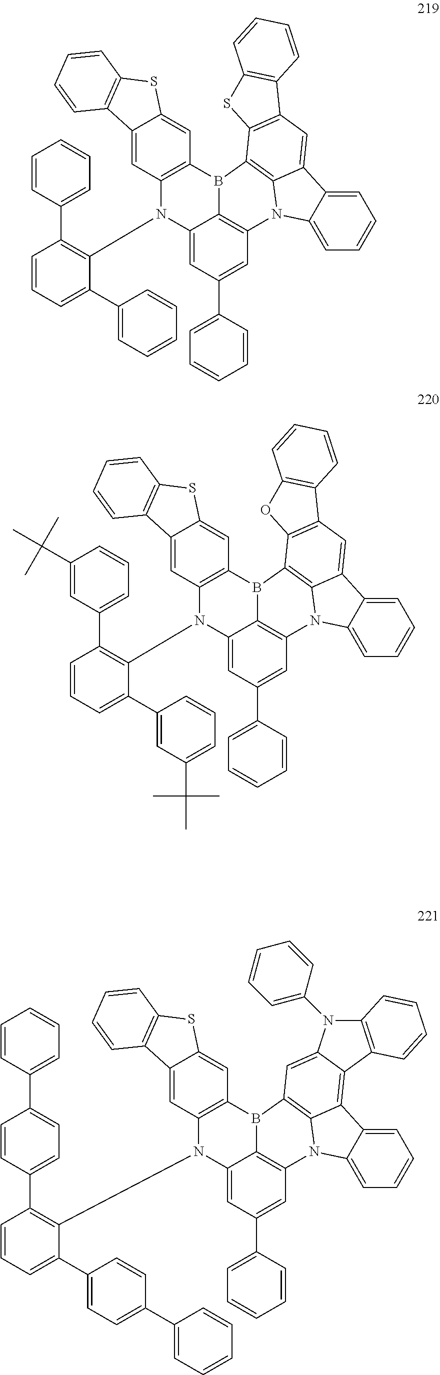 [SMILES: c1ccc(-c2cc3c4c(c2)-n2c5ccccc5c5cc6c(sc7ccccc76)c(c52)B4c2cc4sc5ccccc5c4cc2N3c2c(-c3ccccc3)cccc2-c2ccccc2)cc1 ; CC(C)(C)c1cccc(-c2cccc(-c3cccc(C(C)(C)C)c3)c2N2c3cc4c(cc3B3c5c2cc(-c2ccccc2)cc5-n2c5ccccc5c5cc6c(oc7ccccc76)c3c52)sc2ccccc24)c1 ; c1ccc(-c2ccc(-c3cccc(-c4ccc(-c5ccccc5)cc4)c3N3c4cc5c(cc4B4c6c3cc(-c3ccccc3)cc6-n3c6ccccc6c6c7c8ccccc8n(-c8ccccc8)c7cc4c63)sc3ccccc35)cc2)cc1]

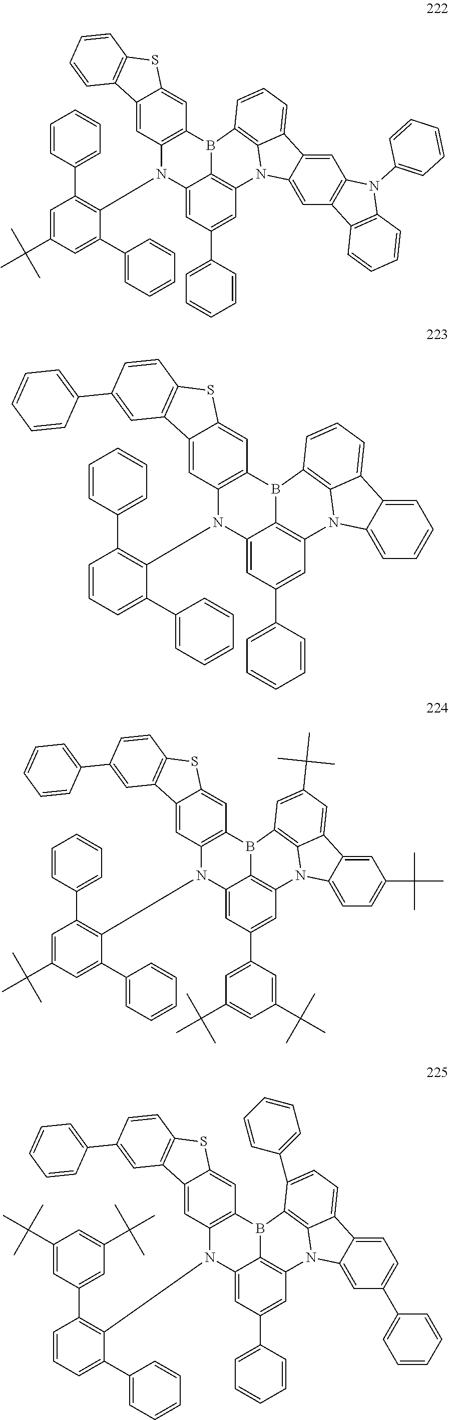

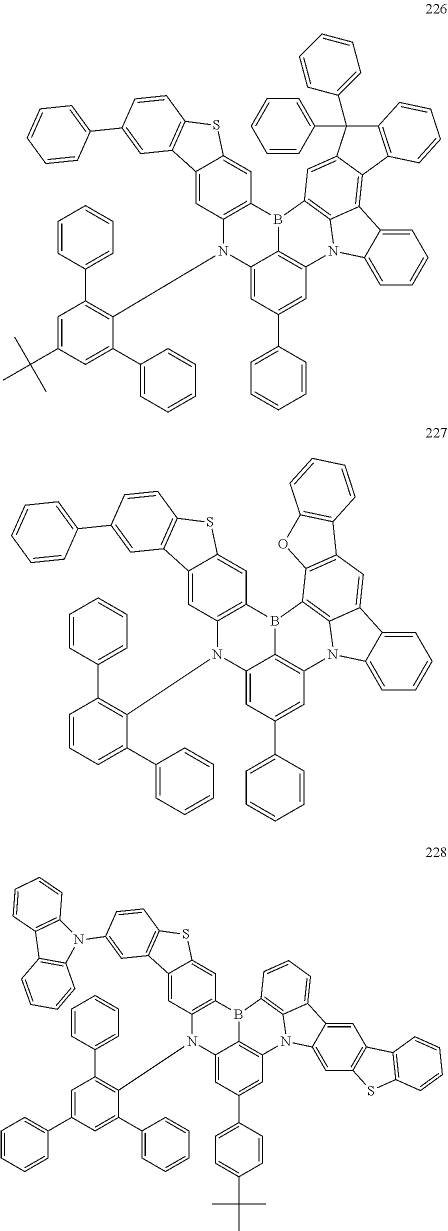 [SMILES: CC(C)(C)c1cc(-c2ccccc2)c(N2c3cc4c(cc3B3c5c2cc(-c2ccccc2)cc5-n2c5ccccc5c5c6c(cc3c52)C(c2ccccc2)(c2ccccc2)c2ccccc2-6)sc2ccc(-c3ccccc3)cc24)c(-c2ccccc2)c1 ; c1ccc(-c2cc3c4c(c2)-n2c5ccccc5c5cc6c(oc7ccccc76)c(c52)B4c2cc4sc5ccc(-c6ccccc6)cc5c4cc2N3c2c(-c3ccccc3)cccc2-c2ccccc2)cc1 ; CC(C)(C)c1ccc(-c2cc3c4c(c2)-n2c5cc6sc7ccccc7c6cc5c5cccc(c52)B4c2cc4sc5ccc(-n6c7ccccc7c7ccccc76)cc5c4cc2N3c2c(-c3ccccc3)cc(-c3ccccc3)cc2-c2ccccc2)cc1]

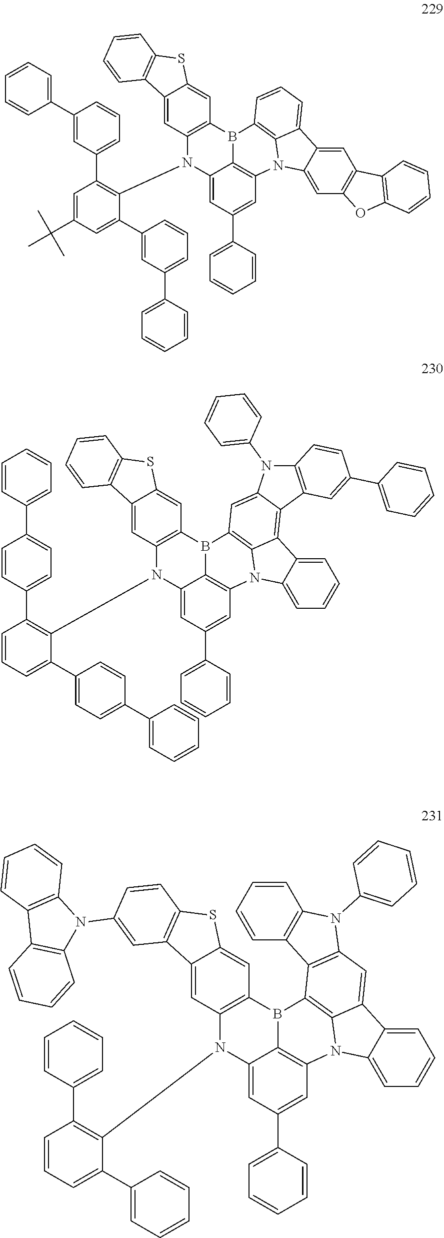 [SMILES: CC(C)(C)c1cc(-c2cccc(-c3ccccc3)c2)c(N2c3cc4c(cc3B3c5c2cc(-c2ccccc2)cc5-n2c5cc6oc7ccccc7c6cc5c5cccc3c52)sc2ccccc24)c(-c2cccc(-c3ccccc3)c2)c1 ; c1ccc(-c2ccc(-c3cccc(-c4ccc(-c5ccccc5)cc4)c3N3c4cc5c(cc4B4c6c3cc(-c3ccccc3)cc6-n3c6ccccc6c6c7c8cc(-c9ccccc9)ccc8n(-c8ccccc8)c7cc4c63)sc3ccccc35)cc2)cc1 ; c1ccc(-c2cc3c4c(c2)-n2c5ccccc5c5cc6c(c(c52)B4c2cc4sc5ccc(-n7c8ccccc8c8ccccc87)cc5c4cc2N3c2c(-c3ccccc3)cccc2-c2ccccc2)c2ccccc2n6-c2ccccc2)cc1]

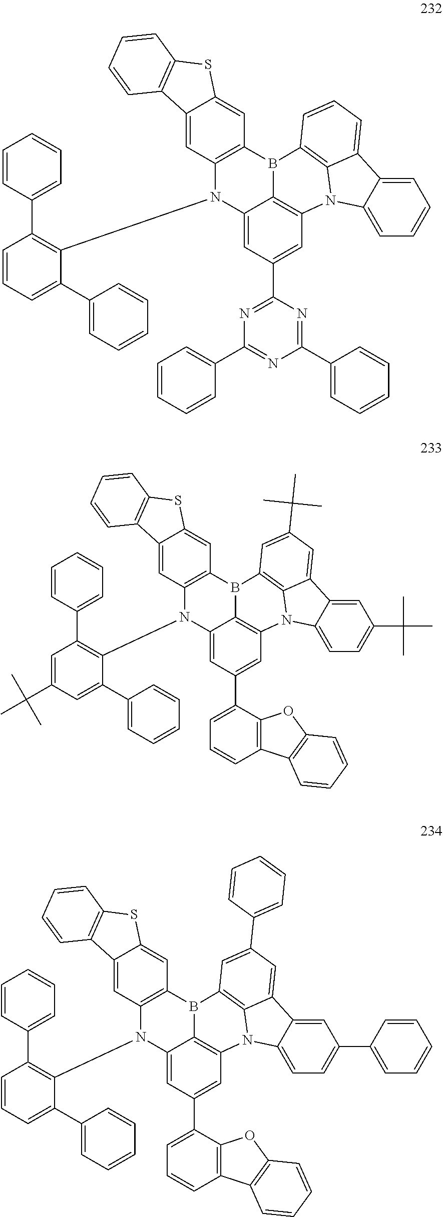 [SMILES: c1ccc(-c2nc(-c3ccccc3)nc(-c3cc4c5c(c3)-n3c6ccccc6c6cccc(c63)B5c3cc5sc6ccccc6c5cc3N4c3c(-c4ccccc4)cccc3-c3ccccc3)n2)cc1 ; CC(C)(C)c1cc(-c2ccccc2)c(N2c3cc4c(cc3B3c5c2cc(-c2cccc6c2oc2ccccc26)cc5-n2c5ccc(C(C)(C)C)cc5c5cc(C(C)(C)C)cc3c52)sc2ccccc24)c(-c2ccccc2)c1 ; c1ccc(-c2ccc3c(c2)c2cc(-c4ccccc4)cc4c2n3-c2cc(-c3cccc5c3oc3ccccc35)cc3c2B4c2cc4sc5ccccc5c4cc2N3c2c(-c3ccccc3)cccc2-c2ccccc2)cc1]

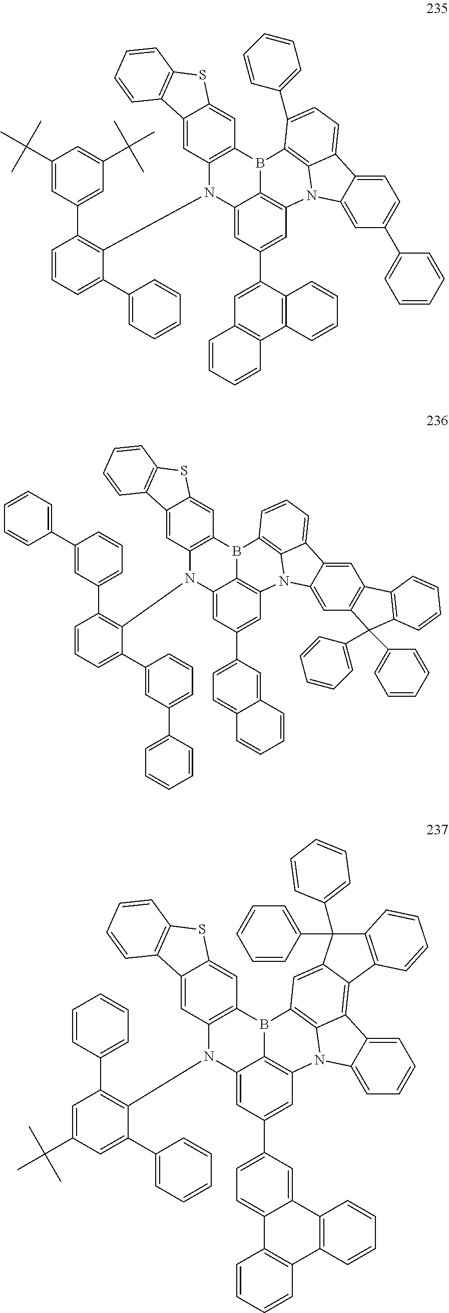 [SMILES: CC(C)(C)c1cc(-c2cccc(-c3ccccc3)c2N2c3cc4c(cc3B3c5c2cc(-c2cc6ccccc6c6ccccc26)cc5-n2c5cc(-c6ccccc6)ccc5c5ccc(-c6ccccc6)c3c52)sc2ccccc24)cc(C(C)(C)C)c1 ; c1ccc(-c2cccc(-c3cccc(-c4cccc(-c5ccccc5)c4)c3N3c4cc5c(cc4B4c6c3cc(-c3ccc7ccccc7c3)cc6-n3c6cc7c(cc6c6cccc4c63)-c3ccccc3C7(c3ccccc3)c3ccccc3)sc3ccccc35)c2)cc1 ; CC(C)(C)c1cc(-c2ccccc2)c(N2c3cc4c(cc3B3c5c2cc(-c2ccc6c7ccccc7c7ccccc7c6c2)cc5-n2c5ccccc5c5c6c(cc3c52)C(c2ccccc2)(c2ccccc2)c2ccccc2-6)sc2ccccc24)c(-c2ccccc2)c1]

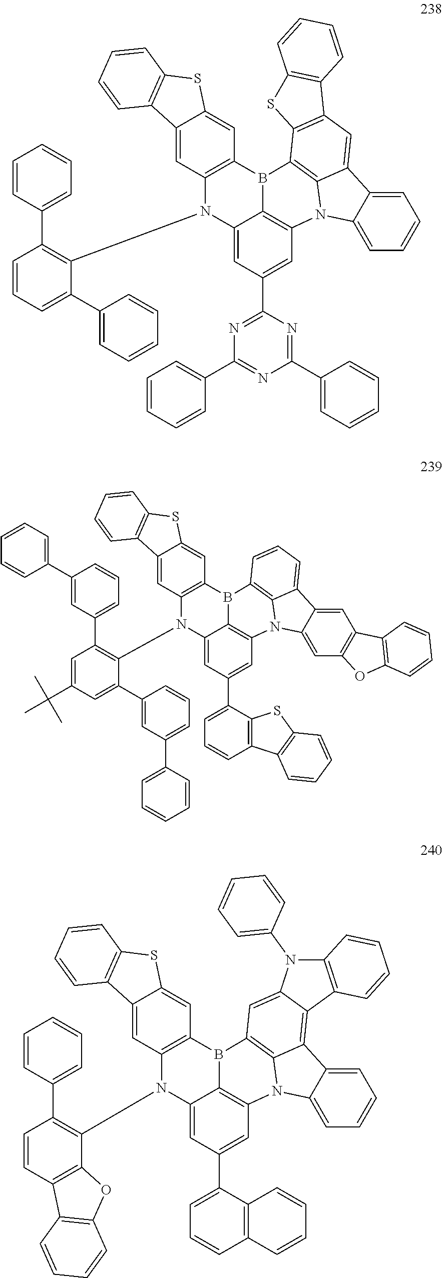 [SMILES: c1ccc(-c2nc(-c3ccccc3)nc(-c3cc4c5c(c3)-n3c6ccccc6c6cc7c(sc8ccccc87)c(c63)B5c3cc5sc6ccccc6c5cc3N4c3c(-c4ccccc4)cccc3-c3ccccc3)n2)cc1 ; CC(C)(C)c1cc(-c2cccc(-c3ccccc3)c2)c(N2c3cc4c(cc3B3c5c2cc(-c2cccc6c2sc2ccccc26)cc5-n2c5cc6oc7ccccc7c6cc5c5cccc3c52)sc2ccccc24)c(-c2cccc(-c3ccccc3)c2)c1 ; c1ccc(-c2ccc3c(oc4ccccc43)c2N2c3cc4c(cc3B3c5c2cc(-c2cccc6ccccc26)cc5-n2c5ccccc5c5c6c7ccccc7n(-c7ccccc7)c6cc3c52)sc2ccccc24)cc1]

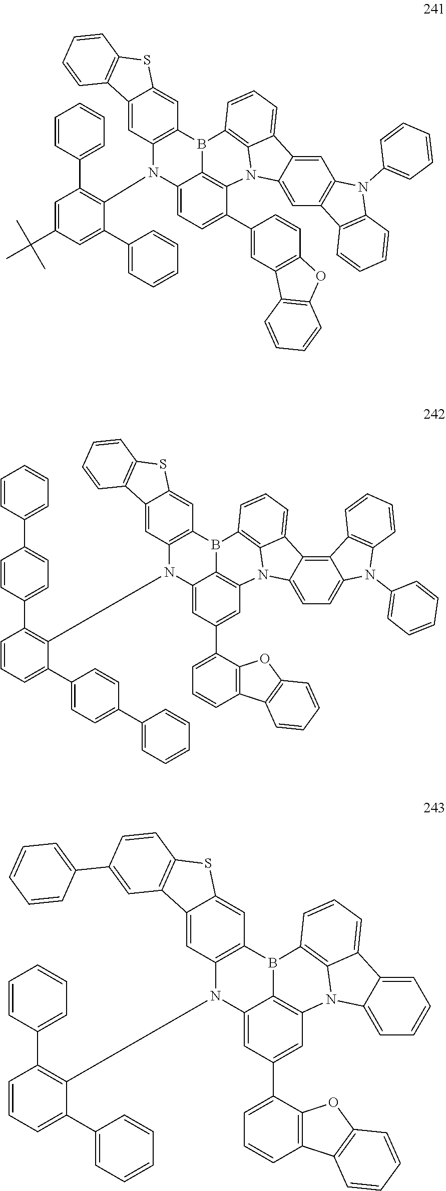 [SMILES: CC(C)(C)c1cc(-c2ccccc2)c(N2c3cc4c(cc3B3c5c2ccc(-c2ccc6oc7ccccc7c6c2)c5-n2c5cc6c7ccccc7n(-c7ccccc7)c6cc5c5cccc3c52)sc2ccccc24)c(-c2ccccc2)c1 ; c1ccc(-c2ccc(-c3cccc(-c4ccc(-c5ccccc5)cc4)c3N3c4cc5c(cc4B4c6c3cc(-c3cccc7c3oc3ccccc37)cc6-n3c6ccc7c(c8ccccc8n7-c7ccccc7)c6c6cccc4c63)sc3ccccc35)cc2)cc1 ; c1ccc(-c2ccc3sc4cc5c(cc4c3c2)N(c2c(-c3ccccc3)cccc2-c2ccccc2)c2cc(-c3cccc4c3oc3ccccc34)cc3c2B5c2cccc4c5ccccc5n-3c24)cc1]

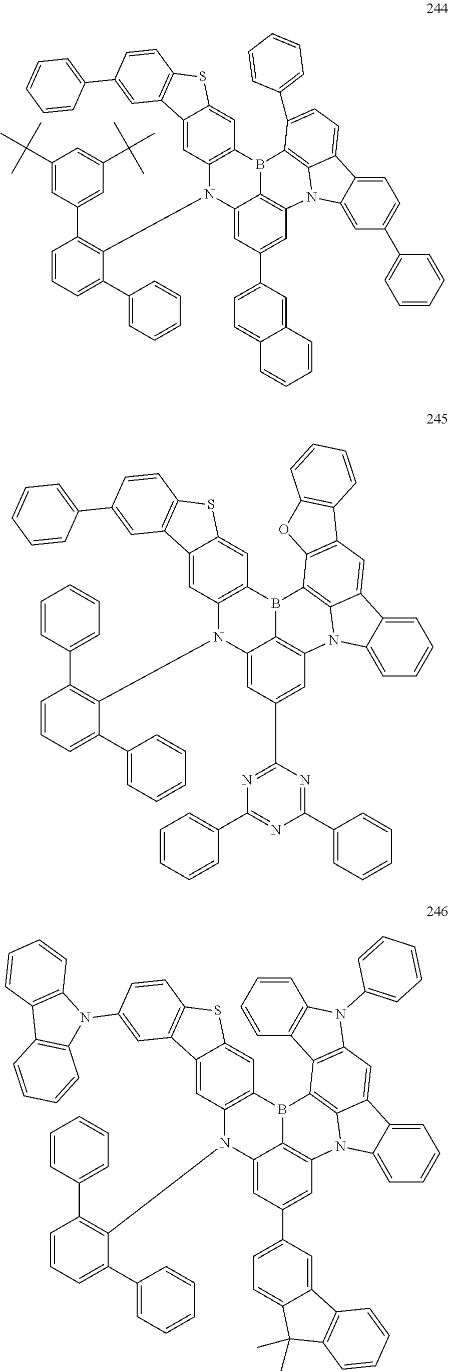 [SMILES: CC(C)(C)c1cc(-c2cccc(-c3ccccc3)c2N2c3cc4c(cc3B3c5c2cc(-c2ccc6ccccc6c2)cc5-n2c5cc(-c6ccccc6)ccc5c5ccc(-c6ccccc6)c3c52)sc2ccc(-c3ccccc3)cc24)cc(C(C)(C)C)c1 ; c1ccc(-c2ccc3sc4cc5c(cc4c3c2)N(c2c(-c3ccccc3)cccc2-c2ccccc2)c2cc(-c3nc(-c4ccccc4)nc(-c4ccccc4)n3)cc3c2B5c2c4oc5ccccc5c4cc4c5ccccc5n-3c24)cc1 ; CC1(C)c2ccccc2-c2cc(-c3cc4c5c(c3)-n3c6ccccc6c6cc7c(c(c63)B5c3cc5sc6ccc(-n8c9ccccc9c9ccccc98)cc6c5cc3N4c3c(-c4ccccc4)cccc3-c3ccccc3)c3ccccc3n7-c3ccccc3)ccc21]

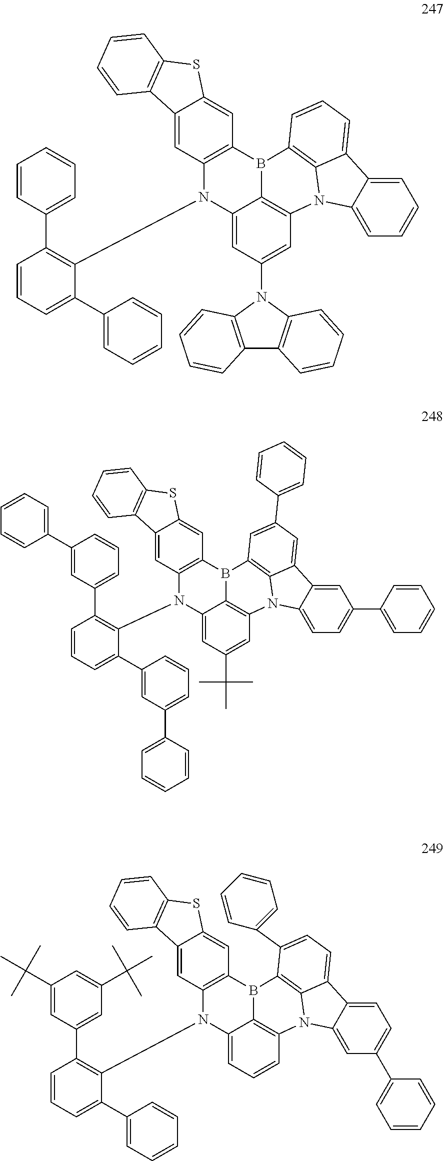 [SMILES: c1ccc(-c2cccc(-c3ccccc3)c2N2c3cc4c(cc3B3c5c2cc(-n2c6ccccc6c6ccccc62)cc5-n2c5ccccc5c5cccc3c52)sc2ccccc24)cc1 ; CC(C)(C)c1cc2c3c(c1)-n1c4ccc(-c5ccccc5)cc4c4cc(-c5ccccc5)cc(c41)B3c1cc3sc4ccccc4c3cc1N2c1c(-c2cccc(-c3ccccc3)c2)cccc1-c1cccc(-c2ccccc2)c1 ; CC(C)(C)c1cc(-c2cccc(-c3ccccc3)c2N2c3cc4c(cc3B3c5c2cccc5-n2c5cc(-c6ccccc6)ccc5c5ccc(-c6ccccc6)c3c52)sc2ccccc24)cc(C(C)(C)C)c1]

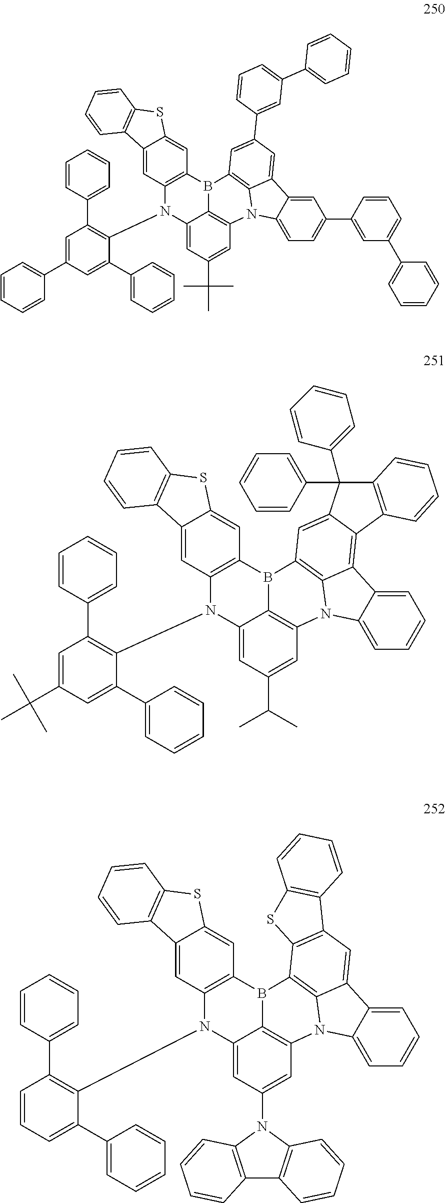 [SMILES: CC(C)(C)c1cc2c3c(c1)-n1c4ccc(-c5cccc(-c6ccccc6)c5)cc4c4cc(-c5cccc(-c6ccccc6)c5)cc(c41)B3c1cc3sc4ccccc4c3cc1N2c1c(-c2ccccc2)cc(-c2ccccc2)cc1-c1ccccc1 ; CC(C)c1cc2c3c(c1)-n1c4ccccc4c4c5c(cc(c41)B3c1cc3sc4ccccc4c3cc1N2c1c(-c2ccccc2)cc(C(C)(C)C)cc1-c1ccccc1)C(c1ccccc1)(c1ccccc1)c1ccccc1-5 ; c1ccc(-c2cccc(-c3ccccc3)c2N2c3cc4c(cc3B3c5c2cc(-n2c6ccccc6c6ccccc62)cc5-n2c5ccccc5c5cc6c(sc7ccccc76)c3c52)sc2ccccc24)cc1]

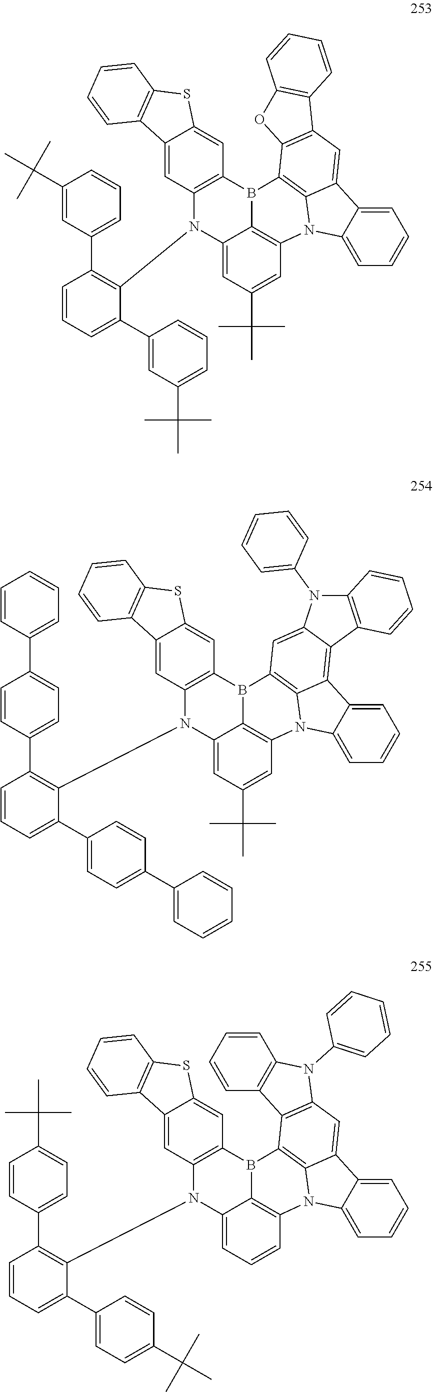 [SMILES: CC(C)(C)c1cccc(-c2cccc(-c3cccc(C(C)(C)C)c3)c2N2c3cc4c(cc3B3c5c2cc(C(C)(C)C)cc5-n2c5ccccc5c5cc6c(oc7ccccc76)c3c52)sc2ccccc24)c1 ; CC(C)(C)c1cc2c3c(c1)-n1c4ccccc4c4c5c6ccccc6n(-c6ccccc6)c5cc(c41)B3c1cc3sc4ccccc4c3cc1N2c1c(-c2ccc(-c3ccccc3)cc2)cccc1-c1ccc(-c2ccccc2)cc1 ; CC(C)(C)c1ccc(-c2cccc(-c3ccc(C(C)(C)C)cc3)c2N2c3cc4c(cc3B3c5c2cccc5-n2c5ccccc5c5cc6c(c3c52)c2ccccc2n6-c2ccccc2)sc2ccccc24)cc1]

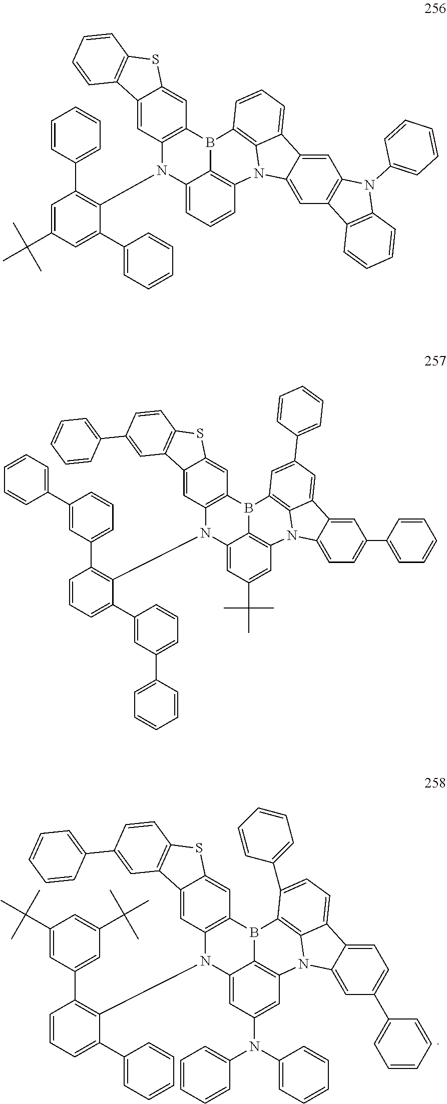 [SMILES: CC(C)(C)c1cc(-c2ccccc2)c(N2c3cc4c(cc3B3c5c2cccc5-n2c5cc6c7ccccc7n(-c7ccccc7)c6cc5c5cccc3c52)sc2ccccc24)c(-c2ccccc2)c1 ; CC(C)(C)c1cc2c3c(c1)-n1c4ccc(-c5ccccc5)cc4c4cc(-c5ccccc5)cc(c41)B3c1cc3sc4ccc(-c5ccccc5)cc4c3cc1N2c1c(-c2cccc(-c3ccccc3)c2)cccc1-c1cccc(-c2ccccc2)c1 ; CC(C)(C)c1cc(-c2cccc(-c3ccccc3)c2N2c3cc4c(cc3B3c5c2cc(N(c2ccccc2)c2ccccc2)cc5-n2c5cc(-c6ccccc6)ccc5c5ccc(-c6ccccc6)c3c52)sc2ccc(-c3ccccc3)cc24)cc(C(C)(C)C)c1]

The fused polycyclic compound represented by Formula 1 has a structure in which two aromatic hydrocarbon rings are fused at specific positions of a fused ring core, and high efficiency and long lifetime may be achieved.

The fused polycyclic compound includes a fused ring core in which five rings are fused with a first boron atom, a first nitrogen atom, and a second nitrogen atom in the center, and exhibits a wide plate-type skeleton and multiple resonance properties, and thus, highest occupied molecular orbital (HOMO) and lowest unoccupied molecular orbital (LUMO) states in a molecule may be readily separated. Accordingly, the fused polycyclic compound may have a reduced difference (ΔE_{ST}) between a lowest triplet excitation energy level (T1 level) and a lowest singlet excitation energy level (S1 level). Thus, when the fused polycyclic compound is used as a delayed fluorescence emission material, emission efficiency of a light emitting element may be further improved.

In the fused polycyclic compound, a fourth benzene ring, which is one of the two aromatic hydrocarbon rings, may be connected with the second benzene ring of the fused ring core via a first heteroatom and may form an additional fused ring. The first heteroatom may be connected at a para position to the first nitrogen atom of the fused ring core. In the fused polycyclic compound, since the fourth benzene ring is connected at the specific position of the fused ring core through the first heteroatom to form the additional fused ring, redshift of a molecule may be induced, while maintaining high emission efficiency and long lifetime characteristics.

The fused polycyclic compound may have a structure according to Structure C1 below. The fused polycyclic compound includes a fused ring core in which five rings are fused with a first boron atom, a first nitrogen atom, and a second nitrogen atom in the center, and readily separates HOMO and LUMO states on a wide plate-type skeleton, and accordingly, exhibits improved multiple resonance properties. Referring to Structure C1, by locating a first heteroatom at position “a” in the structure of the fused ring core with the boron atom, the first nitrogen atom, and the second nitrogen atom in the center, it may be inferred that the LUMO is distributed at the first nitrogen atom, and the HOMO is distributed at the first heteroatom. Accordingly, the localization of the HOMO and the LUMO may be reduced in the additional fused ring via the first heteroatom, and bonding/antibonding properties may increase. For example, in the fused ring core, the non-bonding properties of multiple resonance in which the HOMO and the LUMO are distributed on an atomic nucleus may be maintained, but bonding/antibonding properties may be shown in the additionally fused ring, and redshift may be induced. Accordingly, the fused polycyclic compound may induce the redshift of a molecule, while maintaining emission efficiency and lifetime characteristics. Thus, the fused polycyclic compound may achieve high element efficiency and improved lifetime characteristics in a green light wavelength range. For convenience of explanation, substituents that are connected with the benzene rings are omitted from Structure CL.

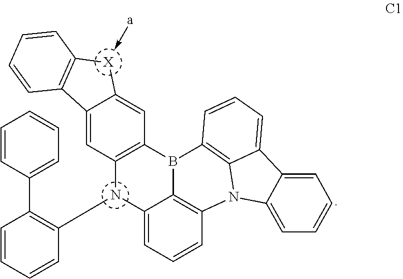

In the fused polycyclic compound, a fifth benzene ring, which is the other of the two aromatic hydrocarbon rings, may be connected with the third benzene ring and the second nitrogen atom of the fused ring core to form an additional fused ring. In the fused polycyclic compound, the fifth benzene ring may be connected with the second nitrogen atom of the fused ring core and a carbon atom of the third benzene ring at an ortho position with respect to the second nitrogen atom, such that a bond is formed between the carbon atom of the third benzene ring and a carbon atom of the fifth benzene ring at an ortho position with respect to the second nitrogen atom, thereby forming an additional fused ring. Since the fifth benzene ring is connected at a specific position of the fused ring core to form an additional fused ring, the fused polycyclic compound may have a deep energy level of the highest occupied molecular orbital (HOMO). Thus, when the fused polycyclic compound is used as a dopant material of an emission layer EML, emission efficiency and lifetime characteristics may improve.

Since the fused polycyclic compound has a deep HOMO energy level, a light emitting element ED using the fused polycyclic compound as a dopant in the emission layer EML may exhibit a reduced difference between the HOMO energy level of a host and the HOMO energy level of the fused polycyclic compound, thereby exhibiting improved element lifetime characteristics. Accordingly, if the fused polycyclic compound is used as a dopant material of the emission layer EML of the light emitting element ED, low driving voltage, high efficiency, and long lifetime characteristics may be achieved. In the specification, an expression that an energy level is “shallow” may describe a low absolute value of an energy level. In the specification, an expression that an energy level is “deep” may describe a high absolute value of an energy level.

In the fused polycyclic compound, since the fifth benzene ring is connected at a specific position of the fused ring core and forms an additional fused ring, rigidity in a molecule increases, structural changes between an excited state and a ground state are small, and a Stokes shift and a full width at half maximum may be markedly reduced, and accordingly, emission with high color purity may be achieved. Therefore, if the fused polycyclic compound is included as a delayed fluorescence dopant in an emission layer EML, emission efficiency and lifetime characteristics may be improved, as well as color purity.

The fused polycyclic compound may effectively maintain a trigonal planar structure of a boron atom through steric hindrance effects by the first substituent. Since the boron atom has electron-deficient properties due to a vacant p-orbital, a bond may be formed with another nucleophile, the trigonal planar structure may change into a tetrahedral structure, and this may contribute to the deterioration of an element. According to embodiments, the fused polycyclic compound includes the first substituent of the fused ring core, and the vacant p-orbital of the boron atom may be effectively protected, and thus, deterioration due to trigonal planar structural deformation may be prevented.

In the fused polycyclic compound, intermolecular interaction is suppressed through steric hindrance effects of the first substituent, and the formation of aggregates, excimers, and exciplexes may be controlled, and accordingly, emission efficiency may be improved. Since the fused polycyclic compound has a bulky structure, intermolecular distance may increase to reduce Dexter energy transfer, and accordingly, an increase of the concentration of triplet excitons in the fused polycyclic compound may be suppressed. Since triplet excitons at a high concentration may remain in an excited state for a long time, decomposition of a compound may be induced, the production of hot excitons having high energy produced through triplet-triplet annihilation (TTA) may be induced, and the cleavage of an adjacent compound structure may be induced. Triplet-triplet annihilation is a bimolecular reaction, which rapidly exhausts triplet excitons used for emitting light, and accordingly, deterioration of emission efficiency may be induced by non-radiative transition. Since intermolecular distance may increase due to the first substituent in the fused polycyclic compound, Dexter energy transfer may be suppressed, and the deterioration of device lifetime that is generated by an increase of triplet concentration may be suppressed. Accordingly, if the fused polycyclic compound is included in an emission layer EML of a light emitting element ED, emission efficiency may be improved, and element lifetime may also increase.

The fused polycyclic compound may be a light emitting material having a central wavelength (Iₘₐₓ) equal to or greater than about 490 nm. For example, the fused polycyclic compound may be a light emitting material having a central wavelength (Iₘₐₓ) in a range of about 490 nm to about 550 nm. In an embodiment, the first polycyclic compound represented by Formula 1 may be a green dopant.

In the light emitting element ED according to an embodiment, the emission layer EML may include a host and a dopant, and the dopant may include the fused polycyclic compound. For example, in the light emitting element ED, the emission layer EML may include a host and a dopant, and the dopant may include the fused polycyclic compound for emitting delayed fluorescence. In an embodiment, the emission layer EML may include at least one compound selected from Compound Group 1 as a thermally activated delayed fluorescence (TADF) dopant.

An emission spectrum of the fused polycyclic compound represented by Formula 1 may have a full width at half maximum (FWHM) in a range of about 10 nm to 50 nm. For example, an emission spectrum of the fused polycyclic compound may have a FWHM in a range of about 20 nm to 40 nm. When an emission spectrum of the fused polycyclic compound has a FWHM within any of the above ranges, emission efficiency may be improved when the light emitting element ED includes the fused polycyclic compound. If the fused polycyclic compound is used as a material of a green light emitting element, element lifetime may be improved.

In an embodiment, the fused polycyclic compound may be a material for emitting thermally activated delayed fluorescence (TADF). In an embodiment, the fused polycyclic compound may be a thermally activated delayed fluorescence dopant having a difference (ΔE_{ST}) between a lowest triplet excitation energy level (T1) and a lowest singlet excitation energy level (S1) equal to or less than about 0.6 eV. For example, the fused polycyclic compound may be a thermally activated delayed fluorescence dopant having a difference (ΔE_{ST}) between a lowest triplet excitation energy level (T1) and a lowest singlet excitation energy level (S1) equal to or less than about 0.2 eV. However, embodiments are not limited thereto.

In the light emitting element ED, the emission layer EML may emit delayed fluorescence. For example, the emission layer EML may emit thermally activated delayed fluorescence (TADF).

The emission layer EML of the light emitting element ED may emit green light. For example, the emission layer EML of the light emitting element ED may emit green light having a central wavelength equal to or greater than about 490 nm. However, embodiments are not limited thereto, and the emission layer EML may emit blue light or red light.

The fused polycyclic compound may be included in an emission layer EML. The fused polycyclic compound may be included in an emission layer EML as a dopant material. The fused polycyclic compound may be a thermally activated delayed fluorescence material. The fused polycyclic compound may be used as a thermally activated delayed fluorescence dopant. For example, in the light emitting element ED, the emission layer EML may include at least one fused polycyclic compound selected from Compound Group 1 as a thermally delayed fluorescence dopant. However, the use of the fused polycyclic compound is not limited thereto.

In an embodiment, the emission layer EML may include multiple compounds. In an embodiment, the emission layer EML may include the fused polycyclic compound represented by Formula 1 as a first compound, and at least one of a second compound represented by Formula HT-1, a third compound represented by Formula ET-1 and a fourth compound represented by Formula D-1.

In an embodiment, the emission layer EML may include the first compound represented by Formula 1, and may further include at least one of a second compound represented by Formula HT-1 and a third compound represented by Formula ET-1.

In an embodiment, the emission layer EML may further include a second compound represented by Formula HT-1. In an embodiment, the second compound may be used as a hole transport host material in the emission layer EML:

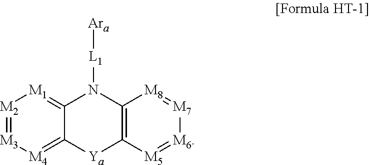

In Formula HT-1, M₁ to M₈ may each independently be N or C(R₅₁). For example, M₁ to M₈ may each independently be C(R₅₁). As another example, any one of M₁ to M₈ may be N, and the remainder of M₁ to M₈ may each independently be C(R₅₁).

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene rings that are connected to the nitrogen atom of Formula HT-1 may be connected to each other via a direct linkage,

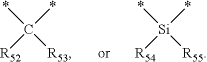

In Formula HT-1, if Yₐ is a direct linkage, the second compound represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2:

[chemical structure]

[chemical structure]

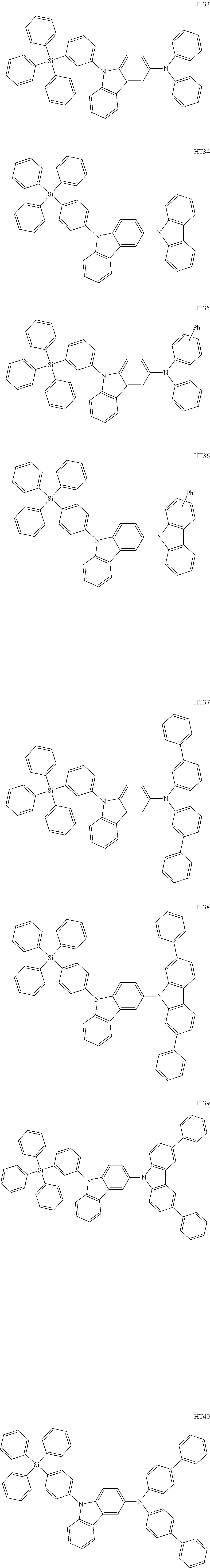

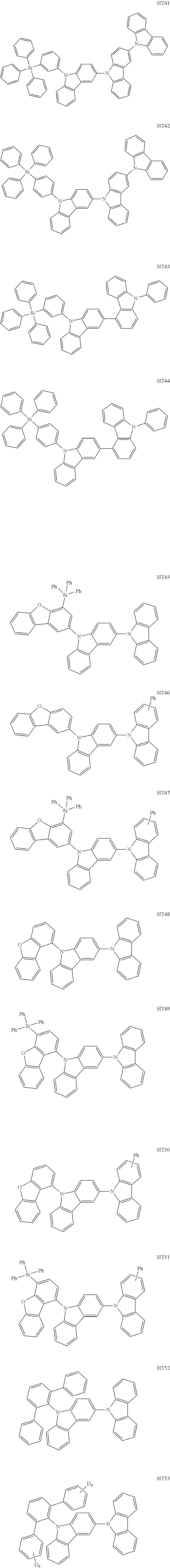

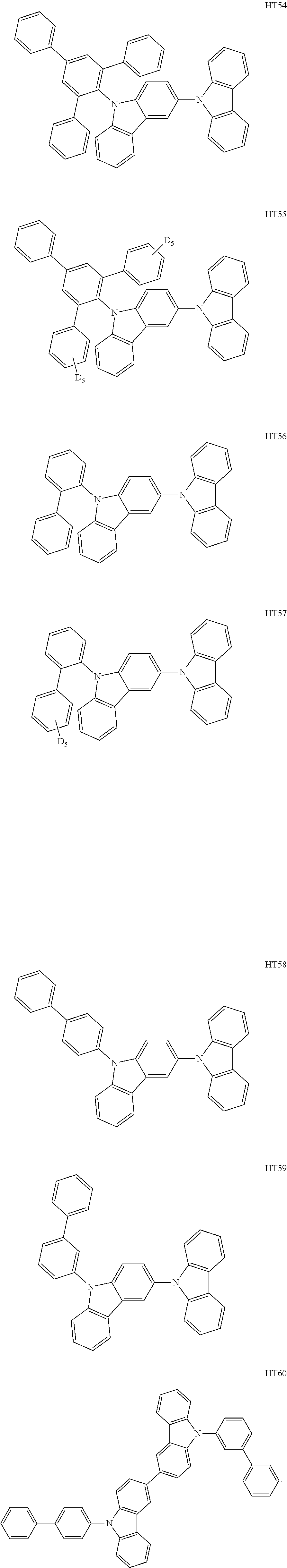

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML:

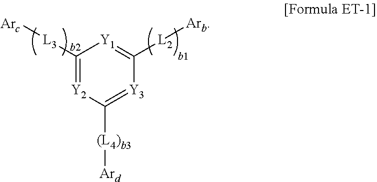

In Formula ET-1, at least one of Y₁ to Y₃ may each be N, and the remainder of Y₁ to Y₃ may each independently be C(R₅₆). For example, one of Y₁ to Y₃ may be N, and the remainder of Y₁ to Y₃ may each independently be C(R₅₆). Thus, the third compound represented by Formula ET-1 may include a pyridine moiety. As another example, two of Y₁ to Y₃ may each be N, and the remainder of Y₁ to Y₃ may be C(R₅₆). Thus, the third compound represented by Formula ET-1 may include a pyrimidine moiety. As yet another example, Y₁ to Y₃ may each be N. Thus, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar_{b} to Ar_{d} may each independently be a substituted or unsubstituted phenyl group or a substituted or unsubstituted carbazole group.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, multiple groups of each of L₂ to L₄ may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3:

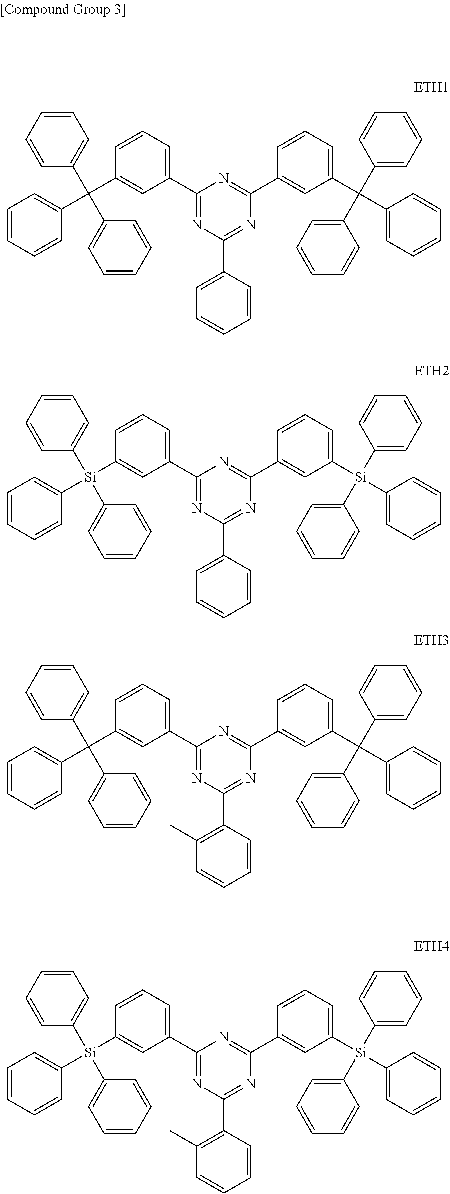 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

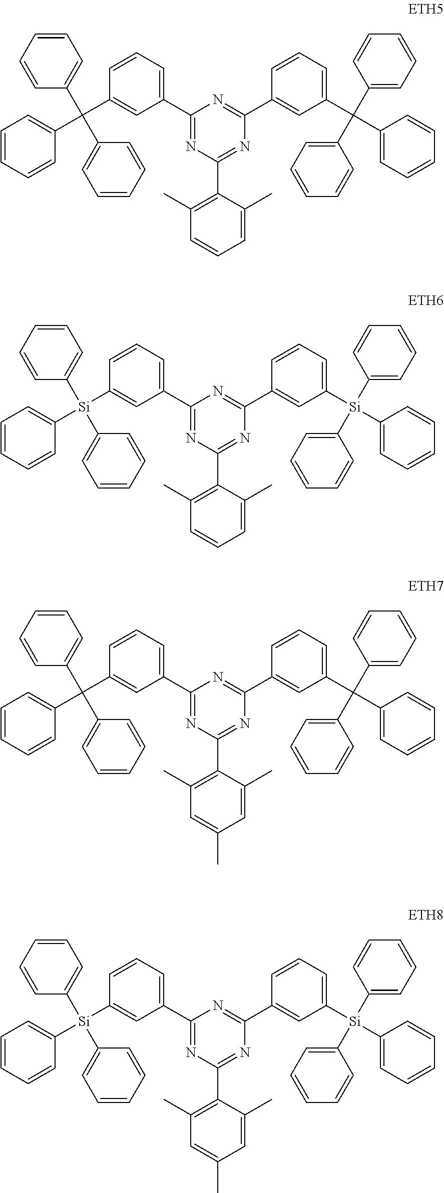 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

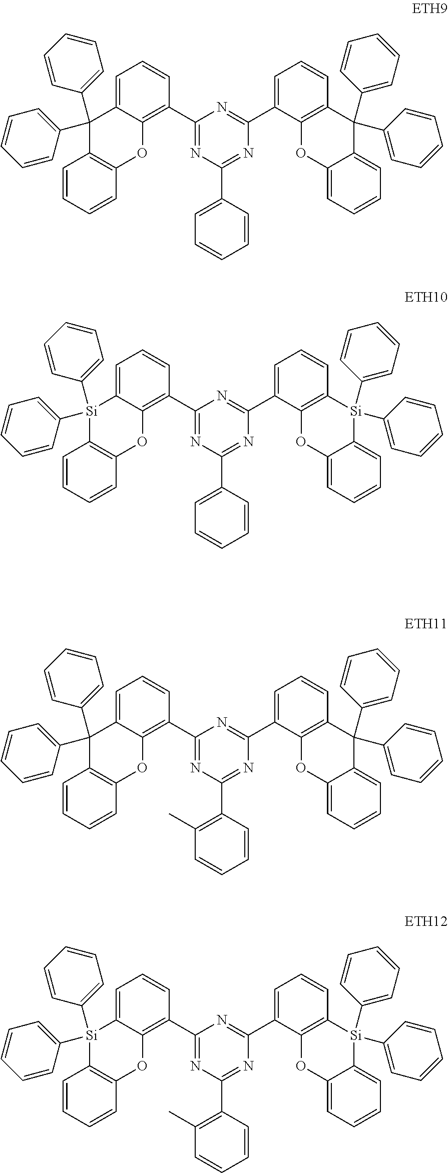 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

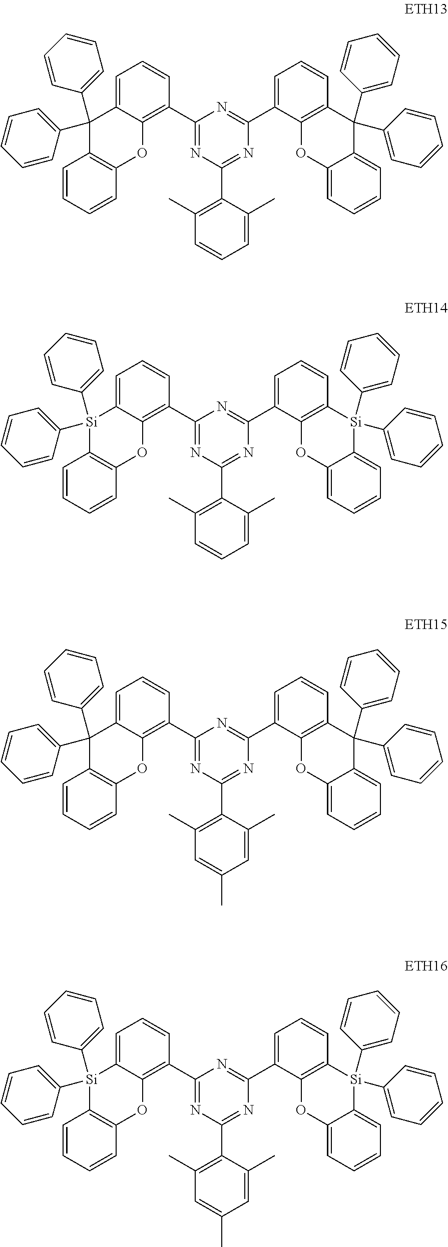 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

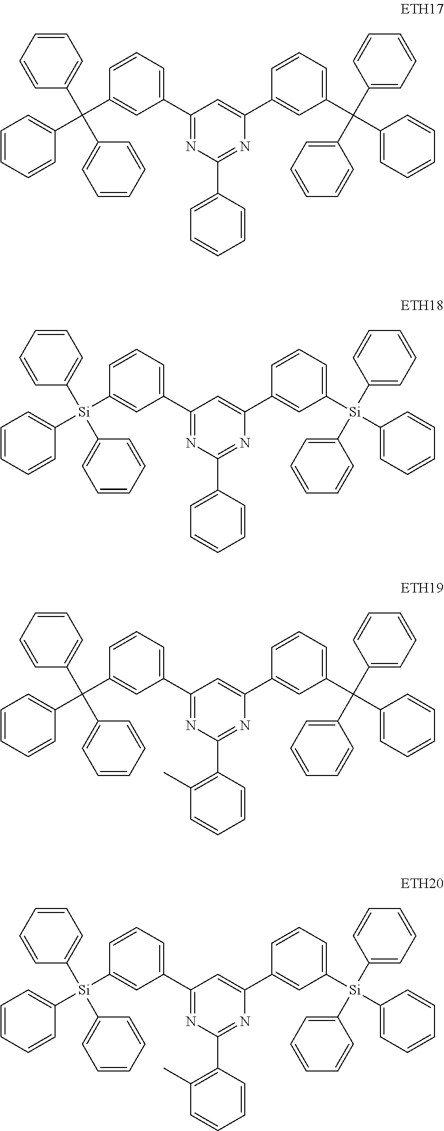 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

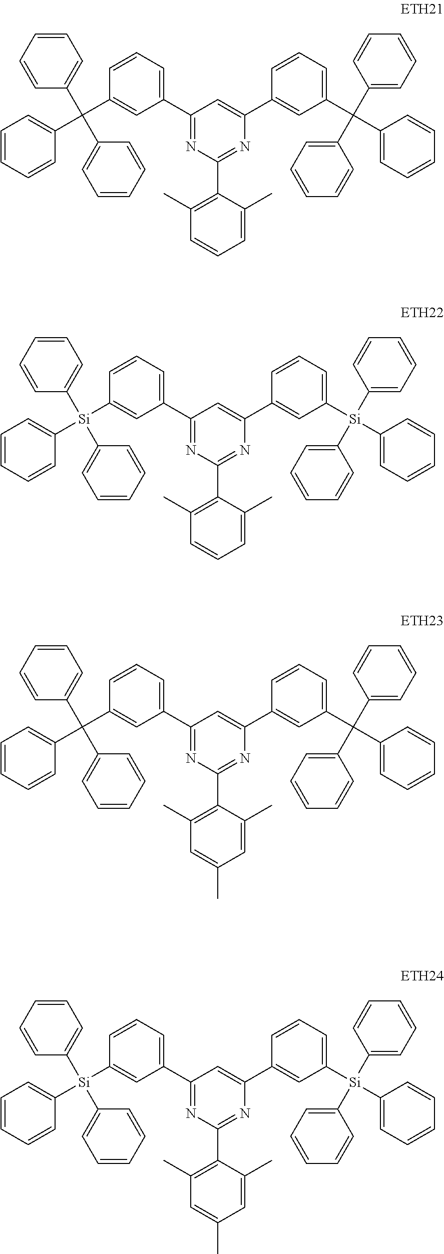 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

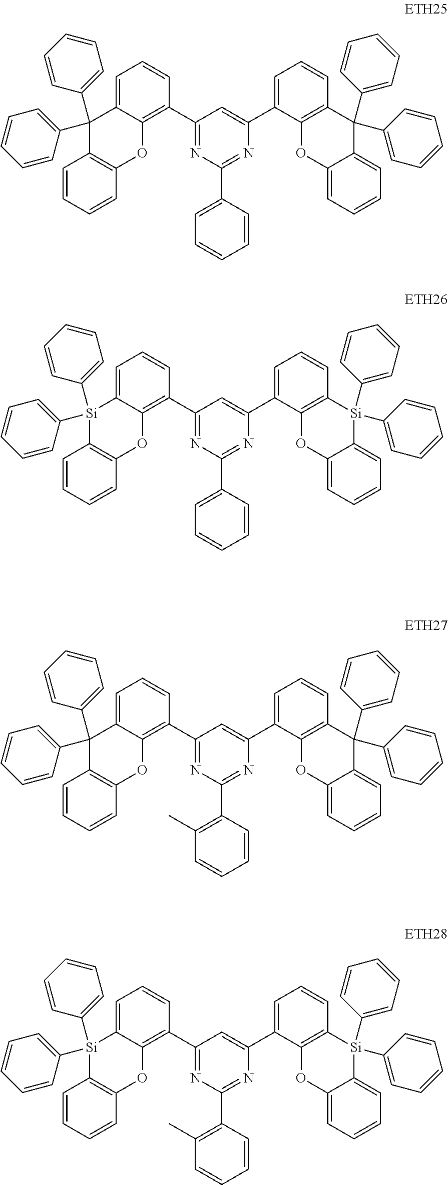 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

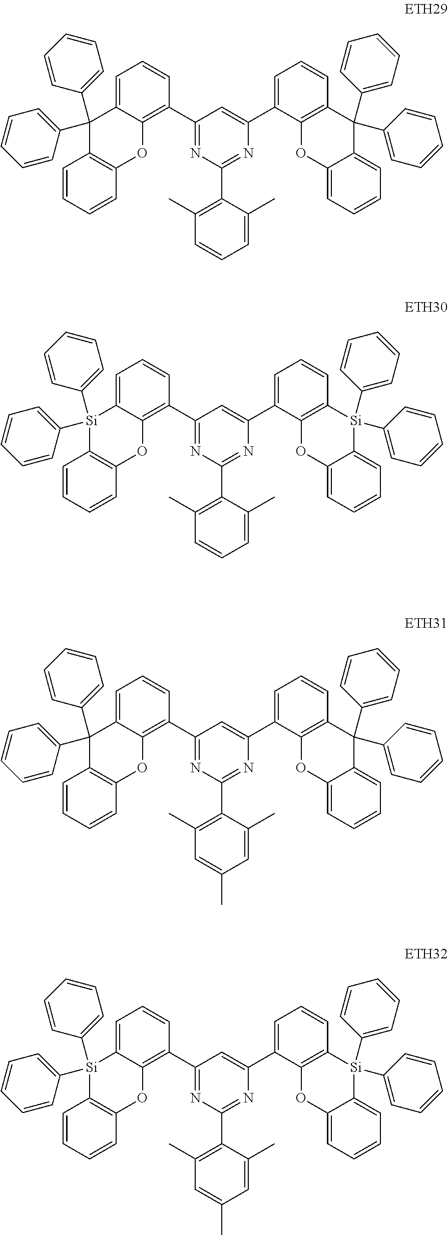 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

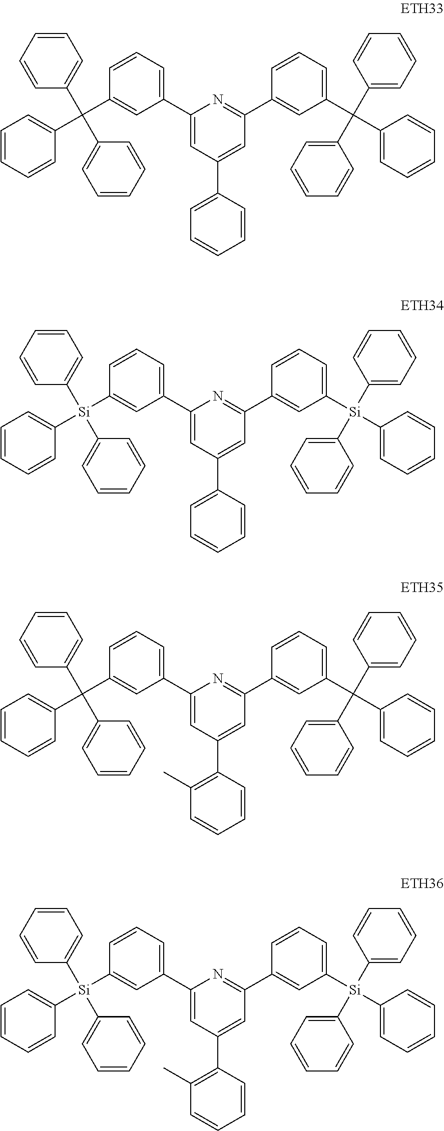 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

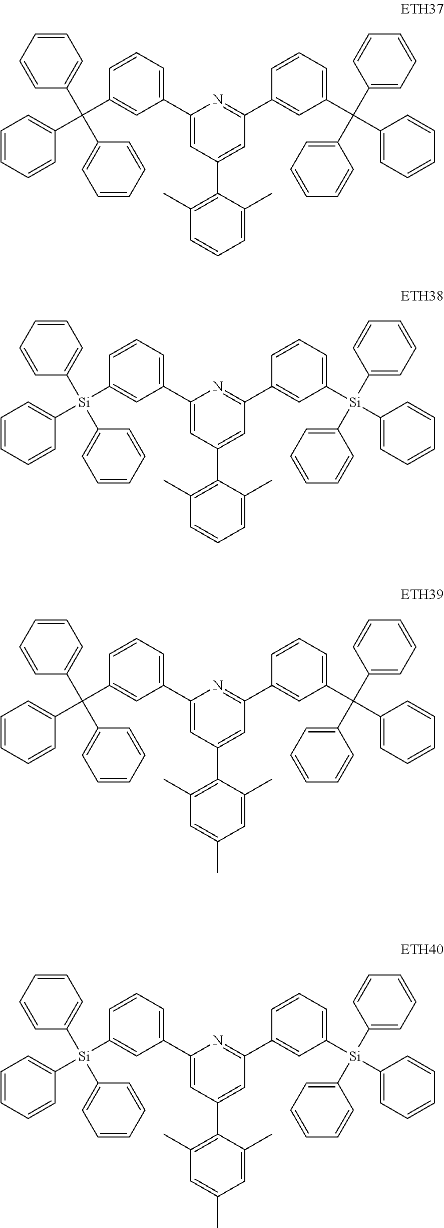 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

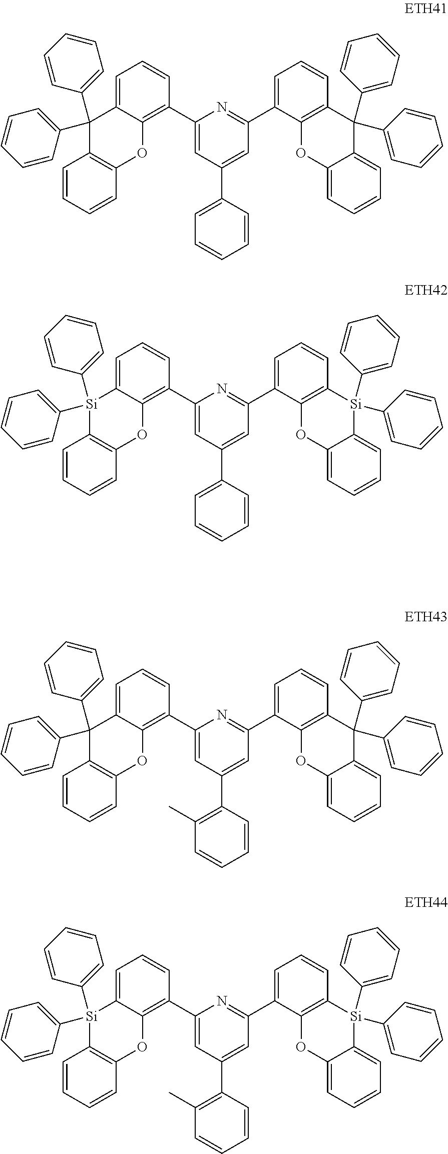 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

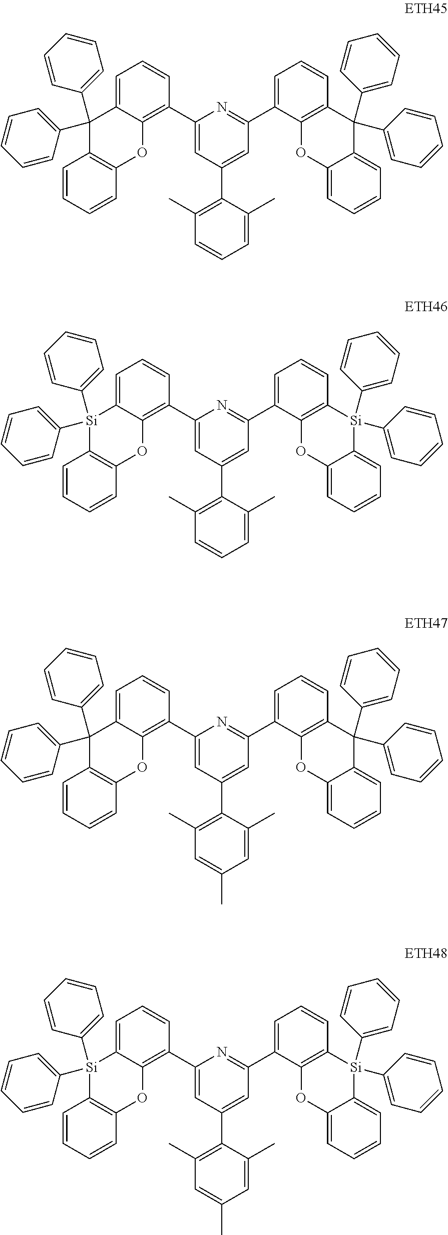 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

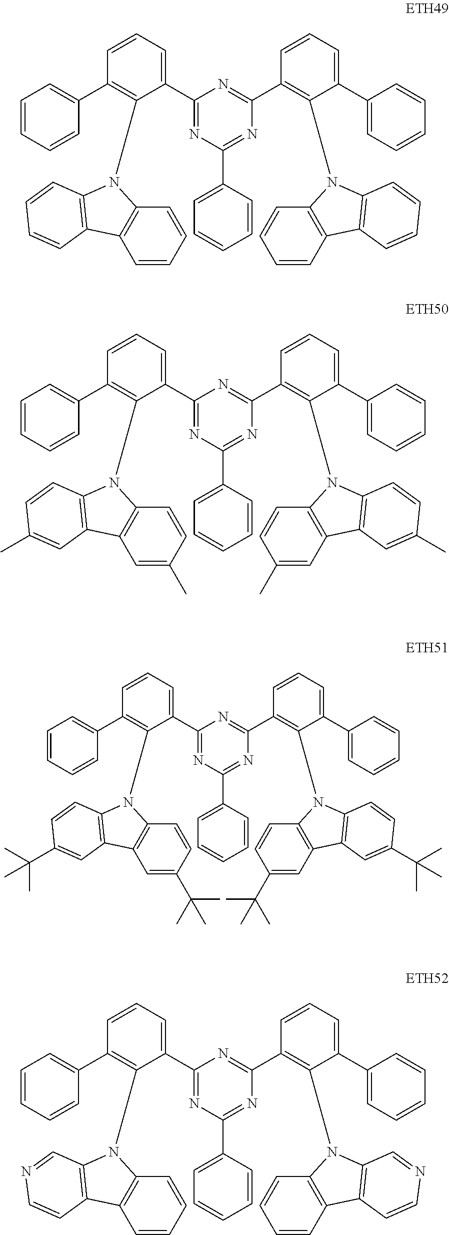

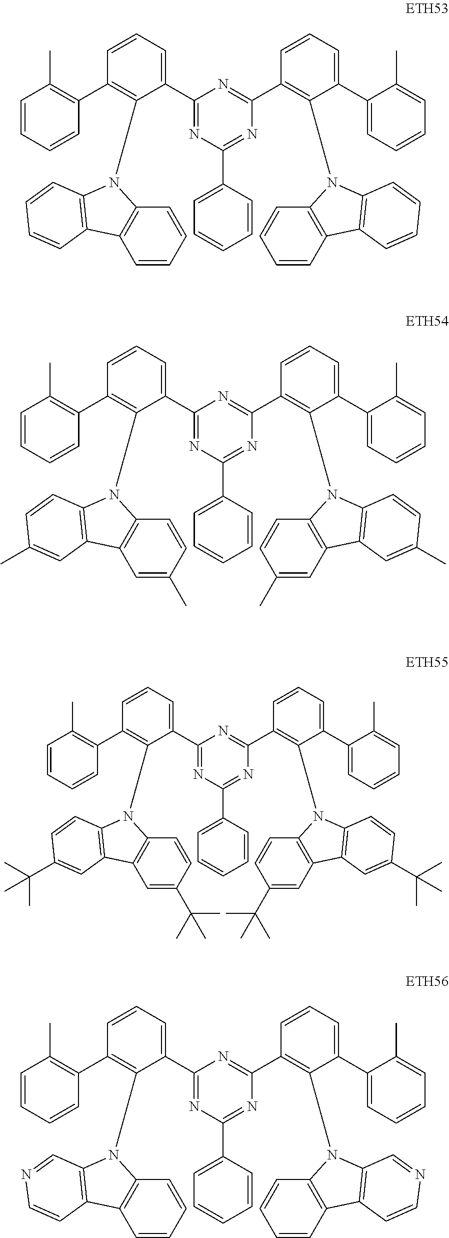

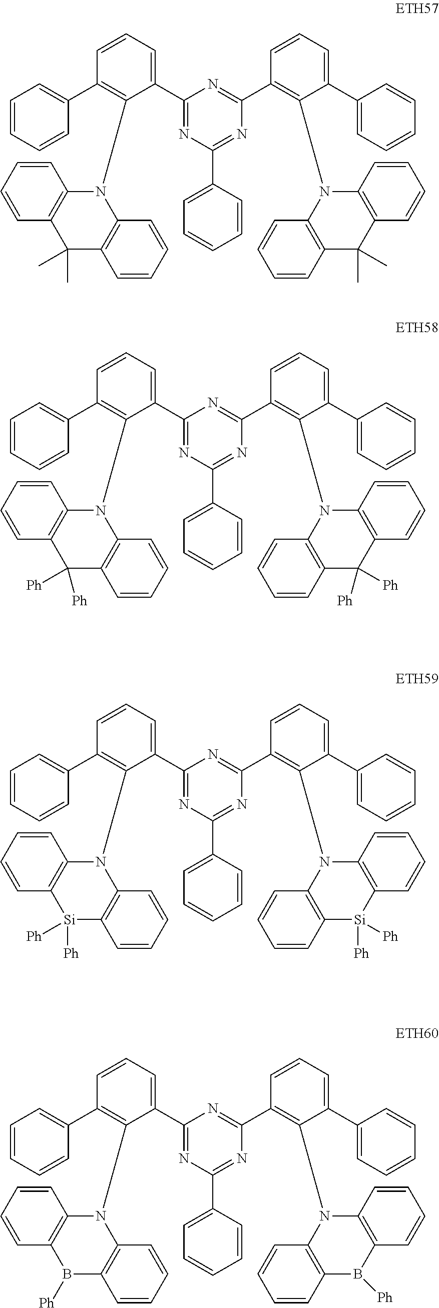

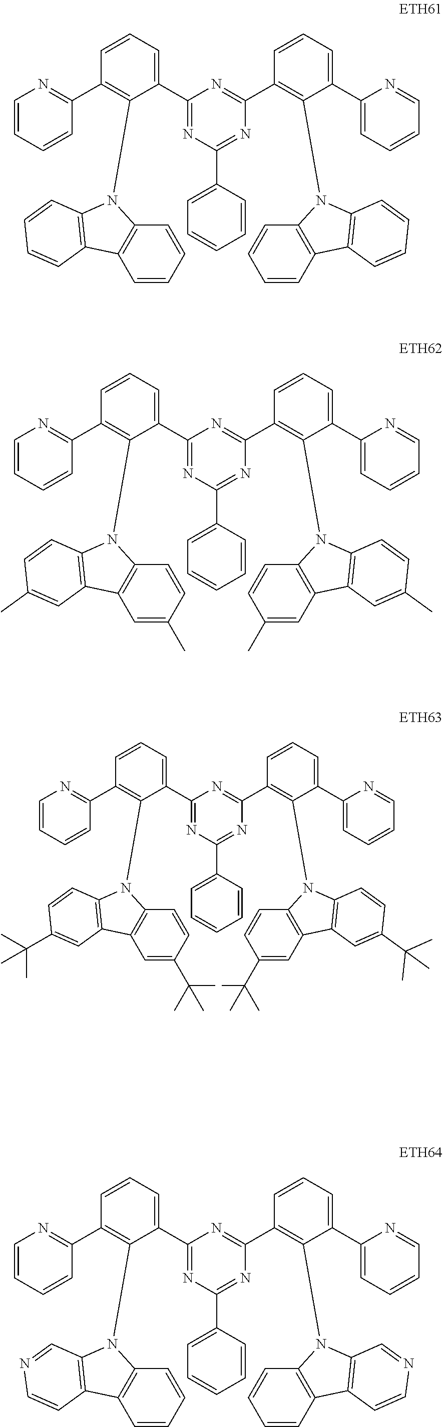

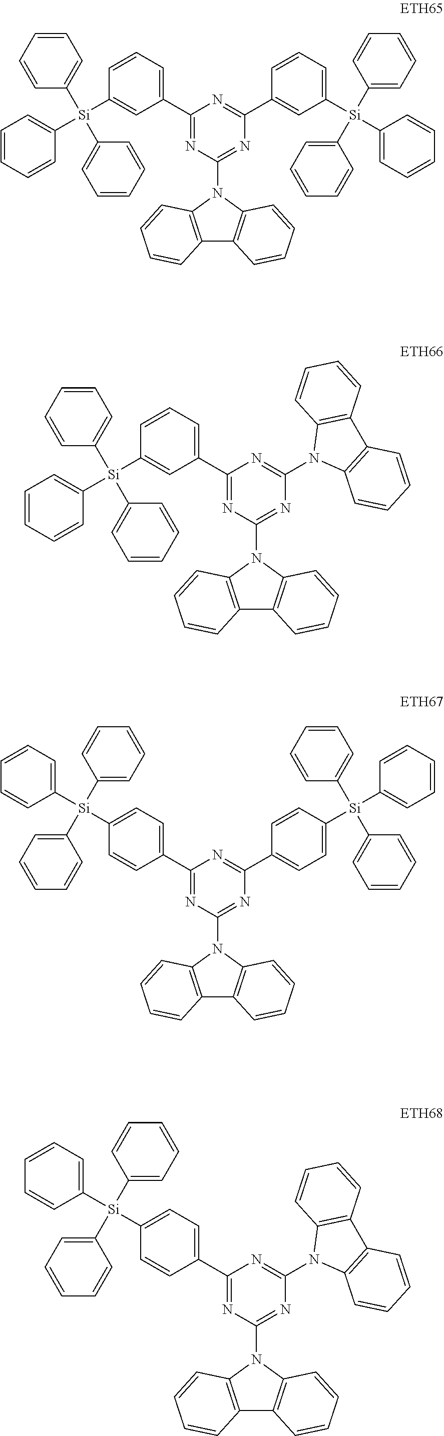 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

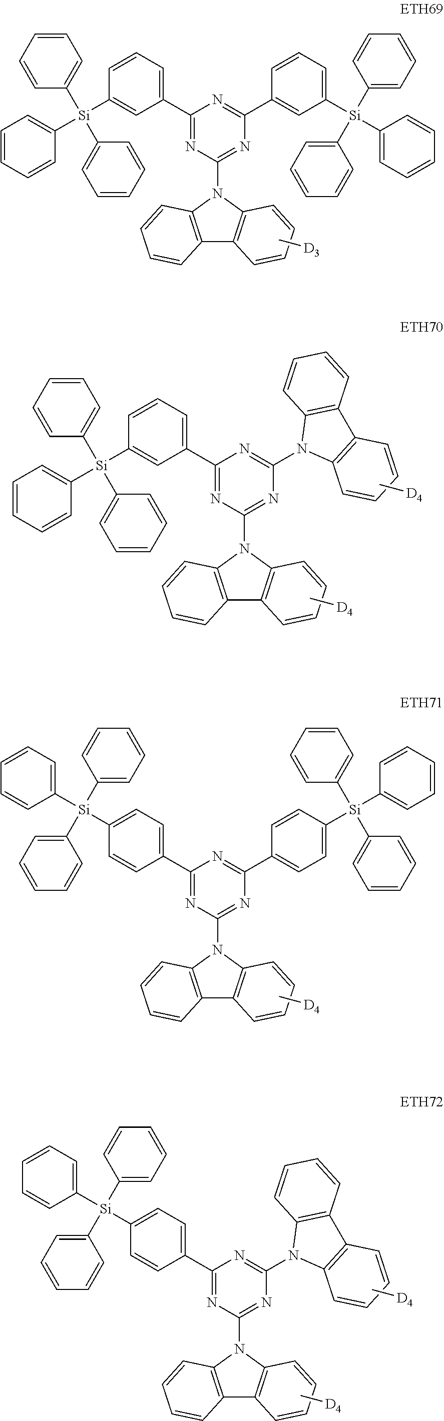

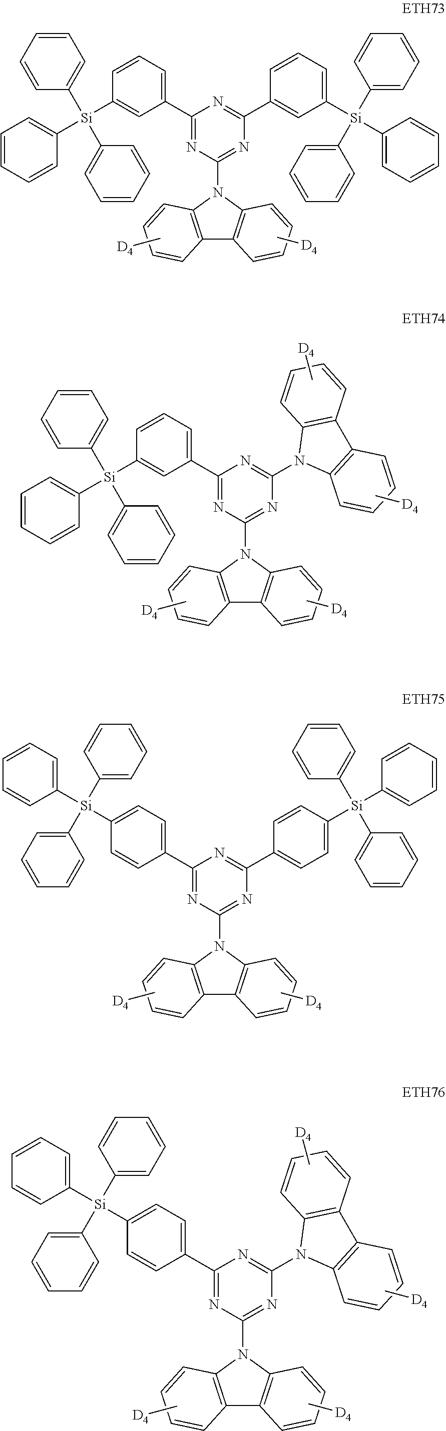

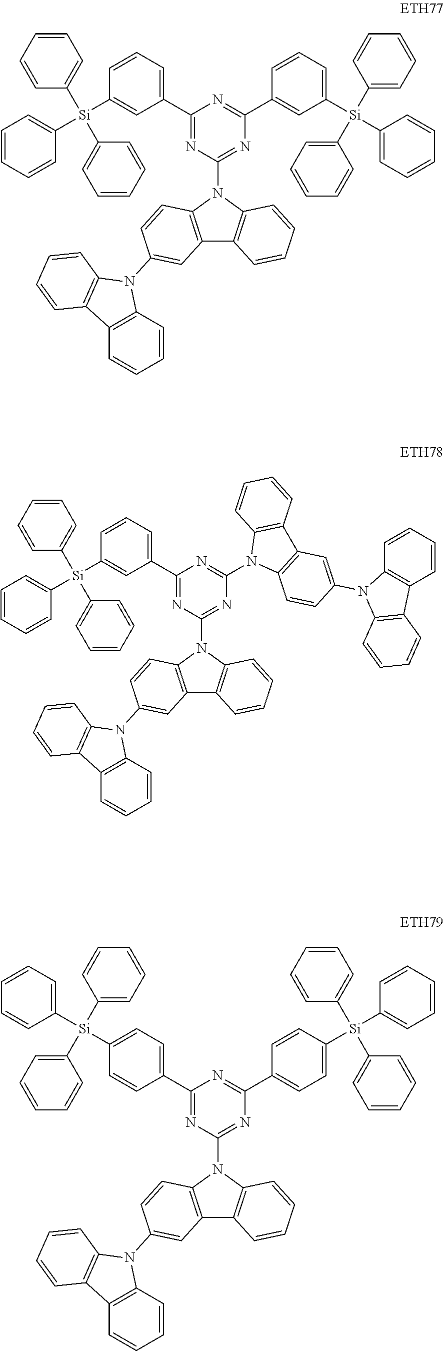 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

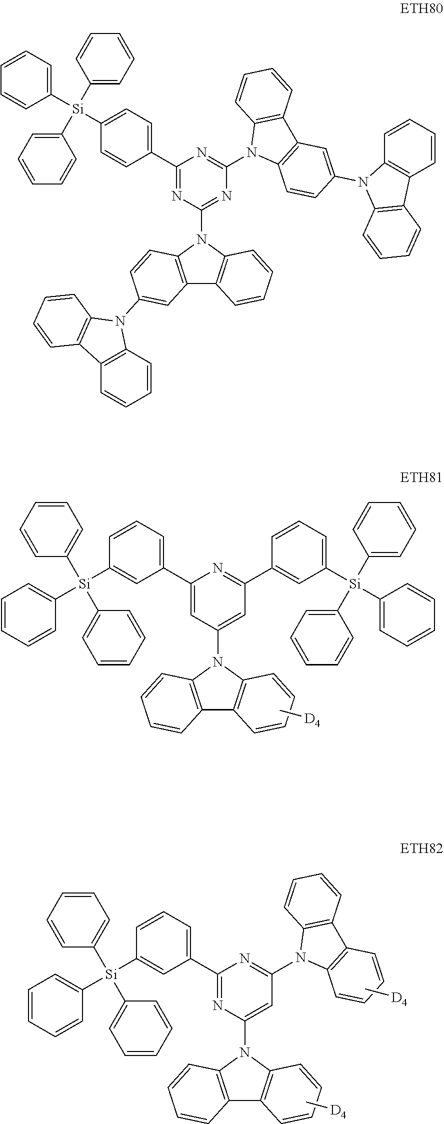

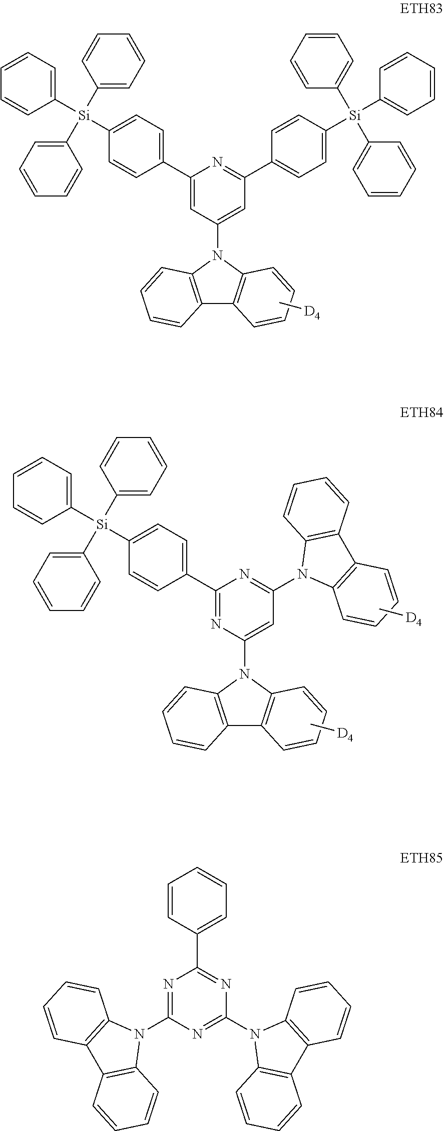

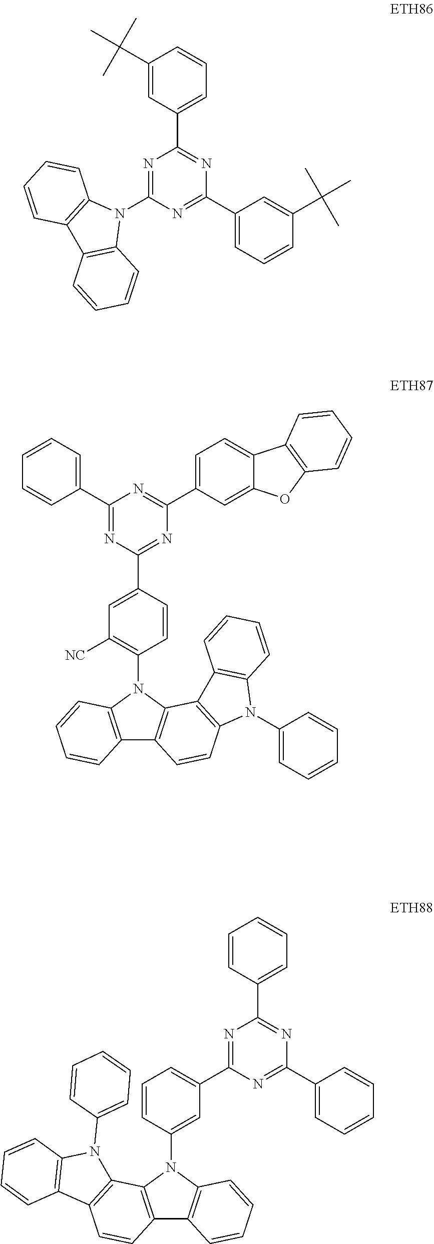 [SMILES: CC(C)(C)c1cccc(-c2nc(-c3cccc(C(C)(C)C)c3)nc(-n3c4ccccc4c4ccccc43)n2)c1 ; N#Cc1cc(-c2nc(-c3ccccc3)nc(-c3ccc4c(c3)oc3ccccc34)n2)ccc1-n1c2ccccc2c2ccc3c(c4ccccc4n3-c3ccccc3)c21 ; c1ccc(-c2nc(-c3ccccc3)nc(-c3cccc(-n4c5ccccc5c5ccc6c7ccccc7n(-c7ccccc7)c6c54)c3)n2)cc1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy of the exciplex may have a value that is smaller than an energy gap of each host material. The exciplex may have a triplet energy level equal to or less than about 3.0 eV, which is an energy gap between the hole transport host and the electron transport host.

In an embodiment, the emission layer EML may include a fourth compound, in addition to the first compound, the second compound, and the third compound. The fourth compound may be used as a phosphorescent sensitizer in the emission layer EML. Energy may be transferred from the fourth compound to the first compound, thereby effecting light emission.

In an embodiment, the emission layer EML may include an organometallic complex that includes platinum (Pt) as a central metal atom and ligands bonded to the central metal atom, as a fourth compound. In an embodiment, the emission layer EML may further include a fourth compound represented by Formula D-1:

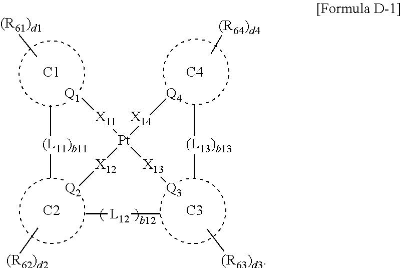

In Formula D-1, Q₁ to Q₄ may each independently be C or N.

In Formula D-1, C1 to C4 may each independently be a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms.

In Formula D-1, X₁₁ to X₁₄ may each independently be a direct linkage, or *—O—*. For example, one of X₁₁ to X₁₄ may be *—O—*, and the remainder of X₁₁ to X₁₄ may each be a direct linkage.

In Formula D-1, L₁₁ to L₁₃ may each independently be a direct linkage, *—O—*, *—S—*,

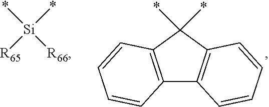

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, -* represents a bond to one of C1 to C4.

In Formula D-1, b11 to b13 may each independently be 0 or 1. If b11 is 0, C1 and C2 may not be directly bonded to each other. If b12 is 0, C2 and C3 may not be directly bonded to each other. If b3 is 0, C3 and C4 may not be directly bonded to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. If d1 to d4 are each 2 or more, multiple groups of each of R₆₁ to R₆₄ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-5:

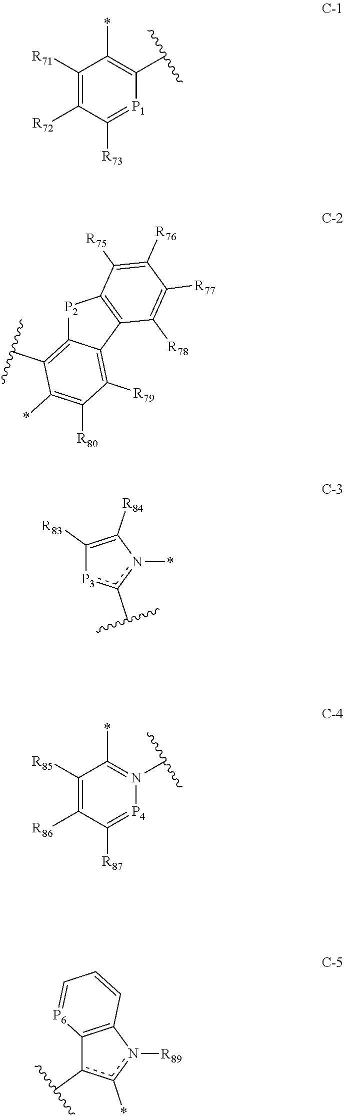

In Formula C-1 to Formula C-5, P₁ may be C—* or C(R₇₄), P₂ may be N—* or N(R₅₁), P₃ may be N—* or N(R₈₂), P₄ may be C—* or C(R₈₈), and P₆ may be C—* or C(R₉₀).

In Formula C-1 to Formula C-5, R₇₁ to R₉₀ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula C-1 to Formula C-5,

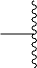

represents a bond to Pt, which is a central metal atom, and -* represents a bond to an adjacent ring group (C1 to C4) or to a linking moiety (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby effecting light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby effecting light emission. In an embodiment, the fourth compound may be a sensitizer. In the light emitting element ED, the fourth compound included in the emission layer EML may serve as a sensitizer that transfers energy from a host (for example, an exciplex host) to the first compound, which is a light-emitting dopant. For example, the fourth compound, which serves as an auxiliary dopant, may accelerate energy transfer to the first compound, which serves as a light emitting dopant, thereby increasing an emission ratio of the first compound. Accordingly, the emission layer EML may exhibit improved emission efficiency. If energy transfer to the first compound increases, excitons formed in the emission layer EML may not accumulate and may rapidly emit light, so that deterioration of the light emitting element ED may be reduced. Accordingly, the lifetime of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound that includes an organometallic complex, and thus the light emitting element ED may exhibit excellent emission efficiency properties.

In an embodiment, the fourth compound represented by Formula D-1 may be selected from Compound Group 4. In an embodiment, in the light emitting element ED, the fourth compound may include at least one compound selected from Compound Group 4:

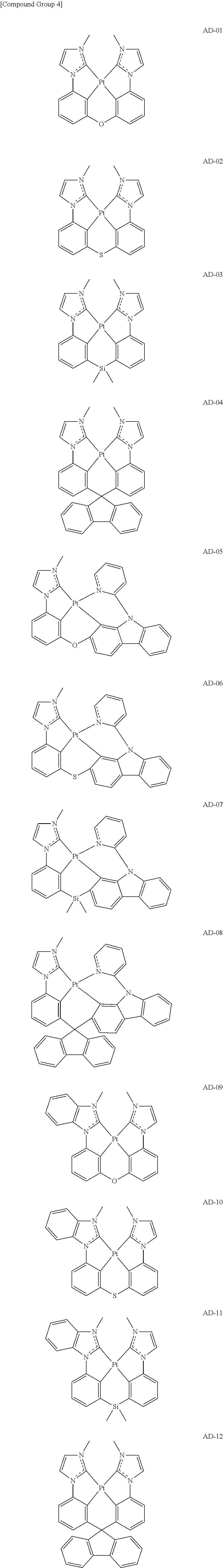

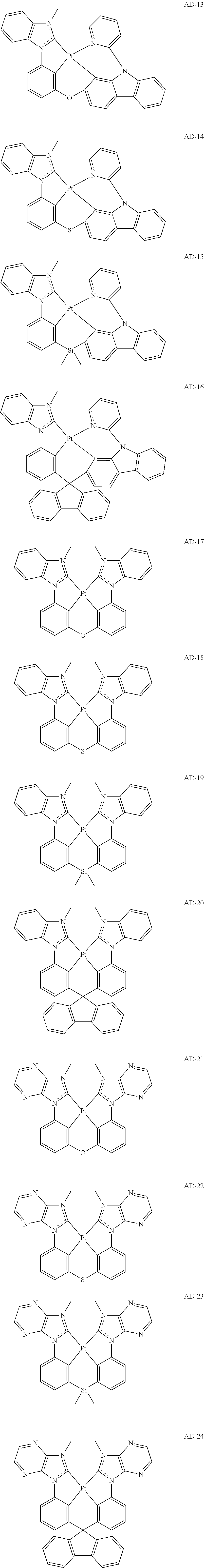

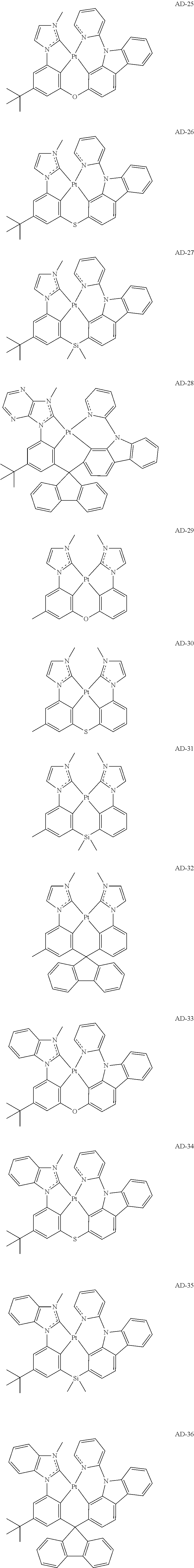

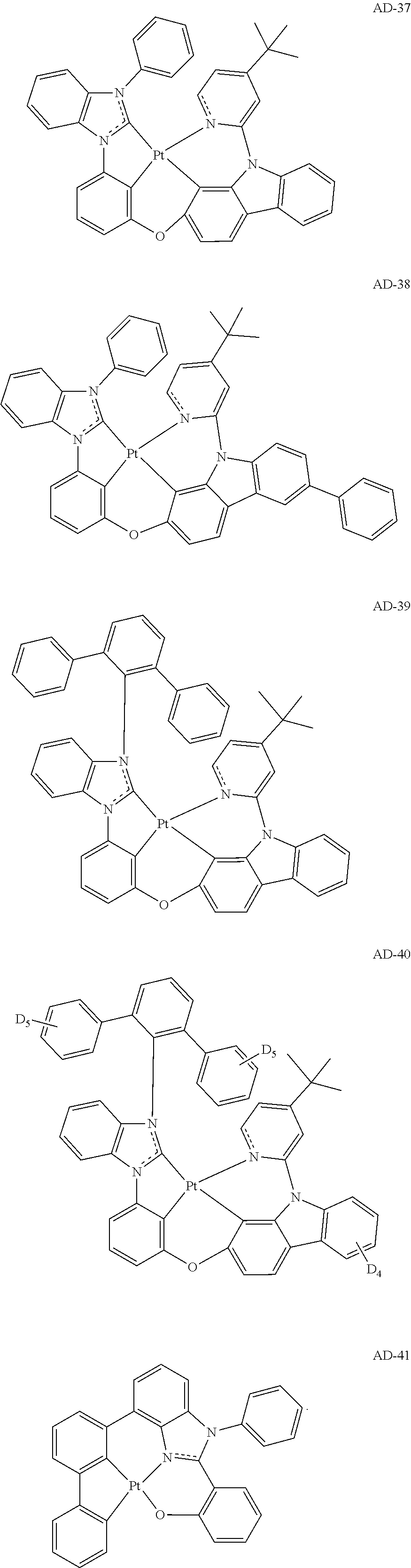

In Compound Group 4, D represents a deuterium atom.

In an embodiment, the light emitting element ED may include multiple emission layers. Multiple emission layers may be provided as a stack, so that a light emitting element ED including multiple emission layers may emit white light. The light emitting element ED including multiple emission layers may be a light emitting element having a tandem structure. If the light emitting element ED includes multiple emission layers, at least one emission layer EML may include the first compound represented by Formula 1. For example, if the light emitting element ED includes multiple emission layers, at least one emission layer EML may include the first compound, the second compound, the third compound, and the fourth compound.

In the light emitting element ED, if the emission layer EML includes the first compound, the second compound, the third compound, and the fourth compound, an amount of the first compound may be in a range of about 0.1 wt % to about 5 wt %, based on a total weight of the first compound, the second compound, the third compound, and the fourth compound. However, embodiments are not limited thereto. If an amount of the first compound satisfies the above-described range, energy transfer from the second compound and the third compound to the first compound may increase, and accordingly, emission efficiency and device lifetime may increase.

In the emission layer EML, a total amount of the second compound and the third compound may be the remainder of the total weight of the first compound, the second compound, the third compound, and the fourth compound, excluding the amount of the first compound and the fourth compound. For example, a combined amount of the second compound and the third compound may be in a range of about 65 wt % to about 95 wt %, based on a total weight of the first compound, the second compound, the third compound, and the fourth compound.

Within the combined amount of the second compound and the third compound in the emission layer EML, a weight ratio of the second compound to the third compound may be in a range of about 3:7 to about 7:3.

If the amounts of the second compound and the third compound satisfy the above-described ranges and ratios, charge balance properties in the emission layer EML may be improved, and emission efficiency and device lifetime may be improved. If the amounts of the second compound and the third compound deviate from the above-described ranges and ratios, charge balance in the emission layer EML may not be achieved, so that emission efficiency may be reduced, and the device may readily deteriorate.

If the emission layer EML includes the fourth compound, an amount of the fourth compound in the emission layer EML may be in a range of about 4 wt % to 30 wt %, based on a total weight of the first compound, the second compound, the third compound, and the fourth compound. However, embodiments are not limited thereto. If an amount of the fourth compound satisfies the above-described range, energy transfer from a host to the first compound, which is a light emitting dopant, may increase so that an emission ratio may improve. Accordingly, emission efficiency of the emission layer EML may improve. If the amounts of the first compound, the second compound, the third compound, and the fourth compound included in the emission layer EML satisfy the above-described ranges and ratios, excellent emission efficiency and long lifetime may be achieved.

In the light emitting element ED, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting elements ED according to embodiments as shown in each of FIG. 3 to FIG. 6, the emission layer EML may further include hosts and dopants of the related art, in addition to the above-described host and dopant.

In an embodiment, the emission layer EML may include a compound represented by Formula E-1. The compound represented by Formula E-1 may be used as a fluorescence host material.

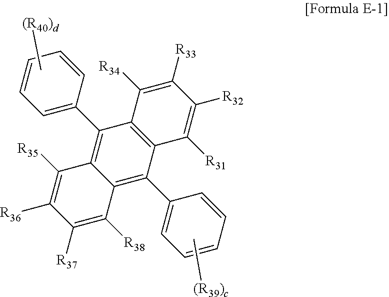

In Formula E-1, R₃₁ to R₄₀ may each independently be a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

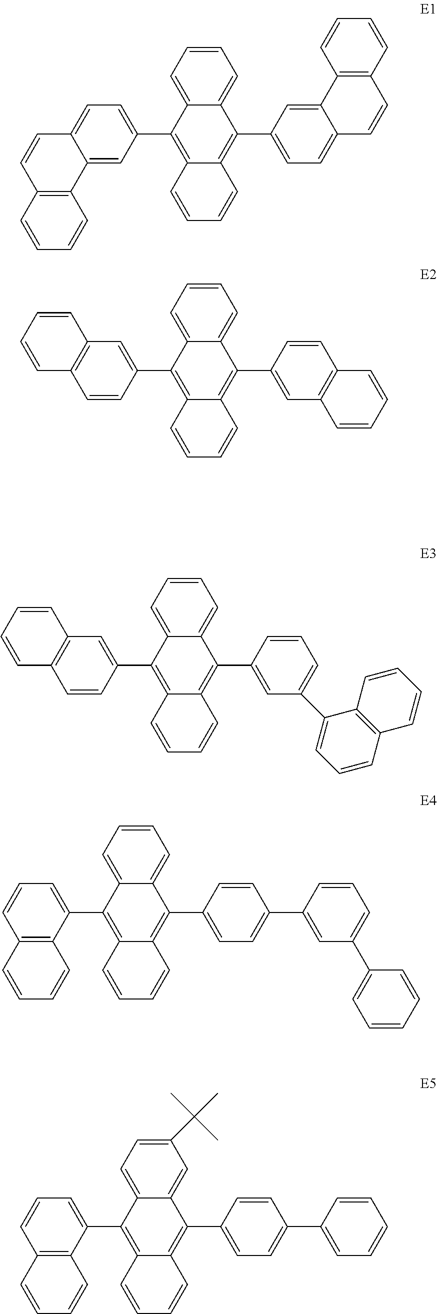

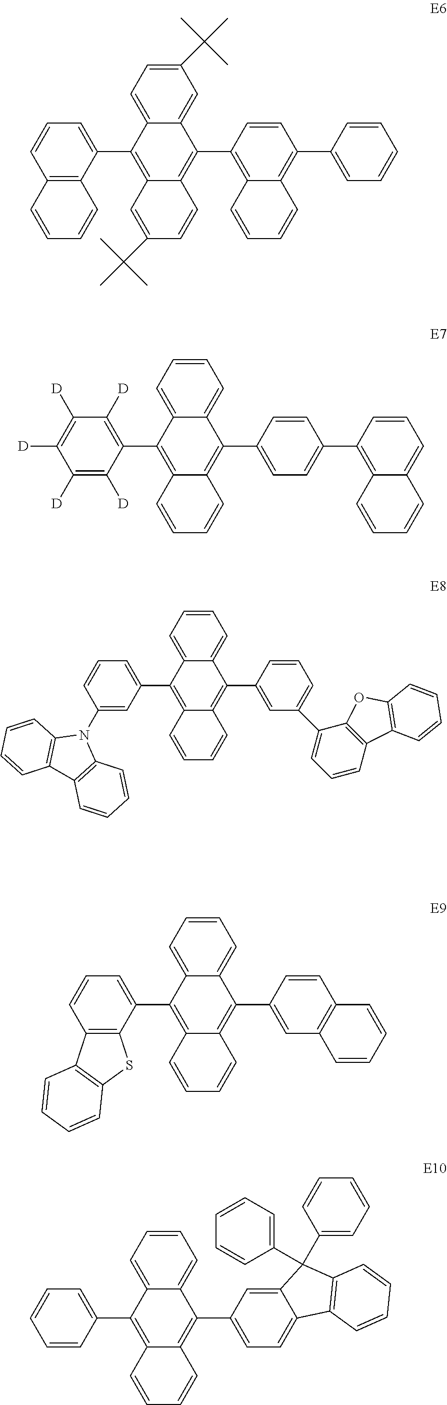

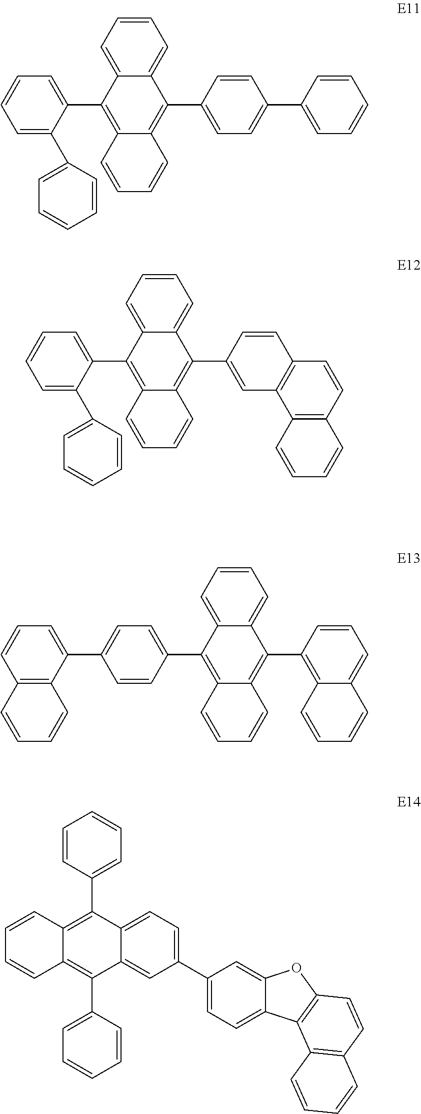

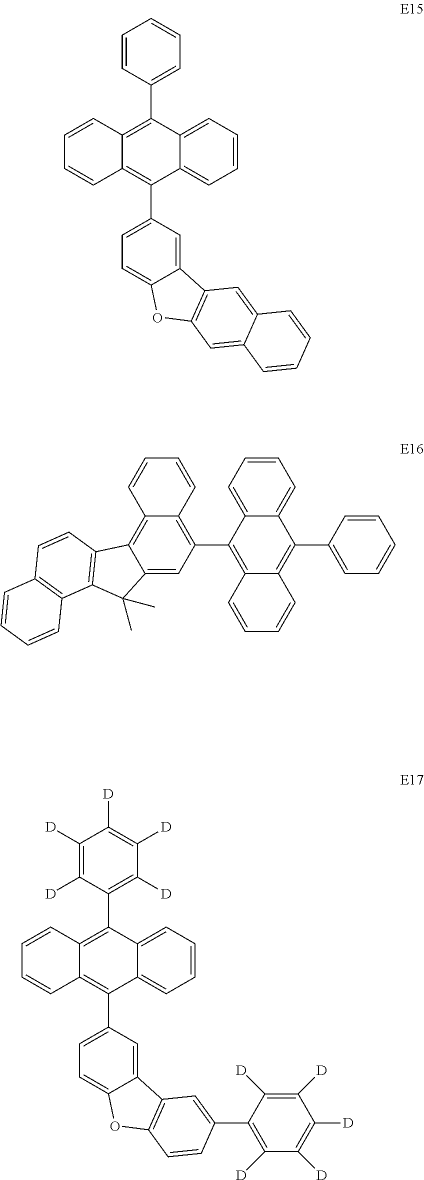

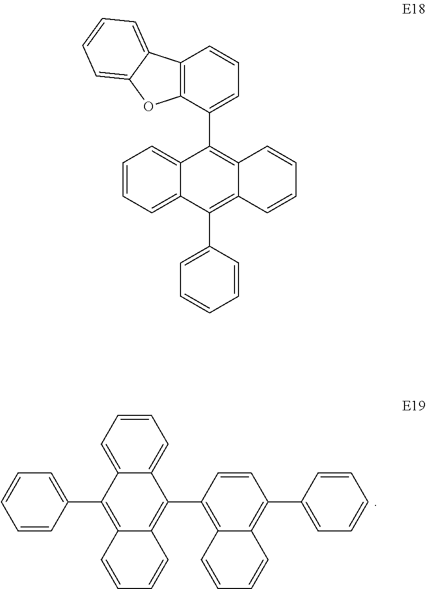

In an embodiment, the emission layer EML may include a compound represented by Formula E-2a or Formula E-2b. The compound represented by Formula E-2a or Formula E-2b may be used as a phosphorescence host material.

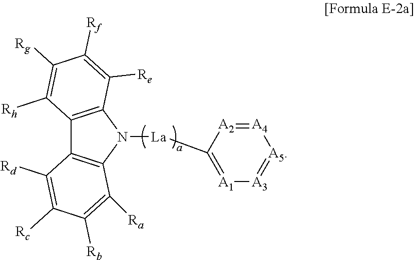

In Formula E-2a, a may be an integer from 0 to 10; and La may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple La groups may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

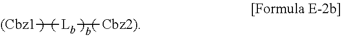

In Formula E-2b, Cbz1 and Cbz2 may each independently be an unsubstituted carbazole group or a carbazole group substituted with an aryl group of 6 to 30 ring-forming carbon atoms. In Formula E-2b, Le may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10. If b is 2 or more, multiple Le groups may each independently be a substituted or unsubstituted arylene group of 6 to 30 ring-forming carbon atoms or a substituted or unsubstituted heteroarylene group of 2 to 30 ring-forming carbon atoms.

In an embodiment, the compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2:

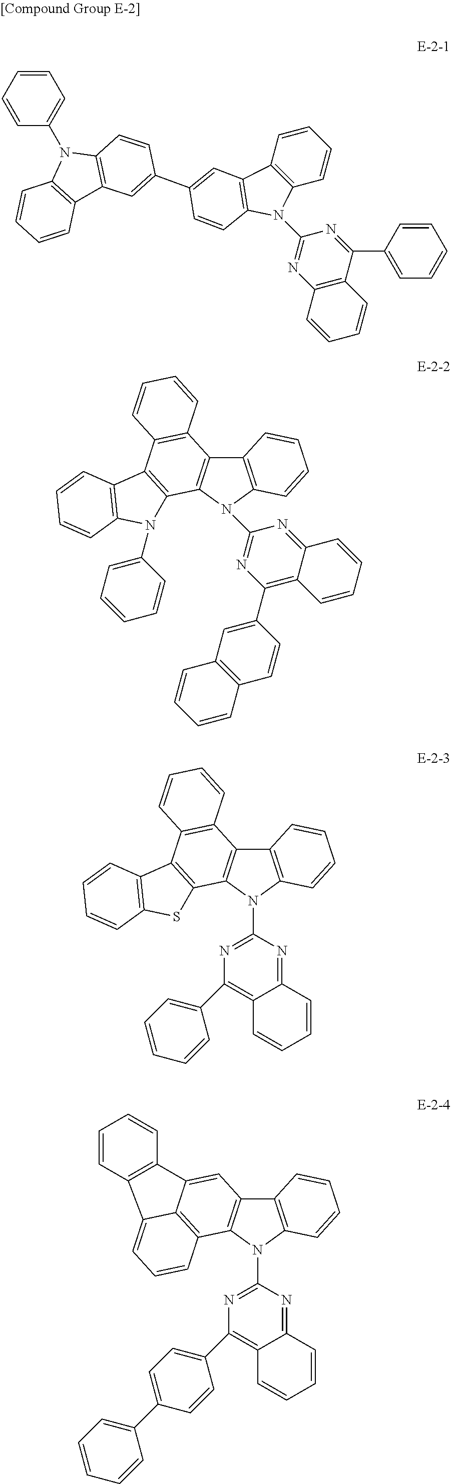

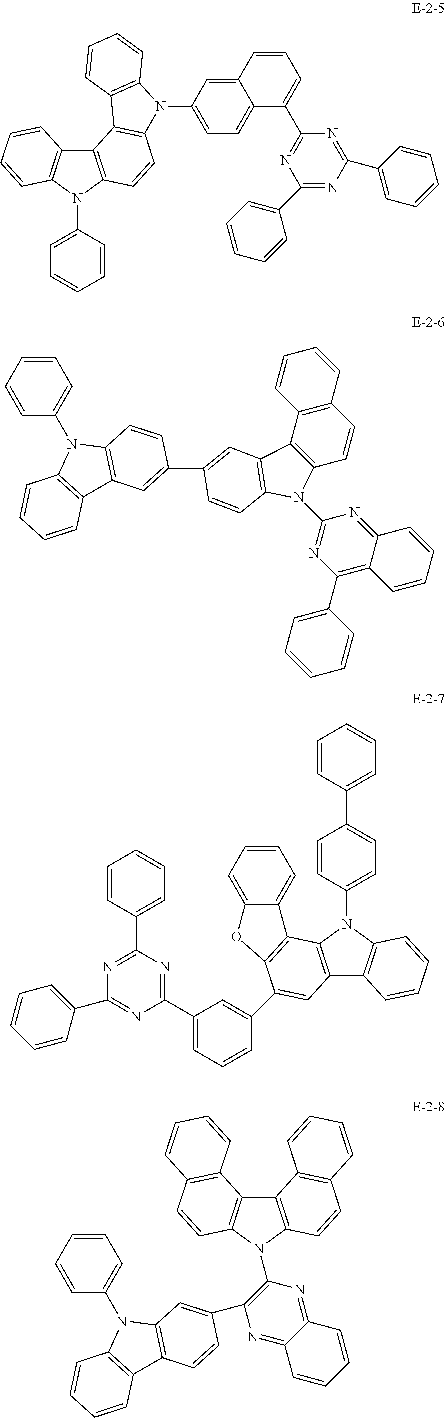 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

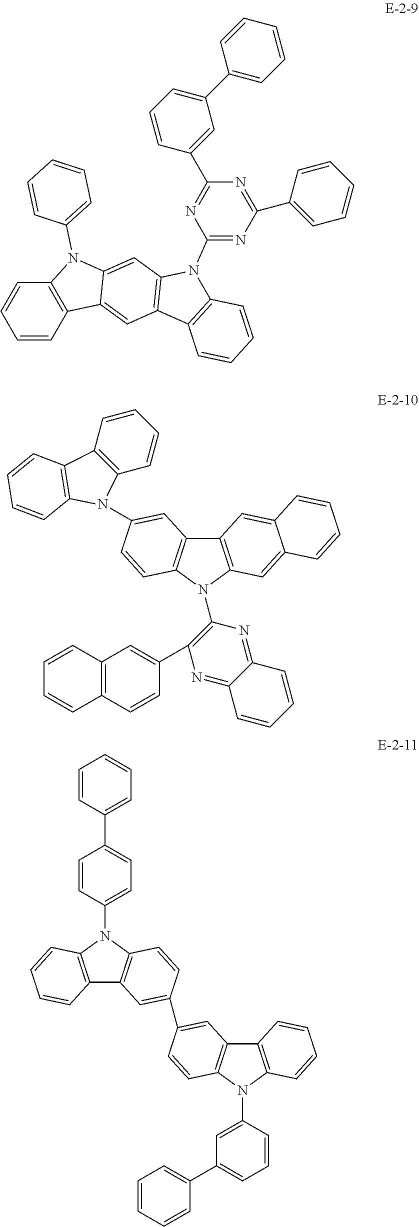 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc4ccccc4nc3-n3c4ccc(-n5c6ccccc6c6ccccc65)cc4c4cc5ccccc5cc43)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

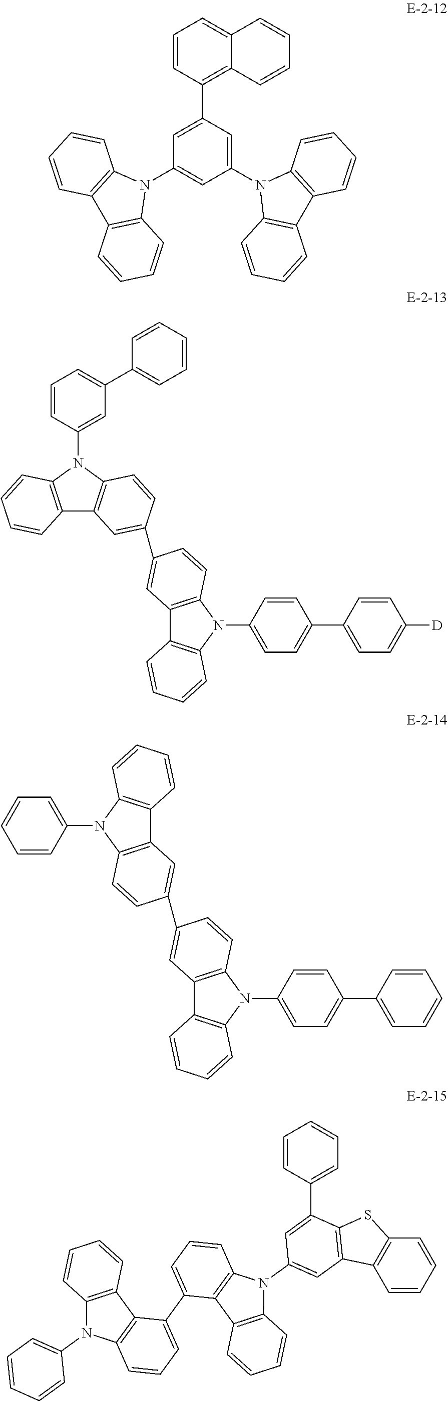 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

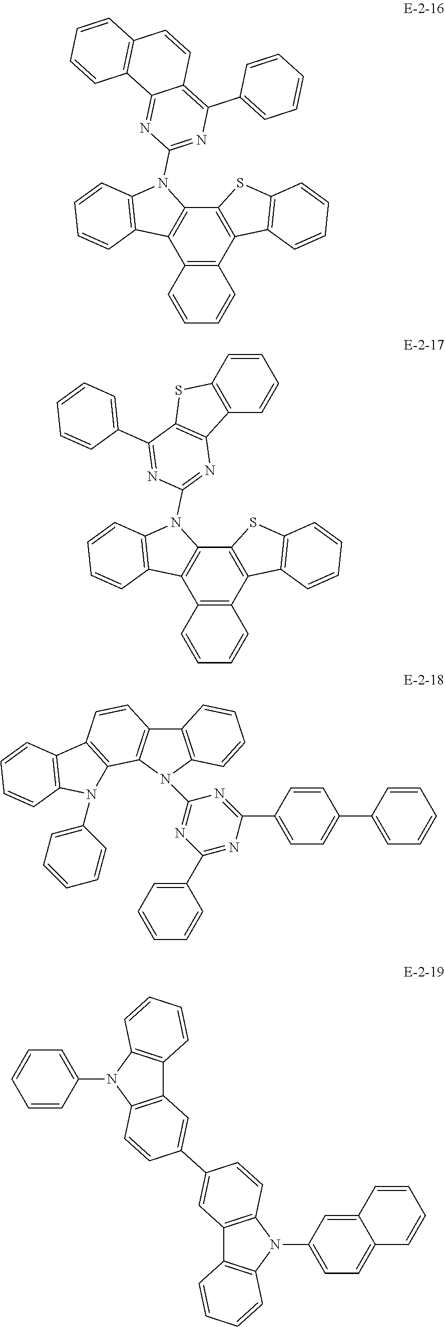

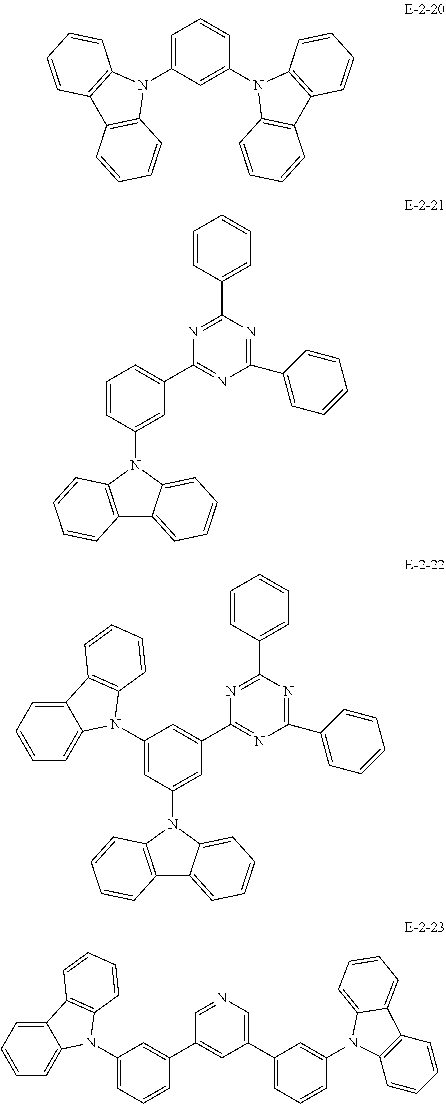 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

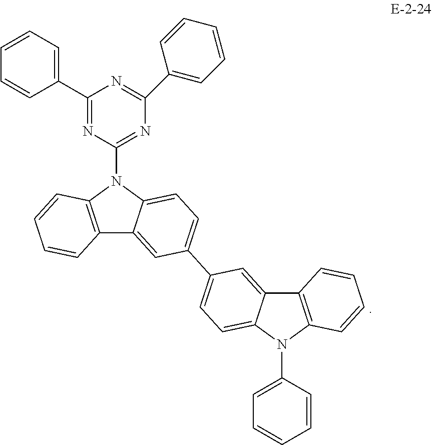 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the emission layer EML may include a compound represented by Formula M-a. The compound represented by Formula M-a may be used as a phosphorescence dopant material.

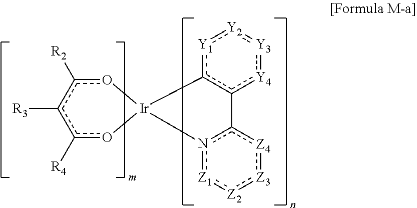

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. In Formula M-a, m may be 0 or 1, and n may be 2 or 3. In Formula M-a, if m is 0, n may be 3, and if m is 1, n may be 2.

In an embodiment, the compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

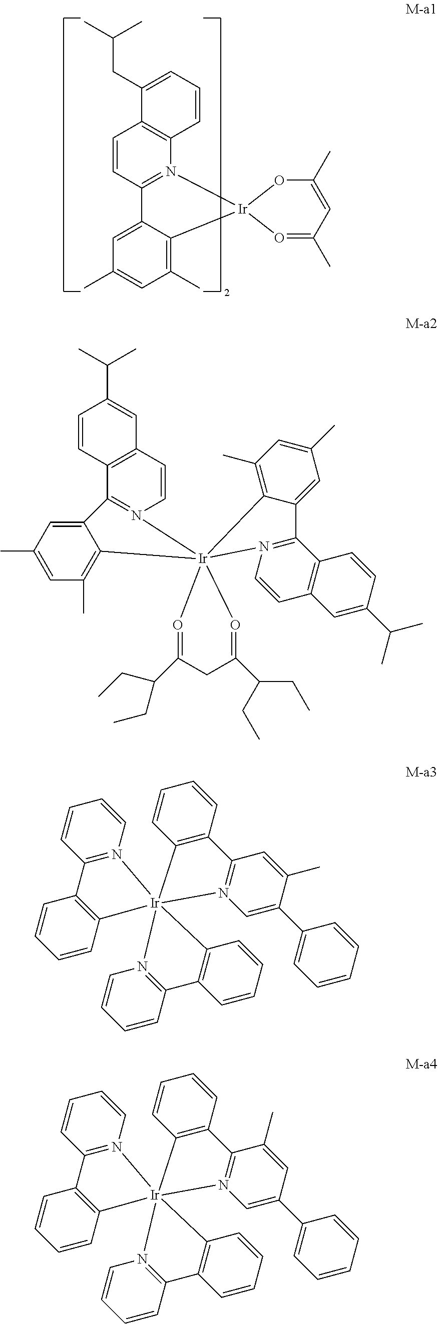

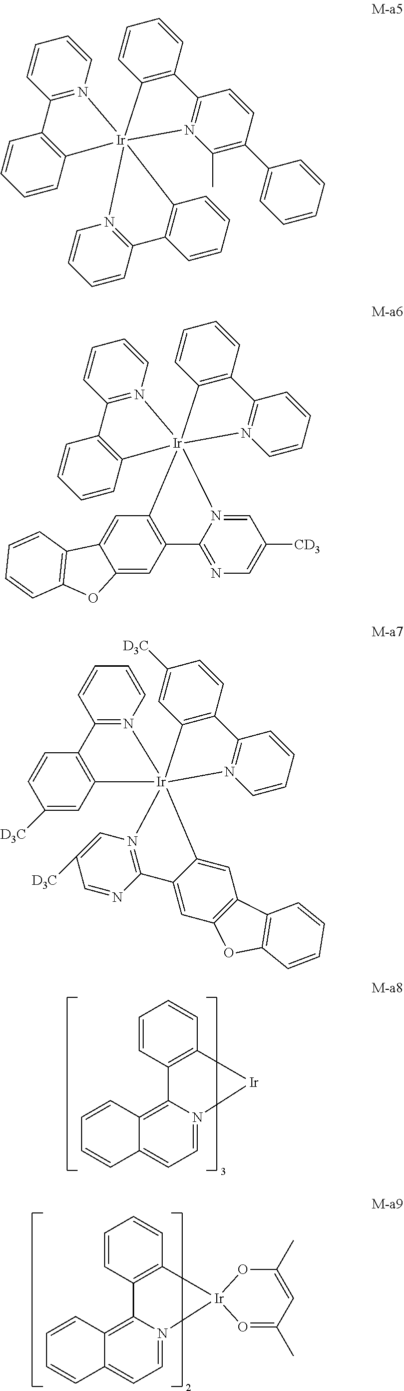

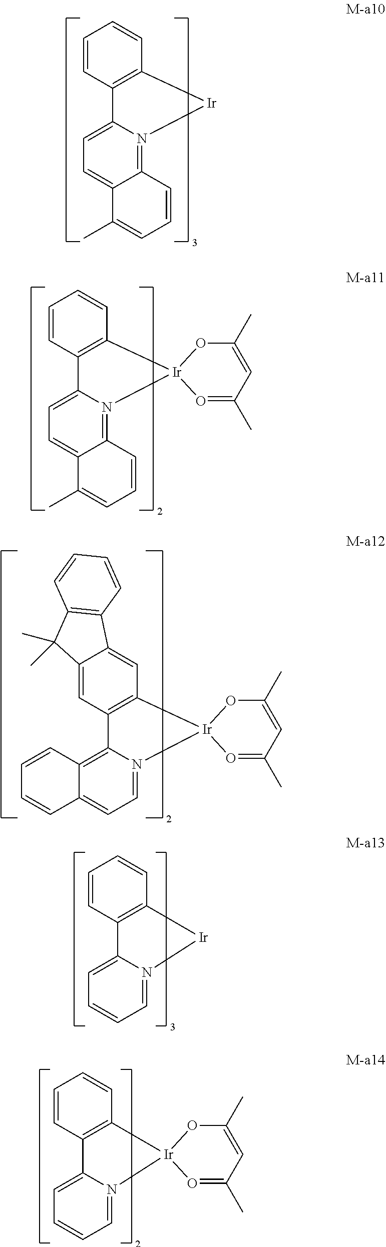

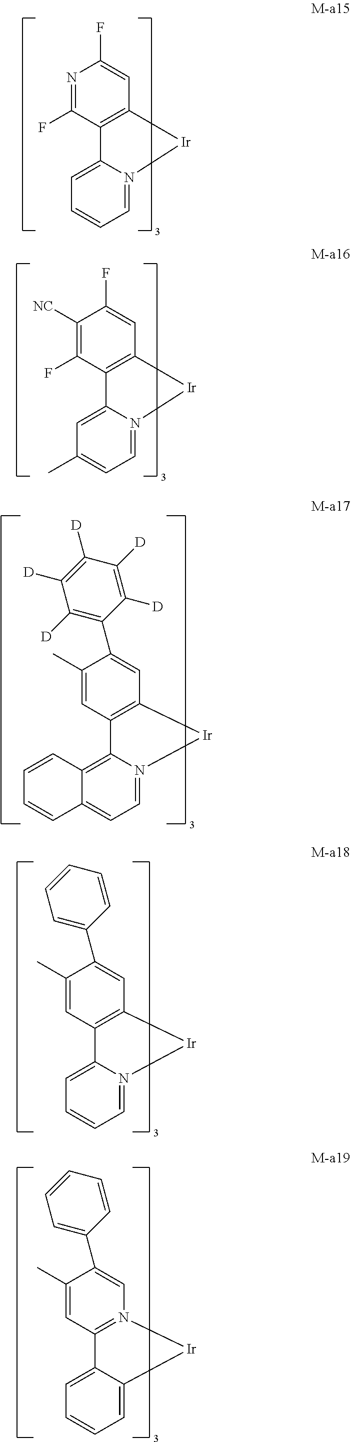

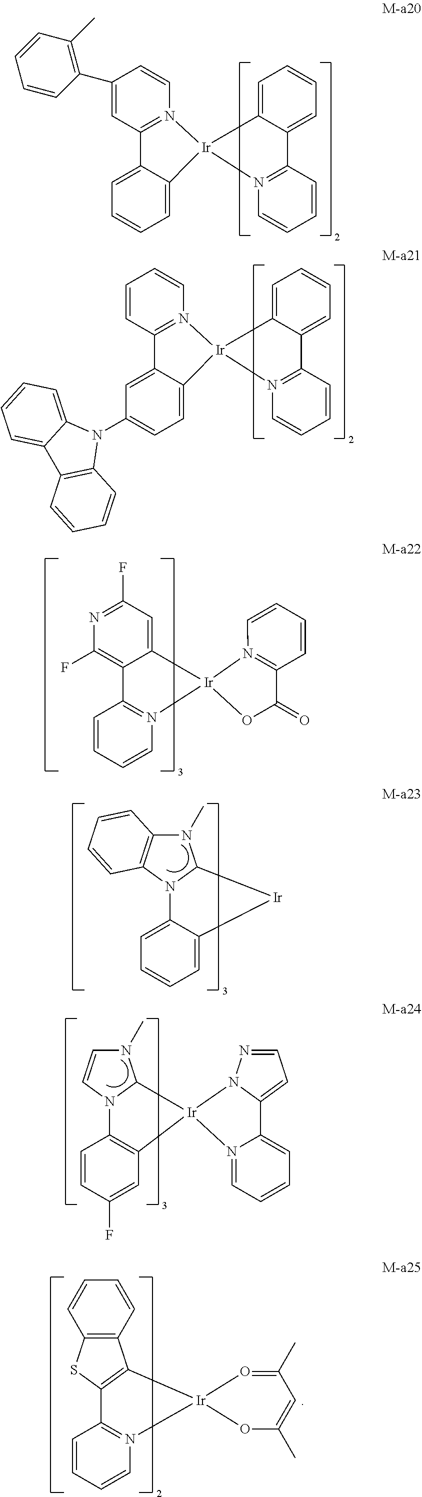

In an embodiment, the emission layer EML may further include a compound represented by one of Formula F-a to Formula F-c. The compound represented by one of Formula F-a to Formula F-c may be used as a fluorescence dopant material.

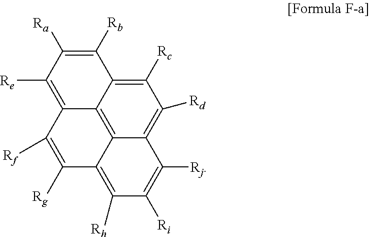

In Formula F-a, two of Rₐ to Rⱼ may each independently be substituted with a group represented by *—NAr₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may each independently be a heteroaryl group including O or S as a ring-forming atom.

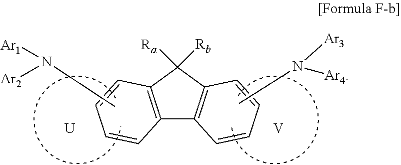

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at the part indicated by U or V, respectively, and if the number of U or V is 0, a fused ring may not be present at the part indicated by U or V, respectively. If the number of U is 0 and the number of V is 1, or if the number of U is 1 and the number of V is 0, a fused ring having the fluorene core of Formula F-b may be a cyclic compound with four rings. If the number of U and V is each 0, a fused ring having the fluorene core of Formula F-b may be a cyclic compound with three rings. If the number of U and V is each 1, a fused ring having the fluorene core of Formula F-b may be a cyclic compound with five rings.

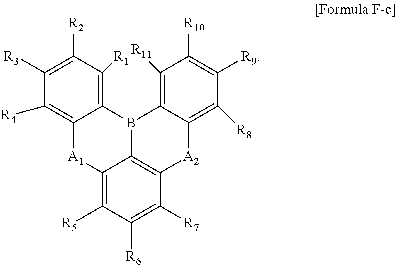

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may each independently be combined with a substituent of an adjacent ring to form a fused ring. For example, if A₁ and A₂ are each independently N(Rₘ), A₁ may be combined with R₄ or R₅ to form a fused ring. For example, A₂ may be combined with R₇ or R₈ to form a fused ring.

In an embodiment, the emission layer EML may include, as a dopant material of the related art, a styryl derivative (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, the phosphorescence dopant may include a metal complex that includes iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In an embodiment, the emission layer may include a quantum dot.

In the specification, a quantum dot may be a crystal of a semiconductor compound. The quantum dot may emit light in various emission wavelengths according to a size of the crystal. The quantum dot may emit light in various emission wavelengths by controlling an elemental ratio of a quantum dot compound.

A diameter of the quantum dot may be, for example, in a range of about 1 nm to about 10 nm.

A quantum dot may be synthesized by chemical bath deposition, metal organic chemical vapor deposition, molecular beam epitaxy, or be a similar process therewith.

Chemical bath deposition is a method of mixing an organic solvent and a precursor material and growing a quantum dot particle crystal. While growing the crystal, the organic solvent may serve as a dispersant that is coordinated on a surface of the quantum dot crystal and may control the growth of the crystal. Accordingly, chemical bath deposition may be more advantageous when compared to a vapor deposition method such as metal organic chemical vapor deposition (MOCVD) and molecular beam epitaxy (MBE), and the growth of a quantum dot particle may be controlled through a low-cost process.

In an embodiment, the emission layer EML may include a quantum dot material. The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof.

In an embodiment, a Group II-VI compound may further include a Group I metal and/or a Group IV element. Examples of a Group I-II-VI compound may include: CuSnS and CuZnS. Examples of a Group II-IV-VI compound may include ZnSnS and the like. Examples of a Group I-II-IV-VI compound may include a quaternary compound selected from the group consisting of Cu₂ZnSnS₂, Cu₂ZnSnS₄, Cu₂ZnSnSe₄, Ag₂ZnSnS₂, and a mixture thereof.

Examples of a Group III-VI compound may include a binary compound such as In₂S₃, and In₂Se₃; a ternary compound such as InGaS₃ and InGaSe₃; and any combination thereof.

Examples of a Group I-III-VI compound may include: a ternary compound selected from the group consisting of AgInS, AgInS₂, CuInS, CuInS₂, AgGaS₂, CuGaS₂, CuGaO₂, AgGaO₂, AgAlO₂, and a mixture thereof; a quaternary compound such as AgInGaS₂, and CuInGaS₂; and any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V group compound may further include a Group II group element. Examples of a Group III-II-V compound may include InZnP, etc.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; and any combination thereof.

Examples of a Group II-IV-V compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

Examples of a Group IV element may include Si, Ge, and a mixture thereof. Examples of a Group IV compound may include a binary compound selected from the group consisting of SiC, SiGe, and a mixture thereof.

Each element included in a compound, such as a binary compound, a ternary compound, or a quaternary compound, may be present in a particle at a uniform concentration or at a non-uniform concentration. For example, a formula may indicate the elements that are included in a compound, but an elemental ratio of the compound may vary. For example, AgInGaS₂ may indicate AgInₓGa₁₋ₓS₂ (where x is a real number between 0 and 1).

A binary compound, a ternary compound, or a quaternary compound may be present in a particle at a uniform concentration or at a partially different concentration distribution state. In an embodiment, a quantum dot may have a core/shell structure in which a quantum dot surrounds another quantum dot. An interface between the core and the shell may have a concentration gradient in which the concentration of an element that is present in the shell decreases toward the core.

In embodiments, the quantum dot may have the above-described core-shell structure a nanocrystal core and a shell that surrounds the core. The shell of a quantum dot may serve as a protection layer that prevents chemical deformation of the core to maintain semiconductor properties and/or may serve as a charging layer that imparts the quantum dot with electrophoretic properties. The shell may have a single layer structure or a multilayer structure. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO; or a ternary compound such as MgAl₂O₄, CoFe₂O₄, NiFe₂O₄ and CoMn₂O₄. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission spectrum equal to or less than about 45 nm. For example, the quantum dot may have a FWHM of an emission spectrum equal to or less than about 40 nm. For example, the quantum dot may have a FWHM of an emission spectrum equal to or less than about 30 nm. Within any of the above ranges, color purity or color reproducibility may be improved. Light that is emitted through a quantum dot may be emitted in all directions, so that light viewing angle properties may be improved.

The shape of a quantum dot may be any shape that is used in the related art. For example, a quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

As a size of quantum dot or an elemental ratio of the quantum dot compound is adjusted, the energy band gap may be changed accordingly to produce light of various wavelengths from a quantum dot emission layer. Therefore, by using quantum dots as described above (for example, using quantum dots of different sizes or having different elemental ratios of the quantum dot compound), a light emitting element that emits light of various wavelengths may be achieved. For example, the size of the quantum dots or the elemental ratio of the quantum dot compound may be adjusted to emit red light, green light, and/or blue light. For example, the quantum dots may be configured to emit white light by combining light of various colors.

In the light emitting elements ED according to embodiments as shown in each of FIG. 3 to FIG. 6, the electron transport region ETR may be provided on the emission layer EML. The electron transport region ETR may include at least one of an electron blocking layer HBL, an electron transport layer ETL, and an electron injection layer EIL. However, embodiments are not limited thereto.

The electron transport region ETR may have a structure consisting of a layer consisting of a single material, a structure consisting of a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In an embodiment, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

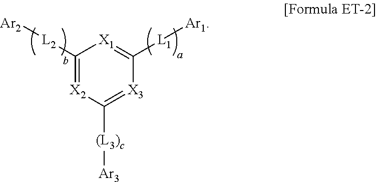

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), CNNPTRZ (4′-(4-(4-(4,6-diphenyl-1,3,5-triazin-2-yl)phenyl)naphthalen-1-yl)-[1,1′-biphenyl]-4-carbonitrile), or a mixture thereof, without limitation.

In an embodiment, the electron transport region ETR may include a compound selected from Compound Group 3.

In an embodiment, the electron transport region ETR may include at least one compound selected from Compounds ET1 to ET36:

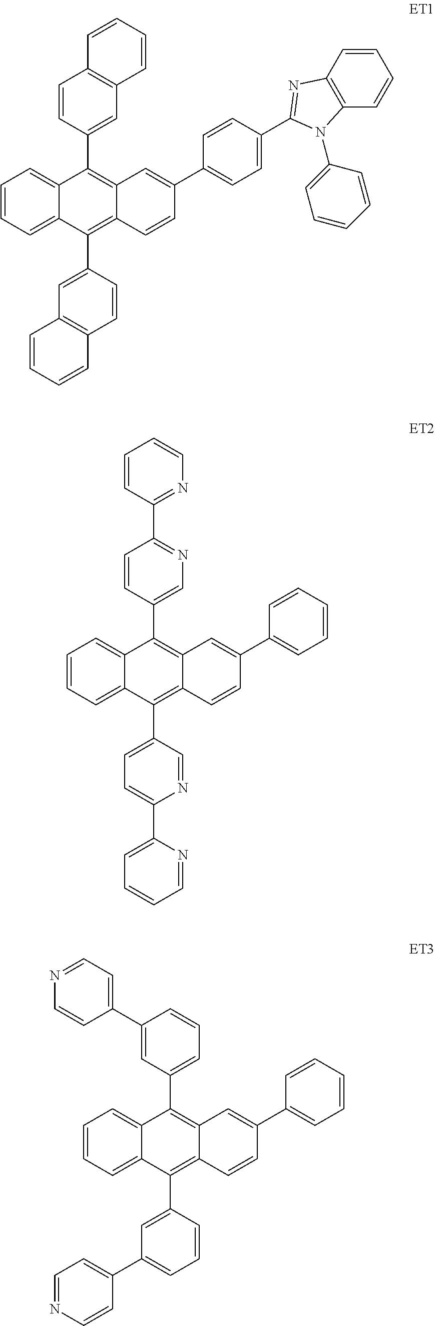 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

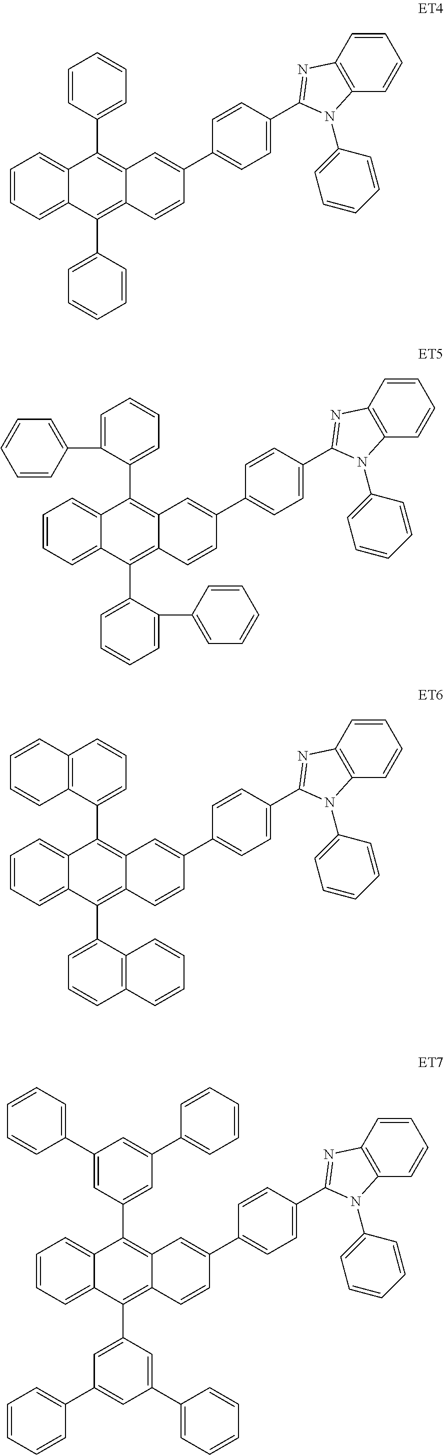 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

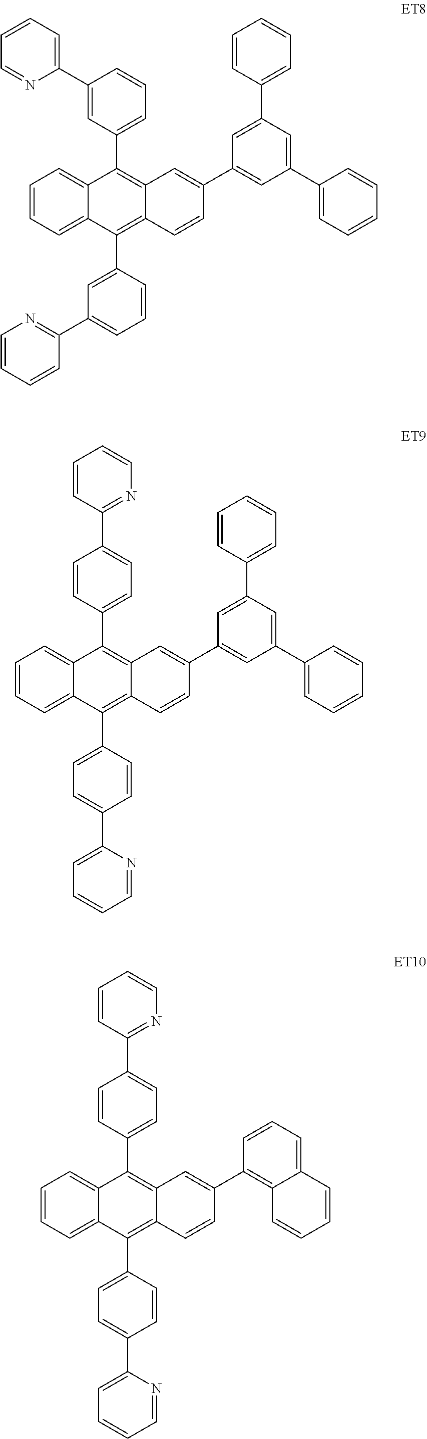 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

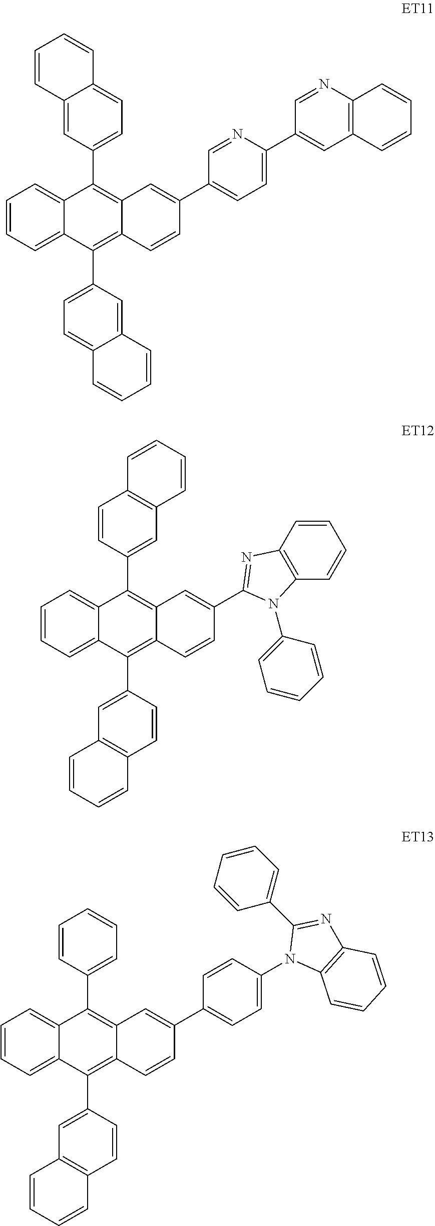 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

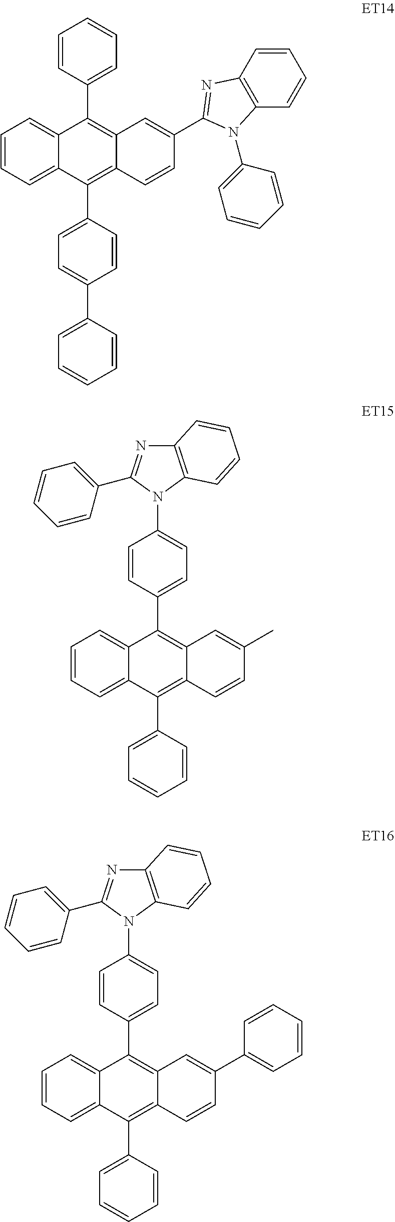 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

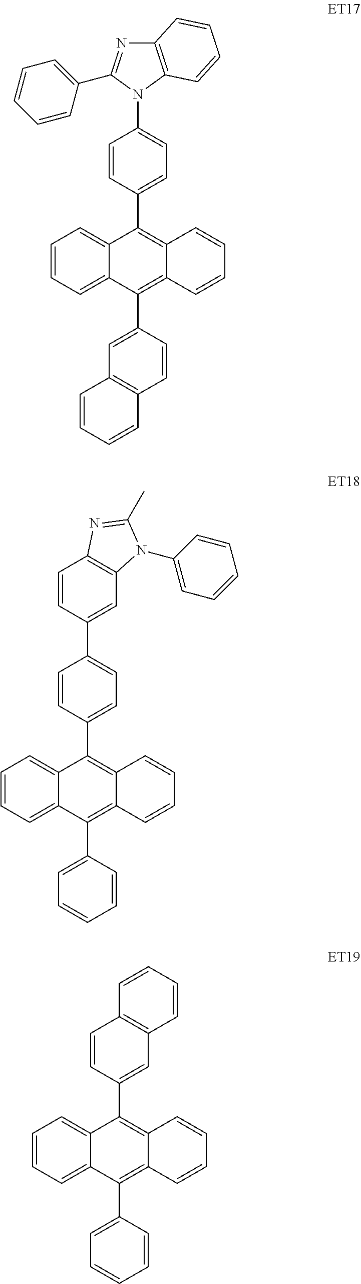

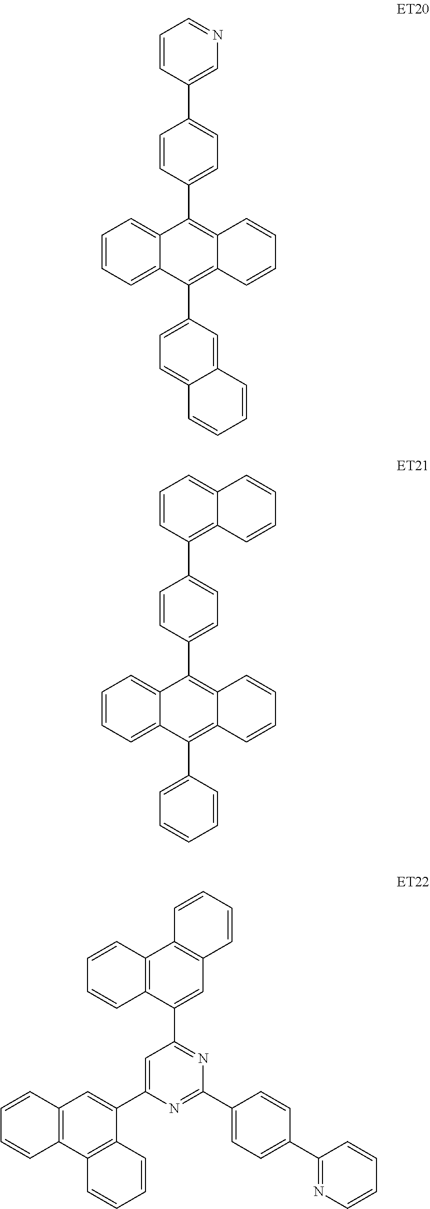

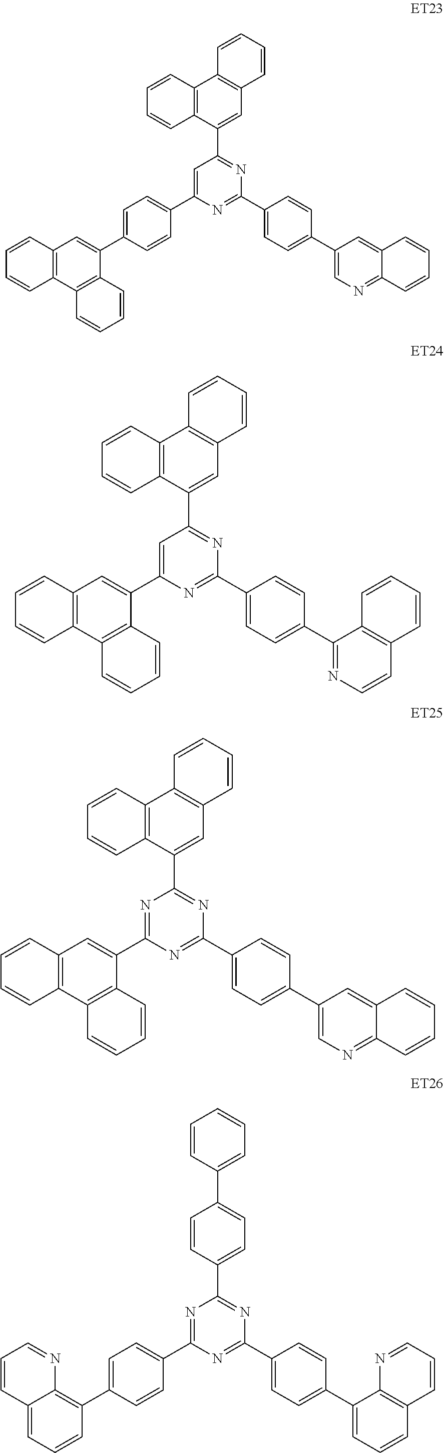 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

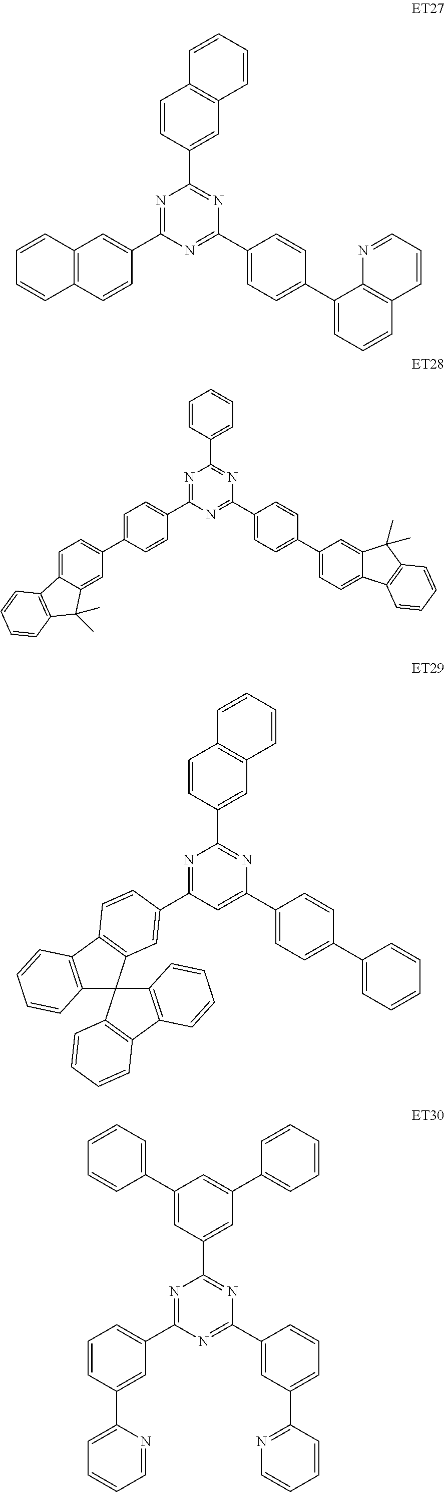

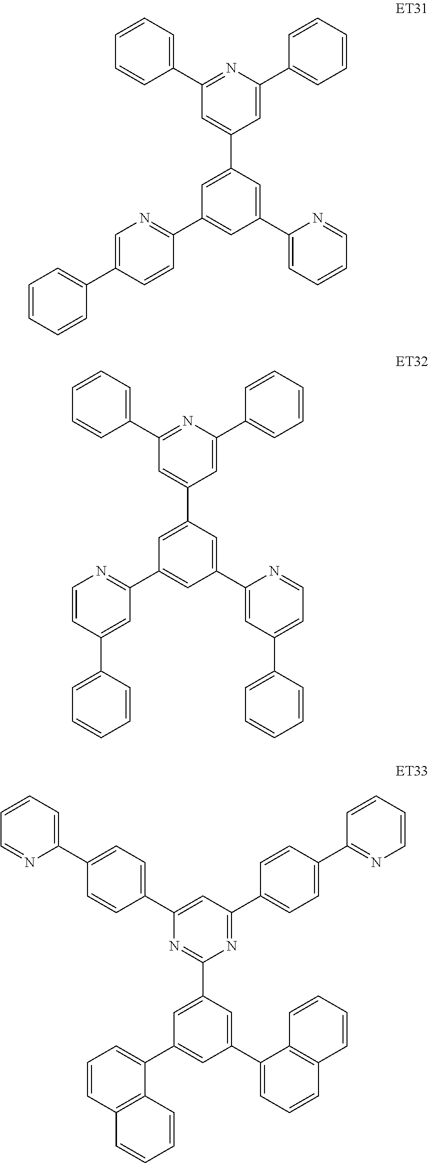 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

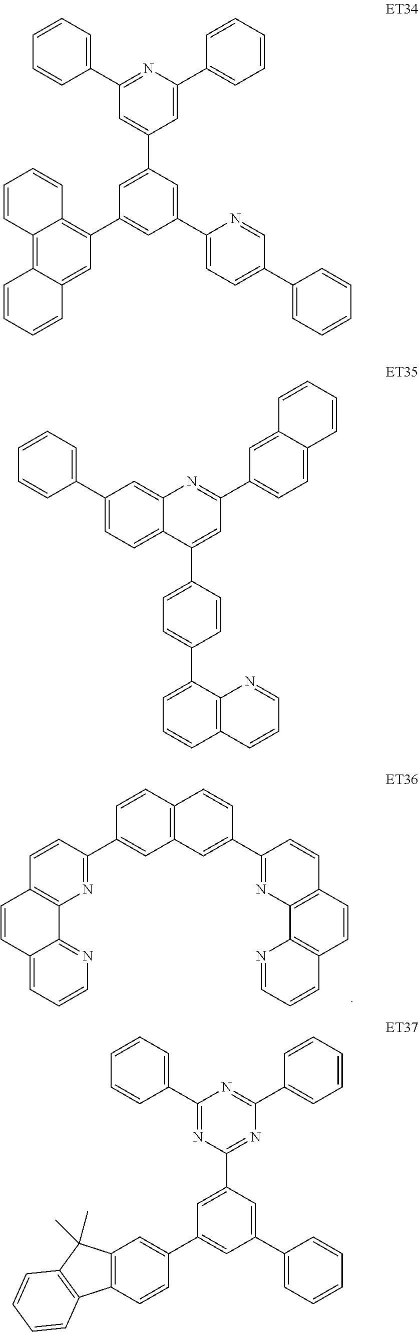

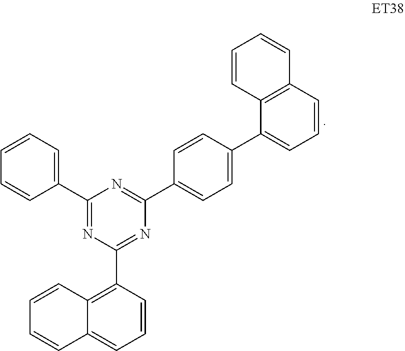 [SMILES: c1ccc(-c2nc(-c3ccc(-c4cccc5ccccc45)cc3)nc(-c3cccc4ccccc34)n2)cc1]

In an embodiment, the electron transport region ETR may include a metal halide such as LiF, NaCl, CsF, RbCl, RbI, CuI and KI, a lanthanide such as Yb, or a co-deposited material of a metal halide and a lanthanide. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR may also be formed of a mixture of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen), in addition to the aforementioned materials. However, embodiments are not limited thereto.

The electron transport region ETR may include the compounds of the electron transport region ETR in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without a substantial increase of driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more of the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a multilayer structure or a single layer structure.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or may include an epoxy resin, or an acrylate such as methacrylate. In an embodiment, the capping layer CPL may include at least one of Compounds P1 to P5, but embodiments are not limited thereto.

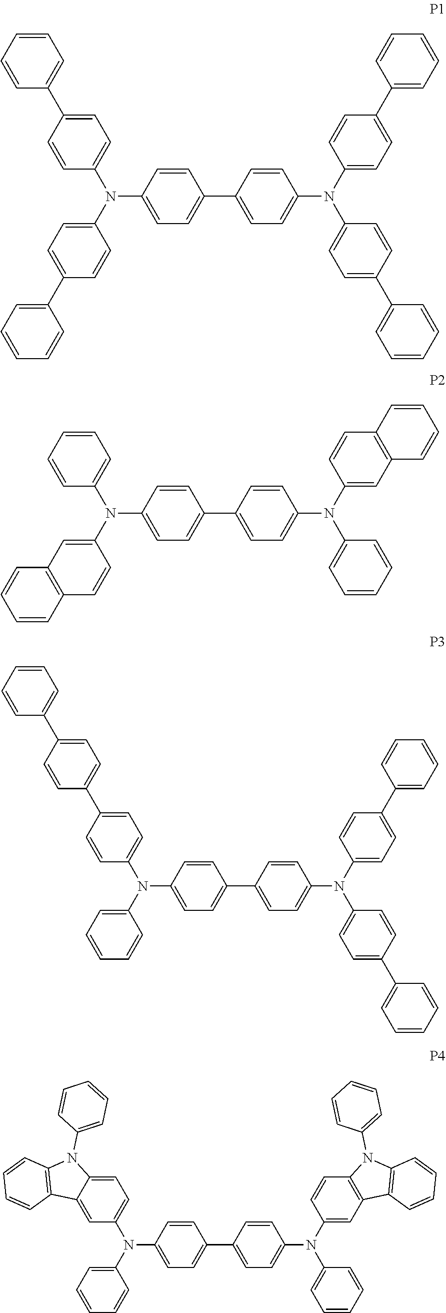 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

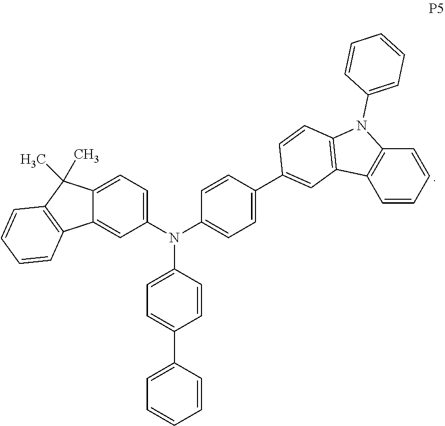 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

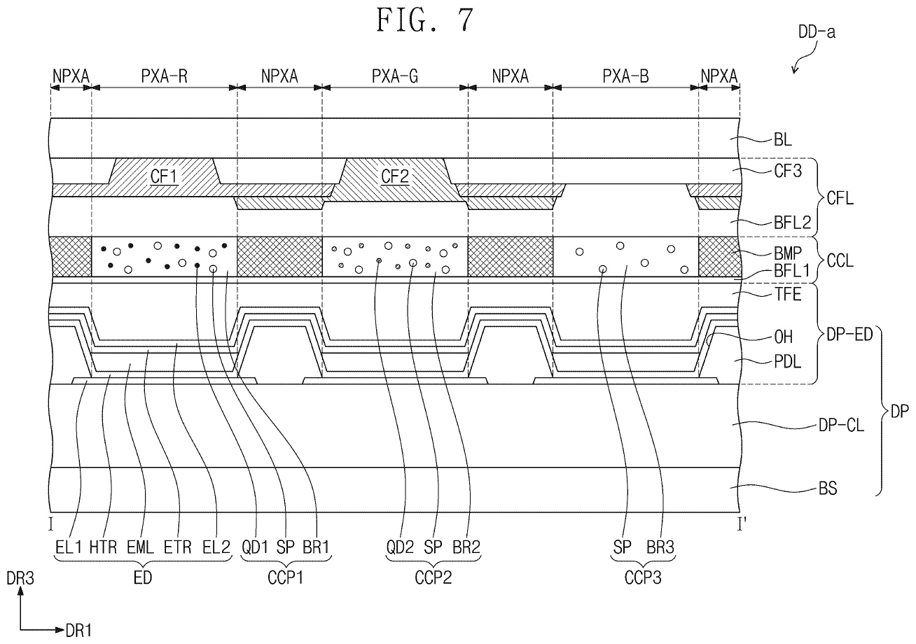

FIG. 7 to FIG. 10 are each a schematic cross-sectional view of a display device according to an embodiment. In the descriptions of the display devices according to embodiments as shown in FIG. 7 to FIG. 10, the features which have been described above with respect to FIG. 1 to FIG. 6 will not be explained again, and the differing features will be explained.

Referring to FIG. 7, the display device DD-a according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display device layer DP-ED; and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element according to one of FIG. 3 to FIG. 6 as described above.

The emission layer EML of the light emitting element ED included in the display device DD-a according to an embodiment may include the fused polycyclic compound according to an embodiment as described above.

Referring to FIG. 7, the emission layer EML may be disposed in an opening OH defined in a pixel defining film PDL. For example, the emission layer EML, which is separated by the pixel defining film PDL and correspondingly provided to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light and emit the resulting light. For example, the light controlling layer CCL may be a layer that includes a quantum dot or a layer that includes a phosphor.

The light controlling layer CCL may include light controlling parts CCP1, CCP2, and CCP3. The light controlling parts CCP1, CCP2, and CCP3 may be spaced apart from one another.

Referring to FIG. 7, a partition pattern BMP may be disposed between the light controlling parts CCP1, CCP2, and CCP3 that are spaced apart from one another, but embodiments are not limited thereto. In FIG. 7, it is shown that the partition pattern BMP does not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits first color light.

In an embodiment, the first light controlling part CCP1 may provide red light, which is the second color light, and the second light controlling part CCP2 may provide green light, which is the third color light. The third color controlling part CCP3 may provide blue light by transmitting the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may include base resins BR1, BR2, and BR3, in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2, and BR3 are mediums in which the quantum dots QD1 and QD2 and the scatterer SP are dispersed, and may include various resin compositions, which may be referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, will be referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. In an embodiment, a color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film that secures light transmittance. The barrier layers BFL1 and BFL2 may each independently further include an organic material. The barrier layers BFL1 and BFL2 may be composed of a single layer or of multiple layers.

In the display device DD-a, the color filter layer CFL may be disposed on the light controlling layer CCL. In an embodiment, the color filter layer CFL may be directly disposed on the light controlling layer CCL. For example, the barrier layer BFL2 may be omitted.

The color filter layer CFL may include filters CF1, CF2, and CF3. The first filter CF1, the second filter CF2, and the third filter CF3 may be disposed to respectively correspond to a red light emitting region PXA-R, a green light emitting region PXA-G, and a blue light emitting region PXA-B.

The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, the color filter layer CFL may further include a light blocking part (not shown). The light blocking part (not shown) may be a black matrix. The light blocking part (not shown) may include an organic light blocking material or an inorganic light blocking material, each including a black pigment or a black dye. The light blocking part (not shown) may prevent light leakage, and may separate the boundaries between adjacent filters CF1, CF2, and CF3.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted t.

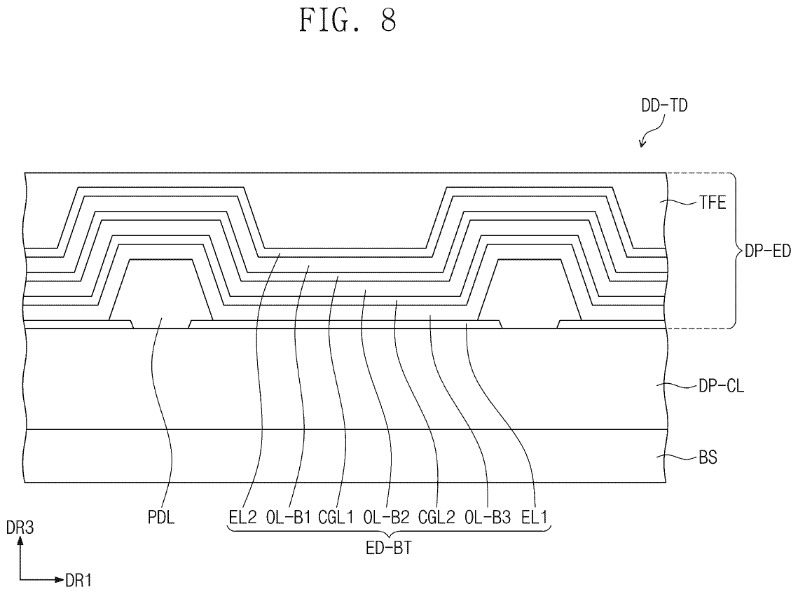

FIG. 8 is a schematic cross-sectional view of a portion of a display device according to an embodiment. In a display device DD-TD according to an embodiment, the light emitting element ED-BT may include light emitting structures OL-B1, OL-B2, and OL-B3. The light emitting element ED-BT may include a first electrode EL1 and a second electrode EL2 that are disposed opposite each other, and the light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, an emission layer EML (FIG. 7), and an electron transport region ETR, which may be disposed in that order between the first electrode EL1 and the second electrode EL2.

For example, the light emitting element ED-BT included in the display device DD-TD may be a light emitting element having a tandem structure that includes multiple emission layers.

In an embodiment shown in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light in different wavelength ranges, may emit white light.

Charge generating layers CGL1 and CGL2 may each be disposed between two adjacent light emitting structures among the light emitting structures OL-B1, OL-B2, and OL-B3. Charge generating layers CGL1 and CGL2 may each independently include a p-type charge generating layer and/or an n-type charge generating layer.

At least one of the light emitting structures OL-B1, OL-B2, and OL-B3 may each independently include the fused polycyclic compound according to an embodiment. For example, at least one of the emission layers that are included in the light emitting element ED-BT may each independently include the fused polycyclic compound according to an embodiment.

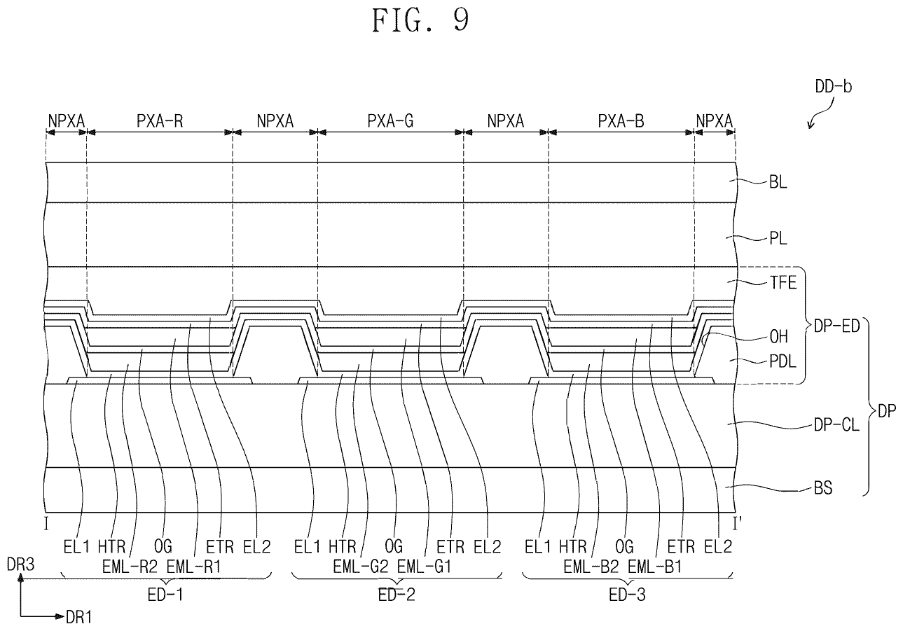

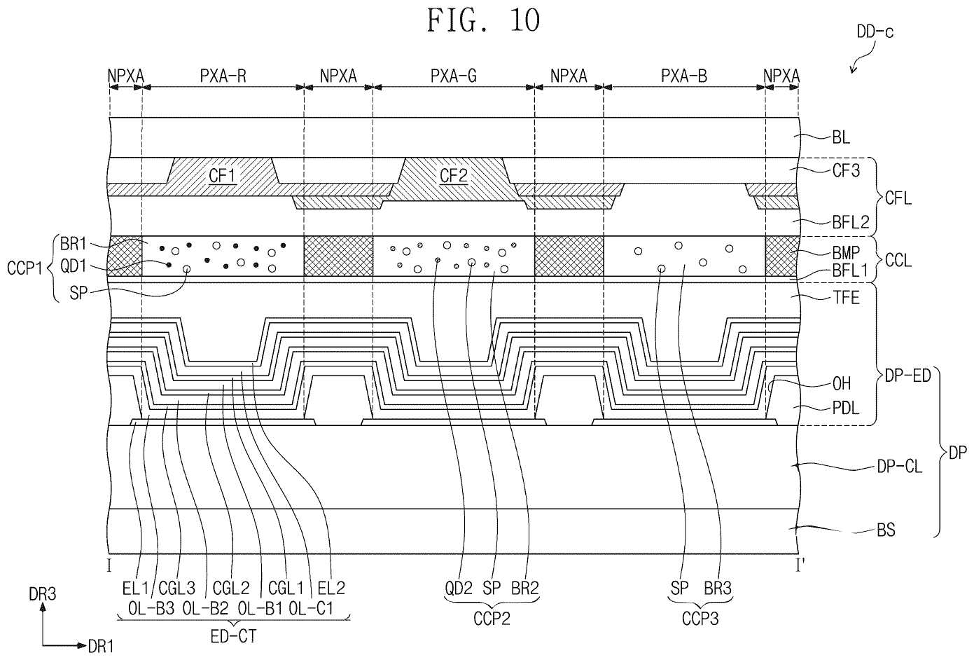

FIG. 9 is a schematic cross-sectional view of a display device according to an embodiment. FIG. 10 is a schematic cross-sectional view of a display device according to an embodiment.

Referring to FIG. 9, a display device DD-b according to an embodiment may include light emitting elements ED-1, ED-2, and ED-3 in which two emission layers are stacked. In comparison to the display device DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength range.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single layer structure or a multilayer structure. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for each of the first to third light emitting elements ED-1, ED-2, and ED-3. However, embodiments are not limited thereto, and the emission auxiliary part OG may be provided by being patterned in the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on the display device layer DP-ED. The optical auxiliary layer PL may include a polarization layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

At least one emission layer included in the display device DD-b shown in FIG. 9 may include the fused polycyclic compound according to an embodiment. For example, in an embodiment, at least one of a first blue emission layer EML-B1 and a second blue emission layer EML-B2 may include the fused polycyclic compound.

In contrast to FIG. 8 and FIG. 9, FIG. 10 shows a display device DD-c that is different at least in that it includes four light emitting structures OL-B1, OL-B2, OL-B3, and OL-C1. A light emitting element ED-CT may include a first electrode EL1 and a second electrode EL2 that are disposed opposite each other, and first to fourth light emitting structures OL-B1, OL-B2, OL-B3, and OL-C1 that are stacked in a thickness direction between the first electrode EL1 and the second electrode EL2. In an embodiment, the third light emitting structure OL-B3, the second light emitting structure OL-B2, the first light emitting structure OL-B1, and the fourth light emitting structure OL-C1 may be stacked in the stated order in a thickness direction.

Charge generating layers CGL1, CGL2, and CGL3 may each be disposed between two adjacent light emitting structures among the first to fourth light emitting structures OL-B1, OL-B2, OL-B3, and OL-C1. For example, a first charge generating layer CGL1 may be disposed between the first light emitting structure OL-B1 and the fourth light emitting structure OL-C1. For example, a second charge generating layer CGL2 may be disposed between the first light emitting structure OL-B1 and the second light emitting structure OL-B2. For example, a third charge generating layer CGL3 may be disposed between the second light emitting structure OL-B2 and the third light emitting structure OL-B3.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength ranges that are different from each other.

The charge generating layers CGL1, CGL2, and CGL3 that are disposed between adjacent light emitting structures among the first to fourth light emitting structures OL-B1, OL-B2, OL-B3, and OL-C1 may each independently include a p-type charge generating layer and/or an n-type charge generating layer.

In the display device DD-c, at least one of the light emitting structures OL-B1, OL-B2, OL-B3, and OL-C1 may each independently include the fused polycyclic compound according to an embodiment. For example, in an embodiment, at least one of the first to third light emitting structures OL-B1, OL-B2, and OL-B3 may each independently include the fused polycyclic compound.

The light emitting element ED according to an embodiment may include the fused polycyclic compound according to an embodiment in at least one functional layer disposed between the first electrode EL1 and the second electrode EL2, thereby exhibiting excellent emission efficiency and improved service life characteristics. For example, the emission layer EML of the light emitting element ED may include the fused polycyclic compound, and the light emitting element ED may exhibit a long service life.

In an embodiment, an electronic apparatus may include a display device that includes multiple light emitting elements and a control part that controls the display device. The electronic apparatus may be an apparatus that is activated by an electrical signal. The electronic apparatus may include display devices according to various embodiments. Examples of an electronic apparatus may include large, medium-sized, and small apparatuses, such as a television, a monitor, a billboard, a personal computer, a laptop computer, a personal digital terminal, a display device for a vehicle, a game console, a portable electronic device, and a camera.

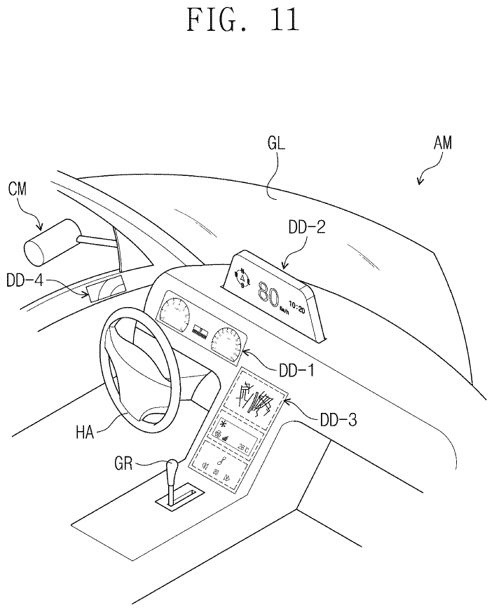

FIG. 11 is a schematic perspective view of a vehicle AM that includes first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c, as explained above with reference to FIGS. 1, 2, and 7 to 10.

In FIG. 11, a vehicle AM is shown as an automobile, but this is only an example, and the first to fourth display devices DD-1, DD-2, DD-3, and DD-4 may be disposed in various transportation means such as a bicycle, a motorcycle, a train, a ship, or an airplane. In an embodiment, at least one of the first to fourth display devices DD-1, DD-2, DD-3, and DD-4, each having a structure according to one of display devices DD, DD-TD, DD-a, DD-b, and DD-c, may be included in a personal computer, a laptop computer, a personal digital terminal, a game console, a portable electronic device, a television, a monitor, a billboard, or the like. However, these are merely listed as examples, and the display device may be included in other electronic apparatuses.

At least one of the first to fourth display devices DD-1, DD-2, DD-3, and DD-4 may each independently include a light emitting element ED according to an embodiment as described with reference to any of FIGS. 3 to 6. The light emitting element ED may include a fused polycyclic compound according to an embodiment. At least one of the first to fourth display devices DD-1, DD-2, DD-3, and DD-4 may each independently include a light emitting element ED that includes the fused polycyclic compound, thereby exhibiting an improved display service life.

Referring to FIG. 11, a vehicle AM may include a steering wheel HA and a gearshift GR for operating the vehicle AM. The vehicle AM may include a front window GL that is disposed so as to face a driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), and an image that represents a fuel gauge. The first scale and the second scale may each be represented by a digital image.

A second display device DD-2 may be disposed in a second region facing a driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed of the vehicle AM and may further include information such as the current time. Although not shown in the drawings, in an embodiment, the second information of the second display device DD-2 may be displayed by being projected onto the front window GL.

A third display device DD-3 may be disposed in a third region that is adjacent to the gearshift GR. For example, the third display device DD-3 may be disposed between the driver's seat and a passenger seat, and may be a center information display (CID) for the vehicle AM that displays third information. The passenger seat may be a seat that is spaced apart from the driver's seat, and the gearshift GR may be disposed the driver's seat and the passenger seat. The third information may include information about traffic or road conditions (for example, navigation information), information about music or radio that is playing, a dynamic image (or video) this is being displayed, information about the temperature in the vehicle AM, or the like.

A fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image that is exterior to the vehicle AM, which may be taken by a camera module CM disposed at an exterior of the vehicle AM. The fourth information may include an exterior image of the vehicle AM.

The first to fourth information as described above are only provided as examples, and the first to fourth display devices DD-1, DD-2, DD-3, and DD-4 may further display information about the interior and exterior of the vehicle AM. The first to fourth information may include information that is different from each other. However, embodiments are not limited thereto, and a portion of the first to fourth information may include a same information.

Hereinafter, a fused polycyclic compound according to an embodiment and a light emitting element according to an embodiment will be explained with reference to the Examples and the Comparative Examples. The Examples described below are only provided to assist in understanding the disclosure, and the scope thereof is not limited thereto.

### Examples

### 1. Synthesis of Fused Polycyclic Compound

A synthesis method of a fused polycyclic compound according to an embodiment will be explained in detail by illustrating synthesis methods for Compounds 5, 23, 36, 49, 63, 100, 165, and 240. The synthesis methods for the fused polycyclic compounds explained below are only provided as examples, and the synthesis methods of the fused polycyclic compound according to an embodiment are not limited to the Examples below.

### (1) Synthesis of Compound 5

Compound 5 according to an embodiment may be synthesized, for example, by the reaction below.

### Synthesis of Intermediate 5-1

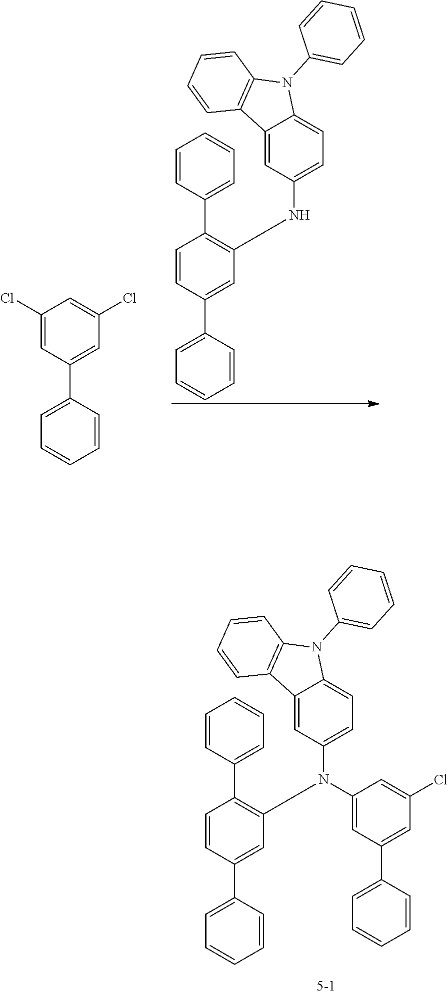 [SMILES: Clc1cc(Cl)cc(-c2ccccc2)c1 ; c1ccc(-c2ccc(-c3ccccc3)c(Nc3ccc4c(c3)c3ccccc3n4-c3ccccc3)c2)cc1 ; Clc1cc(-c2ccccc2)cc(N(c2ccc3c(c2)c2ccccc2n3-c2ccccc2)c2cc(-c3ccccc3)ccc2-c2ccccc2)c1]

After dissolving 3,5-dichloro-1,1′-biphenyl (1 eq), N-([1,1′:4′,1″-terphenyl]-2′-yl)-9-phenyl-9H-carbazol-3-amine (0.8 eq), tris(dibenzylideneacetone)dipalladium(0) (0.05 eq), 2,2′-bis(diphenylphosphino)-1,1′-binaphthyl (BINAP) (0.1 eq), and sodium tert-butoxide (3 eq) in toluene, stirring was performed at about 90 degrees centigrade for about 12 hours. After cooling, the resultant was washed with ethyl acetate and water three times, and an organic layer obtained by layer separation was dried over MgSO₄ and dried under a reduced pressure. Through purification by column chromatography using methylene chloride (MC) and n-hexane, Intermediate 5-1 was obtained (yield: 74%).

### Synthesis of Intermediate 5-2

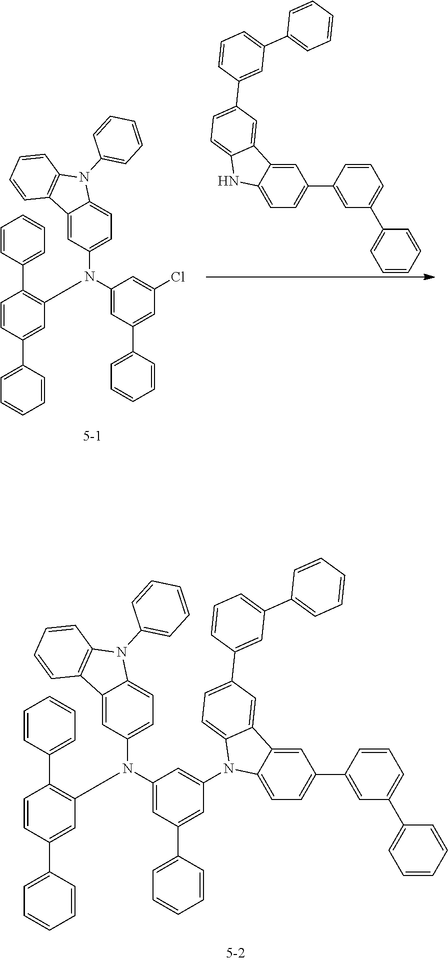 [SMILES: Clc1cc(-c2ccccc2)cc(N(c2ccc3c(c2)c2ccccc2n3-c2ccccc2)c2cc(-c3ccccc3)ccc2-c2ccccc2)c1 ; c1ccc(-c2cccc(-c3ccc4[nH]c5ccc(-c6cccc(-c7ccccc7)c6)cc5c4c3)c2)cc1 ; c1ccc(-c2cccc(-c3ccc4c(c3)c3cc(-c5cccc(-c6ccccc6)c5)ccc3n4-c3cc(-c4ccccc4)cc(N(c4ccc5c(c4)c4ccccc4n5-c4ccccc4)c4cc(-c5ccccc5)ccc4-c4ccccc4)c3)c2)cc1]

After dissolving Intermediate 5-1 (1 eq), 3,6-di([1,1′-biphenyl]-3-yl)-9H-carbazole (1 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 5-2 was obtained (yield: 82%).

### Synthesis of Compound 5

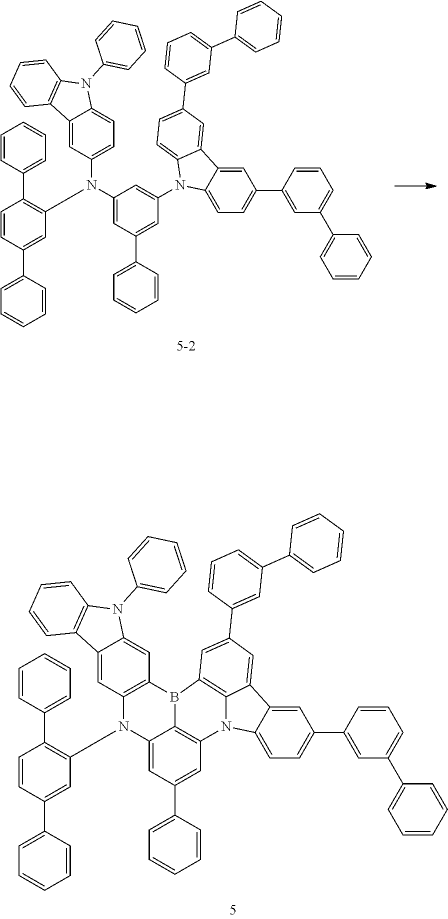 [SMILES: c1ccc(-c2cccc(-c3ccc4c(c3)c3cc(-c5cccc(-c6ccccc6)c5)ccc3n4-c3cc(-c4ccccc4)cc(N(c4ccc5c(c4)c4ccccc4n5-c4ccccc4)c4cc(-c5ccccc5)ccc4-c4ccccc4)c3)c2)cc1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3cc(-c4ccccc4)ccc3-c3ccccc3)c3ccccc3n5-c3ccccc3)c2)cc1]

After dissolving Intermediate 5-2 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 5 (yield: 13%).

### (2) Synthesis of Compound 23

Compound 23 according to an embodiment may be synthesized, for example, by the reaction below.

### Synthesis of Intermediate 23-1

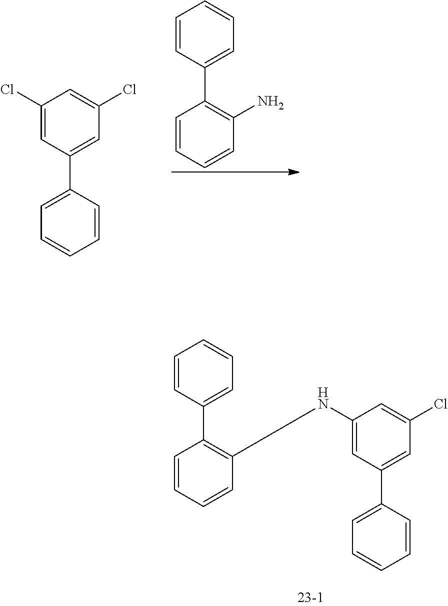 [SMILES: Clc1cc(Cl)cc(-c2ccccc2)c1 ; Nc1ccccc1-c1ccccc1 ; Clc1cc(Nc2ccccc2-c2ccccc2)cc(-c2ccccc2)c1]

After dissolving 3,5-dichloro-1,1′-biphenyl (1 eq), [1,1′-biphenyl]-2-amine (0.8 eq), tris(dibenzylideneacetone)dipalladium(0) (0.05 eq), BINAP (0.1 eq), and sodium tert-butoxide (3 eq) in toluene, stirring was performed at about 90 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 23-1 was obtained (yield: 72%).

### Synthesis of Intermediate 23-2

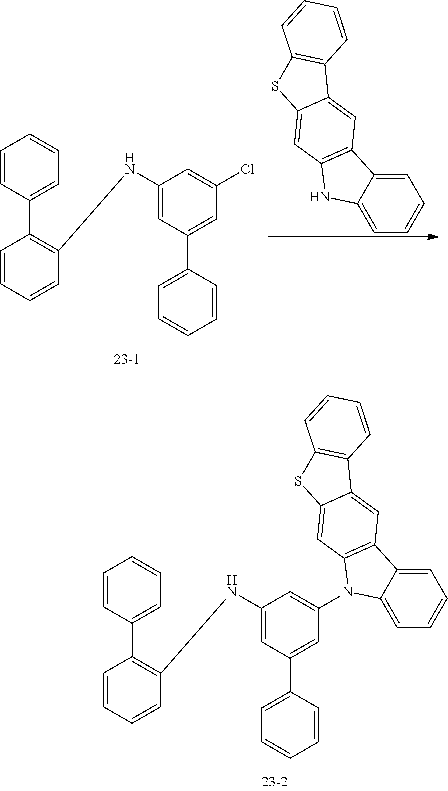 [SMILES: Clc1cc(Nc2ccccc2-c2ccccc2)cc(-c2ccccc2)c1 ; c1ccc2c(c1)[nH]c1cc3sc4ccccc4c3cc12 ; c1ccc(-c2cc(Nc3ccccc3-c3ccccc3)cc(-n3c4ccccc4c4cc5c(cc43)sc3ccccc35)c2)cc1]

After dissolving Intermediate 23-1 (1 eq), 7H-benzo[4,5]thieno[2,3-b]carbazole (1.1 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 23-2 was obtained (yield: 63%).

### Synthesis of Intermediate 23-3

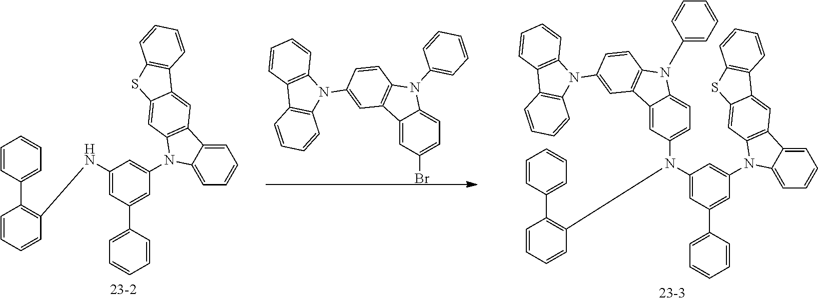 [SMILES: c1ccc(-c2cc(Nc3ccccc3-c3ccccc3)cc(-n3c4ccccc4c4cc5c(cc43)sc3ccccc35)c2)cc1 ; Brc1ccc2c(c1)c1cc(-n3c4ccccc4c4ccccc43)ccc1n2-c1ccccc1 ; c1ccc(-c2cc(N(c3ccc4c(c3)c3cc(-n5c6ccccc6c6ccccc65)ccc3n4-c3ccccc3)c3ccccc3-c3ccccc3)cc(-n3c4ccccc4c4cc5c(cc43)sc3ccccc35)c2)cc1]

After dissolving Intermediate 23-2 (1 eq), 6-bromo-9-phenyl-9H-3,9′-bicarbazole (1.3 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 23-3 was obtained (yield: 66%).

### Synthesis of Compound 23

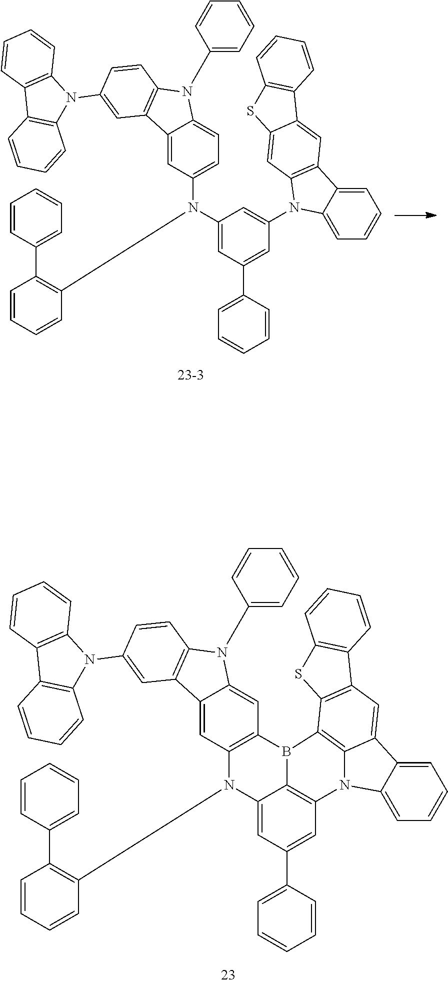 [SMILES: c1ccc(-c2cc(N(c3ccc4c(c3)c3cc(-n5c6ccccc6c6ccccc65)ccc3n4-c3ccccc3)c3ccccc3-c3ccccc3)cc(-n3c4ccccc4c4cc5c(cc43)sc3ccccc35)c2)cc1 ; c1ccc(-c2cc3c4c(c2)-n2c5ccccc5c5cc6c(sc7ccccc76)c(c52)B4c2cc4c(cc2N3c2ccccc2-c2ccccc2)c2cc(-n3c5ccccc5c5ccccc53)ccc2n4-c2ccccc2)cc1]

After dissolving Intermediate 23-3 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 23 (yield: 12%).

### (3) Synthesis of Compound 36

Compound 36 according to an embodiment may be synthesized, for example, by the reaction below.

### Synthesis of Intermediate 36-1

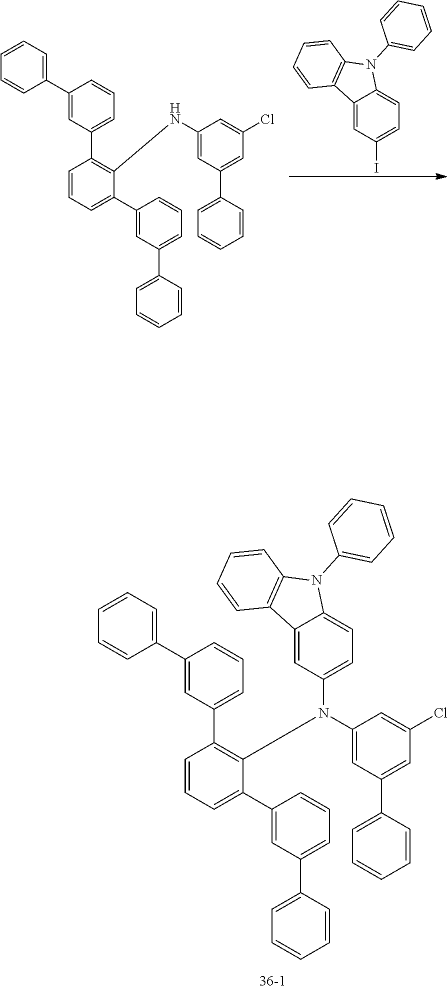 [SMILES: Clc1cc(Nc2c(-c3cccc(-c4ccccc4)c3)cccc2-c2cccc(-c3ccccc3)c2)cc(-c2ccccc2)c1 ; Ic1ccc2c(c1)c1ccccc1n2-c1ccccc1 ; Clc1cc(-c2ccccc2)cc(N(c2ccc3c(c2)c2ccccc2n3-c2ccccc2)c2c(-c3cccc(-c4ccccc4)c3)cccc2-c2cccc(-c3ccccc3)c2)c1]

After dissolving N-(5-chloro-[1,1′-biphenyl]-3-yl)-[1,1′:3′,1″:3″,1′″:3′″,1″″-quinquephenyl]-2″-amine (1 eq), 3-iodo-9-phenyl-9H-carbazole (3 eq), tris(dibenzylideneacetone)dipalladium(0) (0.15 eq), tri-tert-butylphosphine (0.3 eq), and sodium tert-butoxide (5 eq) in o-xylene, stirring was performed at about 150 degrees centigrade for about 48 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 36-1 was obtained (yield: 37%).

### Synthesis of Intermediate 36-2

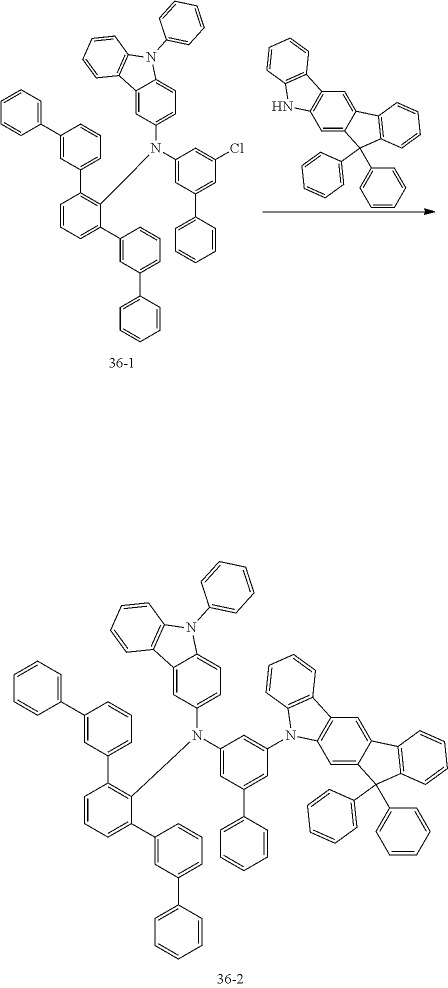 [SMILES: Clc1cc(-c2ccccc2)cc(N(c2ccc3c(c2)c2ccccc2n3-c2ccccc2)c2c(-c3cccc(-c4ccccc4)c3)cccc2-c2cccc(-c3ccccc3)c2)c1 ; c1ccc(C2(c3ccccc3)c3ccccc3-c3cc4c(cc32)[nH]c2ccccc24)cc1 ; c1ccc(-c2cccc(-c3cccc(-c4cccc(-c5ccccc5)c4)c3N(c3cc(-c4ccccc4)cc(-n4c5ccccc5c5cc6c(cc54)C(c4ccccc4)(c4ccccc4)c4ccccc4-6)c3)c3ccc4c(c3)c3ccccc3n4-c3ccccc3)c2)cc1]

After dissolving Intermediate 36-1 (1 eq), 7,7-diphenyl-5,7-dihydroindeno[2,1-b]carbazole (1.2 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 36-2 was obtained (yield: 77%).

### Synthesis of Compound 36

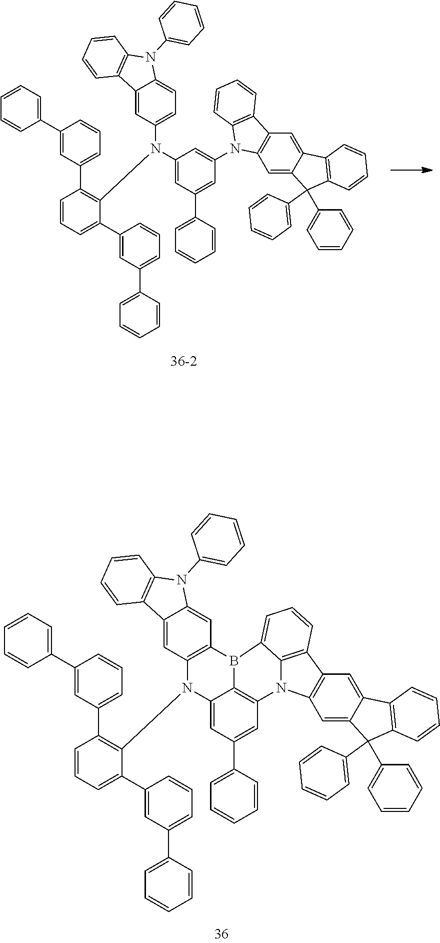 [SMILES: c1ccc(-c2cccc(-c3cccc(-c4cccc(-c5ccccc5)c4)c3N(c3cc(-c4ccccc4)cc(-n4c5ccccc5c5cc6c(cc54)C(c4ccccc4)(c4ccccc4)c4ccccc4-6)c3)c3ccc4c(c3)c3ccccc3n4-c3ccccc3)c2)cc1 ; c1ccc(-c2cccc(-c3cccc(-c4cccc(-c5ccccc5)c4)c3N3c4cc5c6ccccc6n(-c6ccccc6)c5cc4B4c5c3cc(-c3ccccc3)cc5-n3c5cc6c(cc5c5cccc4c53)-c3ccccc3C6(c3ccccc3)c3ccccc3)c2)cc1]

After dissolving Intermediate 36-2 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 36 (yield: 15%).

### (4) Synthesis of Compound 49

Compound 49 according to an embodiment may be synthesized, for example, by the reaction below.

### Synthesis of Intermediate 49-1

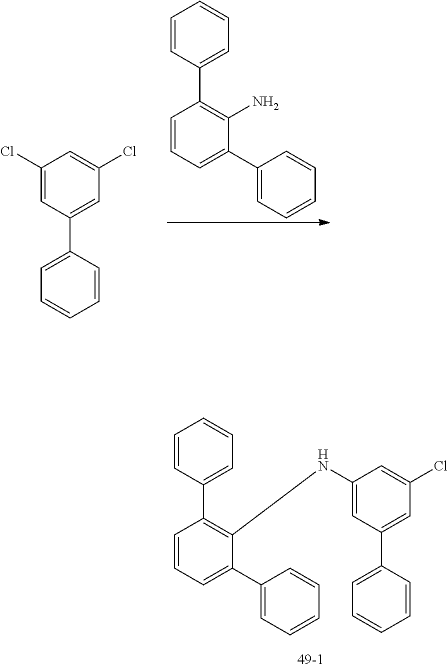

After dissolving 3,5-dichloro-1,1′-biphenyl (1 eq), [1,1′:3′,1″-terphenyl]-2′-amine (0.8 eq), tris(dibenzylideneacetone)dipalladium(0) (0.05 eq), BINAP (0.1 eq), and sodium tert-butoxide (3 eq) in toluene, stirring was performed at about 90 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 49-1 was obtained (yield: 70%).

### Synthesis of Intermediate 49-2

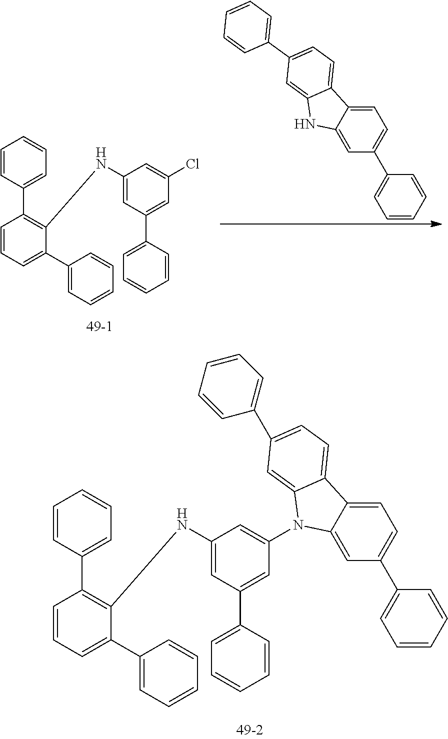 [SMILES: Clc1cc(Nc2c(-c3ccccc3)cccc2-c2ccccc2)cc(-c2ccccc2)c1 ; c1ccc(-c2ccc3c(c2)[nH]c2cc(-c4ccccc4)ccc23)cc1 ; c1ccc(-c2cc(Nc3c(-c4ccccc4)cccc3-c3ccccc3)cc(-n3c4cc(-c5ccccc5)ccc4c4ccc(-c5ccccc5)cc43)c2)cc1]

After dissolving Intermediate 49-1 (1 eq), 2,7-diphenyl-9H-carbazole (1 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 49-2 was obtained (yield: 61%).

### Synthesis of Intermediate 49-3

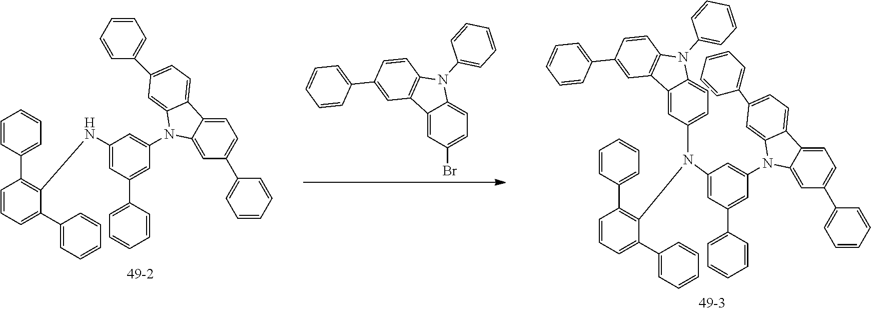 [SMILES: c1ccc(-c2cc(Nc3c(-c4ccccc4)cccc3-c3ccccc3)cc(-n3c4cc(-c5ccccc5)ccc4c4ccc(-c5ccccc5)cc43)c2)cc1 ; Brc1ccc2c(c1)c1cc(-c3ccccc3)ccc1n2-c1ccccc1 ; c1ccc(-c2cc(N(c3ccc4c(c3)c3cc(-c5ccccc5)ccc3n4-c3ccccc3)c3c(-c4ccccc4)cccc3-c3ccccc3)cc(-n3c4cc(-c5ccccc5)ccc4c4ccc(-c5ccccc5)cc43)c2)cc1]

After dissolving Intermediate 49-2 (1 eq), 3-bromo-6,9-diphenyl-9H-carbazole (2.2 eq), tris(dibenzylideneacetone)dipalladium(0) (0.15 eq), tri-tert-butylphosphine (0.3 eq), and sodium tert-butoxide (5 eq) in o-xylene, stirring was performed at about 150 degrees centigrade for about 48 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 49-3 was obtained (yield: 36%).

### Synthesis of Compound 49

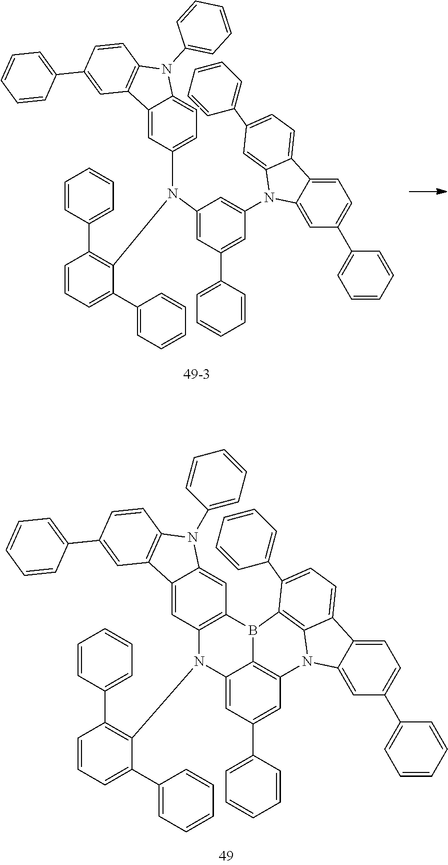 [SMILES: c1ccc(-c2cc(N(c3ccc4c(c3)c3cc(-c5ccccc5)ccc3n4-c3ccccc3)c3c(-c4ccccc4)cccc3-c3ccccc3)cc(-n3c4cc(-c5ccccc5)ccc4c4ccc(-c5ccccc5)cc43)c2)cc1 ; c1ccc(-c2cc3c4c(c2)-n2c5cc(-c6ccccc6)ccc5c5ccc(-c6ccccc6)c(c52)B4c2cc4c(cc2N3c2c(-c3ccccc3)cccc2-c2ccccc2)c2cc(-c3ccccc3)ccc2n4-c2ccccc2)cc1]

After dissolving Intermediate 49-3 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 49 (yield: 9%).

### (5) Synthesis of Compound 63

Compound 63 according to an embodiment may be synthesized, for example, by the reaction below.

### Synthesis of Intermediate 63-1

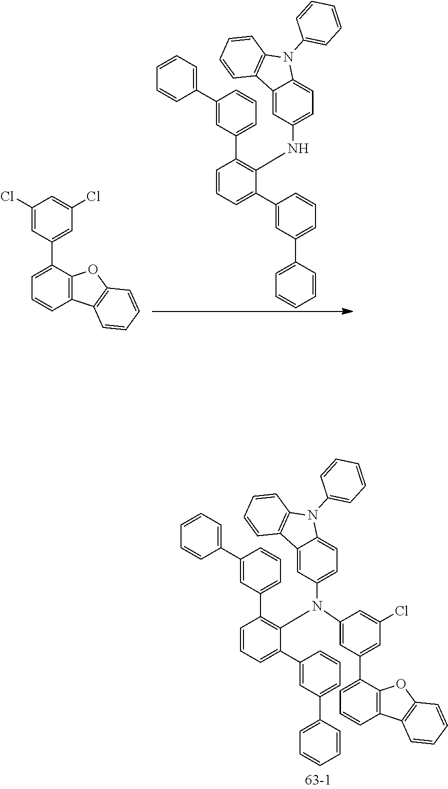 [SMILES: Clc1cc(Cl)cc(-c2cccc3c2oc2ccccc23)c1 ; c1ccc(-c2cccc(-c3cccc(-c4cccc(-c5ccccc5)c4)c3Nc3ccc4c(c3)c3ccccc3n4-c3ccccc3)c2)cc1 ; Clc1cc(-c2cccc3c2oc2ccccc23)cc(N(c2ccc3c(c2)c2ccccc2n3-c2ccccc2)c2c(-c3cccc(-c4ccccc4)c3)cccc2-c2cccc(-c3ccccc3)c2)c1]

After dissolving 4-(3,5-dichlorophenyl)dibenzo[b,d]furan (1 eq), N-([1,1′:3′,1″:3″,1′″:3′″,1″″-quinquephenyl]-2″-yl)-9-phenyl-9H-carbazol-3-amine (0.8 eq), tris(dibenzylideneacetone)dipalladium(0) (0.05 eq), BINAP (0.1 eq), and sodium tert-butoxide (3 eq) in toluene, stirring was performed at about 90 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 63-1 was obtained (yield: 42%).

### Synthesis of Intermediate 63-2

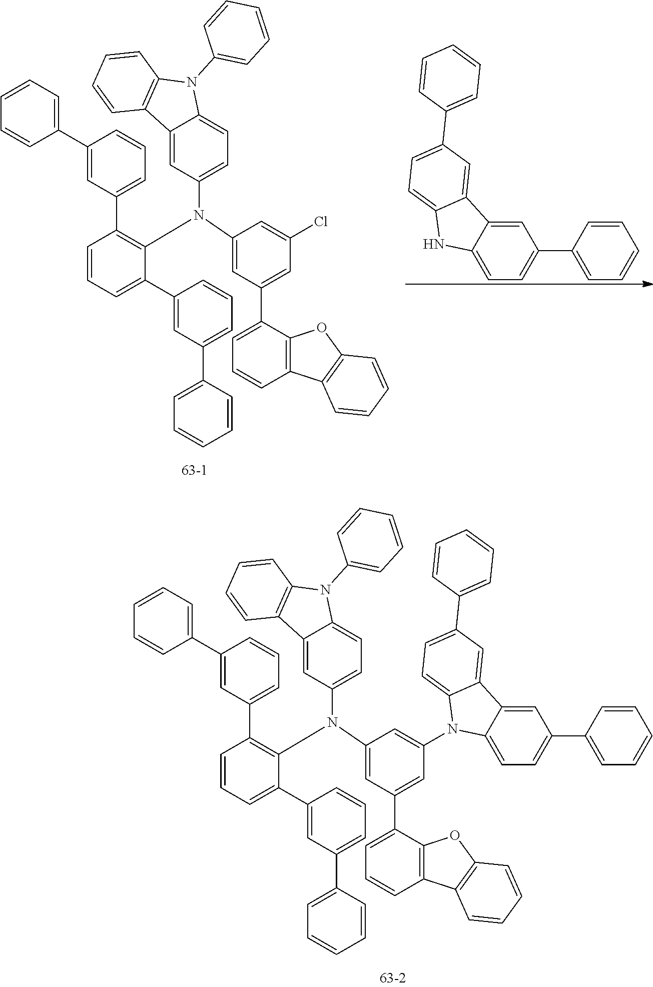 [SMILES: Clc1cc(-c2cccc3c2oc2ccccc23)cc(N(c2ccc3c(c2)c2ccccc2n3-c2ccccc2)c2c(-c3cccc(-c4ccccc4)c3)cccc2-c2cccc(-c3ccccc3)c2)c1 ; c1ccc(-c2ccc3[nH]c4ccc(-c5ccccc5)cc4c3c2)cc1 ; c1ccc(-c2cccc(-c3cccc(-c4cccc(-c5ccccc5)c4)c3N(c3cc(-c4cccc5c4oc4ccccc45)cc(-n4c5ccc(-c6ccccc6)cc5c5cc(-c6ccccc6)ccc54)c3)c3ccc4c(c3)c3ccccc3n4-c3ccccc3)c2)cc1]

After dissolving Intermediate 63-1 (1 eq), 3,6-diphenyl-9H-carbazole (1 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 63-2 was obtained (yield: 75%).

### Synthesis of Compound 63

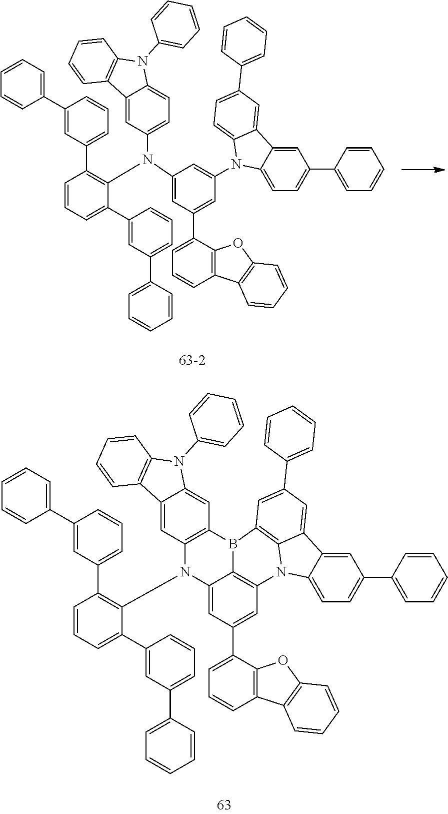 [SMILES: c1ccc(-c2cccc(-c3cccc(-c4cccc(-c5ccccc5)c4)c3N(c3cc(-c4cccc5c4oc4ccccc45)cc(-n4c5ccc(-c6ccccc6)cc5c5cc(-c6ccccc6)ccc54)c3)c3ccc4c(c3)c3ccccc3n4-c3ccccc3)c2)cc1 ; c1ccc(-c2cccc(-c3cccc(-c4cccc(-c5ccccc5)c4)c3N3c4cc5c6ccccc6n(-c6ccccc6)c5cc4B4c5c3cc(-c3cccc6c3oc3ccccc36)cc5-n3c5ccc(-c6ccccc6)cc5c5cc(-c6ccccc6)cc4c53)c2)cc1]

After dissolving Intermediate 63-2 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 63 (yield: 14%).

### (6) Synthesis of Compound 100

Compound 100 according to an embodiment may be synthesized, for example, by the reaction below.

### Synthesis of Intermediate 100-1

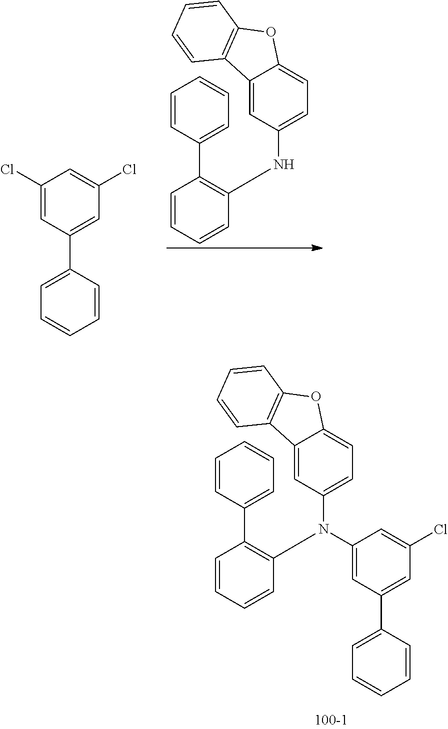 [SMILES: Clc1cc(Cl)cc(-c2ccccc2)c1 ; c1ccc(-c2ccccc2Nc2ccc3oc4ccccc4c3c2)cc1 ; Clc1cc(-c2ccccc2)cc(N(c2ccc3oc4ccccc4c3c2)c2ccccc2-c2ccccc2)c1]

After dissolving 3,5-dichloro-1,1′-biphenyl (1 eq), N-([1,1′-biphenyl]-2-yl)dibenzo[b,d]furan-2-amine (0.9 eq), tris(dibenzylideneacetone)dipalladium(0) (0.05 eq), tri-tert-butylphosphine (0.1 eq), and sodium tert-butoxide (3 eq) in toluene, stirring was performed at about 90 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 100-1 was obtained (yield: 61%).

### Synthesis of Intermediate 100-2

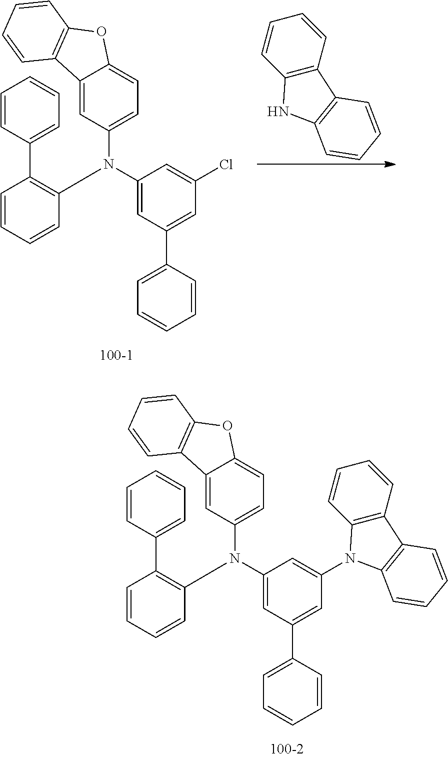 [SMILES: Clc1cc(-c2ccccc2)cc(N(c2ccc3oc4ccccc4c3c2)c2ccccc2-c2ccccc2)c1 ; c1ccc2c(c1)[nH]c1ccccc12 ; c1ccc(-c2cc(N(c3ccc4oc5ccccc5c4c3)c3ccccc3-c3ccccc3)cc(-n3c4ccccc4c4ccccc43)c2)cc1]

After dissolving Intermediate 100-1 (1 eq), 9H-carbazole (1 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 100-2 was obtained (yield: 84%).

### Synthesis of Compound 100

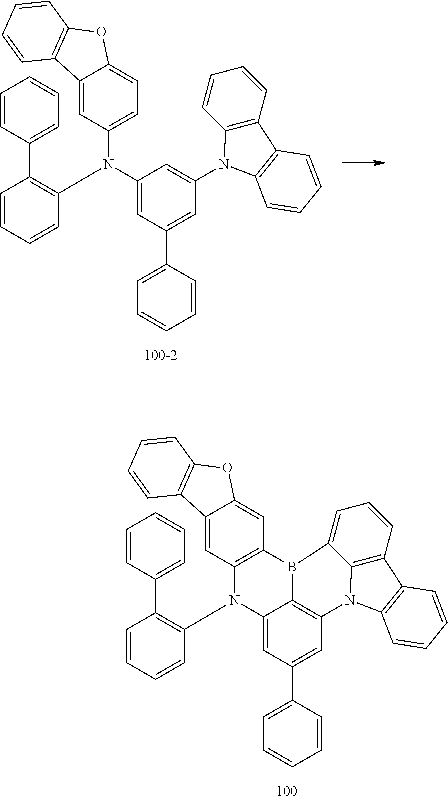 [SMILES: c1ccc(-c2cc(N(c3ccc4oc5ccccc5c4c3)c3ccccc3-c3ccccc3)cc(-n3c4ccccc4c4ccccc43)c2)cc1 ; c1ccc(-c2cc3c4c(c2)-n2c5ccccc5c5cccc(c52)B4c2cc4oc5ccccc5c4cc2N3c2ccccc2-c2ccccc2)cc1]

After dissolving Intermediate 100-2 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 100 (yield: 15%).

### (7) Synthesis of Compound 165

Compound 165 according to an embodiment may be synthesized, for example, by the reaction below.

### Synthesis of Intermediate 165-1

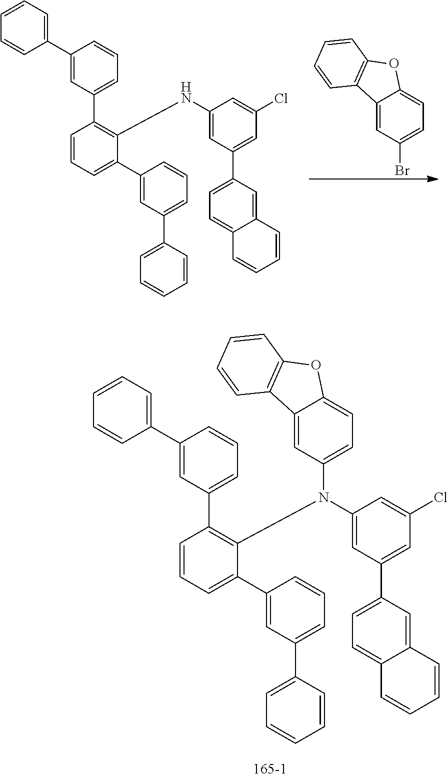 [SMILES: Clc1cc(Nc2c(-c3cccc(-c4ccccc4)c3)cccc2-c2cccc(-c3ccccc3)c2)cc(-c2ccc3ccccc3c2)c1 ; Brc1ccc2oc3ccccc3c2c1 ; Clc1cc(-c2ccc3ccccc3c2)cc(N(c2ccc3oc4ccccc4c3c2)c2c(-c3cccc(-c4ccccc4)c3)cccc2-c2cccc(-c3ccccc3)c2)c1]

After dissolving N-(3-chloro-5-(naphthalen-2-yl)phenyl)-[1,1′:3′,1″:3″,1′″:3′″,1″″-quinquephenyl]-2″-amine (1 eq), 2-bromodibenzo[b,d]furan (3 eq), tris(dibenzylideneacetone)dipalladium(0) (0.15 eq), tri-tert-butylphosphine (0.3 eq), and sodium tert-butoxide (5 eq) in o-xylene, stirring was performed at about 150 degrees centigrade for about 48 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 165-1 was obtained (yield: 43%).

### Synthesis of Intermediate 165-2

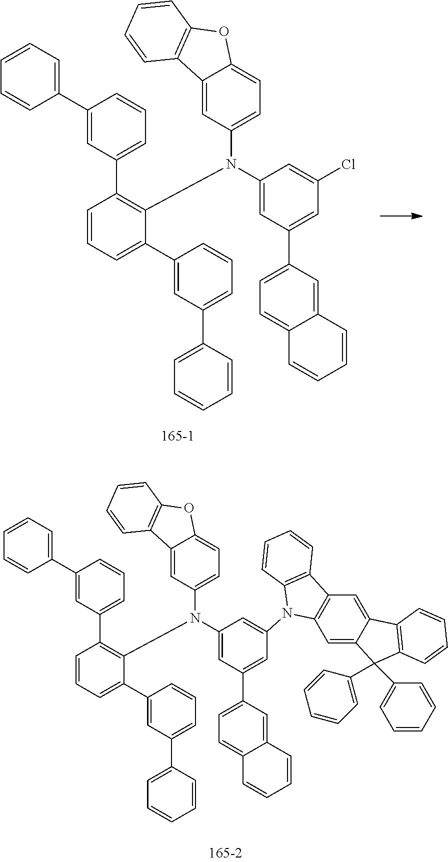 [SMILES: Clc1cc(-c2ccc3ccccc3c2)cc(N(c2ccc3oc4ccccc4c3c2)c2c(-c3cccc(-c4ccccc4)c3)cccc2-c2cccc(-c3ccccc3)c2)c1 ; c1ccc(-c2cccc(-c3cccc(-c4cccc(-c5ccccc5)c4)c3N(c3cc(-c4ccc5ccccc5c4)cc(-n4c5ccccc5c5cc6c(cc54)C(c4ccccc4)(c4ccccc4)c4ccccc4-6)c3)c3ccc4oc5ccccc5c4c3)c2)cc1]

After dissolving Intermediate 165-1 (1 eq), 7,7-diphenyl-5,7-dihydroindeno[2,1-b]carbazole (1.1 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 165-2 was obtained (yield: 72%).

### Synthesis of Compound 165

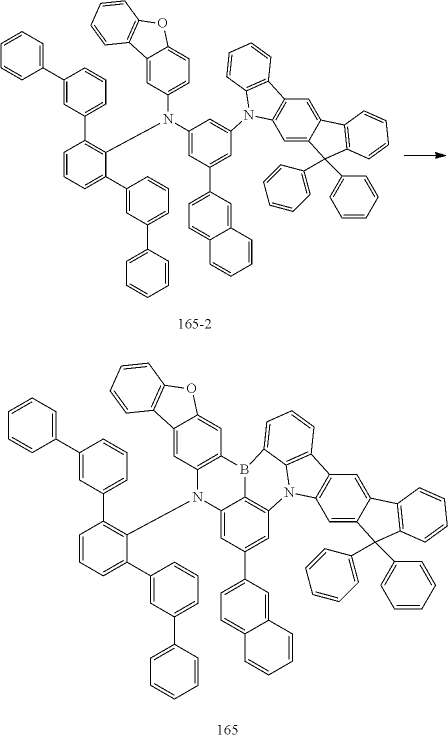 [SMILES: c1ccc(-c2cccc(-c3cccc(-c4cccc(-c5ccccc5)c4)c3N(c3cc(-c4ccc5ccccc5c4)cc(-n4c5ccccc5c5cc6c(cc54)C(c4ccccc4)(c4ccccc4)c4ccccc4-6)c3)c3ccc4oc5ccccc5c4c3)c2)cc1 ; c1ccc(-c2cccc(-c3cccc(-c4cccc(-c5ccccc5)c4)c3N3c4cc5c(cc4B4c6c3cc(-c3ccc7ccccc7c3)cc6-n3c6cc7c(cc6c6cccc4c63)-c3ccccc3C7(c3ccccc3)c3ccccc3)oc3ccccc35)c2)cc1]

After dissolving Intermediate 165-2 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 165 (yield: 15%).

### (8) Synthesis of Compound 240

Compound 240 according to an embodiment may be synthesized, for example, by the reaction below.

### Synthesis of Intermediate 240-1

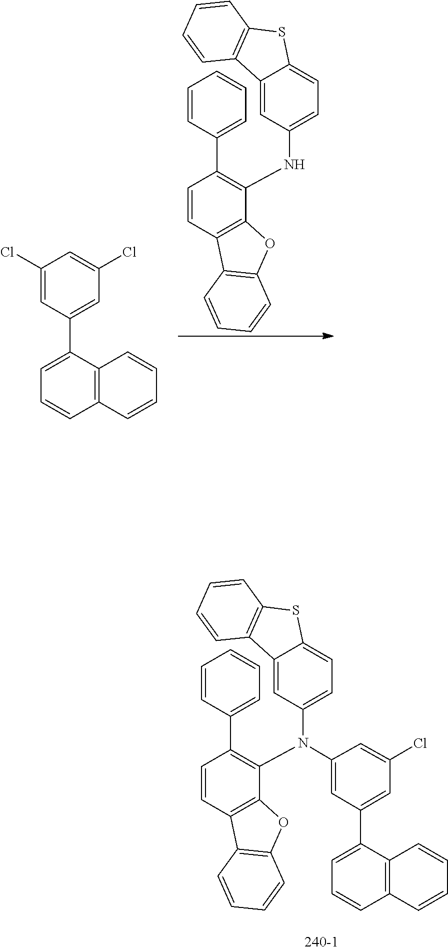 [SMILES: Clc1cc(Cl)cc(-c2cccc3ccccc23)c1 ; c1ccc(-c2ccc3c(oc4ccccc43)c2Nc2ccc3sc4ccccc4c3c2)cc1 ; Clc1cc(-c2cccc3ccccc23)cc(N(c2ccc3sc4ccccc4c3c2)c2c(-c3ccccc3)ccc3c2oc2ccccc23)c1]

After dissolving 1-(3,5-dichlorophenyl)naphthalene (1 eq), N-(dibenzo[b,d]thiophen-2-yl)-3-phenyldibenzo[b,d]furan-4-amine (0.8 eq), tris(dibenzylideneacetone)dipalladium(0) (0.05 eq), BINAP (0.1 eq), and sodium tert-butoxide (3 eq) in toluene, stirring was performed at about 90 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 240-1 was obtained (yield: 66%).

### Synthesis of Intermediate 240-2

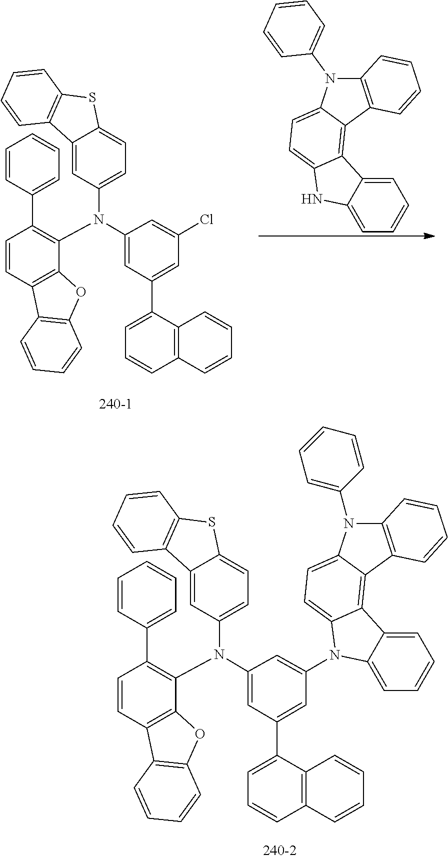 [SMILES: Clc1cc(-c2cccc3ccccc23)cc(N(c2ccc3sc4ccccc4c3c2)c2c(-c3ccccc3)ccc3c2oc2ccccc23)c1 ; c1ccc(-n2c3ccccc3c3c4c(ccc32)[nH]c2ccccc24)cc1 ; c1ccc(-c2ccc3c(oc4ccccc43)c2N(c2cc(-c3cccc4ccccc34)cc(-n3c4ccccc4c4c5c6ccccc6n(-c6ccccc6)c5ccc43)c2)c2ccc3sc4ccccc4c3c2)cc1]

After dissolving Intermediate 240-1 (1 eq), 5-phenyl-5,8-dihydroindolo[2,3-c]carbazole (1.2 eq), tris(dibenzylideneacetone)dipalladium(0) (0.05 eq), tri-tert-butylphosphine (0.1 eq), and sodium tert-butoxide (3 eq) in toluene, stirring was performed at about 110 degrees centigrade for about 12 hours. After cooling, the resultant was washed with ethyl acetate and water three times, and an organic layer obtained by layer separation was dried over MgSO₄ and dried under a reduced pressure. Through purification by column chromatography using MC and n-hexane, Intermediate 240-2 was obtained (yield: 60%).

### Synthesis of Compound 240

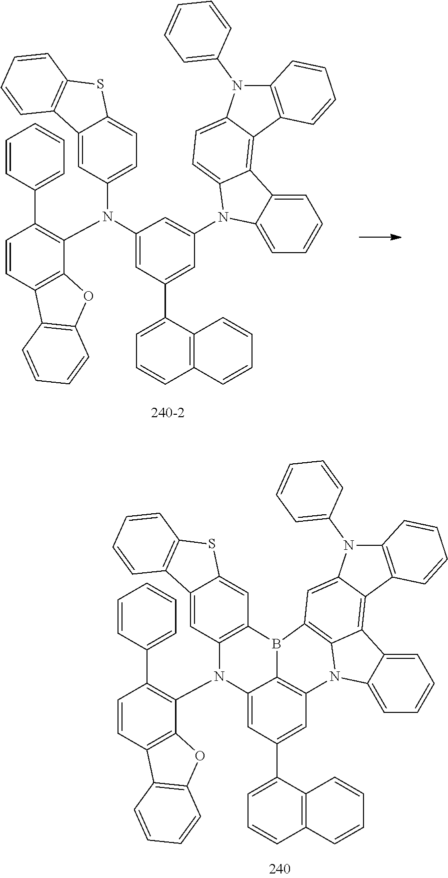 [SMILES: c1ccc(-c2ccc3c(oc4ccccc43)c2N(c2cc(-c3cccc4ccccc34)cc(-n3c4ccccc4c4c5c6ccccc6n(-c6ccccc6)c5ccc43)c2)c2ccc3sc4ccccc4c3c2)cc1 ; c1ccc(-c2ccc3c(oc4ccccc43)c2N2c3cc4c(cc3B3c5c2cc(-c2cccc6ccccc26)cc5-n2c5ccccc5c5c6c7ccccc7n(-c7ccccc7)c6cc3c52)sc2ccccc24)cc1]

After dissolving Intermediate 240-2 (1 eq) in o-dichlorobenzene, the temperature was reduced to about 0 degrees centigrade, and BBr₃ (3 eq) was slowly injected thereto under a nitrogen atmosphere. After finishing the dropwise addition, the temperature was raised to about 180 degrees centigrade, followed by stirring for about 24 hours. After cooling, triethylamine was slowly added dropwise to a flask containing the reaction product to quench the reaction, and ethyl alcohol was added to the reaction product to precipitate. The precipitate was filtered to obtain a crude product. The solid content thus obtained was purified by column chromatography using MC and n-hexane, and recrystallized using toluene and acetone to obtain Compound 240 (yield: 8%).

### 2. Manufacture and Evaluation of Light Emitting Element

The light emitting element according to an embodiment, including the fused polycyclic compound according to an embodiment in an emission layer, was manufactured by a method below. Light emitting elements of Example 1 to Example 8 were manufactured using Compounds 5, 23, 36, 49, 63, 100, 165, and 240, respectively, as the dopant materials of an emission layer. Comparative Examples 1 to 5 respectively correspond to light emitting elements manufactured using Comparative Compounds C1 to C5 as the dopant materials of an emission layer.

### Example Compounds

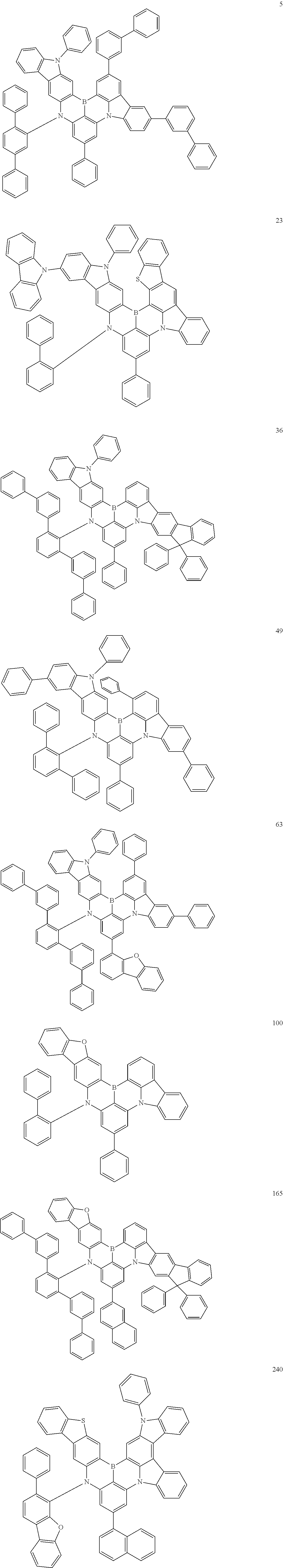

### [Comparative Compounds]

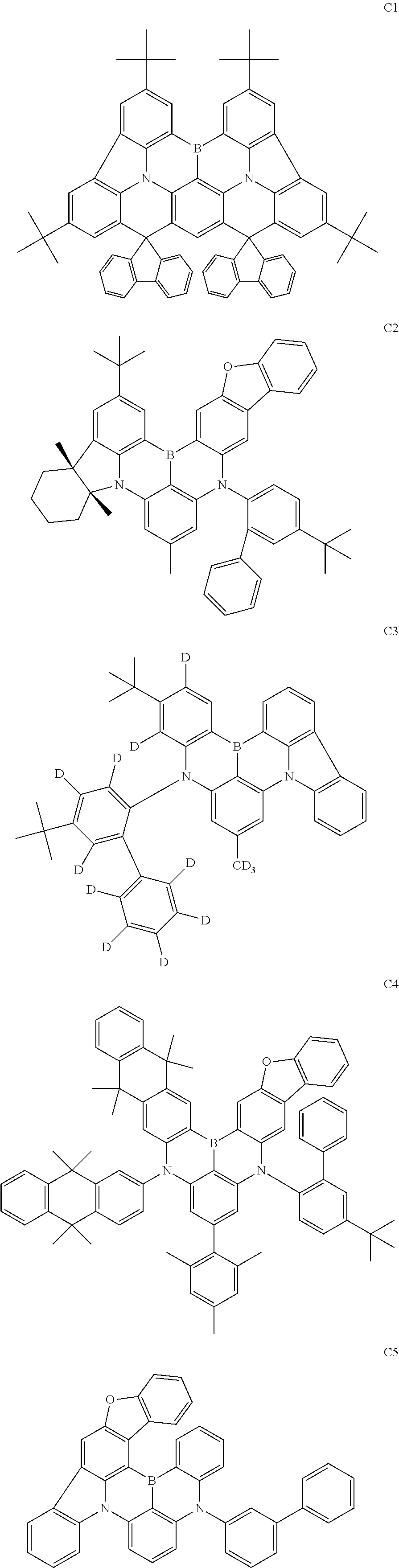

### (Manufacture of Light Emitting Element)

For the manufacture of the light emitting elements of the Examples and Comparative Examples, a glass substrate on which an ITO electrode of about 15 Ω/cm² (1200 Å) was formed (a product of Corning Co.) was cut to a size of about 50 mm×50 mm×0.7 mm, cleansed with ultrasonic waves using isopropyl alcohol and pure water for about 5 minutes each, exposed to ultraviolet light for about 30 minutes, cleansed by exposure to ozone to form an anode, and the anode was installed in a vacuum evaporation apparatus.

On the anode, Compound H-1-1 was deposited to form a hole transport layer with a thickness of about 600 Å, and Compound H-1-20 was deposited on the hole injection layer to form an electron blocking layer with a thickness of about 100 Å.

A mixed host obtained by mixing a second compound and a third compound according to an embodiment at a ratio of about 1:1, the fourth compound, and an Example Compound or a Comparative Compound were co-deposited at a weight ratio of about 85:14:1 to form an emission layer with a thickness of about 300 Å. On the emission layer, Compound ET37 was deposited to form a hole blocking layer with a thickness of about 50 Å. On the hole blocking layer, a mixture of ET38 and LiQ in about 5:5 was deposited to form an electron transport layer with a thickness of about 300 Å. On the electron transport layer, LiQ was deposited to form an electron injection layer with a thickness of about 10 Å. Al was deposited on the electron injection layer to form a second electrode with a thickness of about 1,000 Å.

All layers were formed by a vacuum deposition method. Compound HT60 from Compound Group 2 was used as the second compound, Compound ETH88 from Compound Group 3 was used as the third compound, and Compound M-a26 from Compound Group 4 was used as the fourth compound.

The compounds used for the manufacture of the light emitting elements of the Examples and Comparative Examples are shown below. The materials below were used after purchasing commercial products and performing sublimation purification.

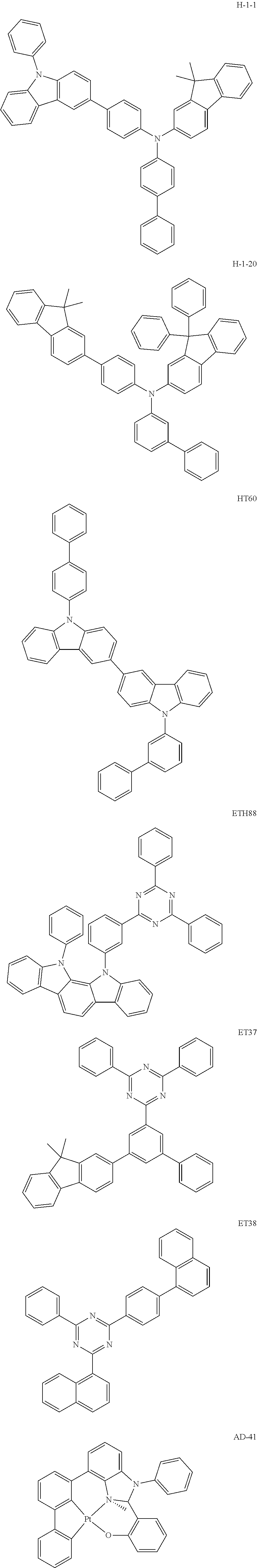

### (Evaluation of Properties of Light Emitting Elements)

The driving voltage, element efficiency, emission wavelength, and element lifetime of the light emitting elements manufactured by using Compounds 5, 23, 36, 49, 63, 100, 165, and 240 and Comparative Compounds C1 to C5 were evaluated. In Table 1, the evaluation results on the light emitting elements of Examples 1 to 8, and Comparative Examples 1 to 5 are shown. In the evaluation results of the properties of the Examples and Comparative Examples shown in Table 1, the driving voltage and the current density were measured using V7000 OLED IVL Test System (Polaronix). For the evaluation of the properties of the light emitting elements manufactured in Examples 1 to 8 and Comparative Examples 1 to 5, driving voltages (V) at a current density of about 10 mA/m², and efficiency (Cd/A) were measured, and in Table 1, the driving voltages are shown as relative driving voltages in contrast to the value of Comparative Example 1. The time consumed from an initial value to reach about 95% luminance when continuously driven at a current density of about 10 mA/m² was measured as the lifetime (T95), and relative lifetime was calculated on the basis of the value of Comparative Example 1.

TABLE 1

| | Host (second | | | Driving | Top | Emission | Lifetime |
|---|---|---|---|---|---|---|---|
| | compound:third | Fourth | First | voltage | efficiency | wavelength | ratio |
| | compound = 5:5) | compound | compound | (V) | (cd/A) | (nm) | (T95) |
| Example 1 | HT60/EHT88 | AD-41 | Compound 5 | 98 | 135 | 528 | 181 |
| Example 2 | HT60/EHT88 | AD-41 | Compound 23 | 95 | 142 | 531 | 226 |
| Example 3 | HT60/EHT88 | AD-41 | Compound 36 | 99 | 153 | 526 | 214 |
| Example 4 | HT60/EHT88 | AD-41 | Compound 49 | 93 | 125 | 524 | 198 |
| Example 5 | HT60/EHT88 | AD-41 | Compound 63 | 94 | 142 | 533 | 217 |
| Example 6 | HT60/EHT88 | AD-41 | Compound 100 | 101 | 118 | 491 | 129 |
| Example 7 | HT60/EHT88 | AD-41 | Compound 165 | 99 | 135 | 529 | 175 |
| Example 8 | HT60/EHT88 | AD-41 | Compound 240 | 102 | 129 | 527 | 186 |
| Comparative | HT60/EHT88 | AD-41 | Comparative | 100 | 101 | 533 | 100 |
| Example 1 | | | Compound C1 | | | | |
| Comparative | HT60/EHT88 | AD-41 | Comparative | 126 | 58 | 518 | 26 |
| Example 2 | | | Compound C2 | | | | |
| Comparative | HT60/EHT88 | AD-41 | Comparative | 133 | 74 | 512 | 46 |
| Example 3 | | | Compound C3 | | | | |
| Comparative | HT60/EHT88 | AD-41 | Comparative | 129 | 88 | 513 | 41 |
| Example 4 | | | Compound C4 | | | | |
| Comparative | HT60/EHT88 | AD-41 | Comparative | 125 | 67 | 511 | 68 |
| Example 5 | | | Compound C5 | | | | |

Referring to the results of Table 1, it could be confirmed that the light emitting elements of the Examples, using the fused polycyclic compounds according to embodiments as light emitting materials, all emitted light in a green wavelength range. It could be confirmed that Example 1 to Example 8 showed improved emission efficiency and lifetime characteristics compared to Comparative Example 1 to Comparative Example 5. Accordingly, it can be found that the fused polycyclic compound according to an embodiment may be used as a dopant material of an emission layer, emitting light in a green wavelength range, and shows improved emission efficiency and excellent lifetime characteristics compared to a conventional dopant material. The fused polycyclic compounds of the Examples have a structure in which two aromatic hydrocarbon rings are fused with a fused ring core at specific positions and may achieve high efficiency and long lifetime. Since the Example Compounds include a first substituent, a boron atom can be effectively protected, and intermolecular interaction may be restrained to control the formation of an excimer or an exciplex, and thus, emission efficiency and lifetime may be increased. Since the Example Compounds have increased distance between adjacent molecules due to the first substituent, and may restrain Dexter energy transfer, deterioration of lifetime generated by increased triplet concentration may be restrained.

The light emitting element according to an embodiment may include the fused polycyclic compound according to an embodiment as the light emitting dopant of a thermally activated delayed fluorescence (TADF) light emitting element, and may achieve high element efficiency in a green light wavelength range and improved lifetime characteristics.

The light emitting element according to an embodiment may show improved element properties of high efficiency and long lifetime.

The fused polycyclic compound according to an embodiment may be included in the emission layer of a light emitting element and may contribute to the increase of the efficiency and lifetime of the light emitting element.

The display device according to an embodiment may show excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element, comprising:
a first electrode;
a second electrode disposed on the first electrode; and
an emission layer disposed between the first electrode and the second electrode, wherein
the emission layer comprises a first compound represented by Formula 1: 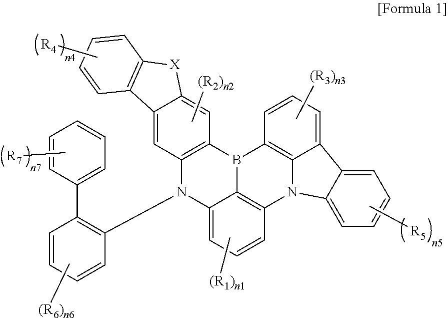
wherein in Formula 1,
X is O, S, or N(R₈),
R₁ to R₇ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
R₈ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n1 and n3 are each independently an integer from 0 to 3,
n2 is an integer from 0 to 2,
n4 to n6 are each independently an integer from 0 to 4, and
n7 is an integer from 0 to 5.

2. The light emitting element of claim 1, wherein the first compound is represented by one of Formula 2-1 to Formula 2-3: 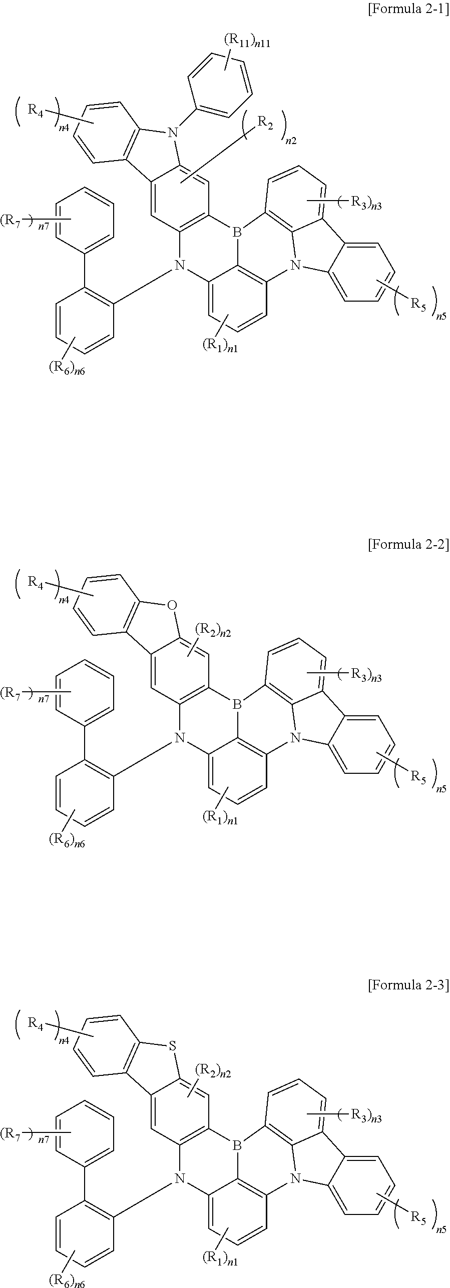
wherein in Formula 2-1 to Formula 2-3,
R₁₁ is a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n11 is an integer from 0 to 5, and
R₁ to R₇ and n1 to n7 are the same as defined in Formula 1.

3. The light emitting element of claim 1, wherein the first compound is represented by Formula 3-1 or Formula 3-2: 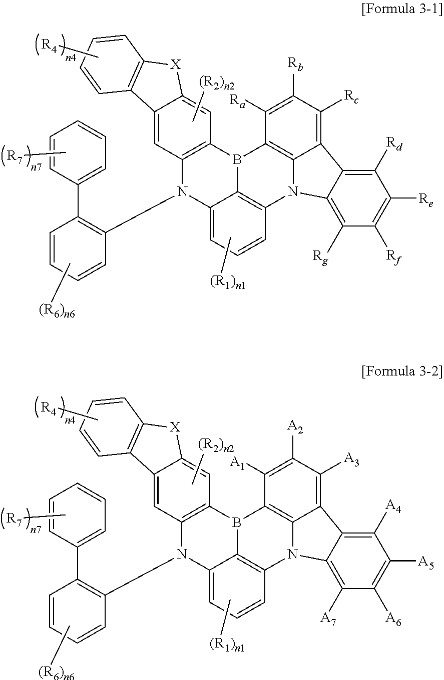
wherein in Formula 3-1 and Formula 3-2,
X, R₁, R₂, R₄, R₆, R₇, n1, n2, n4, n6, and n7 are the same as defined in Formula 1,
Rₐ to R_{g} are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
provided that:
at least one of Rₐ to R_{g} is each independently a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; or
at least one pair of adjacent groups among Rₐ to R_{g} are positions where a moiety represented by Formula 4 is fused, and
A₁ to A₇ are each independently a hydrogen atom or a deuterium atom: 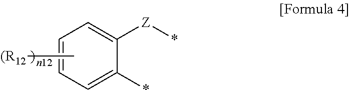
wherein in Formula 4,
-* are positions which are fused with a pair of adjacent groups among Rₐ to R_{g} in Formula 3-1,
Z is O, S, N(R₁₃), or C(R₁₄)(R₁₅),
R₁₂ to R₁₅ are each independently a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, and
n12 is an integer from 0 to 4.

4. The light emitting element of claim 3, wherein in Formula 3-1, at least one of Rₐ to R_{g} is each independently a substituted or unsubstituted t-butyl group, a substituted or unsubstituted phenyl group, or a substituted or unsubstituted biphenyl group.

5. The light emitting element of claim 1, wherein the first compound is represented by Formula 5: 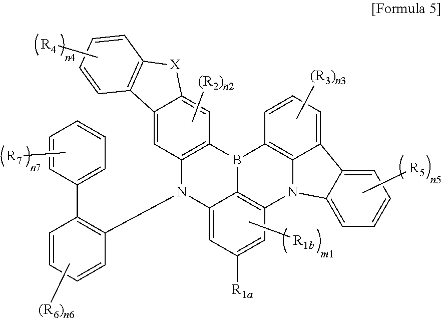
wherein in Formula 5,
R₁ₐ is a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R_{1b} is a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m1 is an integer from 0 to 2, and
X, R₂ to R₇, and n2 to n7 are the same as defined in Formula 1.

6. The light emitting element of claim 5, wherein in Formula 5, R₁ₐ is a substituted or unsubstituted isopropyl group, a substituted or unsubstituted t-butyl group, a substituted or unsubstituted diphenylamine group, a substituted or unsubstituted phenyl group, a substituted or unsubstituted biphenyl group, a substituted or unsubstituted terphenyl group, a substituted or unsubstituted naphthyl group, a substituted or unsubstituted triphenylene group, a substituted or unsubstituted fluorenyl group, a substituted or unsubstituted pyridine group, a substituted or unsubstituted triazine group, a substituted or unsubstituted carbazole group, a substituted or unsubstituted dibenzofuran group, a substituted or unsubstituted dibenzothiophene group, or a substituted or unsubstituted xanthene group.

7. The light emitting element of claim 1, wherein the first compound is represented by Formula 6: 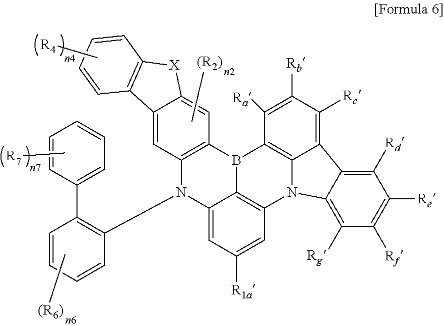
wherein in Formula 6,
X, R₂, R₄, R₆, R₇, n2, n4, n6, and n7 are the same as defined in Formula 1,
Rₐ′ to R_{g}′ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
provided that:
at least one of Rₐ′ to R_{c}′ and at least one of R_{d}′ to R_{g}′ are each independently a substituted or unsubstituted alkyl group of 1 to 10 carbon atoms or a substituted or unsubstituted aryl group of 6 to 15 ring-forming carbon atoms; or
a pair of adjacent groups among Rₐ′ to R_{g}′ are positions where a moiety represented by Formula 7 is fused,
R₁ₐ′ is a substituted or unsubstituted alkyl group of 1 to 10 carbon atoms, or a group represented by one of Formula A-1 to Formula A-11: 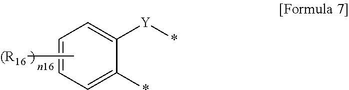
wherein in Formula 7,
-* are positions which are fused with a pair of adjacent groups among Rₐ′ to R_{g}′ in Formula 6,
Y is O, S, N(R₁₇), or C(R₁₈)(R₁₉),
R₁₆ to R₁₉ are each independently a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, and
n16 is an integer from 0 to 4: 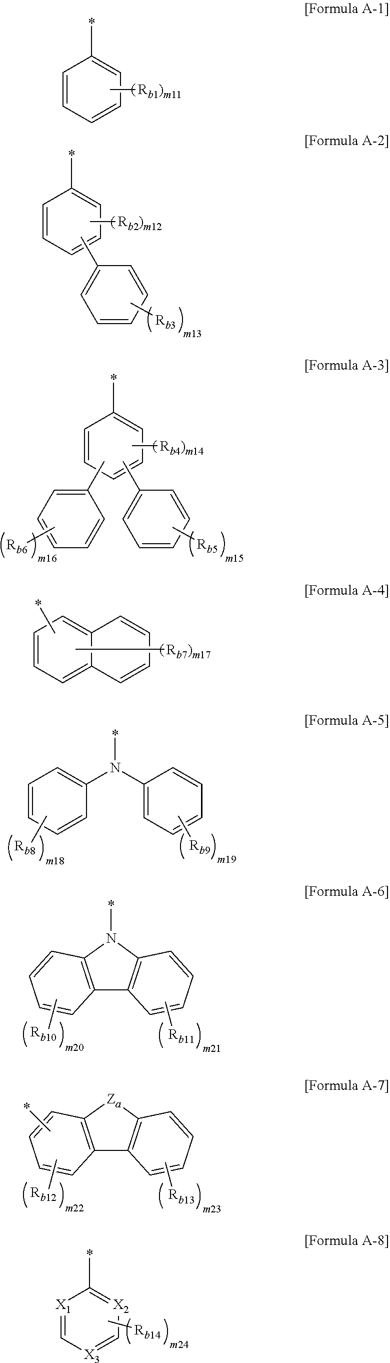 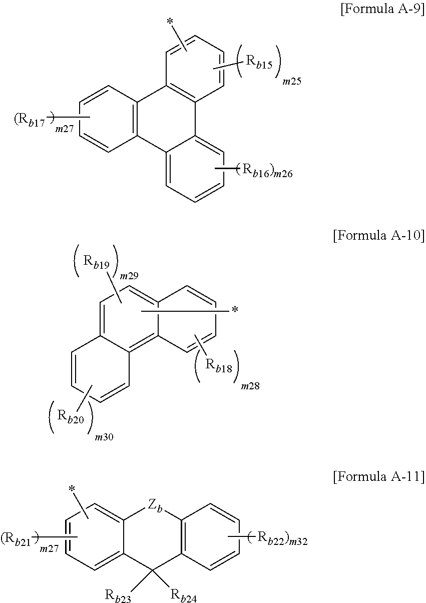
wherein in Formula A-1 to Formula A-11,
Zₐ and Z_{b} are each independently O, S, or N(R_{b25}),
at least one of X₁ to X₃ is each N,
the remainder of X₁ to X₃ are each independently C(R_{b26}),
R_{b1} to R_{b26} are each independently a hydrogen atom, a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11, m13, m15, m16, m18, and m19 are each independently an integer from 0 to 5,
m12, m20, m21, m23, m26, m27, m28, m30, and m32 are each independently an integer from 0 to 4,
m14, m22, m25, and m31 are each independently an integer from 0 to 3,
m17 is an integer from 0 to 7,
m24 and m29 are each independently an integer from 0 to 2,
a sum of m28 and m29 is 5 or less, and
-* is a position connected with Formula 6.

8. The light emitting element of claim 1, wherein the first compound is represented by Formula 8: 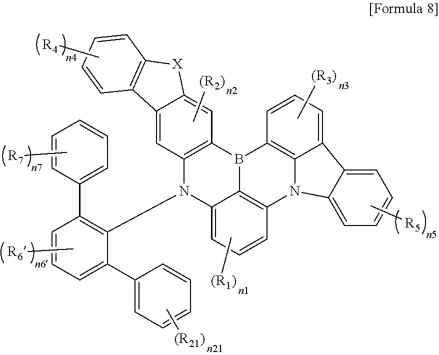
wherein in Formula 8,
R₆′ and R₂₁ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n6′ is an integer from 0 to 3,
n21 is an integer from 0 to 5, and
X, R₁ to R₅, R₇, n1 to n5, and n7 are the same as defined in Formula 1.

9. The light emitting element of claim 1, wherein the emission layer emits green light.

10. The light emitting element of claim 1, wherein the emission layer further comprises:
at least one of a second compound represented by Formula HT-1, a third compound represented by Formula ET-1, and a fourth compound represented by Formula D-1: 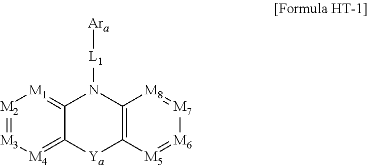
wherein in Formula HT-1,
M₁ to M₈ are each independently N or C(R₅₁),
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, C(R₅₂)(R₅₃), or Si(R₅₄)(R₅₅),
Arₐ is a substituted or unsubstituted aryl group of 6 to 30 ring-forming carbon atoms or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring; 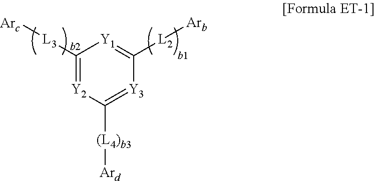
wherein in Formula ET-1,
at least one of Y₁ to Y₃ is each N,
the remainder of Y₁ to Y₃ are each independently C(R₅₆),
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer from 0 to 10,
Ar_{b} to Ar_{d} are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms: 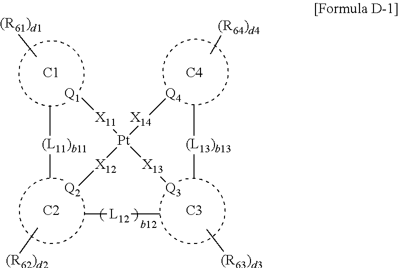
wherein in Formula D-1,
Q₁ to Q₄ are each independently C or N,
C1 to C4 are each independently a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms,
X₁₁ to X₁₄ are each independently a direct linkage or *—O—*,
L₁₁ to L₁₃ are each independently a direct linkage, *—O—*, *—S—*, 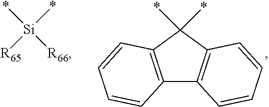
a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and
d1 to d4 are each independently an integer from 0 to 4.

11. A display device comprising:
a circuit layer disposed on a base layer; and
a display element layer disposed on the circuit layer and comprising a light emitting element, wherein
the light emitting element comprises:
a first electrode;
a second electrode disposed on the first electrode; and
an emission layer disposed between the first electrode and the second electrode, the emission layer comprises a first compound represented by Formula 1: 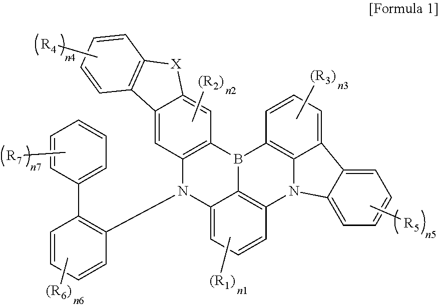
wherein in Formula 1,
X is O, S, or N(R₈),
R₁ to R₇ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
R₈ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n1 and n3 are each independently an integer from 0 to 3,
n2 is an integer from 0 to 2,
n4 to n6 are each independently an integer from 0 to 4, and
n7 is an integer from 0 to 5.

12. The display device of claim 11, wherein
the light emitting element further comprises a capping layer disposed on the second electrode, and
the capping layer has a refractive index equal to or greater than about 1.6, with respect to light in a wavelength range of about 550 nm to about 660 nm.

13. The display device of claim 11, wherein
the display device further comprises a light controlling layer disposed on the display element layer, the light controlling layer comprising a quantum dot,
the light emitting element emits first color light, and
the light controlling layer comprises:
a first light controlling part comprising a first quantum dot that converts the first color light into second color light, which has a longer wavelength range than the first color light;
a second light controlling part comprising a second quantum dot that converts the first color light into third color light, which has a longer wavelength range than the first color light and the second color light; and
a third light controlling part that transmits the first color light.

14. The display device of claim 13, wherein
the display device further comprises a color filter layer disposed on the light controlling layer, and
the color filter layer comprises:
a first filter that transmits the second color light;
a second filter that transmits the third color light; and
a third filter that transmits the first color light.

15. A fused polycyclic compound represented by Formula 1: 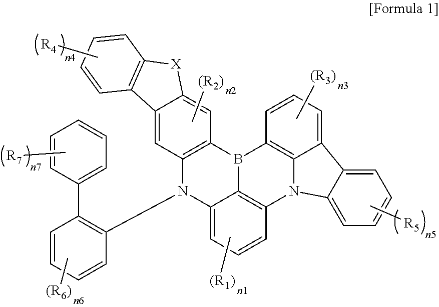
wherein in Formula 1,
X is O, S, or N(R₈),
R₁ to R₇ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
R₈ is a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n1 and n3 are each independently an integer from 0 to 3,
n2 is an integer from 0 to 2,
n4 to n6 are each independently an integer from 0 to 4, and
n7 is an integer from 0 to 5.

16. The fused polycyclic compound of claim 15, wherein the fused polycyclic compound represented by Formula 1 is represented by Formula 3-1 or Formula 3-2: 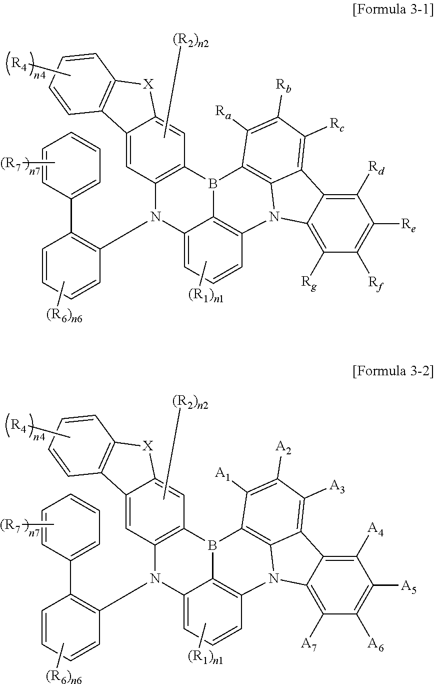
wherein in Formula 3-1 and Formula 3-2,
X, R₁, R₂, R₄, R₆, R₇, n1, n2, n4, n6, and n7 are the same as defined in Formula 1,
Rₐ to R_{g} are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
provided that:
at least one of Rₐ to R_{g} is each independently a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; or
at least one pair of adjacent groups among Rₐ to R_{g} are positions where a moiety represented by the following Formula 4 is fused, and
A₁ to A₇ are each independently a hydrogen atom or a deuterium atom: 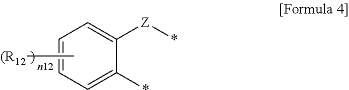
wherein in Formula 4,
-* are positions which are fused with a pair of adjacent groups among Rₐ to R_{g} in Formula 3-1,
Z is O, S, N(R₁₃), or C(R₁₄)(R₁₅),
R₁₂ to R₁₅ are each independently a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, and
n12 is an integer from 0 to 4.

17. The fused polycyclic compound of claim 15, wherein the fused polycyclic compound represented by Formula 1 is represented by Formula 5: 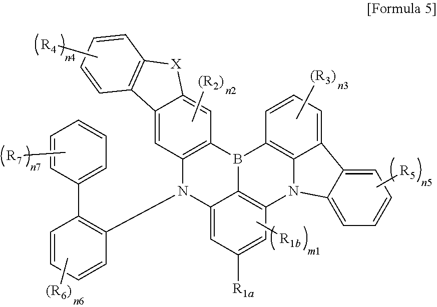
wherein in Formula 5,
R₁ₐ is a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R_{1b} is a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
m1 is an integer from 0 to 2, and
X, R₂ to R₇, and n2 to n7 are the same as defined in Formula 1.

18. The fused polycyclic compound of claim 15, wherein the fused polycyclic compound represented by Formula 1 is represented by Formula 6: 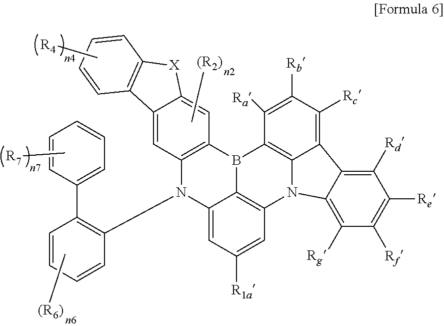
wherein in Formula 6,
X, R₂, R₄, R₆, R₇, n2, n4, n6, and n7 are the same as defined in Formula 1,
Rₐ′ to R_{g}′ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
provided that:
at least one of Rₐ′ to R_{c}′ and at least one of R_{d}′ to R_{g}′ are each independently a substituted or unsubstituted alkyl group of 1 to 10 carbon atoms or a substituted or unsubstituted aryl group of 6 to 15 ring-forming carbon atoms; or
a pair adjacent groups among Rₐ′ to R_{g}′ are positions where a moiety represented by the following Formula 7 is fused, and
R₁ₐ′ is a substituted or unsubstituted alkyl group of 1 to 10 carbon atoms, or a group represented by one of Formula A-1 to Formula A-11: 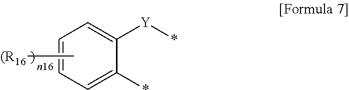
wherein in Formula 7,
-* are positions which are fused with a pair of adjacent groups among Rₐ′ to R_{g}′ in Formula 6,
Y is O, S, N(R₁₇), or C(R₁₈)(R₁₉),
R₁₆ to R₁₉ are each independently a hydrogen atom, a deuterium atom, a cyano group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, and
n16 is an integer from 0 to 4: 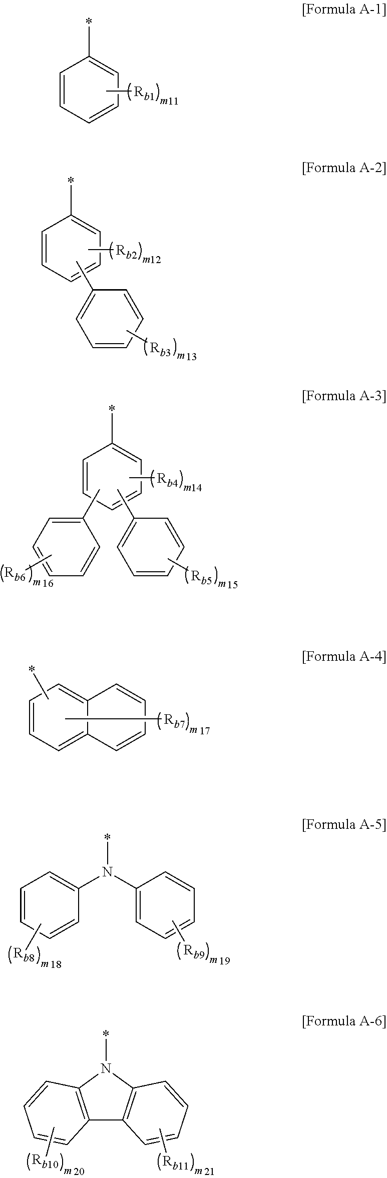 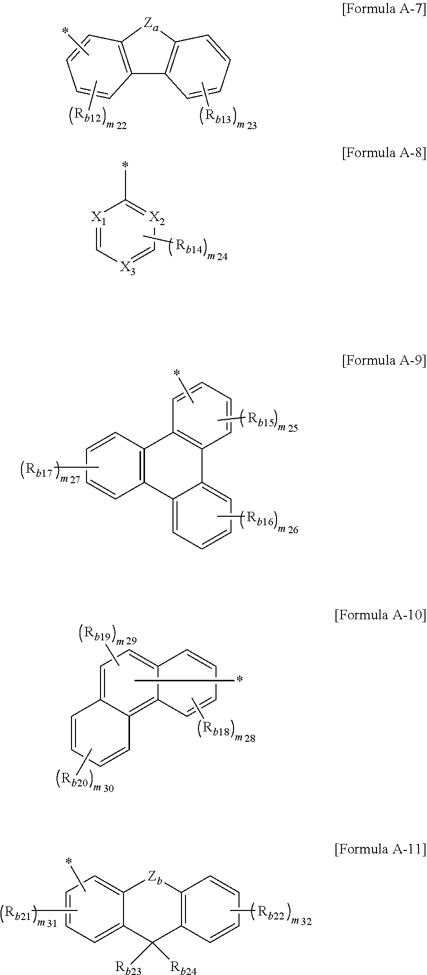
wherein in Formula A-1 to Formula A-11,
Zₐ and Z_{b} are each independently O, S, or N(R_{b25}),
at least one of X₁ to X₃ is each N,
the remainder of X₁ to X₃ are each independently C(R_{b26}),
R_{b1} to R_{b26} are each independently a hydrogen atom, a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m11, m13, m15, m16, m18, and m19 are each independently an integer from 0 to 5,
m12, m20, m21, m23, m26, m27, m28, m30, and m32 are each independently an integer from 0 to 4,
m14, m22, m25, and m31 are each independently an integer from 0 to 3,
m17 is an integer from 0 to 7,
m24 and m29 are each independently an integer from 0 to 2,
a sum of m28 and m29 is 5 or less, and
-* is a position connected with Formula 6.

19. The fused polycyclic compound of claim 15, wherein the fused polycyclic compound represented by Formula 1 is represented by Formula 8: 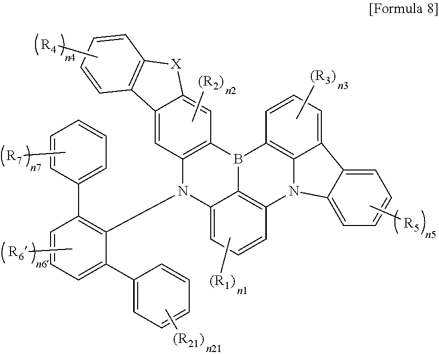
wherein in Formula 8,
R₆′ and R₂₁ are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
n6′ is an integer from 0 to 3,
n21 is an integer from 0 to 5, and
X, R₁ to R₅, R₇, n1 to n5, and n7 are the same as defined in Formula 1.

20. The fused polycyclic compound claim 15, wherein the fused polycyclic compound is selected from Compound Group 1: 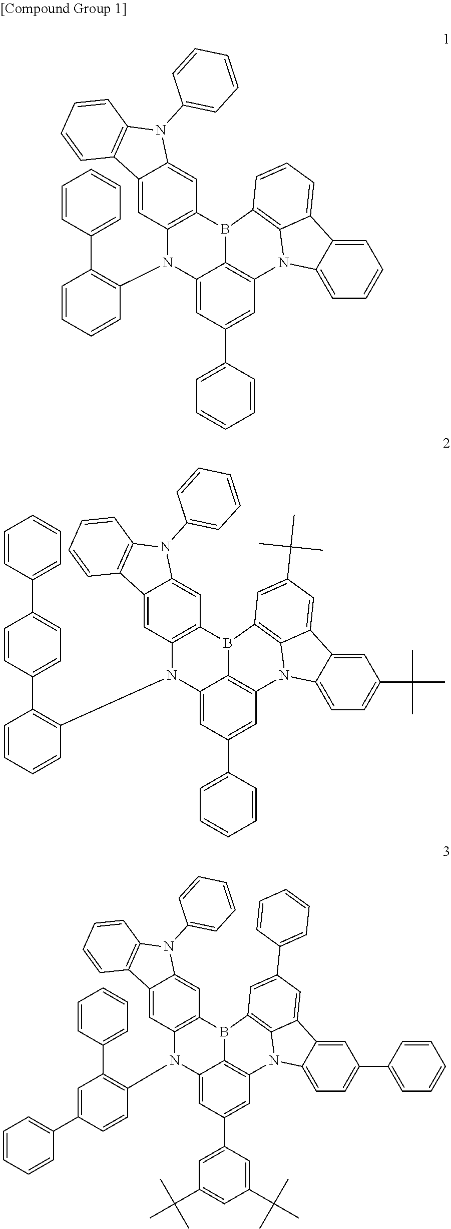 [SMILES: c1ccc(-c2cc3c4c(c2)-n2c5ccccc5c5cccc(c52)B4c2cc4c(cc2N3c2ccccc2-c2ccccc2)c2ccccc2n4-c2ccccc2)cc1 ; CC(C)(C)c1ccc2c(c1)c1cc(C(C)(C)C)cc3c1n2-c1cc(-c2ccccc2)cc2c1B3c1cc3c(cc1N2c1ccccc1-c1ccc(-c2ccccc2)cc1)c1ccccc1n3-c1ccccc1 ; CC(C)(C)c1cc(-c2cc3c4c(c2)-n2c5ccc(-c6ccccc6)cc5c5cc(-c6ccccc6)cc(c52)B4c2cc4c(cc2N3c2ccc(-c3ccccc3)cc2-c2ccccc2)c2ccccc2n4-c2ccccc2)cc(C(C)(C)C)c1] 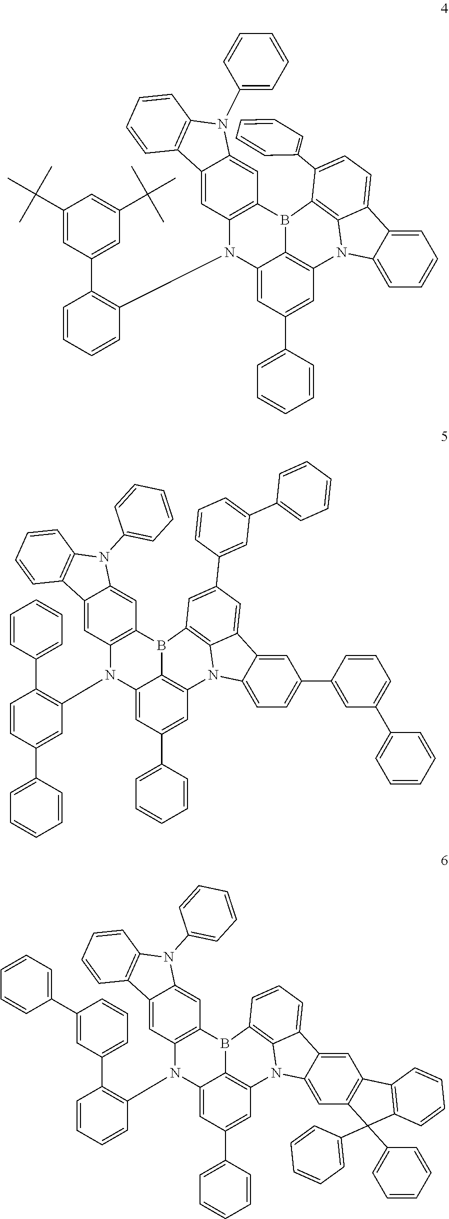 [SMILES: CC(C)(C)c1cc(-c2ccccc2N2c3cc4c5ccccc5n(-c5ccccc5)c4cc3B3c4c2cc(-c2ccccc2)cc4-n2c4ccccc4c4ccc(-c5ccccc5)c3c42)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3cc(-c4ccccc4)ccc3-c3ccccc3)c3ccccc3n5-c3ccccc3)c2)cc1 ; c1ccc(-c2cccc(-c3ccccc3N3c4cc5c6ccccc6n(-c6ccccc6)c5cc4B4c5c3cc(-c3ccccc3)cc5-n3c5cc6c(cc5c5cccc4c53)-c3ccccc3C6(c3ccccc3)c3ccccc3)c2)cc1] 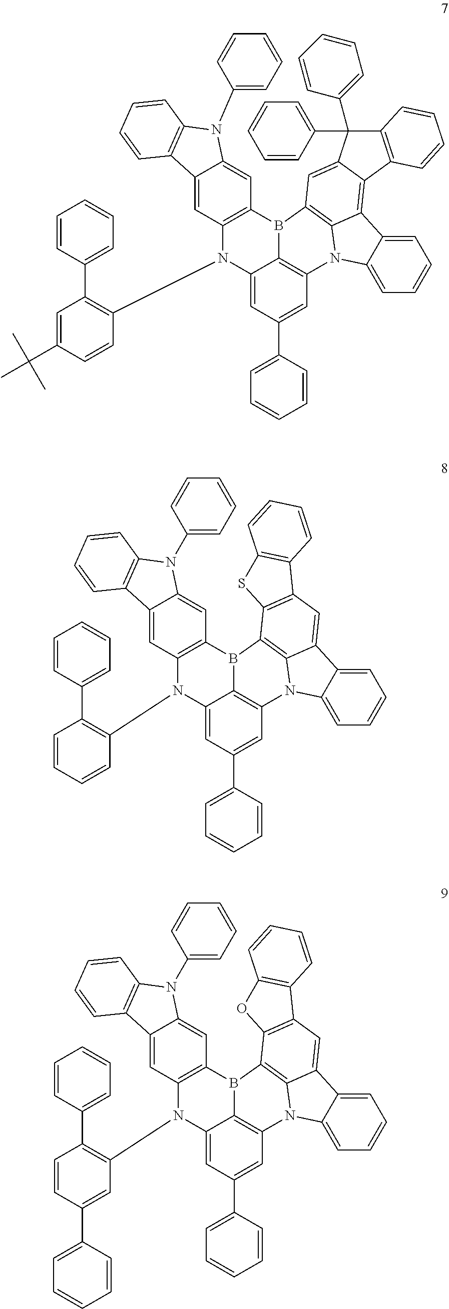 [SMILES: CC(C)(C)c1ccc(N2c3cc4c5ccccc5n(-c5ccccc5)c4cc3B3c4c2cc(-c2ccccc2)cc4-n2c4ccccc4c4c5c(cc3c42)C(c2ccccc2)(c2ccccc2)c2ccccc2-5)c(-c2ccccc2)c1 ; c1ccc(-c2cc3c4c(c2)-n2c5ccccc5c5cc6c(sc7ccccc76)c(c52)B4c2cc4c(cc2N3c2ccccc2-c2ccccc2)c2ccccc2n4-c2ccccc2)cc1 ; c1ccc(-c2ccc(-c3ccccc3)c(N3c4cc5c6ccccc6n(-c6ccccc6)c5cc4B4c5c3cc(-c3ccccc3)cc5-n3c5ccccc5c5cc6c(oc7ccccc76)c4c53)c2)cc1] 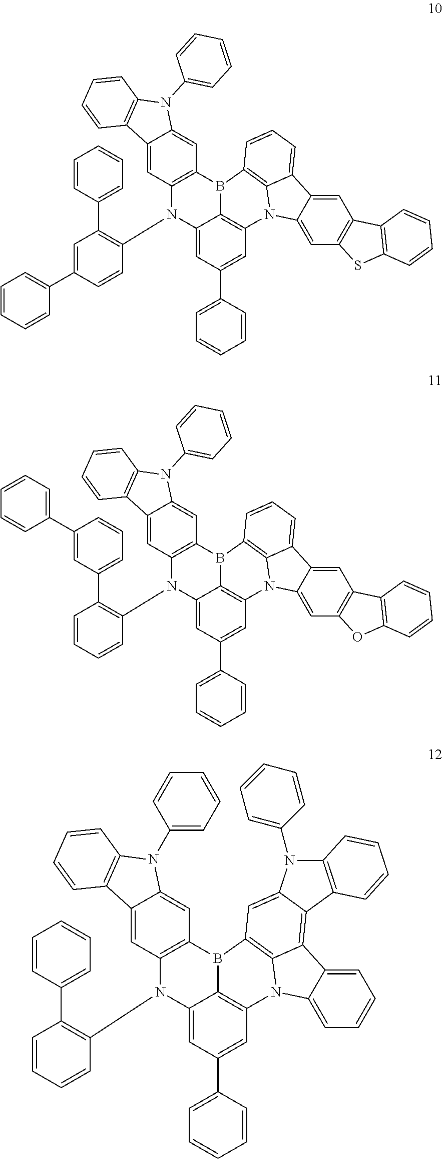 [SMILES: c1ccc(-c2ccc(N3c4cc5c6ccccc6n(-c6ccccc6)c5cc4B4c5c3cc(-c3ccccc3)cc5-n3c5cc6sc7ccccc7c6cc5c5cccc4c53)c(-c3ccccc3)c2)cc1 ; c1ccc(-c2cccc(-c3ccccc3N3c4cc5c6ccccc6n(-c6ccccc6)c5cc4B4c5c3cc(-c3ccccc3)cc5-n3c5cc6oc7ccccc7c6cc5c5cccc4c53)c2)cc1 ; c1ccc(-c2cc3c4c(c2)-n2c5ccccc5c5c6c7ccccc7n(-c7ccccc7)c6cc(c52)B4c2cc4c(cc2N3c2ccccc2-c2ccccc2)c2ccccc2n4-c2ccccc2)cc1] 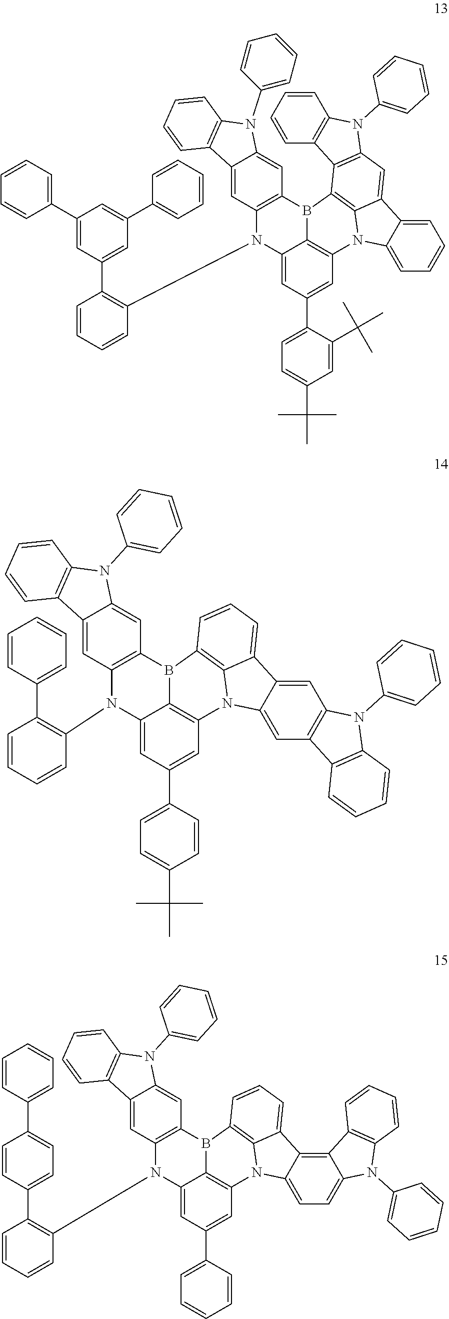 [SMILES: CC(C)(C)c1ccc(-c2cc3c4c(c2)-n2c5ccccc5c5cc6c(c(c52)B4c2cc4c(cc2N3c2ccccc2-c2cc(-c3ccccc3)cc(-c3ccccc3)c2)c2ccccc2n4-c2ccccc2)c2ccccc2n6-c2ccccc2)c(C(C)(C)C)c1 ; CC(C)(C)c1ccc(-c2cc3c4c(c2)-n2c5cc6c7ccccc7n(-c7ccccc7)c6cc5c5cccc(c52)B4c2cc4c(cc2N3c2ccccc2-c2ccccc2)c2ccccc2n4-c2ccccc2)cc1 ; c1ccc(-c2ccc(-c3ccccc3N3c4cc5c6ccccc6n(-c6ccccc6)c5cc4B4c5c3cc(-c3ccccc3)cc5-n3c5ccc6c(c7ccccc7n6-c6ccccc6)c5c5cccc4c53)cc2)cc1] 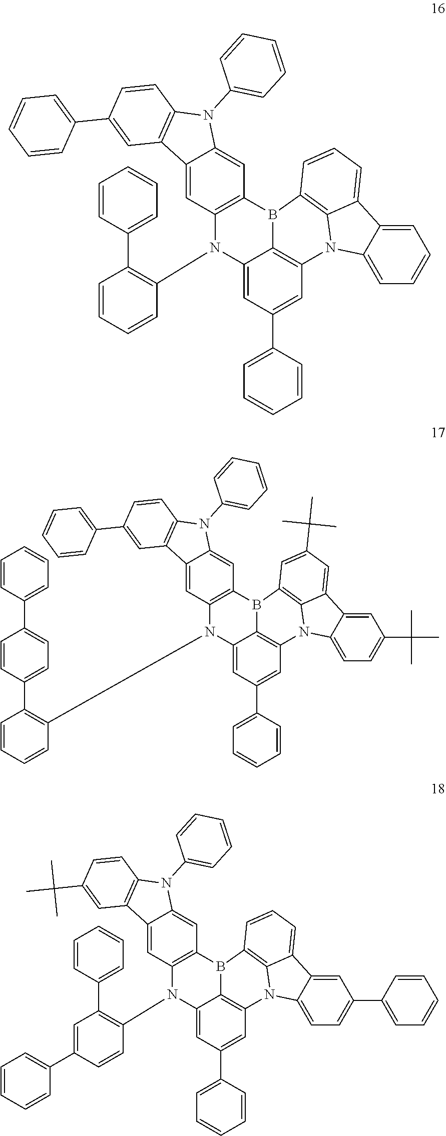 [SMILES: c1ccc(-c2cc3c4c(c2)-n2c5ccccc5c5cccc(c52)B4c2cc4c(cc2N3c2ccccc2-c2ccccc2)c2cc(-c3ccccc3)ccc2n4-c2ccccc2)cc1 ; CC(C)(C)c1ccc2c(c1)c1cc(C(C)(C)C)cc3c1n2-c1cc(-c2ccccc2)cc2c1B3c1cc3c(cc1N2c1ccccc1-c1ccc(-c2ccccc2)cc1)c1cc(-c2ccccc2)ccc1n3-c1ccccc1 ; CC(C)(C)c1ccc2c(c1)c1cc3c(cc1n2-c1ccccc1)B1c2c(cc(-c4ccccc4)cc2-n2c4ccc(-c5ccccc5)cc4c4cccc1c42)N3c1ccc(-c2ccccc2)cc1-c1ccccc1] 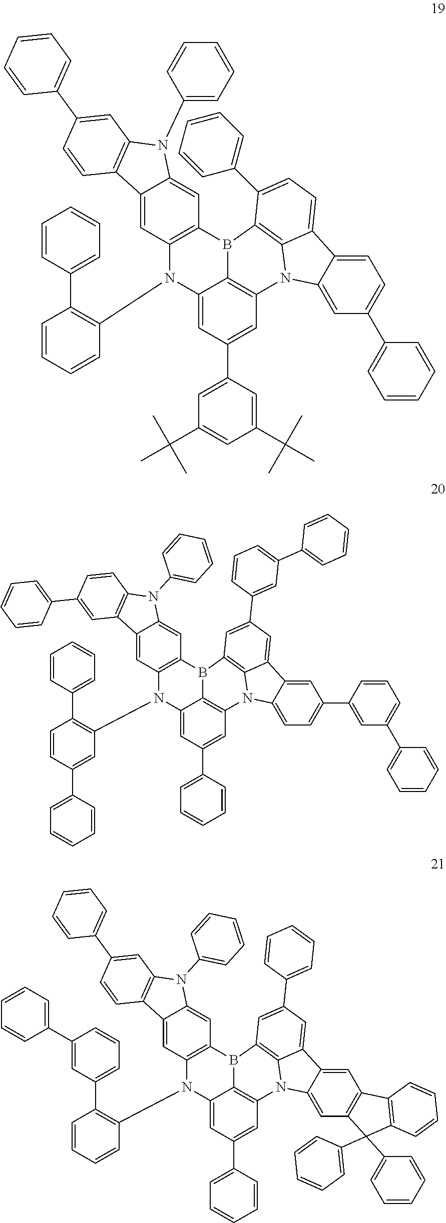 [SMILES: CC(C)(C)c1cc(-c2cc3c4c(c2)-n2c5cc(-c6ccccc6)ccc5c5ccc(-c6ccccc6)c(c52)B4c2cc4c(cc2N3c2ccccc2-c2ccccc2)c2ccc(-c3ccccc3)cc2n4-c2ccccc2)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3cc(-c4ccccc4)ccc3-c3ccccc3)c3cc(-c4ccccc4)ccc3n5-c3ccccc3)c2)cc1 ; c1ccc(-c2cccc(-c3ccccc3N3c4cc5c6ccc(-c7ccccc7)cc6n(-c6ccccc6)c5cc4B4c5c3cc(-c3ccccc3)cc5-n3c5cc6c(cc5c5cc(-c7ccccc7)cc4c53)-c3ccccc3C6(c3ccccc3)c3ccccc3)c2)cc1] 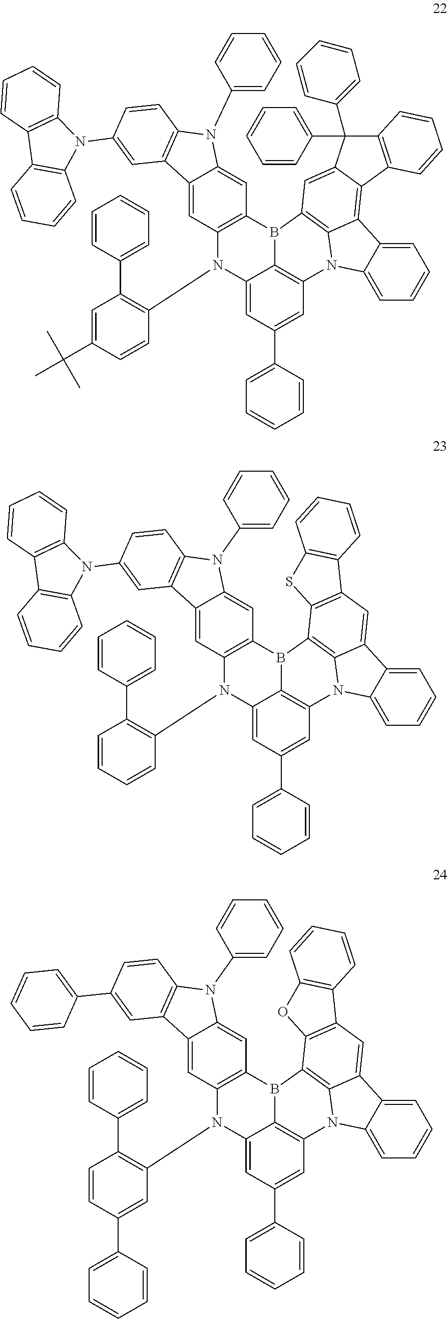 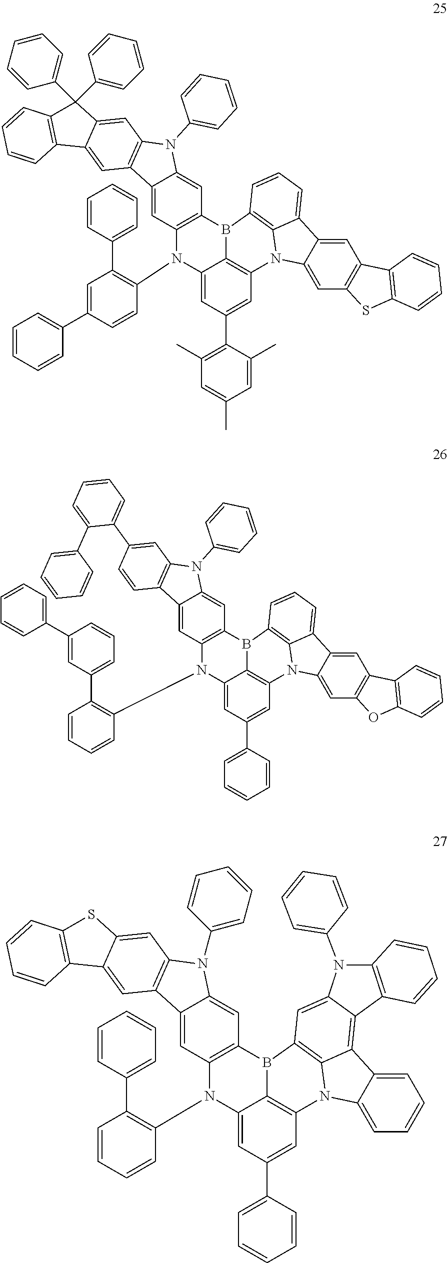 [SMILES: Cc1cc(C)c(-c2cc3c4c(c2)-n2c5cc6sc7ccccc7c6cc5c5cccc(c52)B4c2cc4c(cc2N3c2ccc(-c3ccccc3)cc2-c2ccccc2)c2cc3c(cc2n4-c2ccccc2)C(c2ccccc2)(c2ccccc2)c2ccccc2-3)c(C)c1 ; c1ccc(-c2cccc(-c3ccccc3N3c4cc5c6ccc(-c7ccccc7-c7ccccc7)cc6n(-c6ccccc6)c5cc4B4c5c3cc(-c3ccccc3)cc5-n3c5cc6oc7ccccc7c6cc5c5cccc4c53)c2)cc1 ; c1ccc(-c2cc3c4c(c2)-n2c5ccccc5c5c6c7ccccc7n(-c7ccccc7)c6cc(c52)B4c2cc4c(cc2N3c2ccccc2-c2ccccc2)c2cc3c(cc2n4-c2ccccc2)sc2ccccc23)cc1] 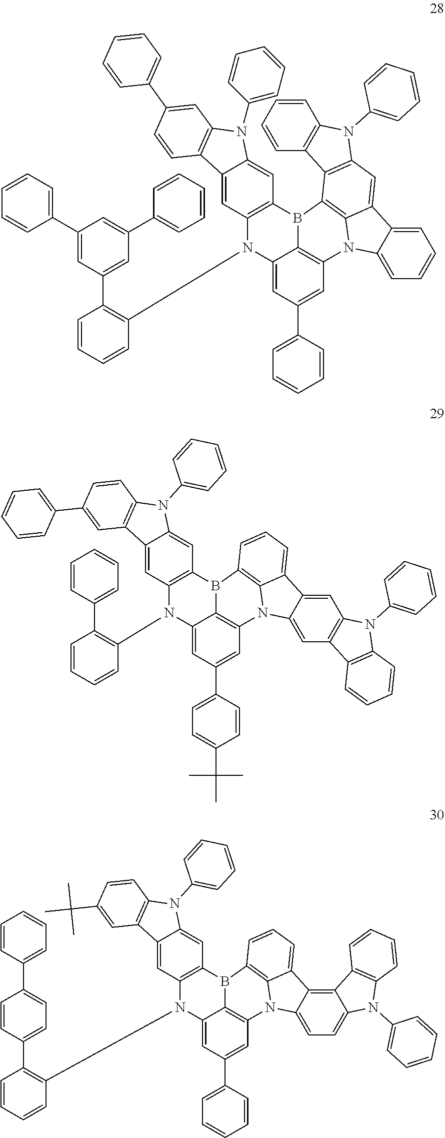 [SMILES: c1ccc(-c2cc(-c3ccccc3)cc(-c3ccccc3N3c4cc5c6ccc(-c7ccccc7)cc6n(-c6ccccc6)c5cc4B4c5c3cc(-c3ccccc3)cc5-n3c5ccccc5c5cc6c(c4c53)c3ccccc3n6-c3ccccc3)c2)cc1 ; CC(C)(C)c1ccc(-c2cc3c4c(c2)-n2c5cc6c7ccccc7n(-c7ccccc7)c6cc5c5cccc(c52)B4c2cc4c(cc2N3c2ccccc2-c2ccccc2)c2cc(-c3ccccc3)ccc2n4-c2ccccc2)cc1 ; CC(C)(C)c1ccc2c(c1)c1cc3c(cc1n2-c1ccccc1)B1c2c(cc(-c4ccccc4)cc2-n2c4ccc5c(c6ccccc6n5-c5ccccc5)c4c4cccc1c42)N3c1ccccc1-c1ccc(-c2ccccc2)cc1] 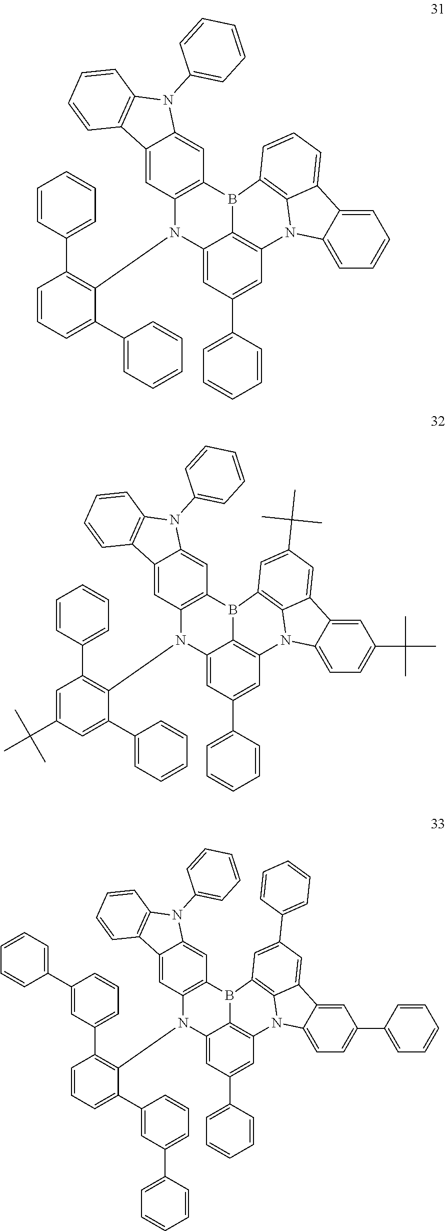 [SMILES: c1ccc(-c2cc3c4c(c2)-n2c5ccccc5c5cccc(c52)B4c2cc4c(cc2N3c2c(-c3ccccc3)cccc2-c2ccccc2)c2ccccc2n4-c2ccccc2)cc1 ; CC(C)(C)c1cc(-c2ccccc2)c(N2c3cc4c5ccccc5n(-c5ccccc5)c4cc3B3c4c2cc(-c2ccccc2)cc4-n2c4ccc(C(C)(C)C)cc4c4cc(C(C)(C)C)cc3c42)c(-c2ccccc2)c1 ; c1ccc(-c2cccc(-c3cccc(-c4cccc(-c5ccccc5)c4)c3N3c4cc5c6ccccc6n(-c6ccccc6)c5cc4B4c5c3cc(-c3ccccc3)cc5-n3c5ccc(-c6ccccc6)cc5c5cc(-c6ccccc6)cc4c53)c2)cc1] 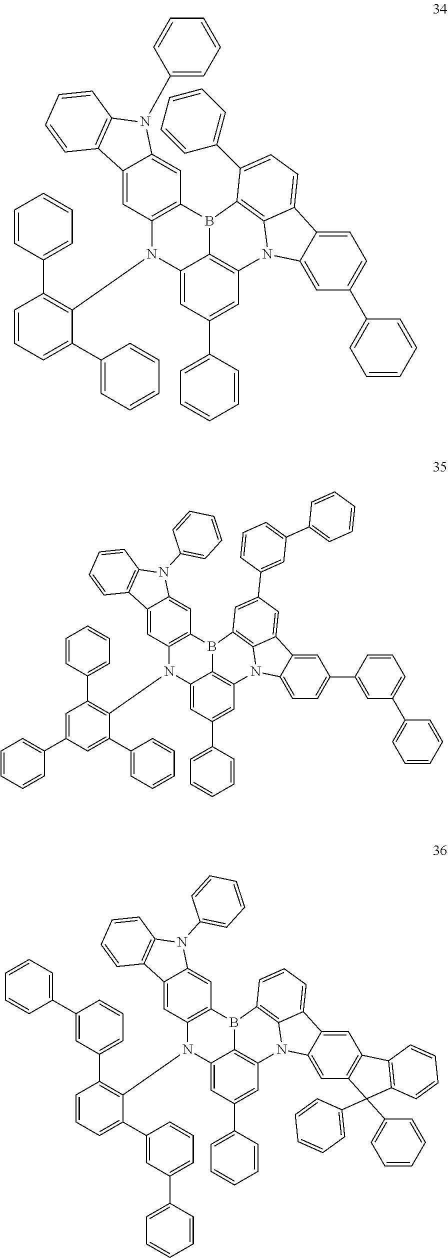 [SMILES: c1ccc(-c2cc3c4c(c2)-n2c5cc(-c6ccccc6)ccc5c5ccc(-c6ccccc6)c(c52)B4c2cc4c(cc2N3c2c(-c3ccccc3)cccc2-c2ccccc2)c2ccccc2n4-c2ccccc2)cc1 ; c1ccc(-c2cccc(-c3ccc4c(c3)c3cc(-c5cccc(-c6ccccc6)c5)cc5c3n4-c3cc(-c4ccccc4)cc4c3B5c3cc5c(cc3N4c3c(-c4ccccc4)cc(-c4ccccc4)cc3-c3ccccc3)c3ccccc3n5-c3ccccc3)c2)cc1 ; c1ccc(-c2cccc(-c3cccc(-c4cccc(-c5ccccc5)c4)c3N3c4cc5c6ccccc6n(-c6ccccc6)c5cc4B4c5c3cc(-c3ccccc3)cc5-n3c5cc6c(cc5c5cccc4c53)-c3ccccc3C6(c3ccccc3)c3ccccc3)c2)cc1] 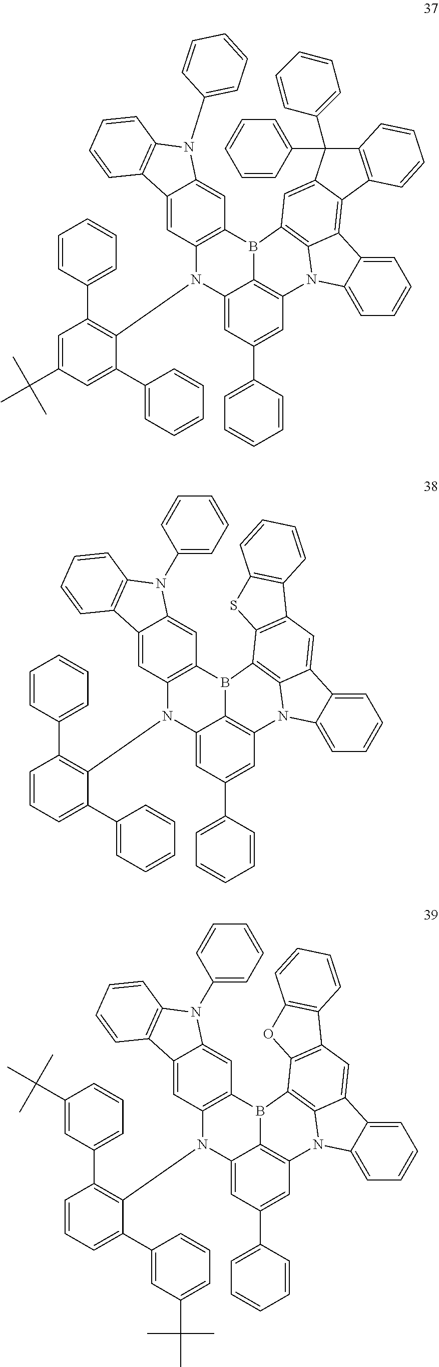 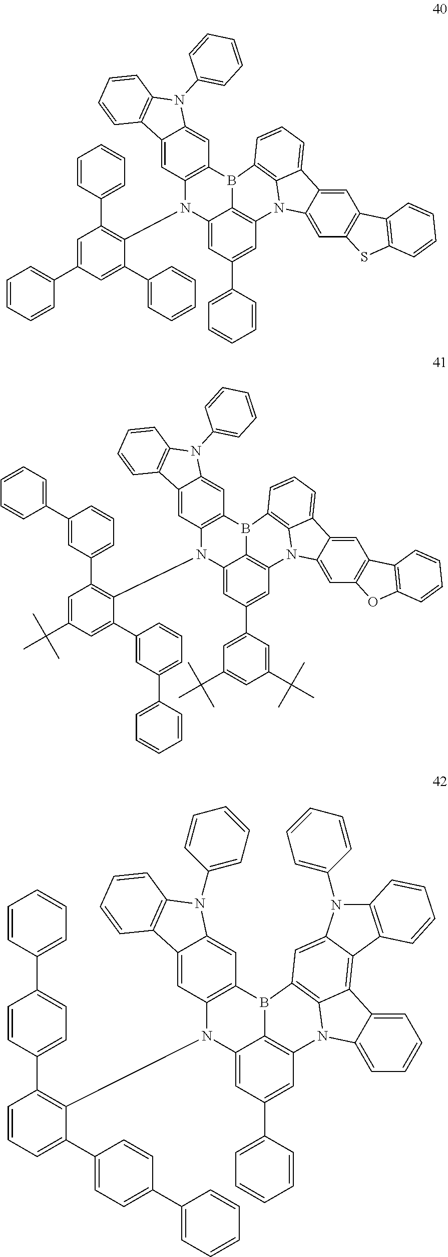 [SMILES: c1ccc(-c2cc(-c3ccccc3)c(N3c4cc5c6ccccc6n(-c6ccccc6)c5cc4B4c5c3cc(-c3ccccc3)cc5-n3c5cc6sc7ccccc7c6cc5c5cccc4c53)c(-c3ccccc3)c2)cc1 ; CC(C)(C)c1cc(-c2cc3c4c(c2)-n2c5cc6oc7ccccc7c6cc5c5cccc(c52)B4c2cc4c(cc2N3c2c(-c3cccc(-c5ccccc5)c3)cc(C(C)(C)C)cc2-c2cccc(-c3ccccc3)c2)c2ccccc2n4-c2ccccc2)cc(C(C)(C)C)c1 ; c1ccc(-c2ccc(-c3cccc(-c4ccc(-c5ccccc5)cc4)c3N3c4cc5c6ccccc6n(-c6ccccc6)c5cc4B4c5c3cc(-c3ccccc3)cc5-n3c5ccccc5c5c6c7ccccc7n(-c7ccccc7)c6cc4c53)cc2)cc1] 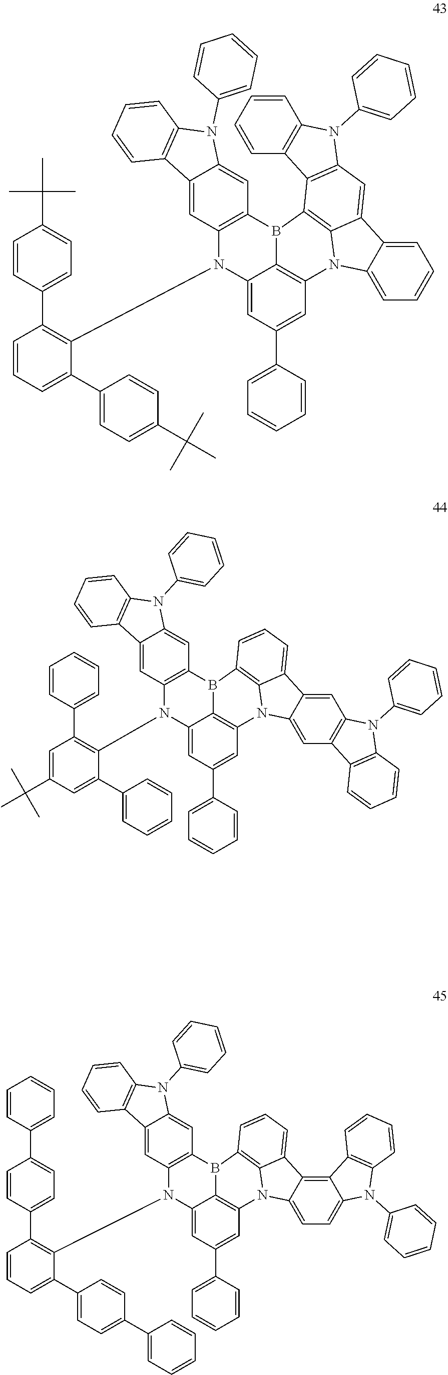 [SMILES: CC(C)(C)c1ccc(-c2cccc(-c3ccc(C(C)(C)C)cc3)c2N2c3cc4c5ccccc5n(-c5ccccc5)c4cc3B3c4c2cc(-c2ccccc2)cc4-n2c4ccccc4c4cc5c(c3c42)c2ccccc2n5-c2ccccc2)cc1 ; CC(C)(C)c1cc(-c2ccccc2)c(N2c3cc4c5ccccc5n(-c5ccccc5)c4cc3B3c4c2cc(-c2ccccc2)cc4-n2c4cc5c6ccccc6n(-c6ccccc6)c5cc4c4cccc3c42)c(-c2ccccc2)c1 ; c1ccc(-c2ccc(-c3cccc(-c4ccc(-c5ccccc5)cc4)c3N3c4cc5c6ccccc6n(-c6ccccc6)c5cc4B4c5c3cc(-c3ccccc3)cc5-n3c5ccc6c(c7ccccc7n6-c6ccccc6)c5c5cccc4c53)cc2)cc1] 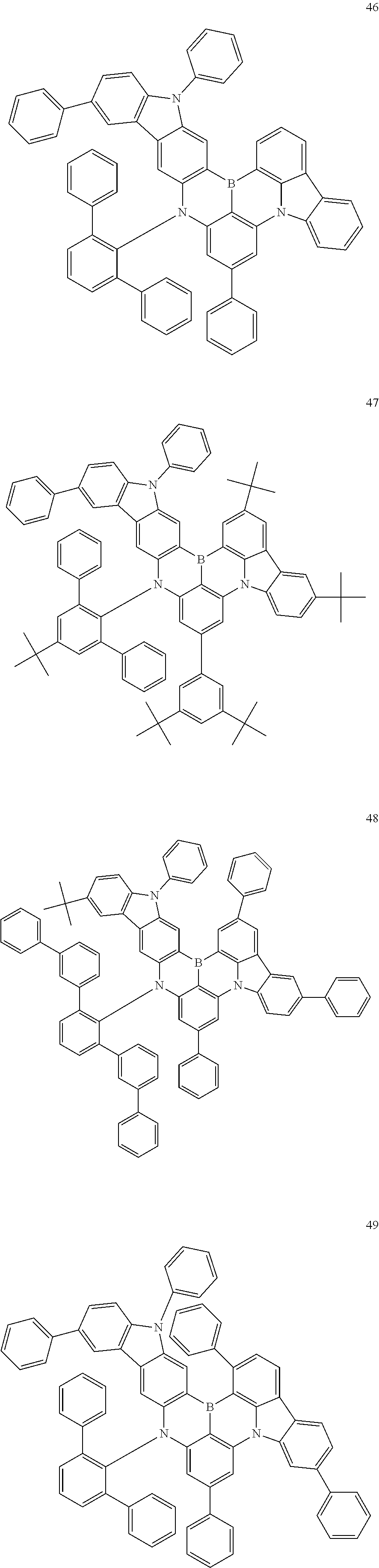 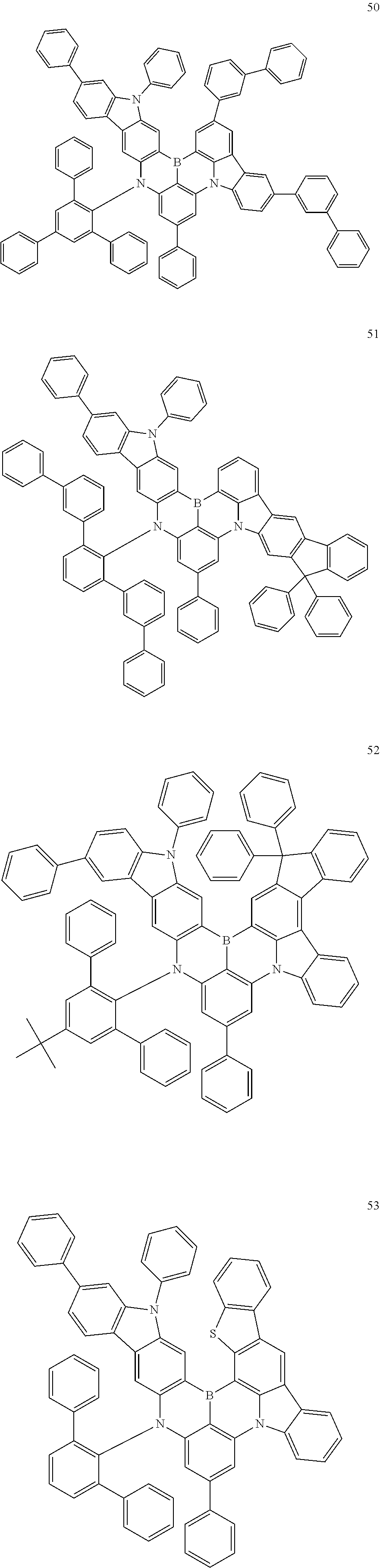 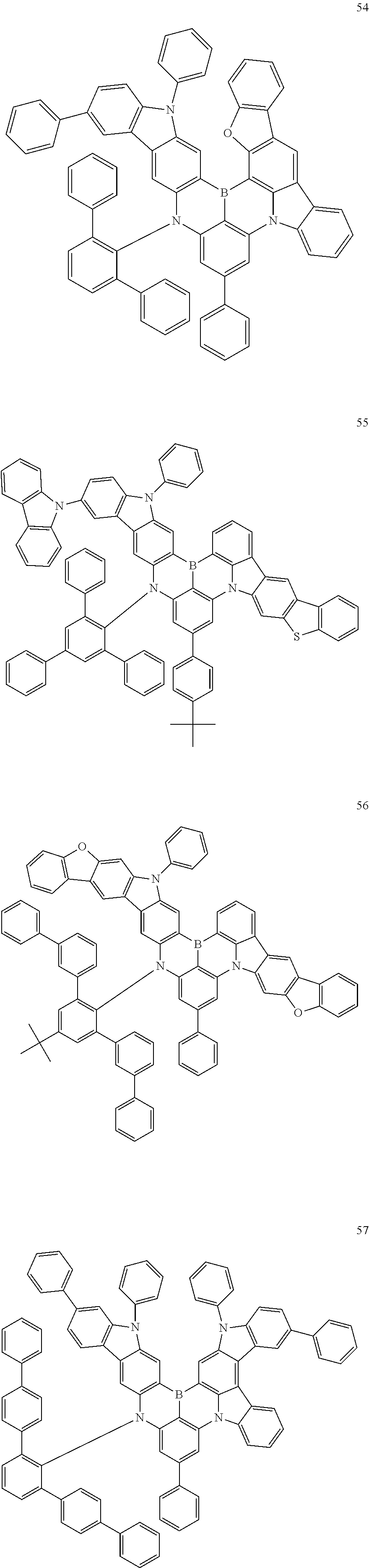 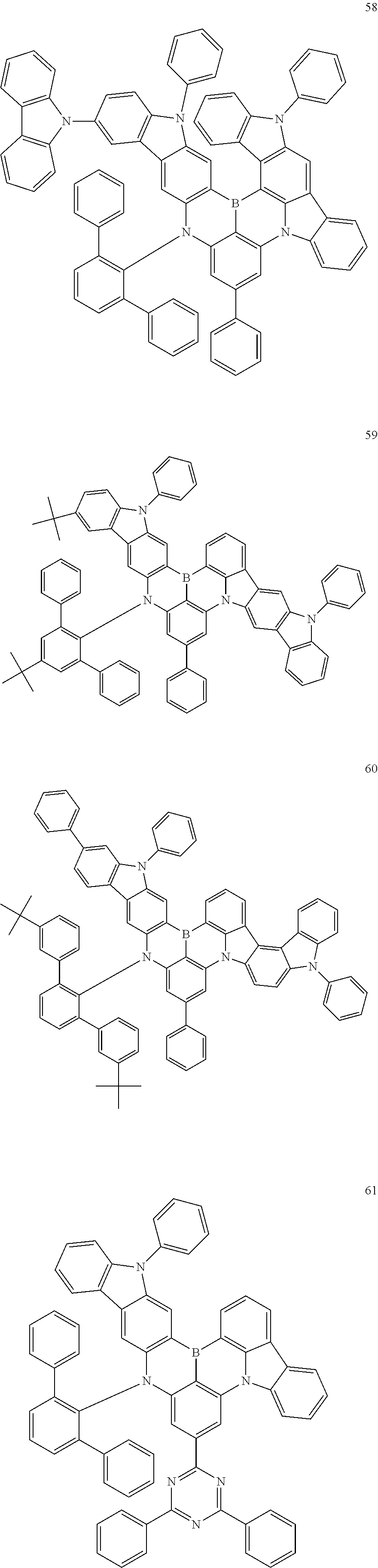 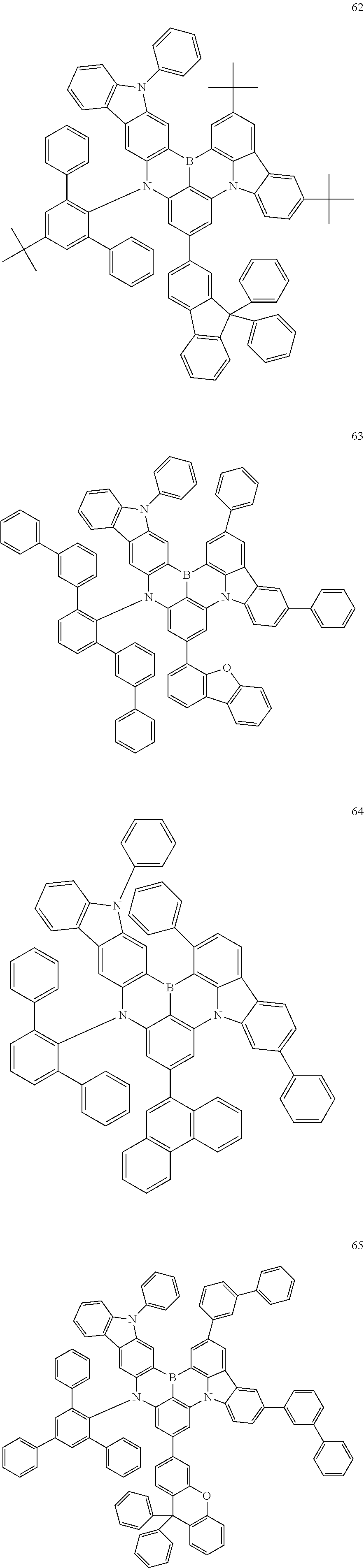 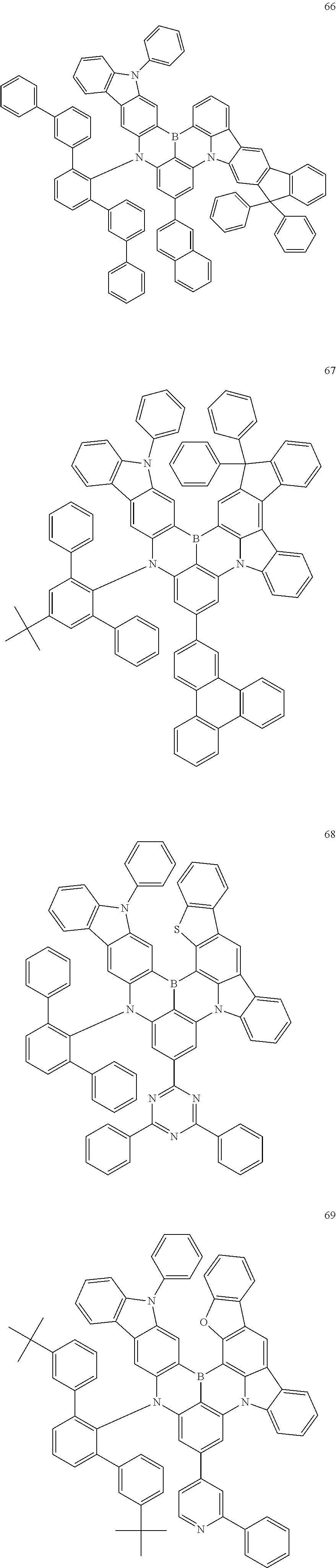 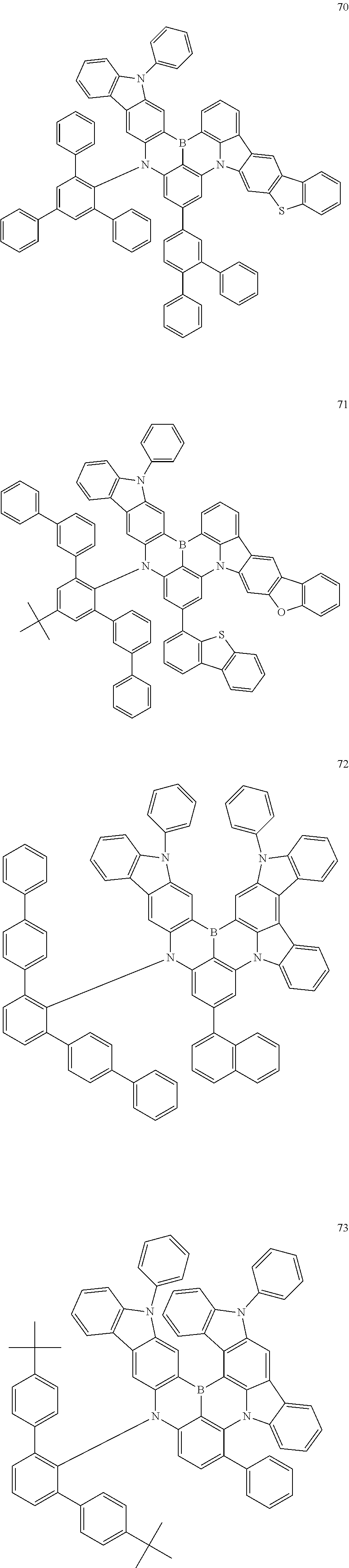 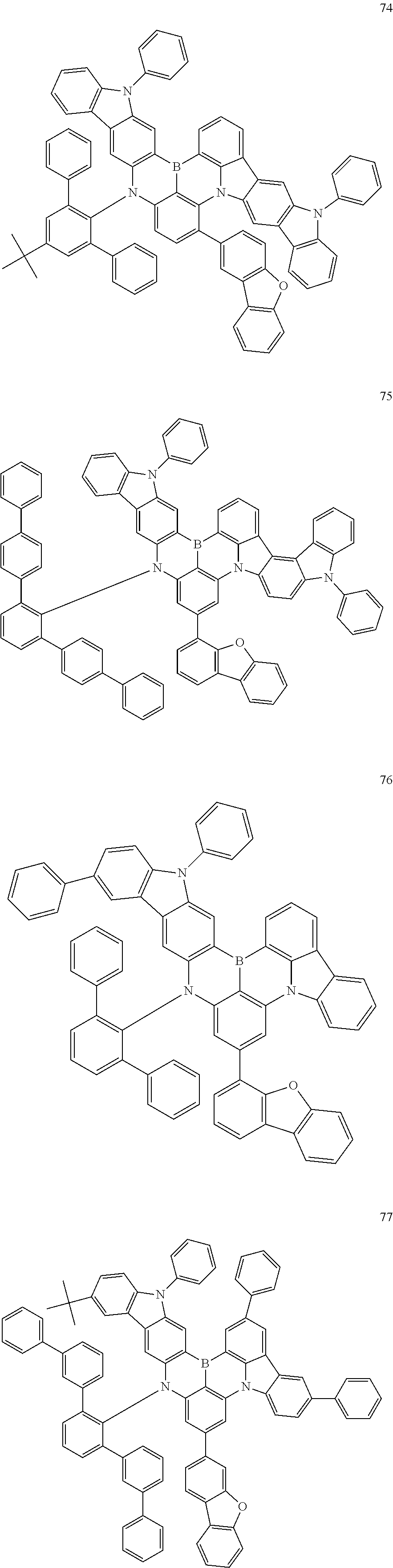 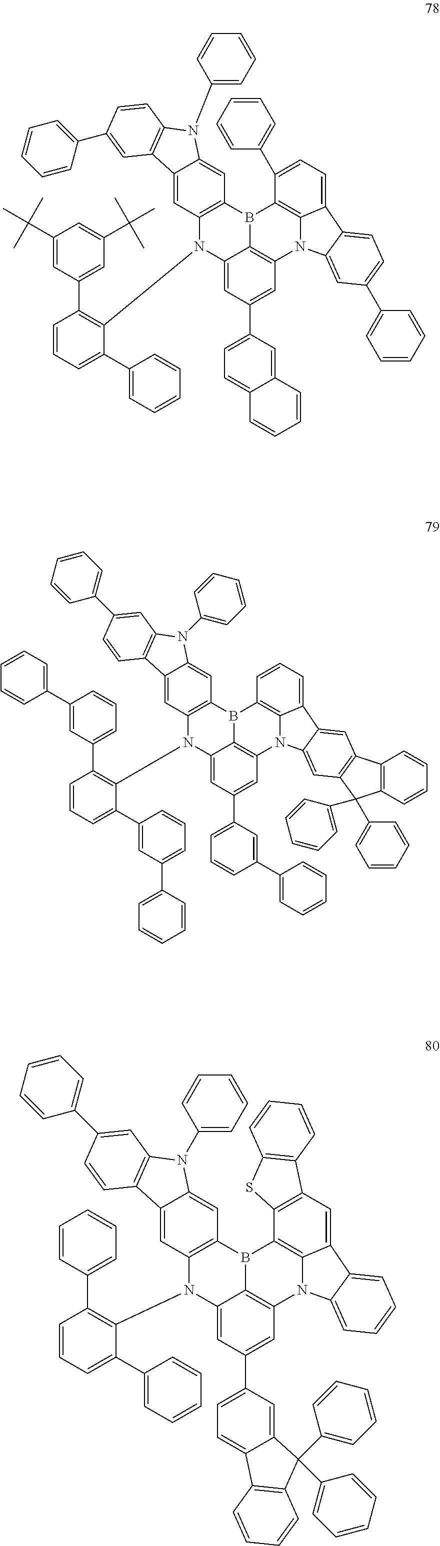 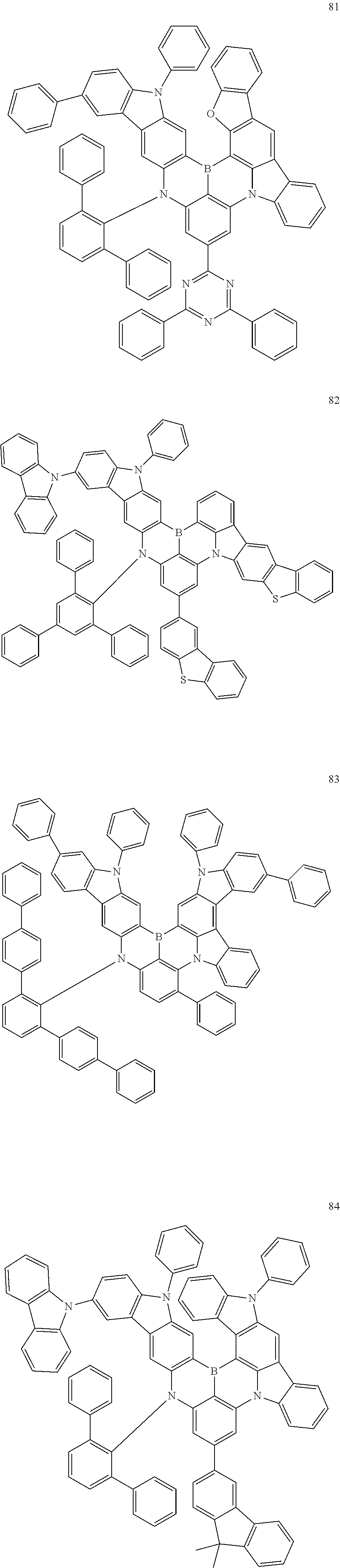 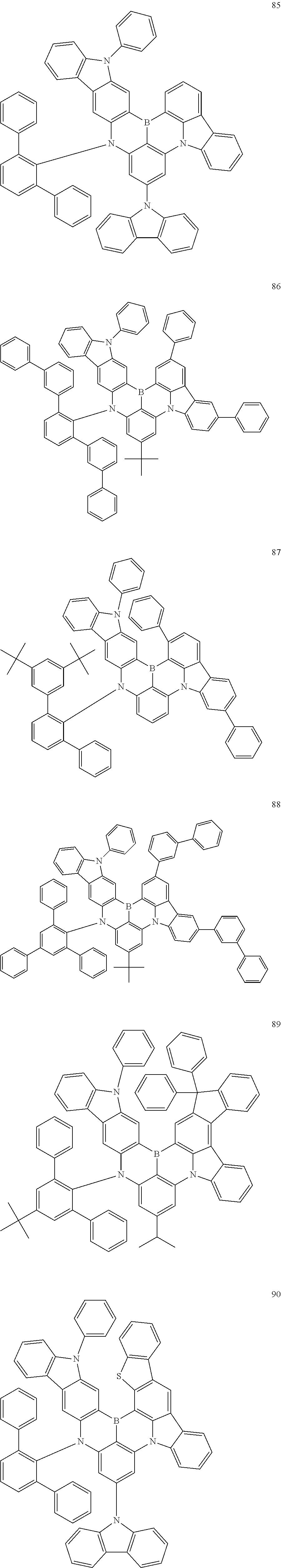 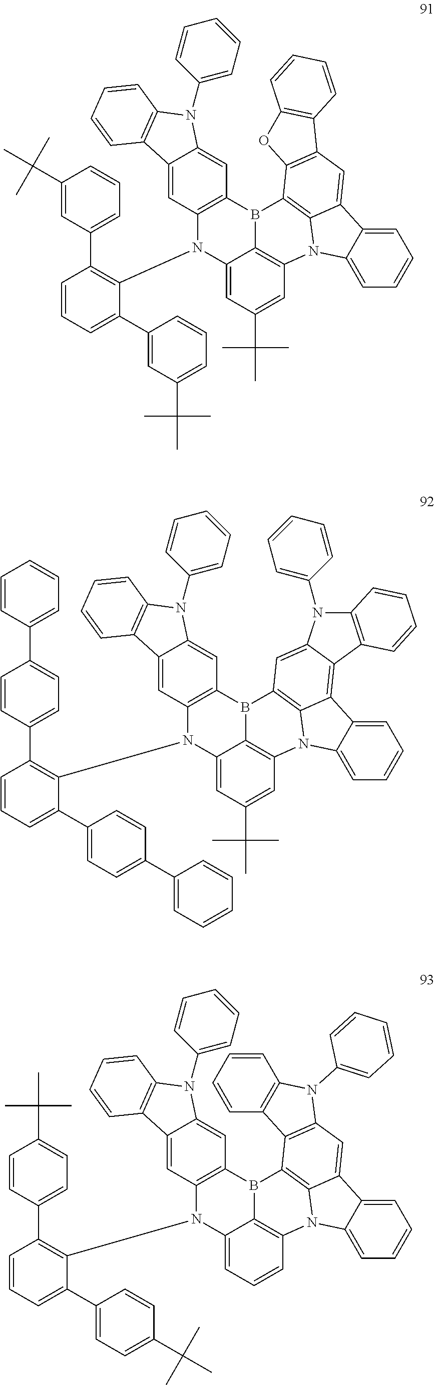 [SMILES: CC(C)(C)c1cccc(-c2cccc(-c3cccc(C(C)(C)C)c3)c2N2c3cc4c5ccccc5n(-c5ccccc5)c4cc3B3c4c2cc(C(C)(C)C)cc4-n2c4ccccc4c4cc5c(oc6ccccc65)c3c42)c1 ; CC(C)(C)c1cc2c3c(c1)-n1c4ccccc4c4c5c6ccccc6n(-c6ccccc6)c5cc(c41)B3c1cc3c(cc1N2c1c(-c2ccc(-c4ccccc4)cc2)cccc1-c1ccc(-c2ccccc2)cc1)c1ccccc1n3-c1ccccc1 ; CC(C)(C)c1ccc(-c2cccc(-c3ccc(C(C)(C)C)cc3)c2N2c3cc4c5ccccc5n(-c5ccccc5)c4cc3B3c4c2cccc4-n2c4ccccc4c4cc5c(c3c42)c2ccccc2n5-c2ccccc2)cc1] 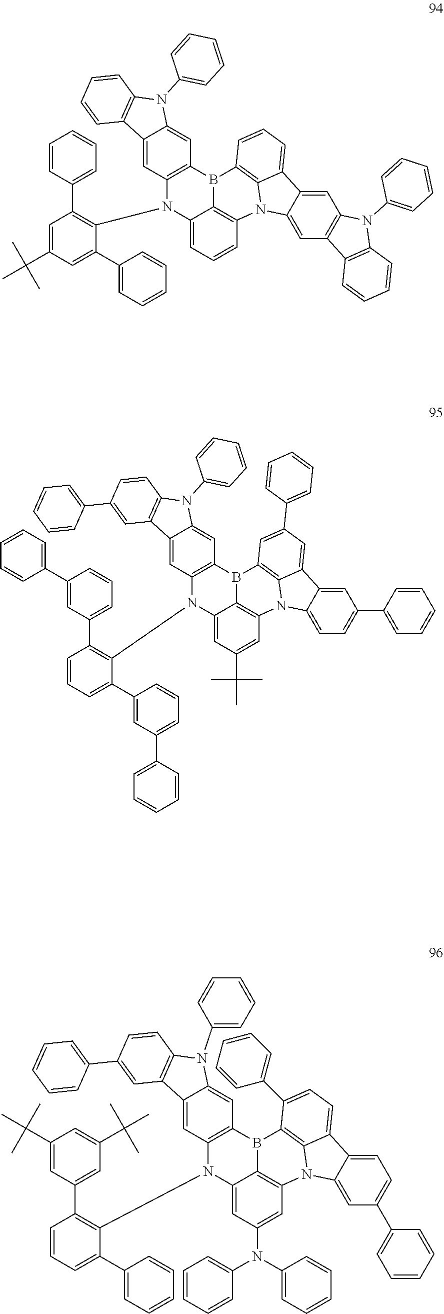 [SMILES: CC(C)(C)c1cc(-c2ccccc2)c(N2c3cc4c5ccccc5n(-c5ccccc5)c4cc3B3c4c2cccc4-n2c4cc5c6ccccc6n(-c6ccccc6)c5cc4c4cccc3c42)c(-c2ccccc2)c1 ; CC(C)(C)c1cc2c3c(c1)-n1c4ccc(-c5ccccc5)cc4c4cc(-c5ccccc5)cc(c41)B3c1cc3c(cc1N2c1c(-c2cccc(-c4ccccc4)c2)cccc1-c1cccc(-c2ccccc2)c1)c1cc(-c2ccccc2)ccc1n3-c1ccccc1 ; CC(C)(C)c1cc(-c2cccc(-c3ccccc3)c2N2c3cc4c5cc(-c6ccccc6)ccc5n(-c5ccccc5)c4cc3B3c4c2cc(N(c2ccccc2)c2ccccc2)cc4-n2c4cc(-c5ccccc5)ccc4c4ccc(-c5ccccc5)c3c42)cc(C(C)(C)C)c1] 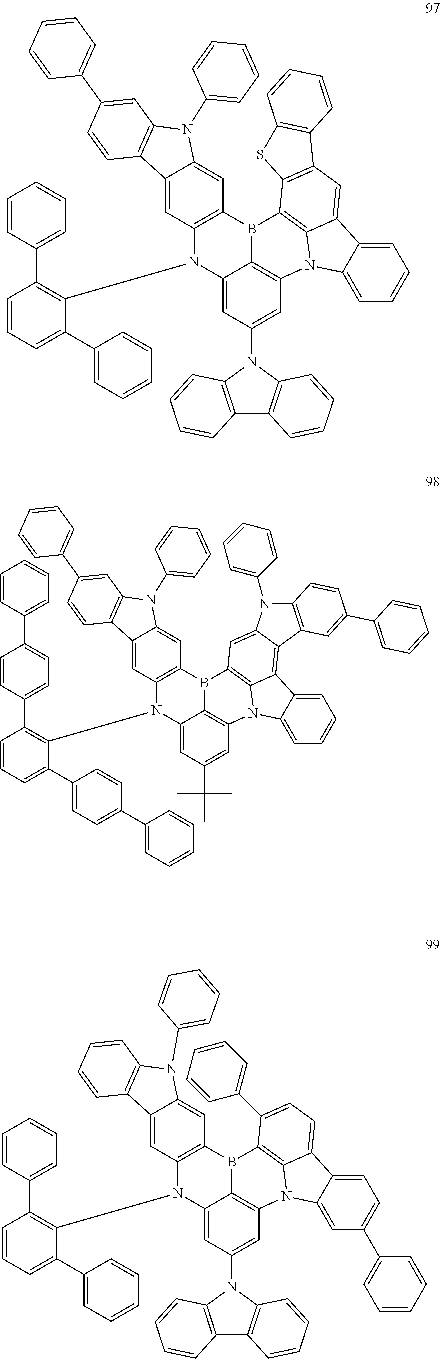 [SMILES: c1ccc(-c2ccc3c4cc5c(cc4n(-c4ccccc4)c3c2)B2c3c(cc(-n4c6ccccc6c6ccccc64)cc3-n3c4ccccc4c4cc6c(sc7ccccc76)c2c43)N5c2c(-c3ccccc3)cccc2-c2ccccc2)cc1 ; CC(C)(C)c1cc2c3c(c1)-n1c4ccccc4c4c5c6cc(-c7ccccc7)ccc6n(-c6ccccc6)c5cc(c41)B3c1cc3c(cc1N2c1c(-c2ccc(-c4ccccc4)cc2)cccc1-c1ccc(-c2ccccc2)cc1)c1ccc(-c2ccccc2)cc1n3-c1ccccc1 ; c1ccc(-c2ccc3c4ccc(-c5ccccc5)c5c4n(c3c2)-c2cc(-n3c4ccccc4c4ccccc43)cc3c2B5c2cc4c(cc2N3c2c(-c3ccccc3)cccc2-c2ccccc2)c2ccccc2n4-c2ccccc2)cc1] 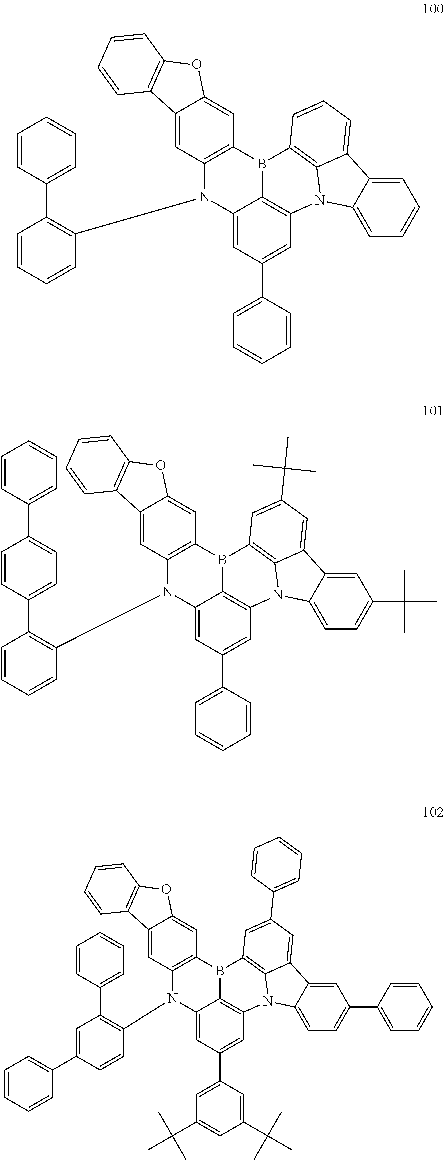 [SMILES: c1ccc(-c2cc3c4c(c2)-n2c5ccccc5c5cccc(c52)B4c2cc4oc5ccccc5c4cc2N3c2ccccc2-c2ccccc2)cc1 ; CC(C)(C)c1ccc2c(c1)c1cc(C(C)(C)C)cc3c1n2-c1cc(-c2ccccc2)cc2c1B3c1cc3oc4ccccc4c3cc1N2c1ccccc1-c1ccc(-c2ccccc2)cc1 ; CC(C)(C)c1cc(-c2cc3c4c(c2)-n2c5ccc(-c6ccccc6)cc5c5cc(-c6ccccc6)cc(c52)B4c2cc4oc5ccccc5c4cc2N3c2ccc(-c3ccccc3)cc2-c2ccccc2)cc(C(C)(C)C)c1] 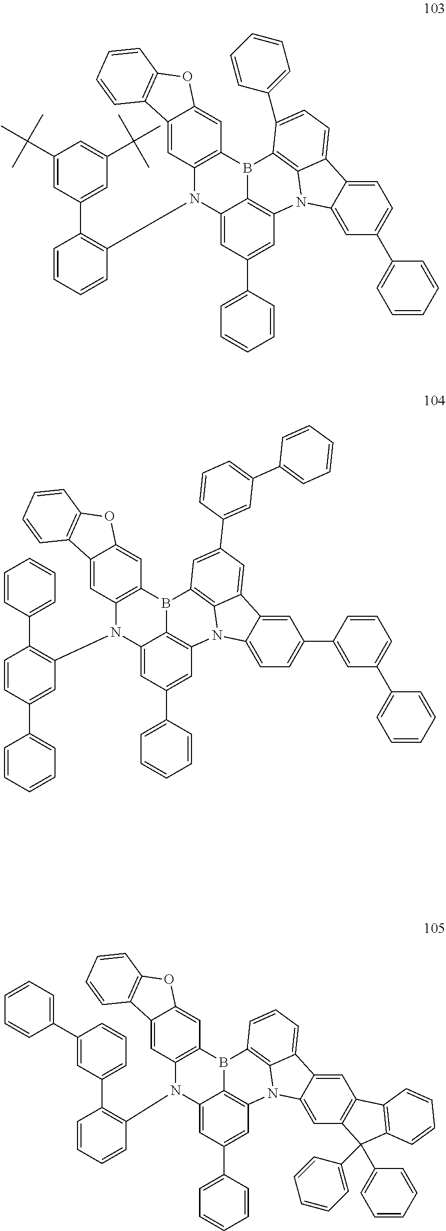 [SMILES: CC(C)(C)c1cc(-c2ccccc2N2c3cc4c(cc3B3c5c2cc(-c2ccccc2)cc5-n2c5cc(-c6ccccc6)ccc5c5ccc(-c6ccccc6)c3c52)oc2ccccc24)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5oc6ccccc6c5cc3N4c3cc(-c4ccccc4)ccc3-c3ccccc3)c2)cc1 ; c1ccc(-c2cccc(-c3ccccc3N3c4cc5c(cc4B4c6c3cc(-c3ccccc3)cc6-n3c6cc7c(cc6c6cccc4c63)-c3ccccc3C7(c3ccccc3)c3ccccc3)oc3ccccc35)c2)cc1] 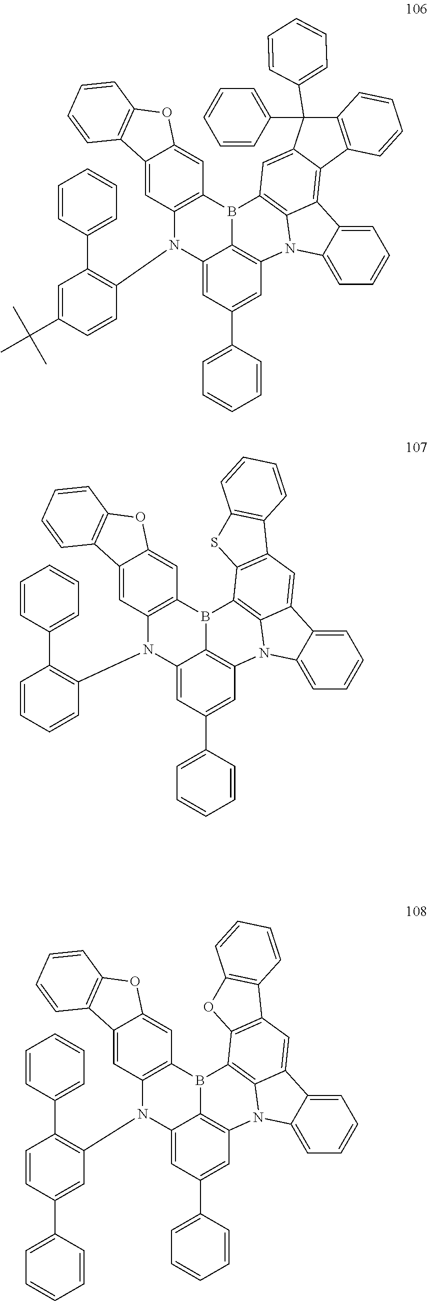 [SMILES: CC(C)(C)c1ccc(N2c3cc4c(cc3B3c5c2cc(-c2ccccc2)cc5-n2c5ccccc5c5c6c(cc3c52)C(c2ccccc2)(c2ccccc2)c2ccccc2-6)oc2ccccc24)c(-c2ccccc2)c1 ; c1ccc(-c2cc3c4c(c2)-n2c5ccccc5c5cc6c(sc7ccccc76)c(c52)B4c2cc4oc5ccccc5c4cc2N3c2ccccc2-c2ccccc2)cc1 ; c1ccc(-c2ccc(-c3ccccc3)c(N3c4cc5c(cc4B4c6c3cc(-c3ccccc3)cc6-n3c6ccccc6c6cc7c(oc8ccccc87)c4c63)oc3ccccc35)c2)cc1] 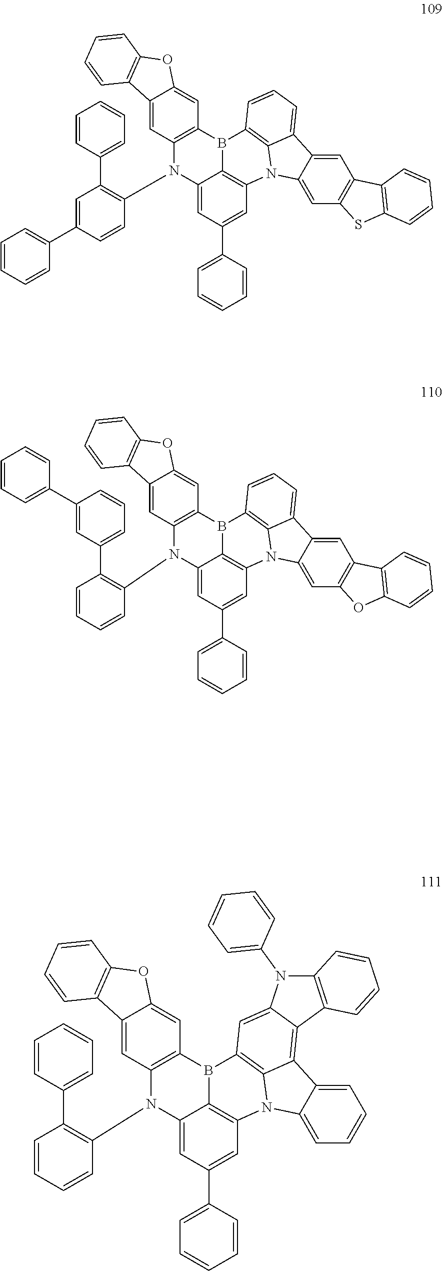 [SMILES: c1ccc(-c2ccc(N3c4cc5c(cc4B4c6c3cc(-c3ccccc3)cc6-n3c6cc7sc8ccccc8c7cc6c6cccc4c63)oc3ccccc35)c(-c3ccccc3)c2)cc1 ; c1ccc(-c2cccc(-c3ccccc3N3c4cc5c(cc4B4c6c3cc(-c3ccccc3)cc6-n3c6cc7oc8ccccc8c7cc6c6cccc4c63)oc3ccccc35)c2)cc1 ; c1ccc(-c2cc3c4c(c2)-n2c5ccccc5c5c6c7ccccc7n(-c7ccccc7)c6cc(c52)B4c2cc4oc5ccccc5c4cc2N3c2ccccc2-c2ccccc2)cc1] 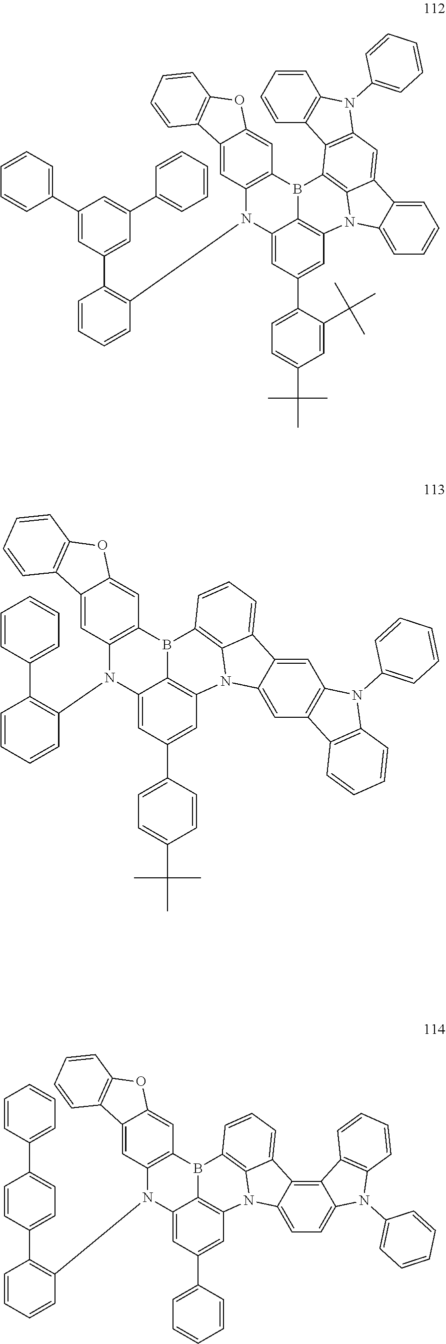 [SMILES: CC(C)(C)c1ccc(-c2cc3c4c(c2)-n2c5ccccc5c5cc6c(c(c52)B4c2cc4oc5ccccc5c4cc2N3c2ccccc2-c2cc(-c3ccccc3)cc(-c3ccccc3)c2)c2ccccc2n6-c2ccccc2)c(C(C)(C)C)c1 ; CC(C)(C)c1ccc(-c2cc3c4c(c2)-n2c5cc6c7ccccc7n(-c7ccccc7)c6cc5c5cccc(c52)B4c2cc4oc5ccccc5c4cc2N3c2ccccc2-c2ccccc2)cc1 ; c1ccc(-c2ccc(-c3ccccc3N3c4cc5c(cc4B4c6c3cc(-c3ccccc3)cc6-n3c6ccc7c(c8ccccc8n7-c7ccccc7)c6c6cccc4c63)oc3ccccc35)cc2)cc1] 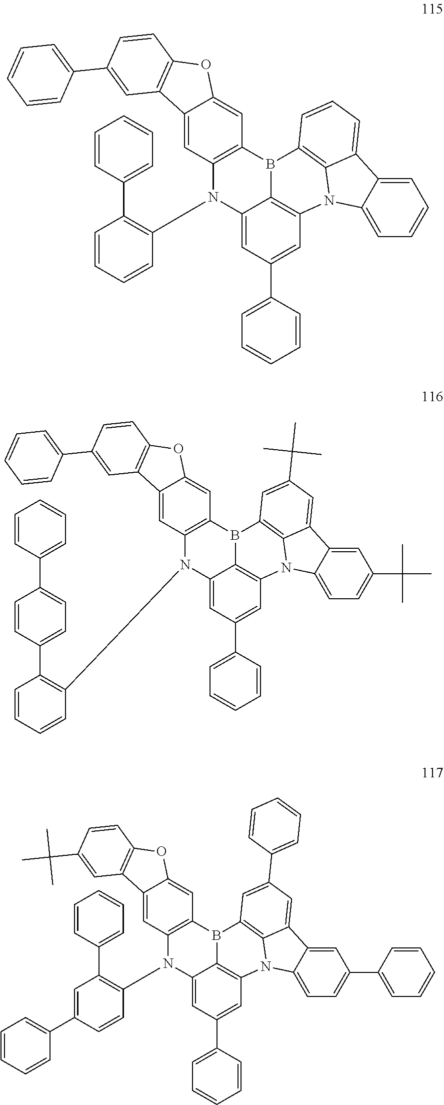 [SMILES: c1ccc(-c2cc3c4c(c2)-n2c5ccccc5c5cccc(c52)B4c2cc4oc5ccc(-c6ccccc6)cc5c4cc2N3c2ccccc2-c2ccccc2)cc1 ; CC(C)(C)c1ccc2c(c1)c1cc(C(C)(C)C)cc3c1n2-c1cc(-c2ccccc2)cc2c1B3c1cc3oc4ccc(-c5ccccc5)cc4c3cc1N2c1ccccc1-c1ccc(-c2ccccc2)cc1 ; CC(C)(C)c1ccc2oc3cc4c(cc3c2c1)N(c1ccc(-c2ccccc2)cc1-c1ccccc1)c1cc(-c2ccccc2)cc2c1B4c1cc(-c3ccccc3)cc3c4cc(-c5ccccc5)ccc4n-2c13] 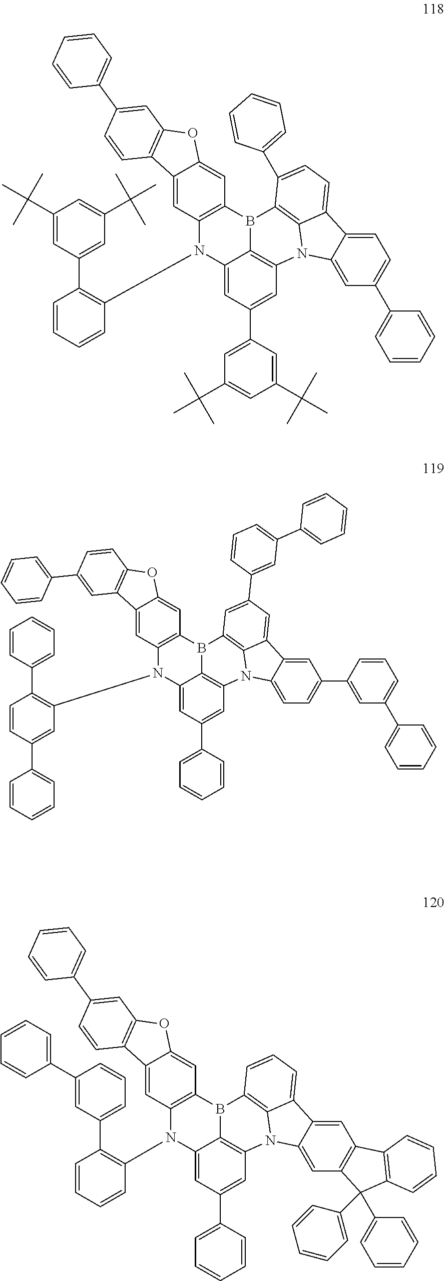 [SMILES: CC(C)(C)c1cc(-c2cc3c4c(c2)-n2c5cc(-c6ccccc6)ccc5c5ccc(-c6ccccc6)c(c52)B4c2cc4oc5cc(-c6ccccc6)ccc5c4cc2N3c2ccccc2-c2cc(C(C)(C)C)cc(C(C)(C)C)c2)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5oc6ccc(-c7ccccc7)cc6c5cc3N4c3cc(-c4ccccc4)ccc3-c3ccccc3)c2)cc1 ; c1ccc(-c2cccc(-c3ccccc3N3c4cc5c(cc4B4c6c3cc(-c3ccccc3)cc6-n3c6cc7c(cc6c6cccc4c63)-c3ccccc3C7(c3ccccc3)c3ccccc3)oc3cc(-c4ccccc4)ccc35)c2)cc1] 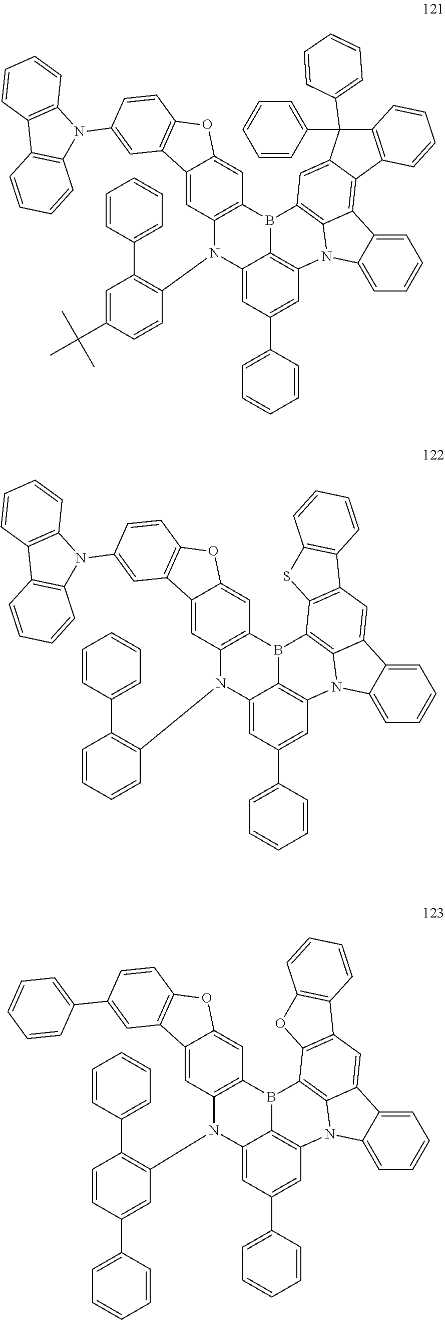 [SMILES: CC(C)(C)c1ccc(N2c3cc4c(cc3B3c5c2cc(-c2ccccc2)cc5-n2c5ccccc5c5c6c(cc3c52)C(c2ccccc2)(c2ccccc2)c2ccccc2-6)oc2ccc(-n3c5ccccc5c5ccccc53)cc24)c(-c2ccccc2)c1 ; c1ccc(-c2cc3c4c(c2)-n2c5ccccc5c5cc6c(sc7ccccc76)c(c52)B4c2cc4oc5ccc(-n6c7ccccc7c7ccccc76)cc5c4cc2N3c2ccccc2-c2ccccc2)cc1 ; c1ccc(-c2ccc(-c3ccccc3)c(N3c4cc5c(cc4B4c6c3cc(-c3ccccc3)cc6-n3c6ccccc6c6cc7c(oc8ccccc87)c4c63)oc3ccc(-c4ccccc4)cc35)c2)cc1] 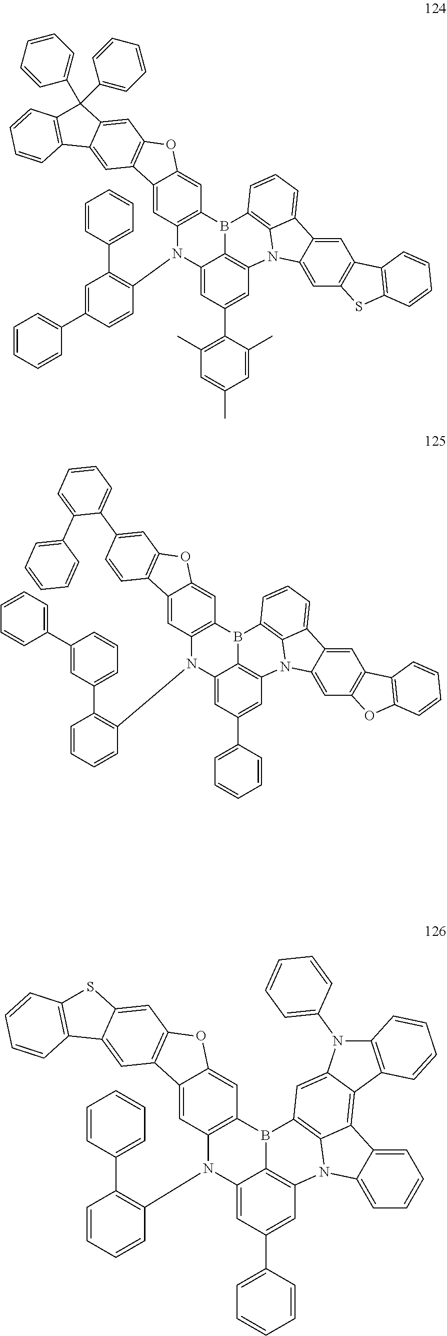 [SMILES: Cc1cc(C)c(-c2cc3c4c(c2)-n2c5cc6sc7ccccc7c6cc5c5cccc(c52)B4c2cc4oc5cc6c(cc5c4cc2N3c2ccc(-c3ccccc3)cc2-c2ccccc2)-c2ccccc2C6(c2ccccc2)c2ccccc2)c(C)c1 ; c1ccc(-c2cccc(-c3ccccc3N3c4cc5c(cc4B4c6c3cc(-c3ccccc3)cc6-n3c6cc7oc8ccccc8c7cc6c6cccc4c63)oc3cc(-c4ccccc4-c4ccccc4)ccc35)c2)cc1 ; c1ccc(-c2cc3c4c(c2)-n2c5ccccc5c5c6c7ccccc7n(-c7ccccc7)c6cc(c52)B4c2cc4oc5cc6sc7ccccc7c6cc5c4cc2N3c2ccccc2-c2ccccc2)cc1] 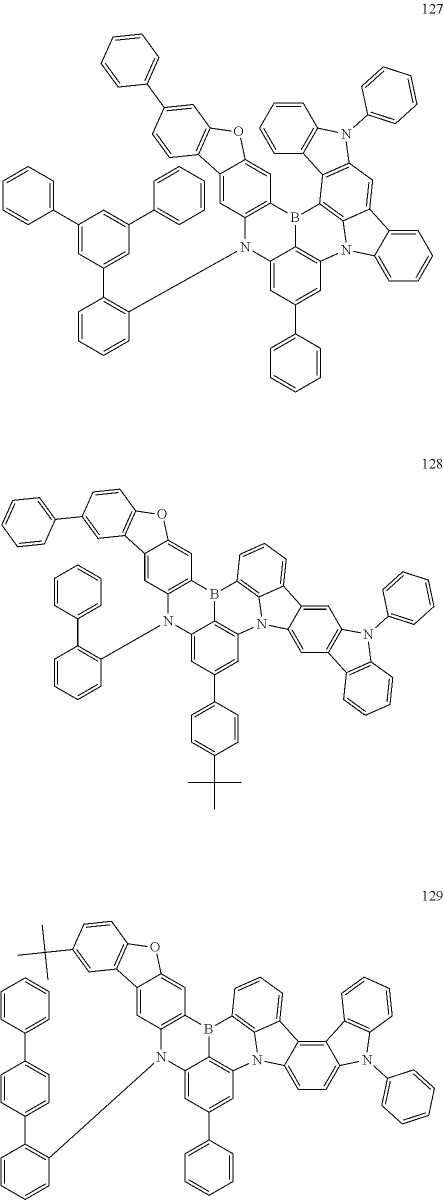 [SMILES: c1ccc(-c2cc(-c3ccccc3)cc(-c3ccccc3N3c4cc5c(cc4B4c6c3cc(-c3ccccc3)cc6-n3c6ccccc6c6cc7c(c4c63)c3ccccc3n7-c3ccccc3)oc3cc(-c4ccccc4)ccc35)c2)cc1 ; CC(C)(C)c1ccc(-c2cc3c4c(c2)-n2c5cc6c7ccccc7n(-c7ccccc7)c6cc5c5cccc(c52)B4c2cc4oc5ccc(-c6ccccc6)cc5c4cc2N3c2ccccc2-c2ccccc2)cc1 ; CC(C)(C)c1ccc2oc3cc4c(cc3c2c1)N(c1ccccc1-c1ccc(-c2ccccc2)cc1)c1cc(-c2ccccc2)cc2c1B4c1cccc3c4c5c6ccccc6n(-c6ccccc6)c5ccc4n-2c13] 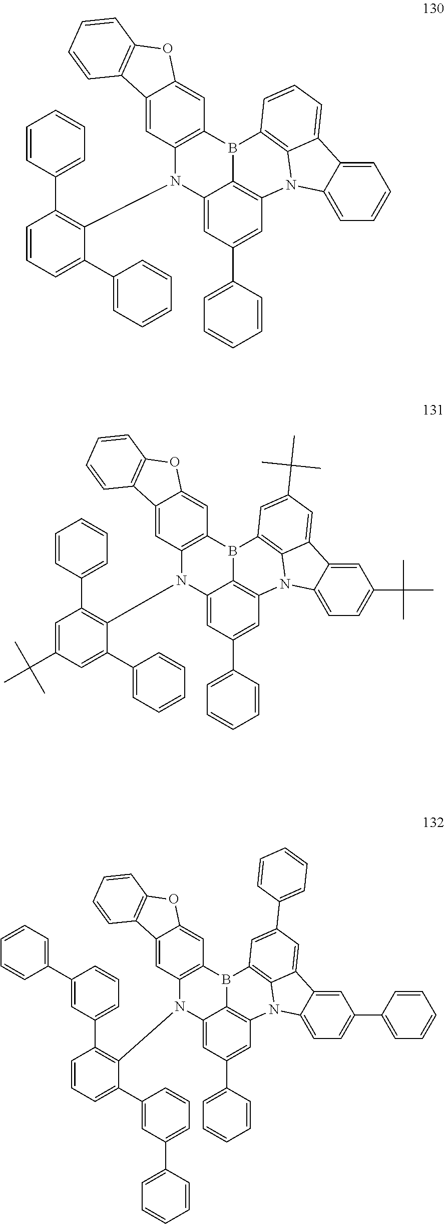 [SMILES: c1ccc(-c2cc3c4c(c2)-n2c5ccccc5c5cccc(c52)B4c2cc4oc5ccccc5c4cc2N3c2c(-c3ccccc3)cccc2-c2ccccc2)cc1 ; CC(C)(C)c1cc(-c2ccccc2)c(N2c3cc4c(cc3B3c5c2cc(-c2ccccc2)cc5-n2c5ccc(C(C)(C)C)cc5c5cc(C(C)(C)C)cc3c52)oc2ccccc24)c(-c2ccccc2)c1 ; c1ccc(-c2cccc(-c3cccc(-c4cccc(-c5ccccc5)c4)c3N3c4cc5c(cc4B4c6c3cc(-c3ccccc3)cc6-n3c6ccc(-c7ccccc7)cc6c6cc(-c7ccccc7)cc4c63)oc3ccccc35)c2)cc1] 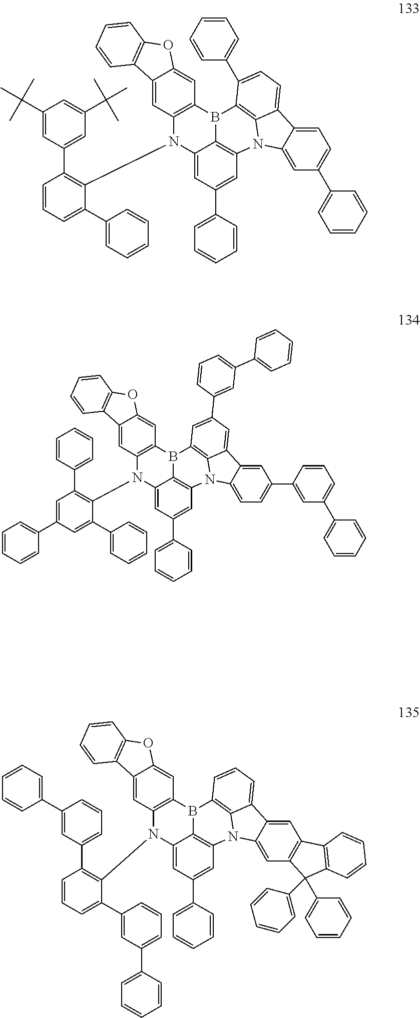 [SMILES: CC(C)(C)c1cc(-c2cccc(-c3ccccc3)c2N2c3cc4c(cc3B3c5c2cc(-c2ccccc2)cc5-n2c5cc(-c6ccccc6)ccc5c5ccc(-c6ccccc6)c3c52)oc2ccccc24)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5oc6ccccc6c5cc3N4c3c(-c4ccccc4)cc(-c4ccccc4)cc3-c3ccccc3)c2)cc1 ; c1ccc(-c2cccc(-c3cccc(-c4cccc(-c5ccccc5)c4)c3N3c4cc5c(cc4B4c6c3cc(-c3ccccc3)cc6-n3c6cc7c(cc6c6cccc4c63)-c3ccccc3C7(c3ccccc3)c3ccccc3)oc3ccccc35)c2)cc1] 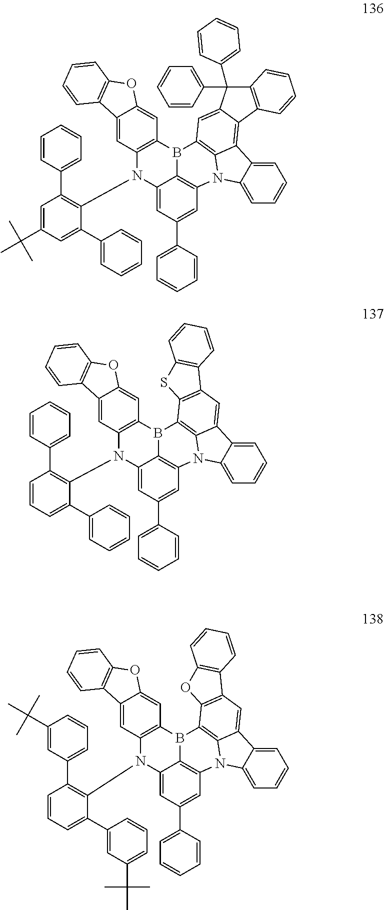 [SMILES: CC(C)(C)c1cc(-c2ccccc2)c(N2c3cc4c(cc3B3c5c2cc(-c2ccccc2)cc5-n2c5ccccc5c5c6c(cc3c52)C(c2ccccc2)(c2ccccc2)c2ccccc2-6)oc2ccccc24)c(-c2ccccc2)c1 ; c1ccc(-c2cc3c4c(c2)-n2c5ccccc5c5cc6c(sc7ccccc76)c(c52)B4c2cc4oc5ccccc5c4cc2N3c2c(-c3ccccc3)cccc2-c2ccccc2)cc1 ; CC(C)(C)c1cccc(-c2cccc(-c3cccc(C(C)(C)C)c3)c2N2c3cc4c(cc3B3c5c2cc(-c2ccccc2)cc5-n2c5ccccc5c5cc6c(oc7ccccc76)c3c52)oc2ccccc24)c1] 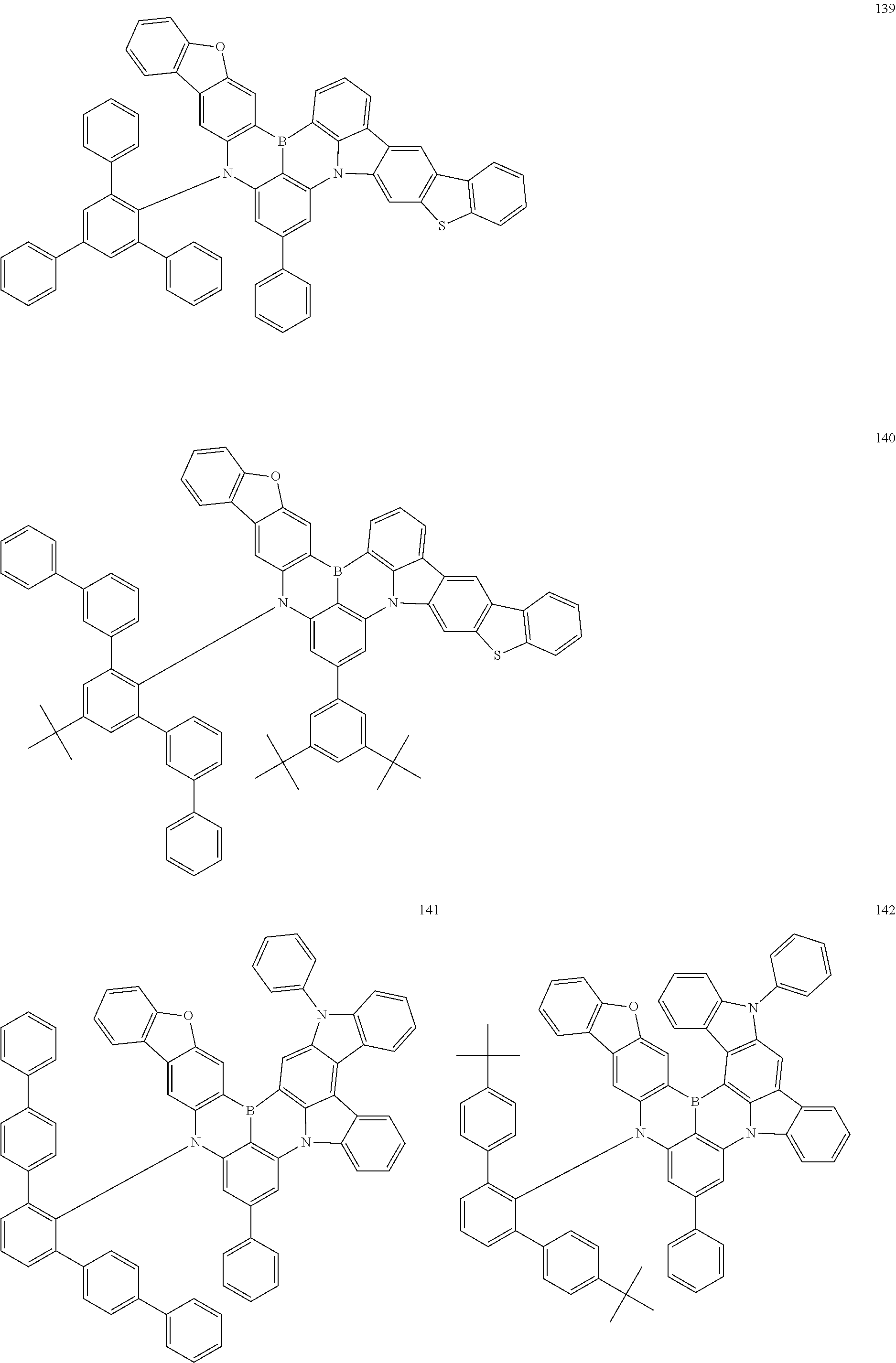 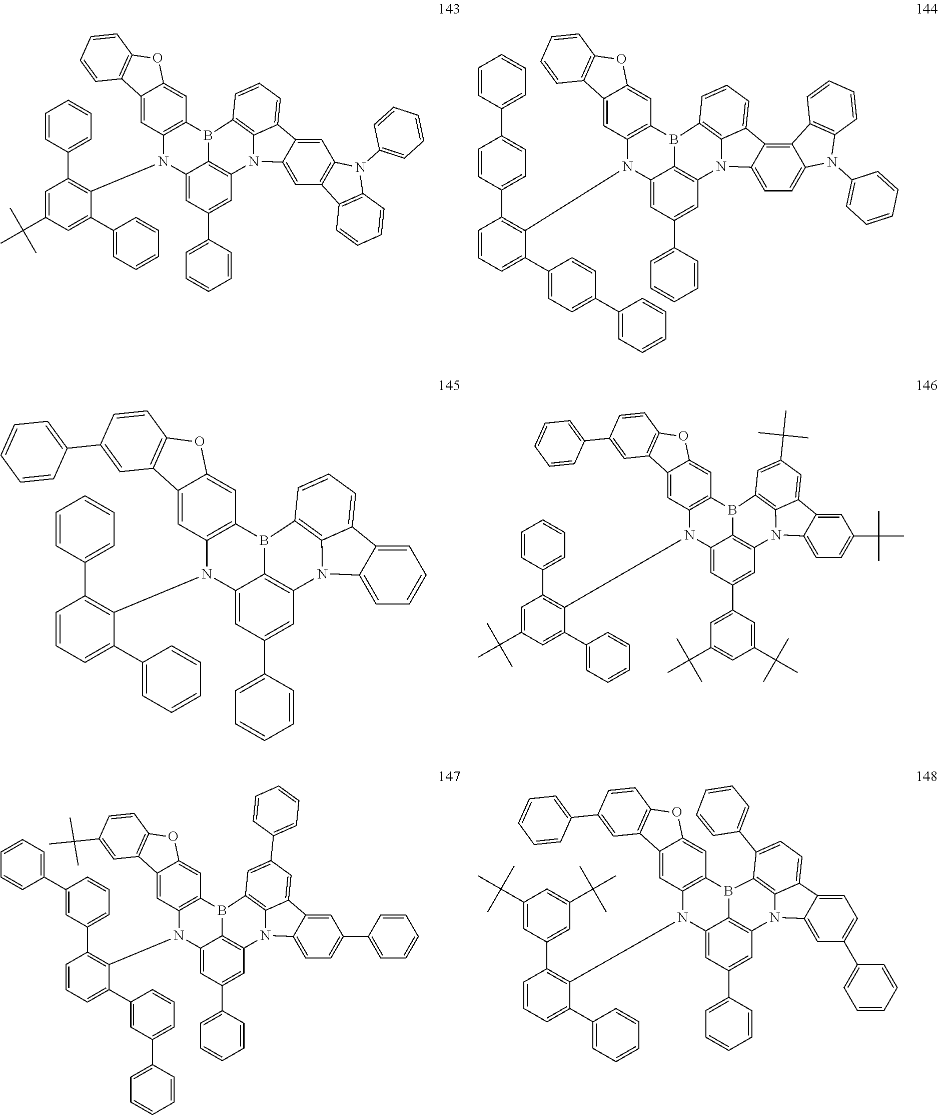 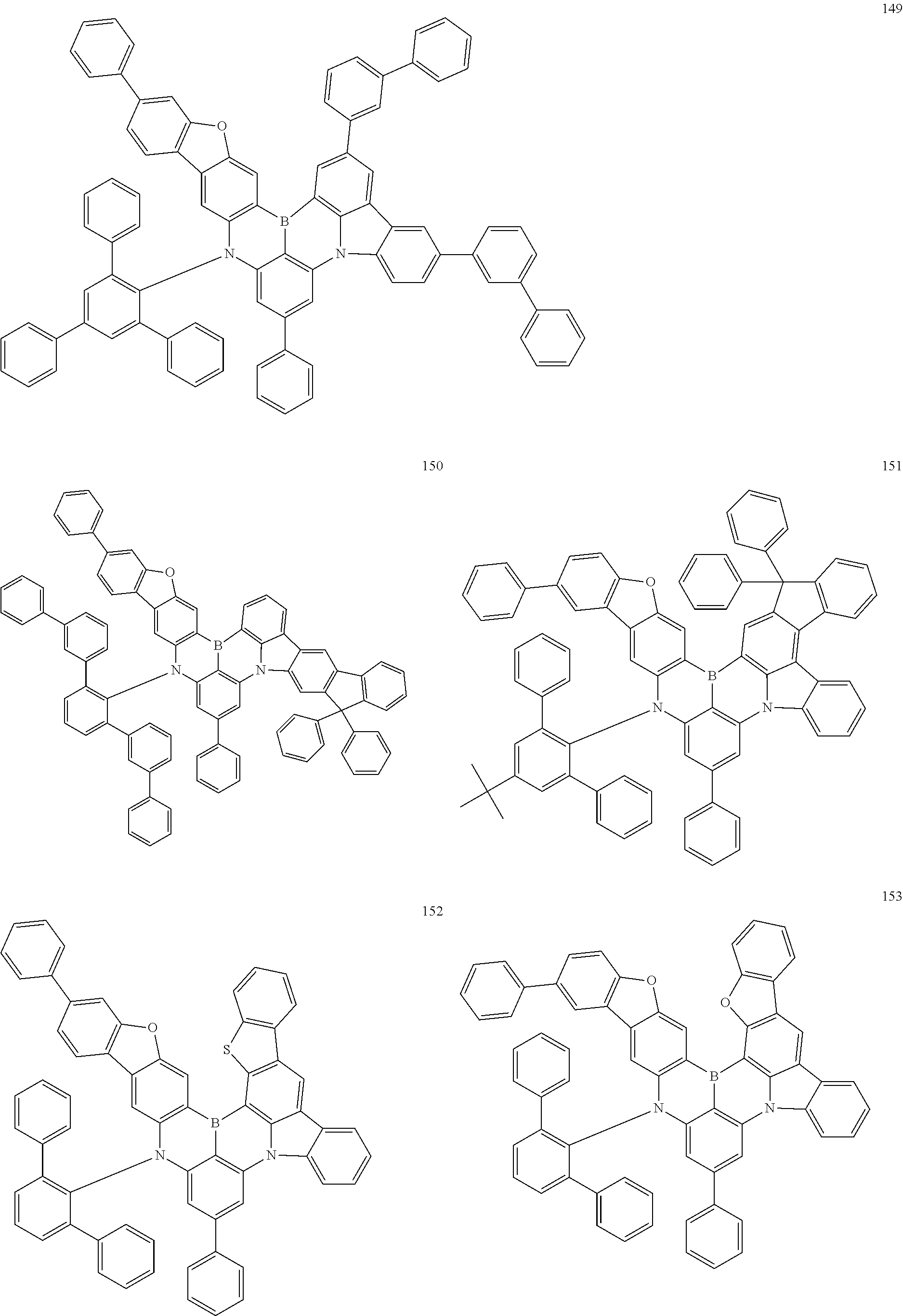 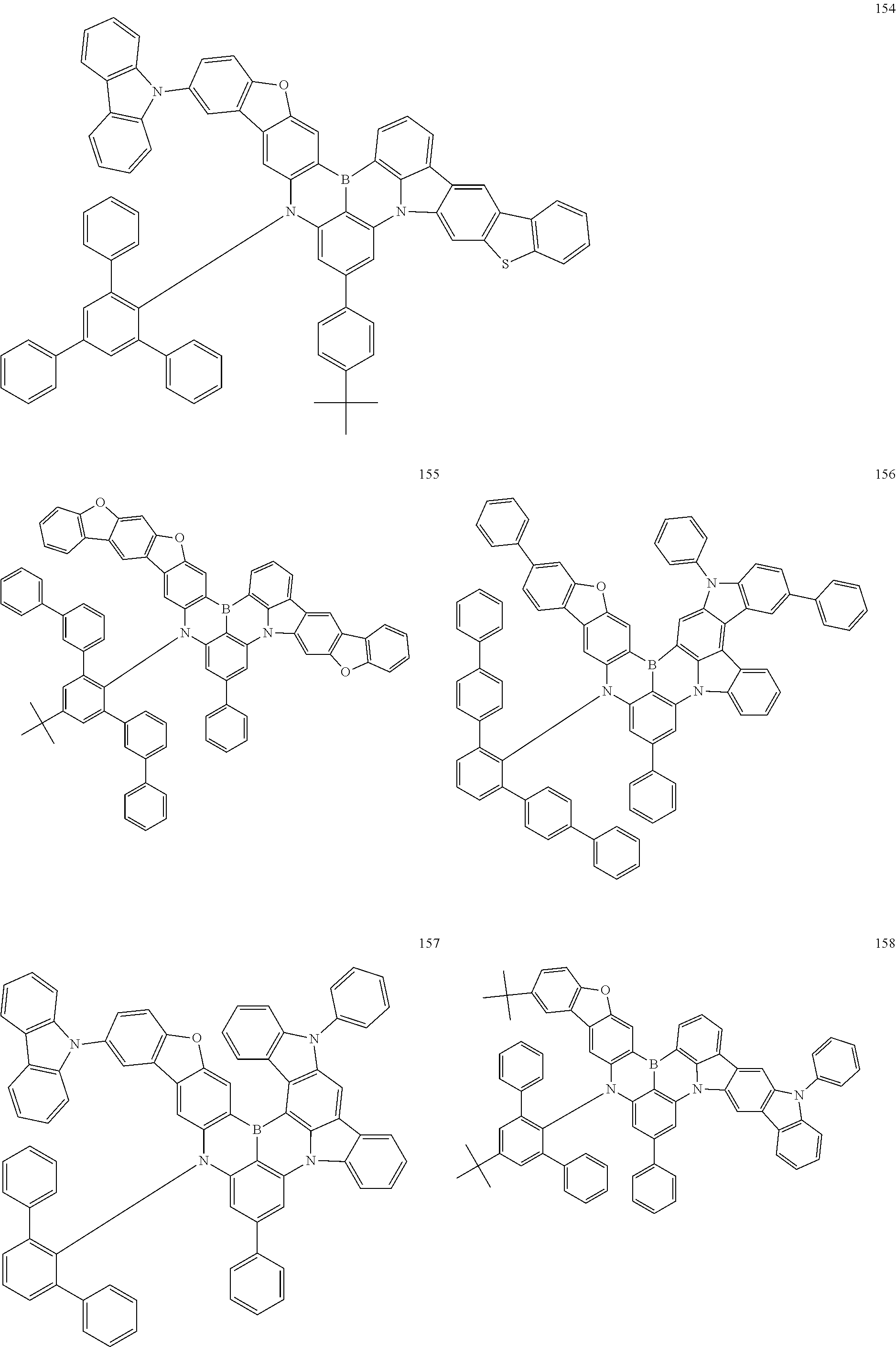 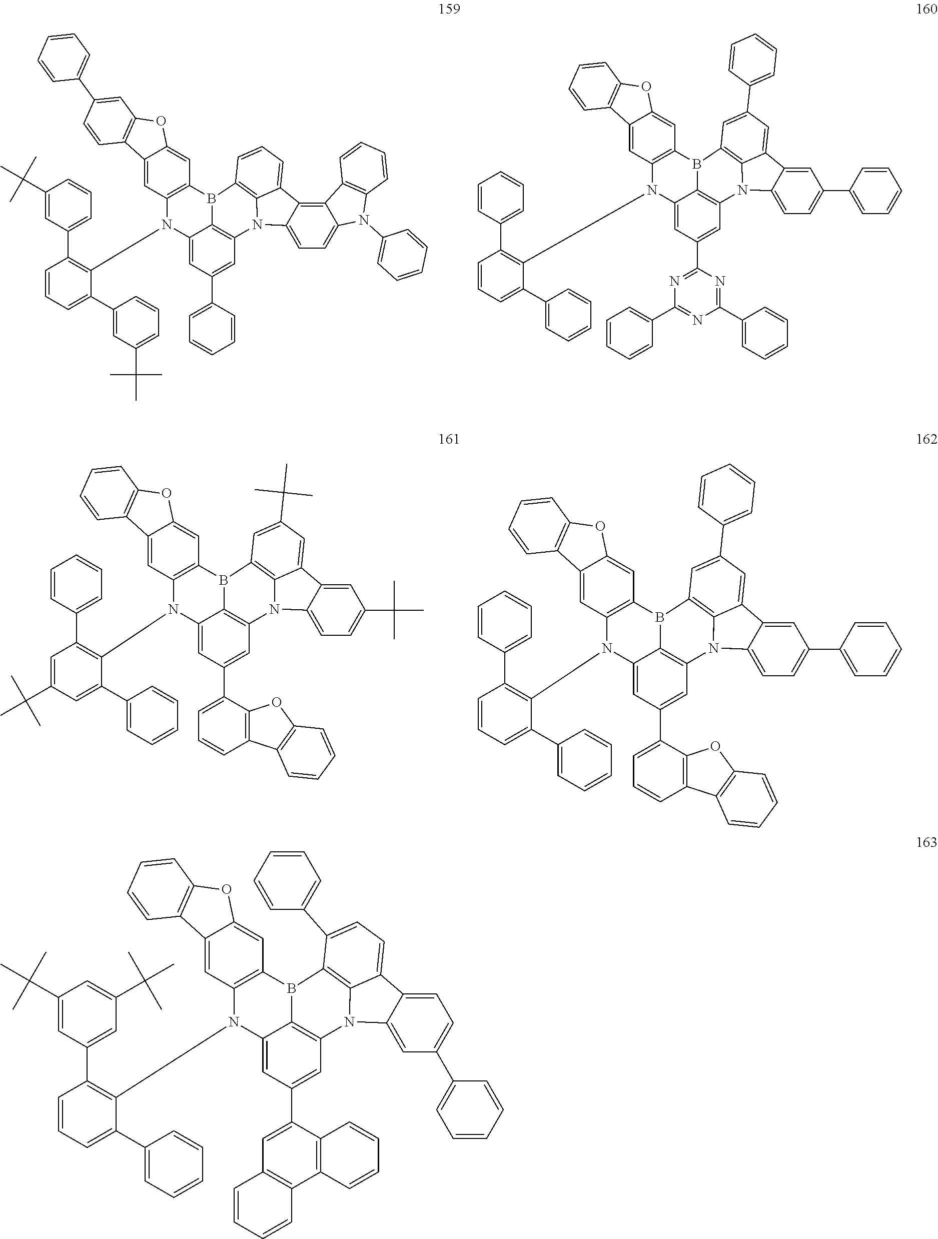 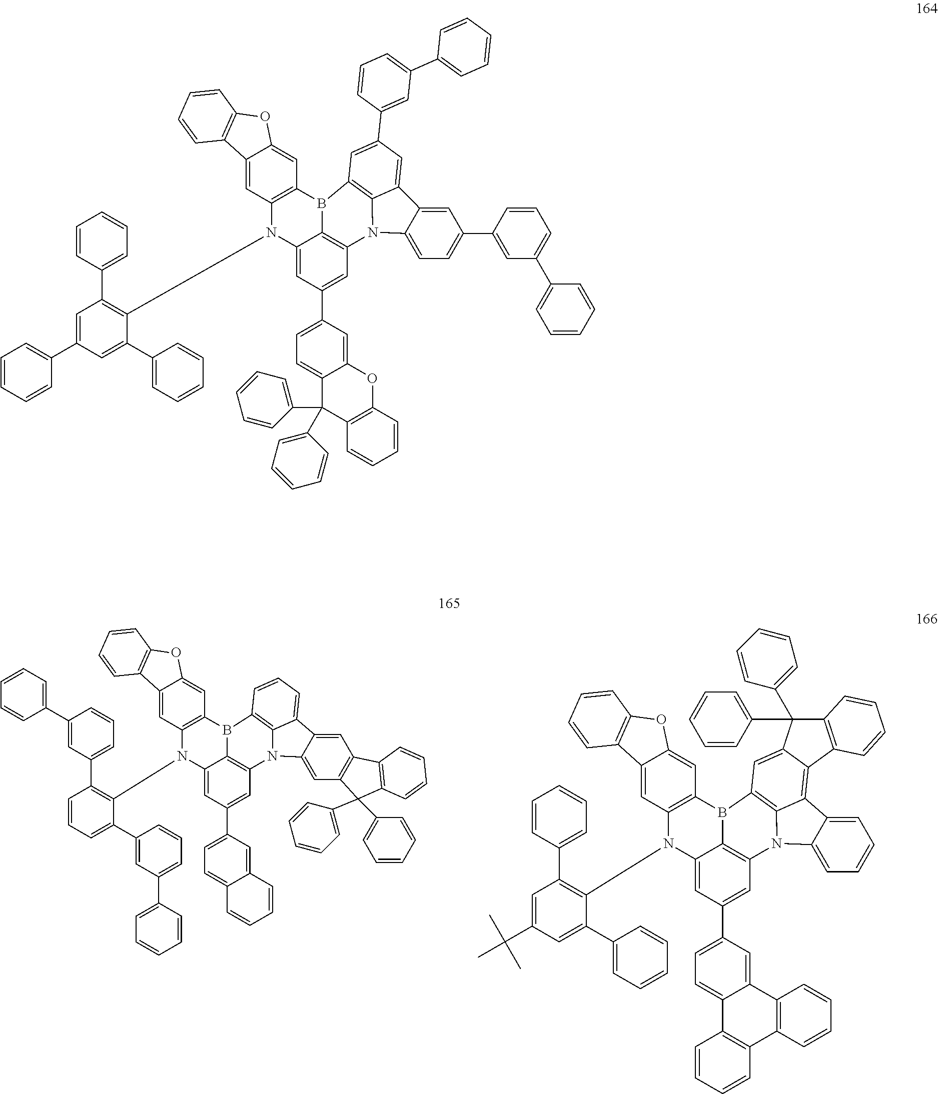 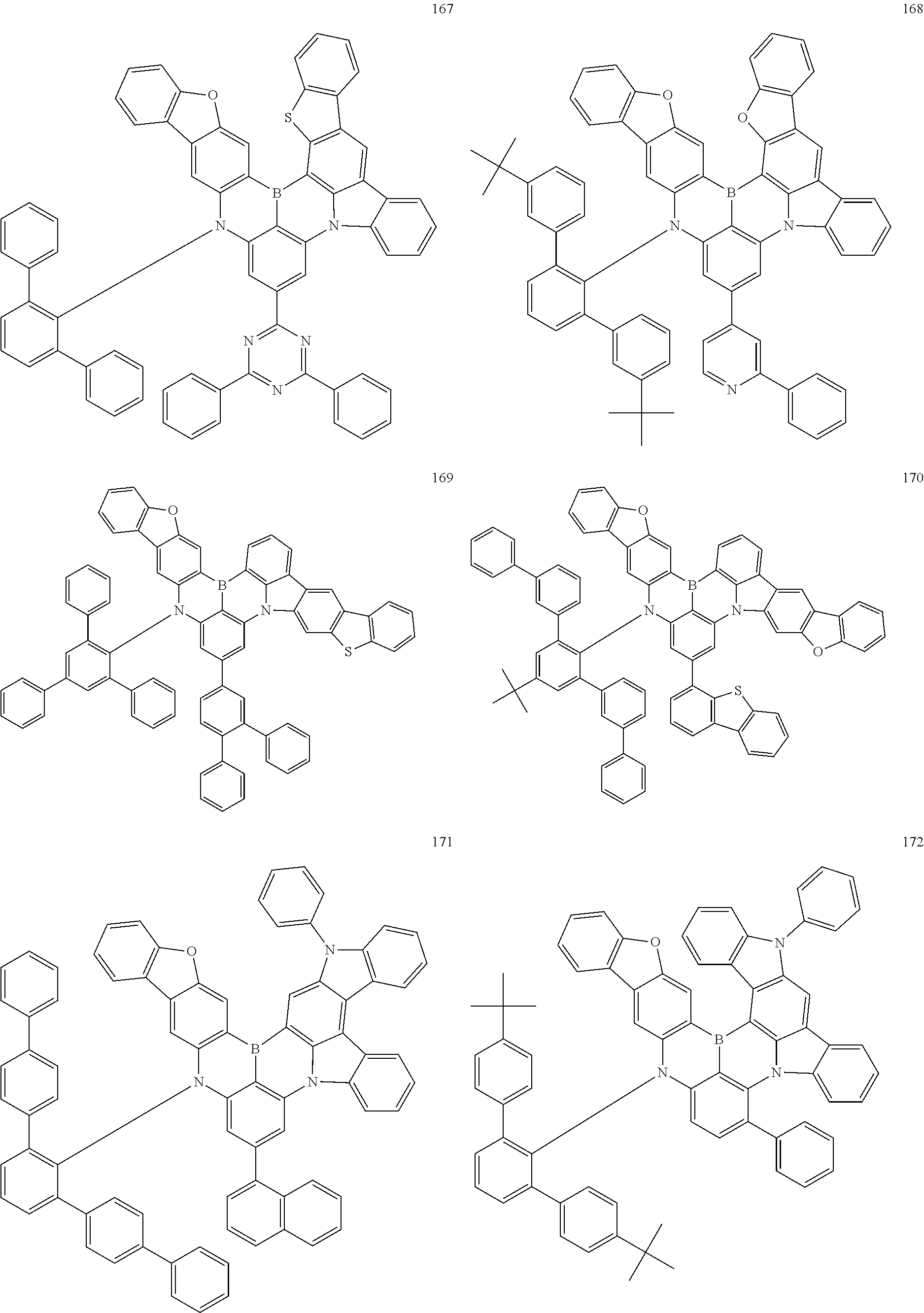 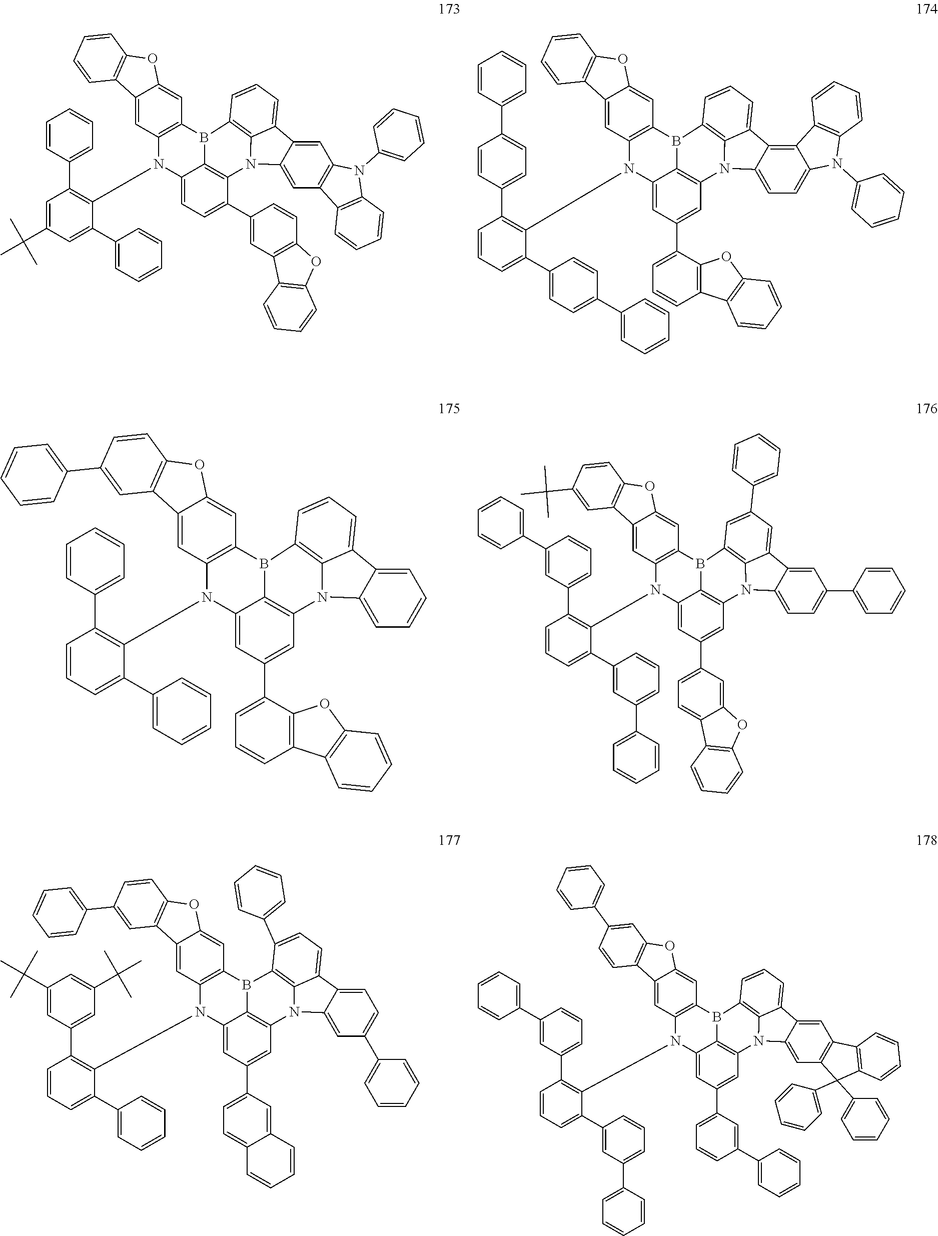 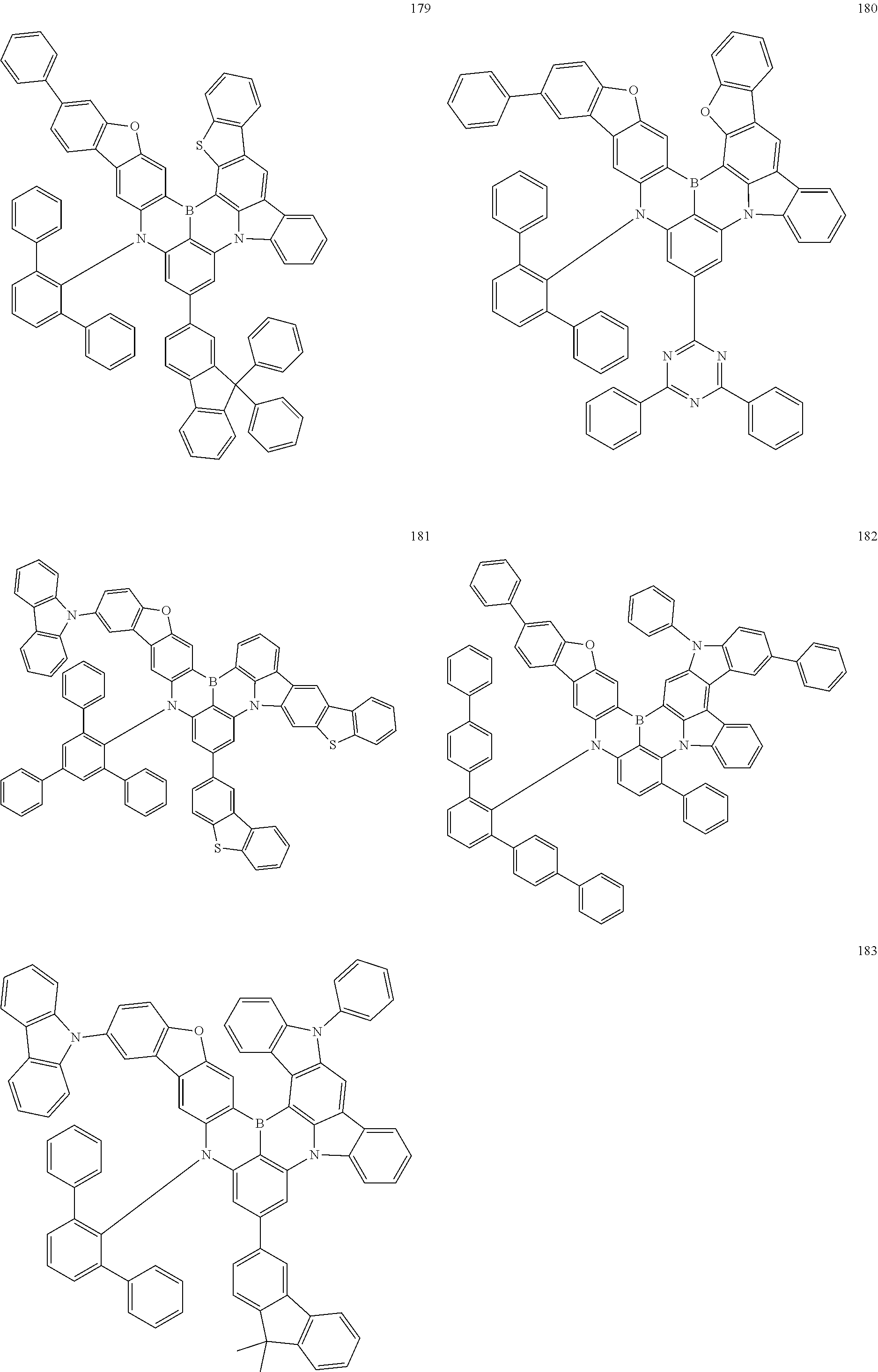 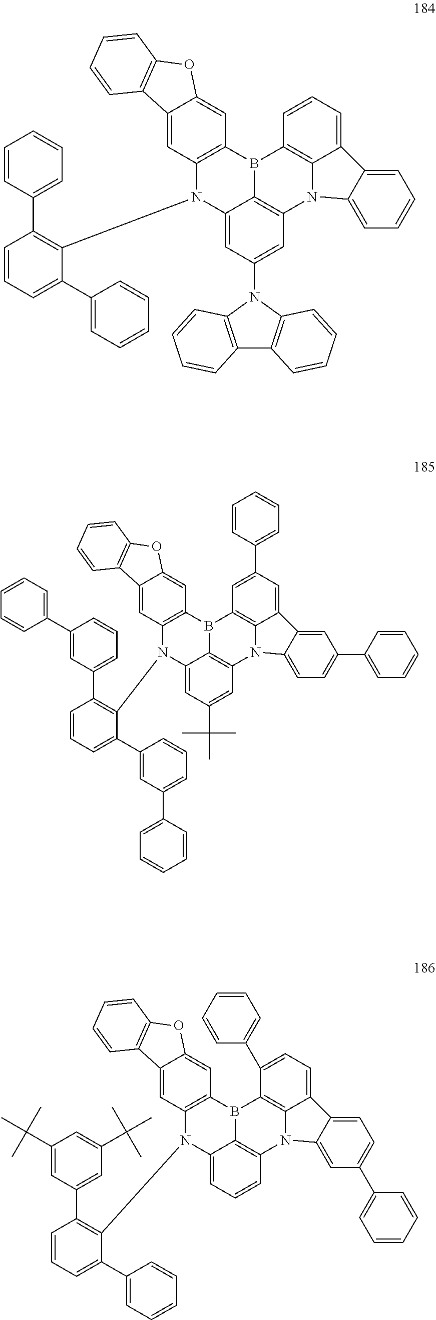 [SMILES: c1ccc(-c2cccc(-c3ccccc3)c2N2c3cc4c(cc3B3c5c2cc(-n2c6ccccc6c6ccccc62)cc5-n2c5ccccc5c5cccc3c52)oc2ccccc24)cc1 ; CC(C)(C)c1cc2c3c(c1)-n1c4ccc(-c5ccccc5)cc4c4cc(-c5ccccc5)cc(c41)B3c1cc3oc4ccccc4c3cc1N2c1c(-c2cccc(-c3ccccc3)c2)cccc1-c1cccc(-c2ccccc2)c1 ; CC(C)(C)c1cc(-c2cccc(-c3ccccc3)c2N2c3cc4c(cc3B3c5c2cccc5-n2c5cc(-c6ccccc6)ccc5c5ccc(-c6ccccc6)c3c52)oc2ccccc24)cc(C(C)(C)C)c1] 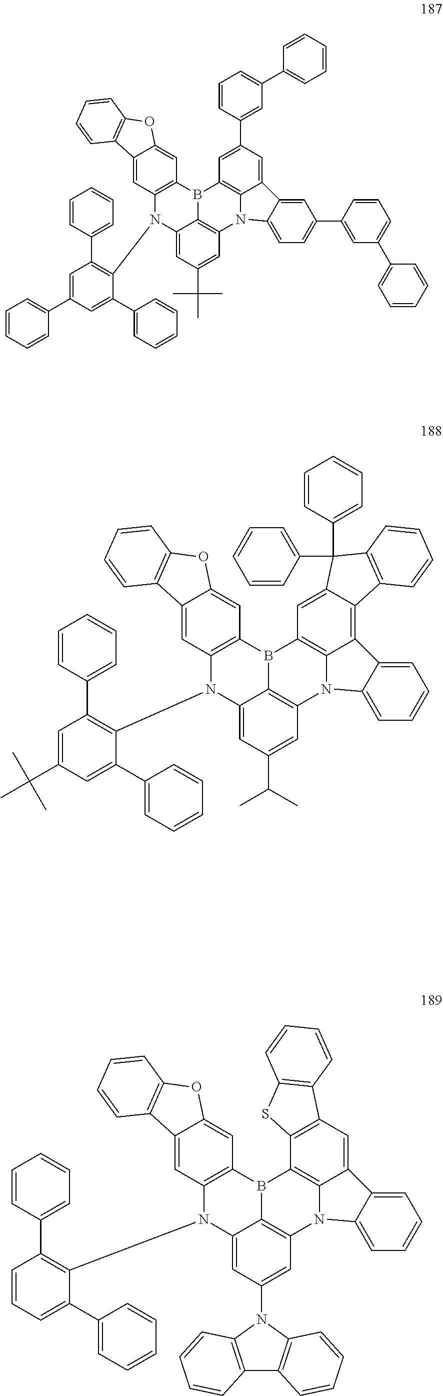 [SMILES: CC(C)(C)c1cc2c3c(c1)-n1c4ccc(-c5cccc(-c6ccccc6)c5)cc4c4cc(-c5cccc(-c6ccccc6)c5)cc(c41)B3c1cc3oc4ccccc4c3cc1N2c1c(-c2ccccc2)cc(-c2ccccc2)cc1-c1ccccc1 ; CC(C)c1cc2c3c(c1)-n1c4ccccc4c4c5c(cc(c41)B3c1cc3oc4ccccc4c3cc1N2c1c(-c2ccccc2)cc(C(C)(C)C)cc1-c1ccccc1)C(c1ccccc1)(c1ccccc1)c1ccccc1-5 ; c1ccc(-c2cccc(-c3ccccc3)c2N2c3cc4c(cc3B3c5c2cc(-n2c6ccccc6c6ccccc62)cc5-n2c5ccccc5c5cc6c(sc7ccccc76)c3c52)oc2ccccc24)cc1] 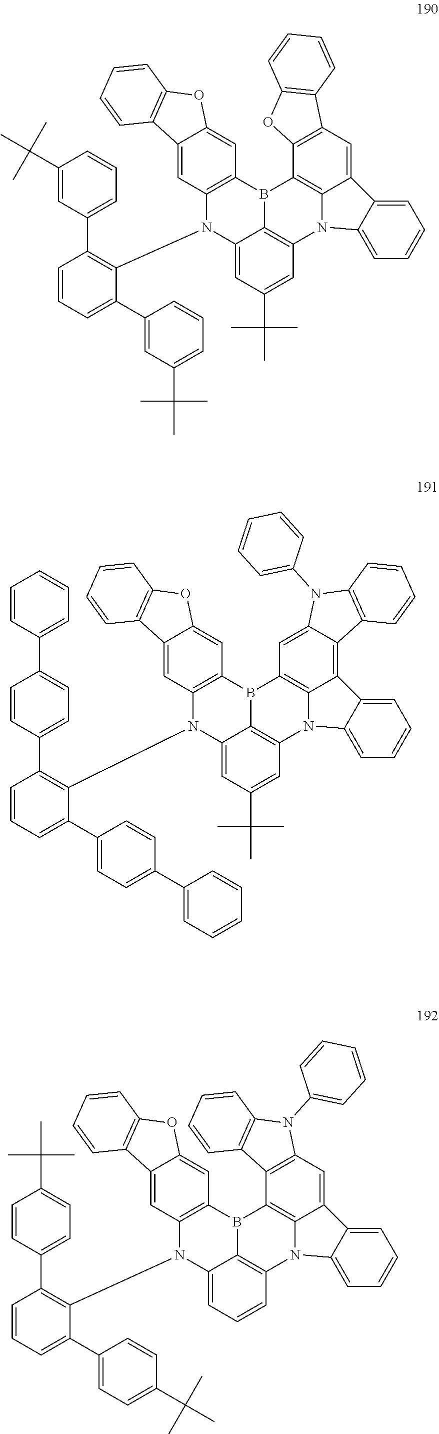 [SMILES: CC(C)(C)c1cccc(-c2cccc(-c3cccc(C(C)(C)C)c3)c2N2c3cc4c(cc3B3c5c2cc(C(C)(C)C)cc5-n2c5ccccc5c5cc6c(oc7ccccc76)c3c52)oc2ccccc24)c1 ; CC(C)(C)c1cc2c3c(c1)-n1c4ccccc4c4c5c6ccccc6n(-c6ccccc6)c5cc(c41)B3c1cc3oc4ccccc4c3cc1N2c1c(-c2ccc(-c3ccccc3)cc2)cccc1-c1ccc(-c2ccccc2)cc1 ; CC(C)(C)c1ccc(-c2cccc(-c3ccc(C(C)(C)C)cc3)c2N2c3cc4c(cc3B3c5c2cccc5-n2c5ccccc5c5cc6c(c3c52)c2ccccc2n6-c2ccccc2)oc2ccccc24)cc1] 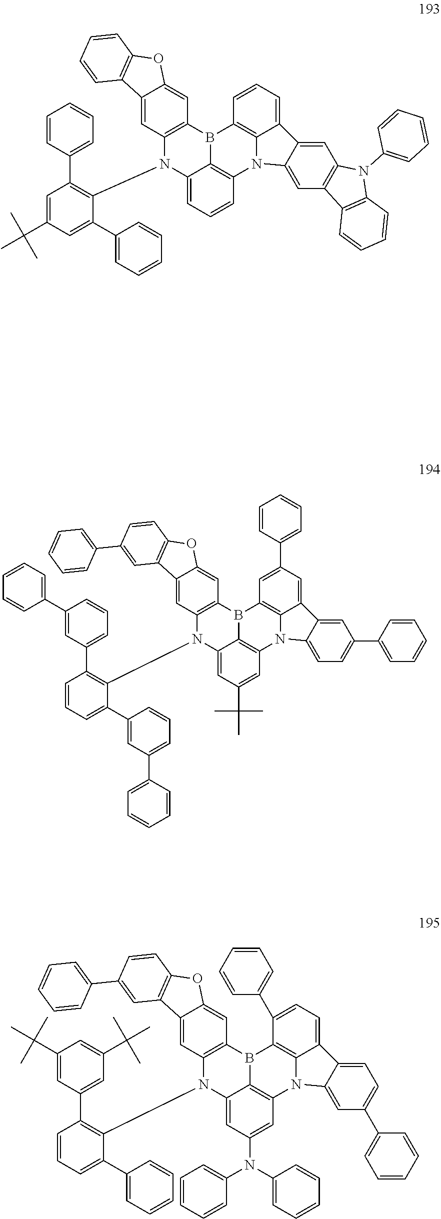 [SMILES: CC(C)(C)c1cc(-c2ccccc2)c(N2c3cc4c(cc3B3c5c2cccc5-n2c5cc6c7ccccc7n(-c7ccccc7)c6cc5c5cccc3c52)oc2ccccc24)c(-c2ccccc2)c1 ; CC(C)(C)c1cc2c3c(c1)-n1c4ccc(-c5ccccc5)cc4c4cc(-c5ccccc5)cc(c41)B3c1cc3oc4ccc(-c5ccccc5)cc4c3cc1N2c1c(-c2cccc(-c3ccccc3)c2)cccc1-c1cccc(-c2ccccc2)c1 ; CC(C)(C)c1cc(-c2cccc(-c3ccccc3)c2N2c3cc4c(cc3B3c5c2cc(N(c2ccccc2)c2ccccc2)cc5-n2c5cc(-c6ccccc6)ccc5c5ccc(-c6ccccc6)c3c52)oc2ccc(-c3ccccc3)cc24)cc(C(C)(C)C)c1] 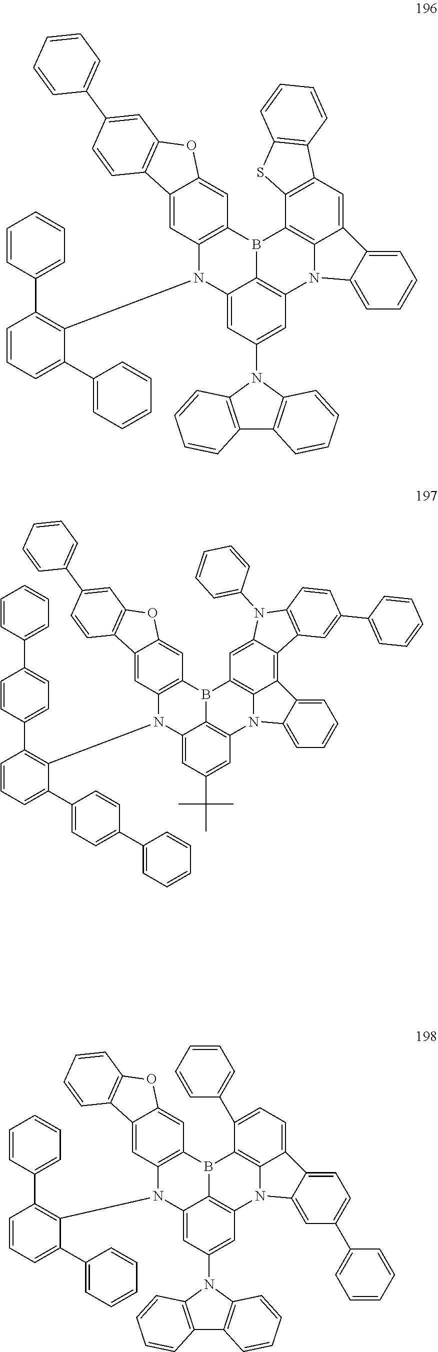 [SMILES: c1ccc(-c2ccc3c(c2)oc2cc4c(cc23)N(c2c(-c3ccccc3)cccc2-c2ccccc2)c2cc(-n3c5ccccc5c5ccccc53)cc3c2B4c2c4sc5ccccc5c4cc4c5ccccc5n-3c24)cc1 ; CC(C)(C)c1cc2c3c(c1)-n1c4ccccc4c4c5c6cc(-c7ccccc7)ccc6n(-c6ccccc6)c5cc(c41)B3c1cc3oc4cc(-c5ccccc5)ccc4c3cc1N2c1c(-c2ccc(-c3ccccc3)cc2)cccc1-c1ccc(-c2ccccc2)cc1 ; c1ccc(-c2ccc3c4ccc(-c5ccccc5)c5c4n(c3c2)-c2cc(-n3c4ccccc4c4ccccc43)cc3c2B5c2cc4oc5ccccc5c4cc2N3c2c(-c3ccccc3)cccc2-c2ccccc2)cc1] 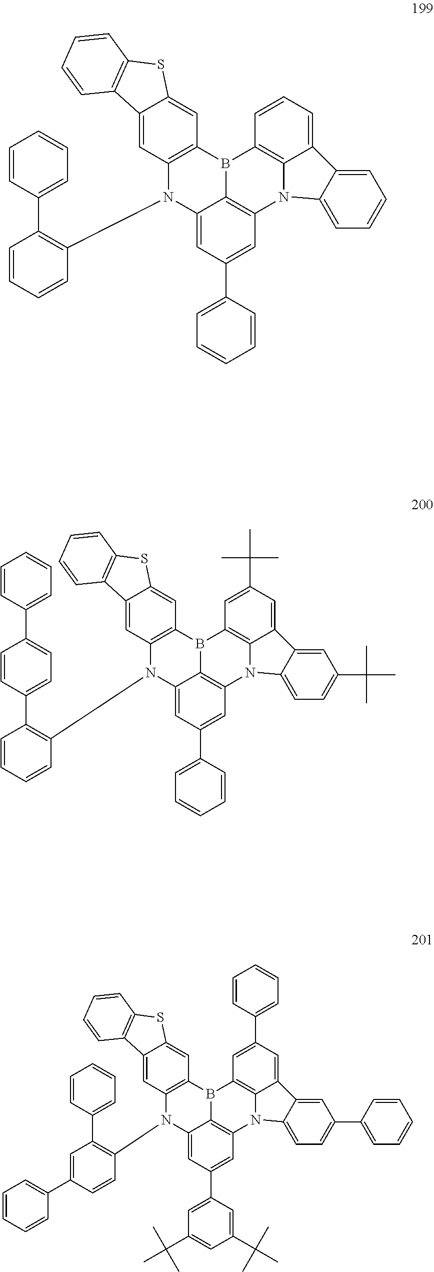 [SMILES: c1ccc(-c2cc3c4c(c2)-n2c5ccccc5c5cccc(c52)B4c2cc4sc5ccccc5c4cc2N3c2ccccc2-c2ccccc2)cc1 ; CC(C)(C)c1ccc2c(c1)c1cc(C(C)(C)C)cc3c1n2-c1cc(-c2ccccc2)cc2c1B3c1cc3sc4ccccc4c3cc1N2c1ccccc1-c1ccc(-c2ccccc2)cc1 ; CC(C)(C)c1cc(-c2cc3c4c(c2)-n2c5ccc(-c6ccccc6)cc5c5cc(-c6ccccc6)cc(c52)B4c2cc4sc5ccccc5c4cc2N3c2ccc(-c3ccccc3)cc2-c2ccccc2)cc(C(C)(C)C)c1] 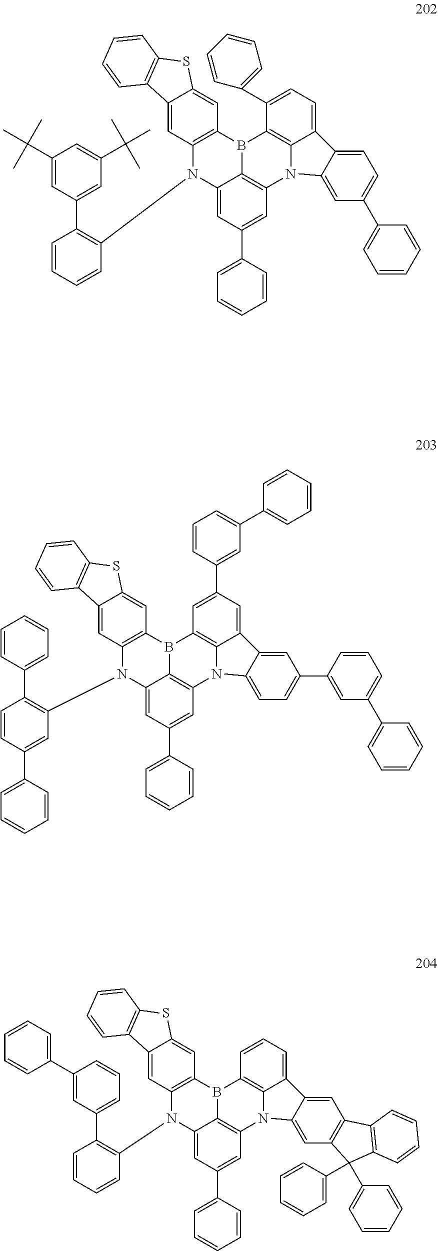 [SMILES: CC(C)(C)c1cc(-c2ccccc2N2c3cc4c(cc3B3c5c2cc(-c2ccccc2)cc5-n2c5cc(-c6ccccc6)ccc5c5ccc(-c6ccccc6)c3c52)sc2ccccc24)cc(C(C)(C)C)c1 ; c1ccc(-c2cccc(-c3ccc4c(c3)c3cc(-c5cccc(-c6ccccc6)c5)cc5c3n4-c3cc(-c4ccccc4)cc4c3B5c3cc5sc6ccccc6c5cc3N4c3cc(-c4ccccc4)ccc3-c3ccccc3)c2)cc1 ; c1ccc(-c2cccc(-c3ccccc3N3c4cc5c(cc4B4c6c3cc(-c3ccccc3)cc6-n3c6cc7c(cc6c6cccc4c63)-c3ccccc3C7(c3ccccc3)c3ccccc3)sc3ccccc35)c2)cc1] 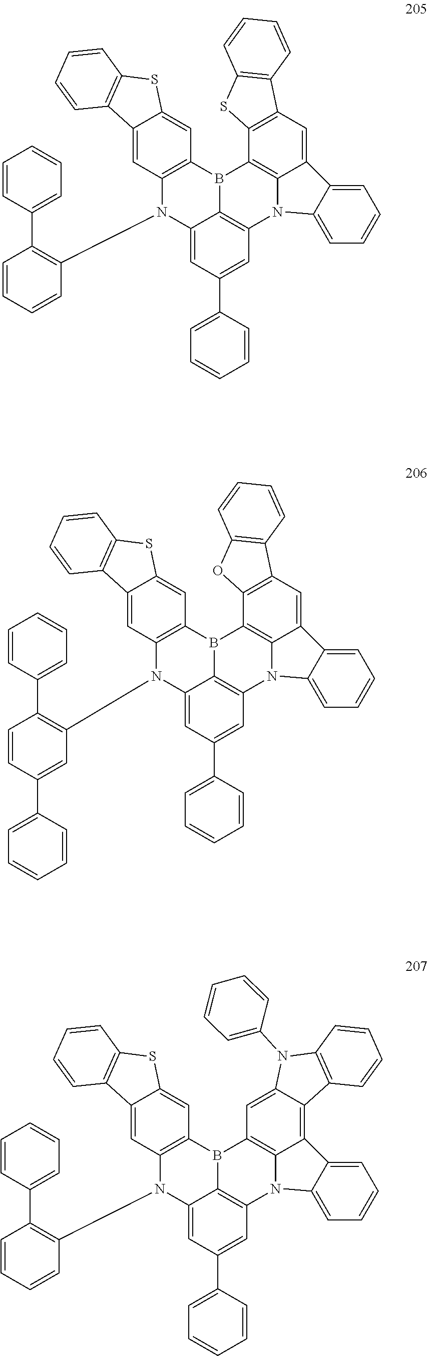 [SMILES: c1ccc(-c2cc3c4c(c2)-n2c5ccccc5c5cc6c(sc7ccccc76)c(c52)B4c2cc4sc5ccccc5c4cc2N3c2ccccc2-c2ccccc2)cc1 ; c1ccc(-c2ccc(-c3ccccc3)c(N3c4cc5c(cc4B4c6c3cc(-c3ccccc3)cc6-n3c6ccccc6c6cc7c(oc8ccccc87)c4c63)sc3ccccc35)c2)cc1 ; c1ccc(-c2cc3c4c(c2)-n2c5ccccc5c5c6c7ccccc7n(-c7ccccc7)c6cc(c52)B4c2cc4sc5ccccc5c4cc2N3c2ccccc2-c2ccccc2)cc1] 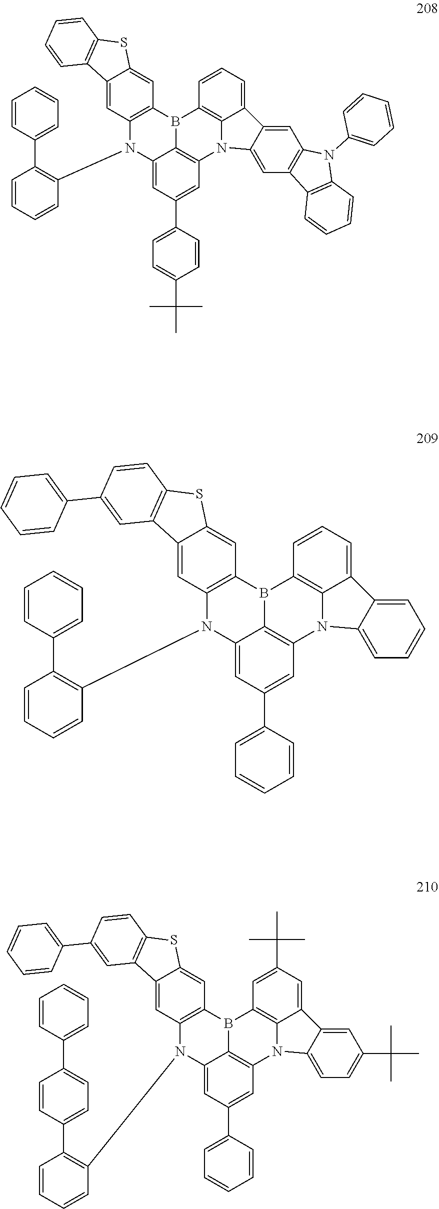 [SMILES: CC(C)(C)c1ccc(-c2cc3c4c(c2)-n2c5cc6c7ccccc7n(-c7ccccc7)c6cc5c5cccc(c52)B4c2cc4sc5ccccc5c4cc2N3c2ccccc2-c2ccccc2)cc1 ; c1ccc(-c2cc3c4c(c2)-n2c5ccccc5c5cccc(c52)B4c2cc4sc5ccc(-c6ccccc6)cc5c4cc2N3c2ccccc2-c2ccccc2)cc1 ; CC(C)(C)c1ccc2c(c1)c1cc(C(C)(C)C)cc3c1n2-c1cc(-c2ccccc2)cc2c1B3c1cc3sc4ccc(-c5ccccc5)cc4c3cc1N2c1ccccc1-c1ccc(-c2ccccc2)cc1] 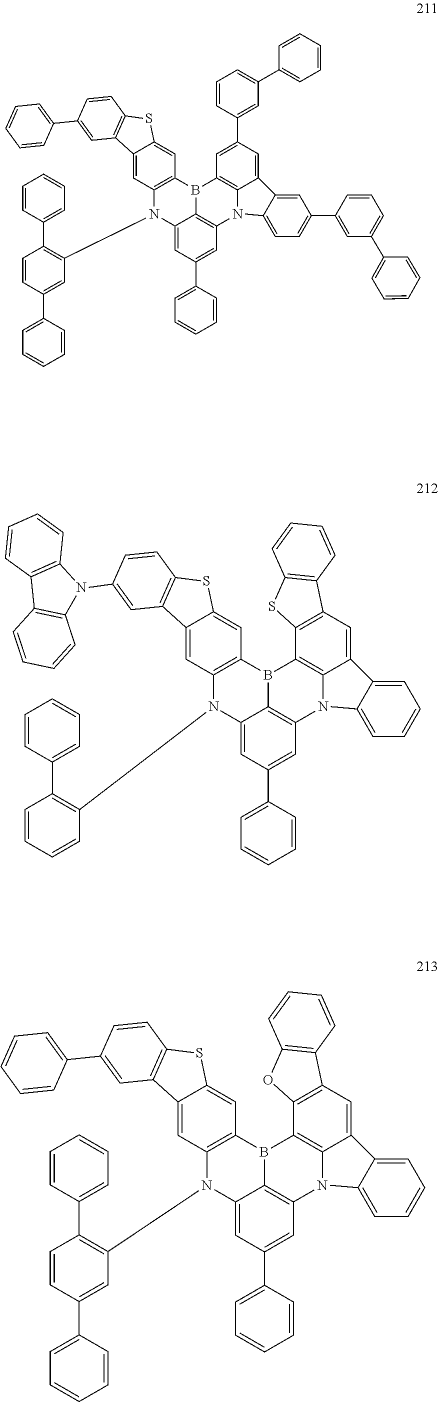 [SMILES: c1ccc(-c2cccc(-c3ccc4c(c3)c3cc(-c5cccc(-c6ccccc6)c5)cc5c3n4-c3cc(-c4ccccc4)cc4c3B5c3cc5sc6ccc(-c7ccccc7)cc6c5cc3N4c3cc(-c4ccccc4)ccc3-c3ccccc3)c2)cc1 ; c1ccc(-c2cc3c4c(c2)-n2c5ccccc5c5cc6c(sc7ccccc76)c(c52)B4c2cc4sc5ccc(-n6c7ccccc7c7ccccc76)cc5c4cc2N3c2ccccc2-c2ccccc2)cc1 ; c1ccc(-c2ccc(-c3ccccc3)c(N3c4cc5c(cc4B4c6c3cc(-c3ccccc3)cc6-n3c6ccccc6c6cc7c(oc8ccccc87)c4c63)sc3ccc(-c4ccccc4)cc35)c2)cc1] 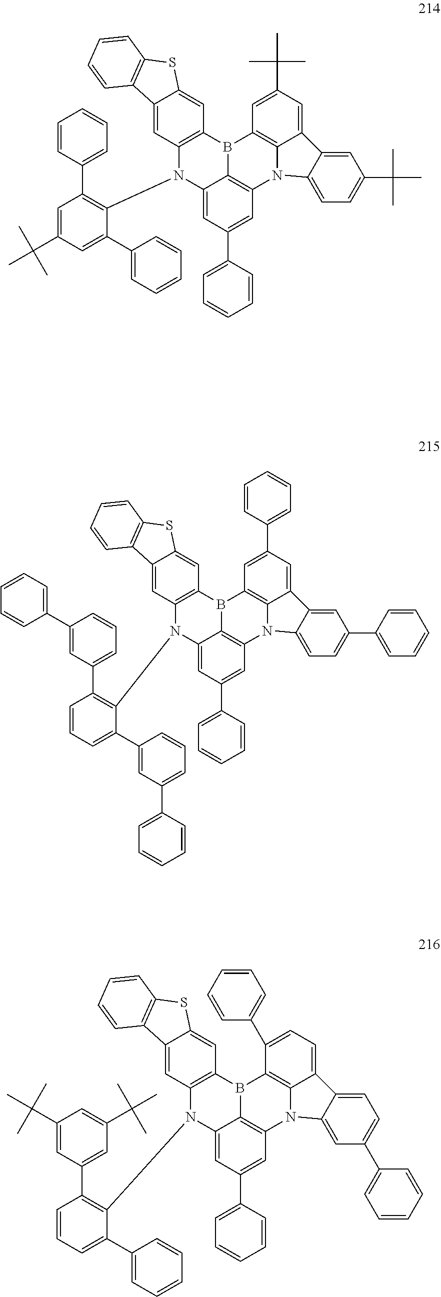 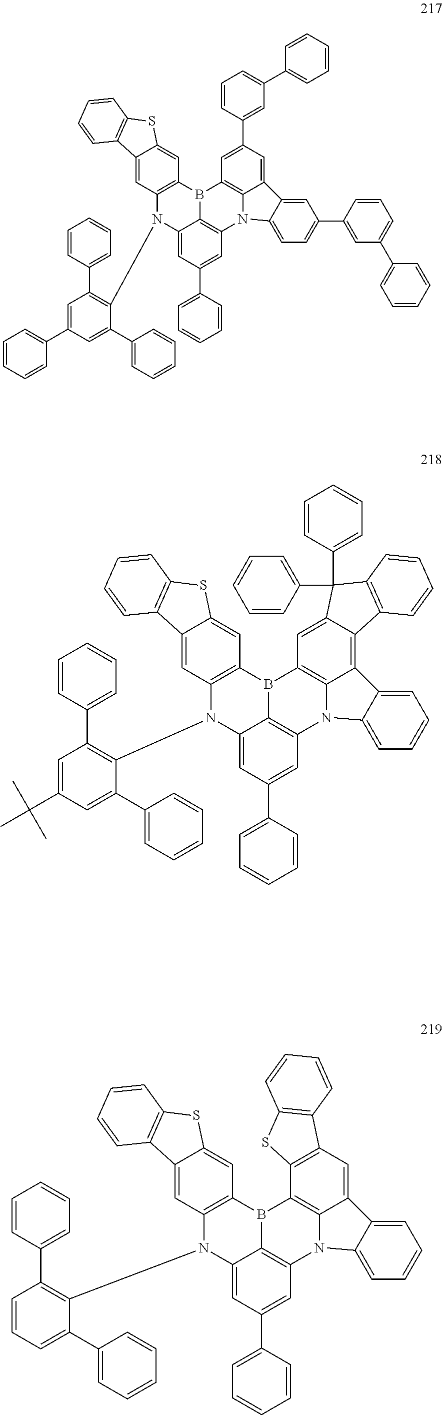 [SMILES: c1ccc(-c2cccc(-c3ccc4c(c3)c3cc(-c5cccc(-c6ccccc6)c5)cc5c3n4-c3cc(-c4ccccc4)cc4c3B5c3cc5sc6ccccc6c5cc3N4c3c(-c4ccccc4)cc(-c4ccccc4)cc3-c3ccccc3)c2)cc1 ; CC(C)(C)c1cc(-c2ccccc2)c(N2c3cc4c(cc3B3c5c2cc(-c2ccccc2)cc5-n2c5ccccc5c5c6c(cc3c52)C(c2ccccc2)(c2ccccc2)c2ccccc2-6)sc2ccccc24)c(-c2ccccc2)c1 ; c1ccc(-c2cc3c4c(c2)-n2c5ccccc5c5cc6c(sc7ccccc76)c(c52)B4c2cc4sc5ccccc5c4cc2N3c2c(-c3ccccc3)cccc2-c2ccccc2)cc1] 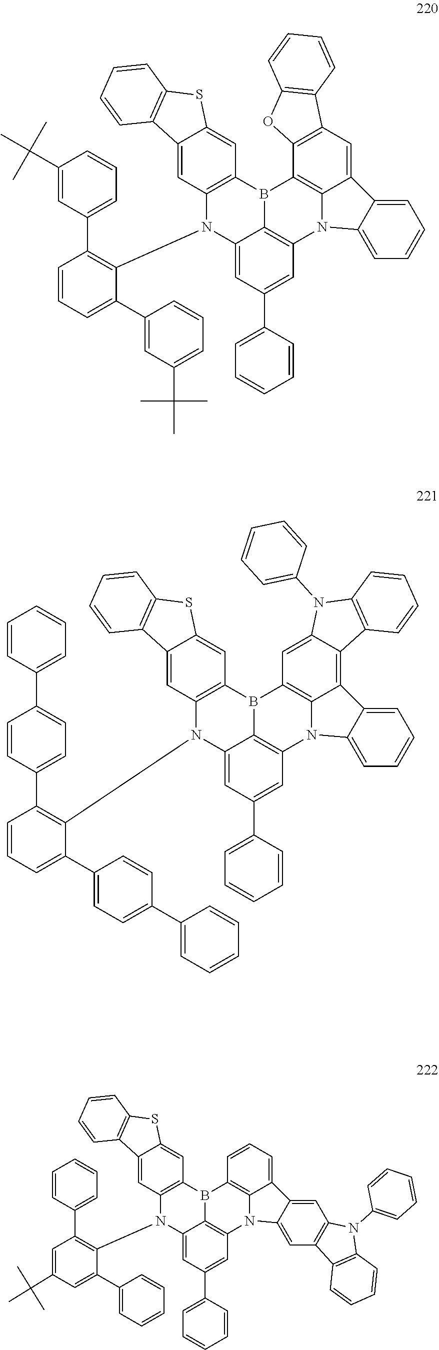 [SMILES: CC(C)(C)c1cccc(-c2cccc(-c3cccc(C(C)(C)C)c3)c2N2c3cc4c(cc3B3c5c2cc(-c2ccccc2)cc5-n2c5ccccc5c5cc6c(oc7ccccc76)c3c52)sc2ccccc24)c1 ; c1ccc(-c2ccc(-c3cccc(-c4ccc(-c5ccccc5)cc4)c3N3c4cc5c(cc4B4c6c3cc(-c3ccccc3)cc6-n3c6ccccc6c6c7c8ccccc8n(-c8ccccc8)c7cc4c63)sc3ccccc35)cc2)cc1 ; CC(C)(C)c1cc(-c2ccccc2)c(N2c3cc4c(cc3B3c5c2cc(-c2ccccc2)cc5-n2c5cc6c7ccccc7n(-c7ccccc7)c6cc5c5cccc3c52)sc2ccccc24)c(-c2ccccc2)c1] 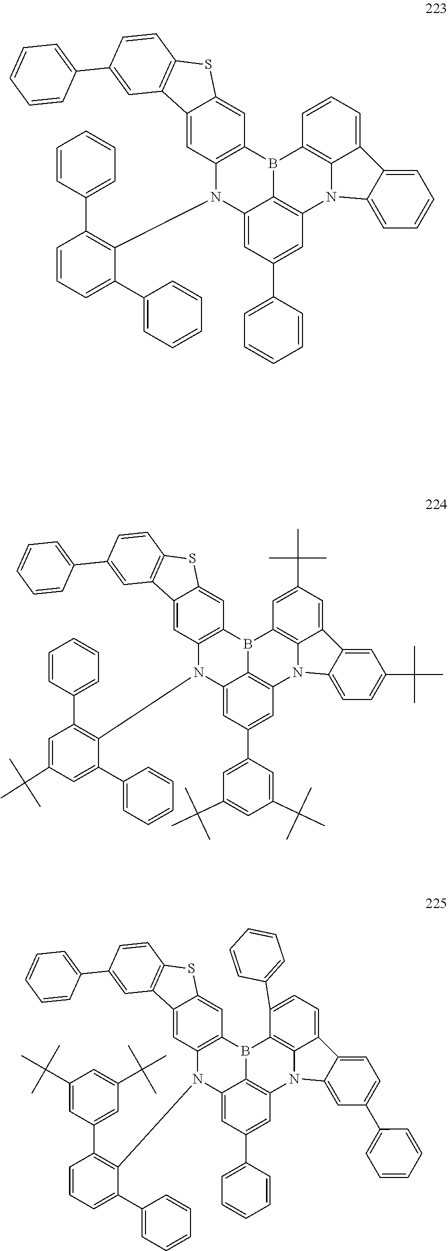 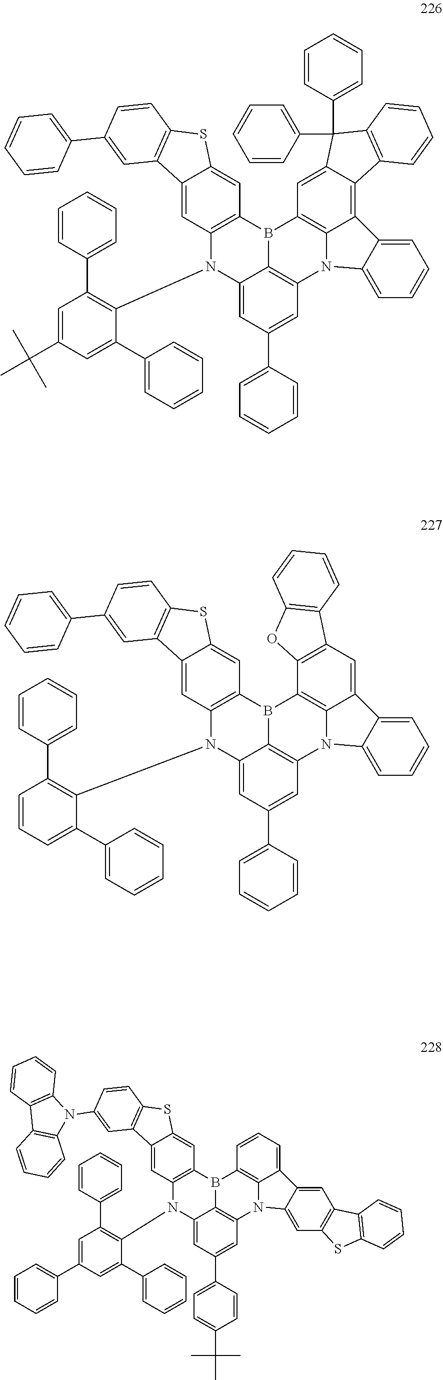 [SMILES: CC(C)(C)c1cc(-c2ccccc2)c(N2c3cc4c(cc3B3c5c2cc(-c2ccccc2)cc5-n2c5ccccc5c5c6c(cc3c52)C(c2ccccc2)(c2ccccc2)c2ccccc2-6)sc2ccc(-c3ccccc3)cc24)c(-c2ccccc2)c1 ; c1ccc(-c2cc3c4c(c2)-n2c5ccccc5c5cc6c(oc7ccccc76)c(c52)B4c2cc4sc5ccc(-c6ccccc6)cc5c4cc2N3c2c(-c3ccccc3)cccc2-c2ccccc2)cc1 ; CC(C)(C)c1ccc(-c2cc3c4c(c2)-n2c5cc6sc7ccccc7c6cc5c5cccc(c52)B4c2cc4sc5ccc(-n6c7ccccc7c7ccccc76)cc5c4cc2N3c2c(-c3ccccc3)cc(-c3ccccc3)cc2-c2ccccc2)cc1] 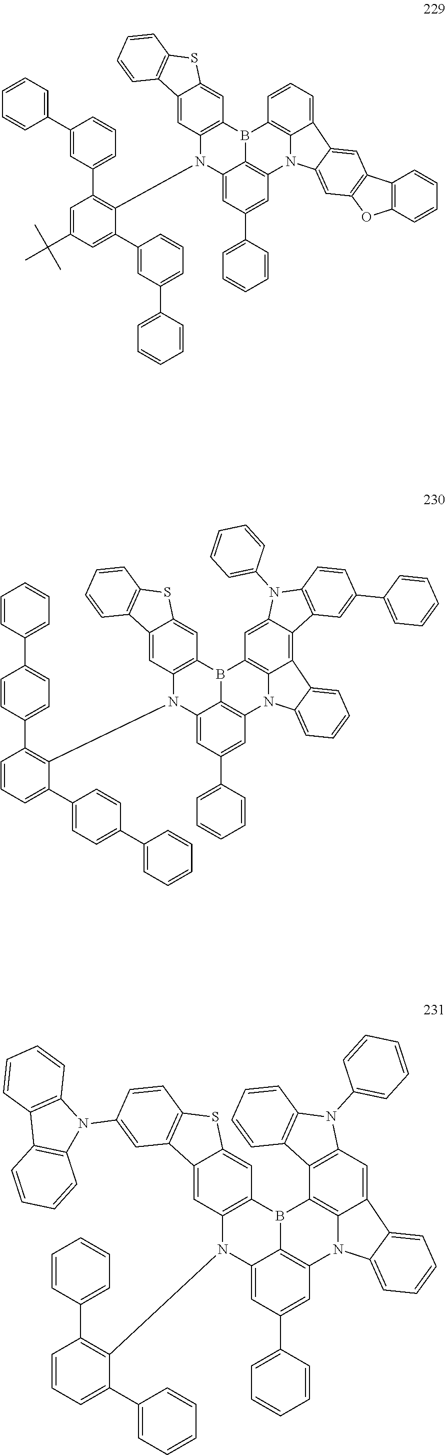 [SMILES: CC(C)(C)c1cc(-c2cccc(-c3ccccc3)c2)c(N2c3cc4c(cc3B3c5c2cc(-c2ccccc2)cc5-n2c5cc6oc7ccccc7c6cc5c5cccc3c52)sc2ccccc24)c(-c2cccc(-c3ccccc3)c2)c1 ; c1ccc(-c2ccc(-c3cccc(-c4ccc(-c5ccccc5)cc4)c3N3c4cc5c(cc4B4c6c3cc(-c3ccccc3)cc6-n3c6ccccc6c6c7c8cc(-c9ccccc9)ccc8n(-c8ccccc8)c7cc4c63)sc3ccccc35)cc2)cc1 ; c1ccc(-c2cc3c4c(c2)-n2c5ccccc5c5cc6c(c(c52)B4c2cc4sc5ccc(-n7c8ccccc8c8ccccc87)cc5c4cc2N3c2c(-c3ccccc3)cccc2-c2ccccc2)c2ccccc2n6-c2ccccc2)cc1] 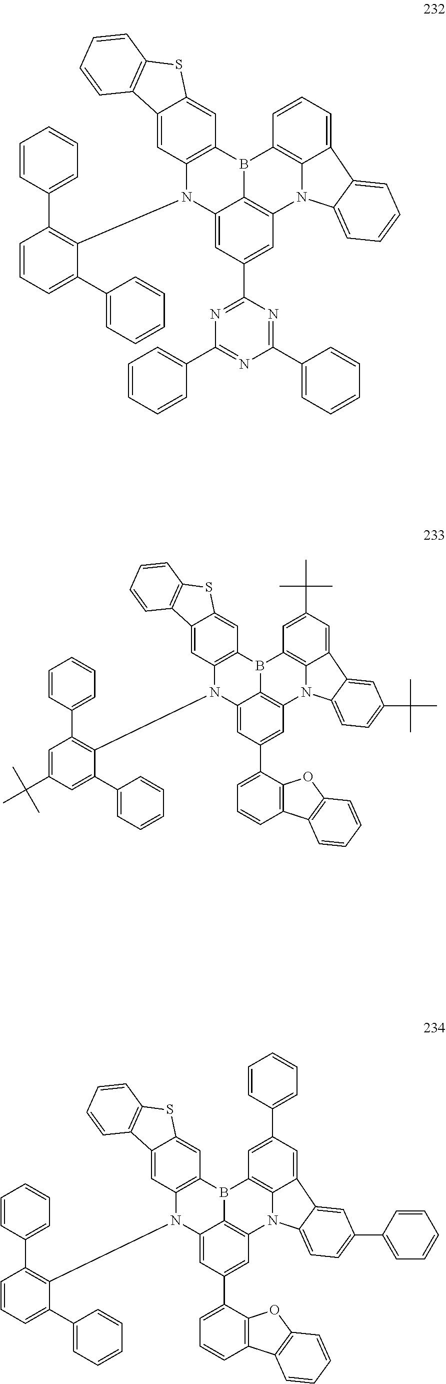 [SMILES: c1ccc(-c2nc(-c3ccccc3)nc(-c3cc4c5c(c3)-n3c6ccccc6c6cccc(c63)B5c3cc5sc6ccccc6c5cc3N4c3c(-c4ccccc4)cccc3-c3ccccc3)n2)cc1 ; CC(C)(C)c1cc(-c2ccccc2)c(N2c3cc4c(cc3B3c5c2cc(-c2cccc6c2oc2ccccc26)cc5-n2c5ccc(C(C)(C)C)cc5c5cc(C(C)(C)C)cc3c52)sc2ccccc24)c(-c2ccccc2)c1 ; c1ccc(-c2ccc3c(c2)c2cc(-c4ccccc4)cc4c2n3-c2cc(-c3cccc5c3oc3ccccc35)cc3c2B4c2cc4sc5ccccc5c4cc2N3c2c(-c3ccccc3)cccc2-c2ccccc2)cc1] 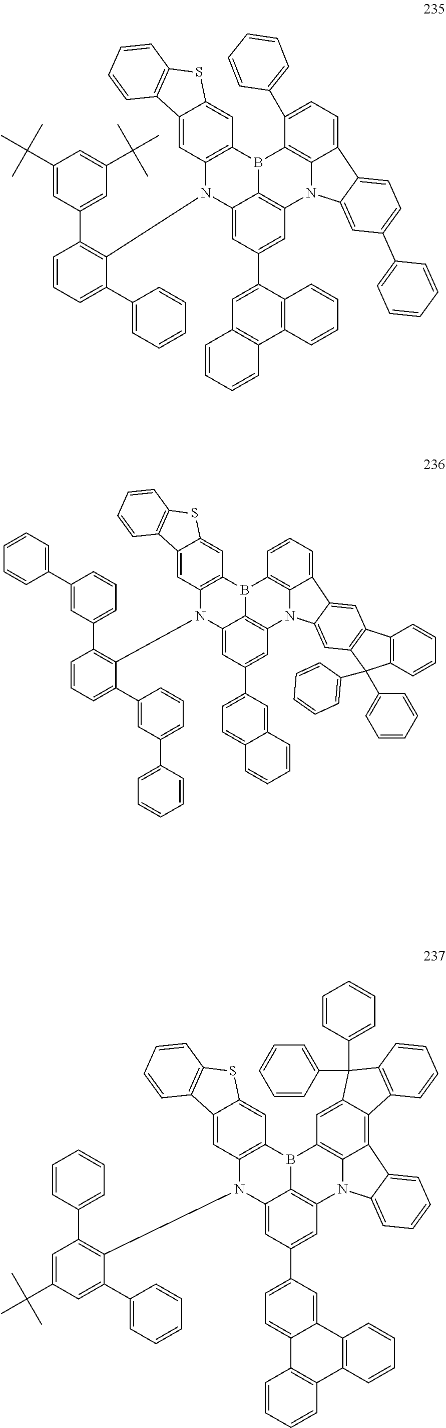 [SMILES: CC(C)(C)c1cc(-c2cccc(-c3ccccc3)c2N2c3cc4c(cc3B3c5c2cc(-c2cc6ccccc6c6ccccc26)cc5-n2c5cc(-c6ccccc6)ccc5c5ccc(-c6ccccc6)c3c52)sc2ccccc24)cc(C(C)(C)C)c1 ; c1ccc(-c2cccc(-c3cccc(-c4cccc(-c5ccccc5)c4)c3N3c4cc5c(cc4B4c6c3cc(-c3ccc7ccccc7c3)cc6-n3c6cc7c(cc6c6cccc4c63)-c3ccccc3C7(c3ccccc3)c3ccccc3)sc3ccccc35)c2)cc1 ; CC(C)(C)c1cc(-c2ccccc2)c(N2c3cc4c(cc3B3c5c2cc(-c2ccc6c7ccccc7c7ccccc7c6c2)cc5-n2c5ccccc5c5c6c(cc3c52)C(c2ccccc2)(c2ccccc2)c2ccccc2-6)sc2ccccc24)c(-c2ccccc2)c1] 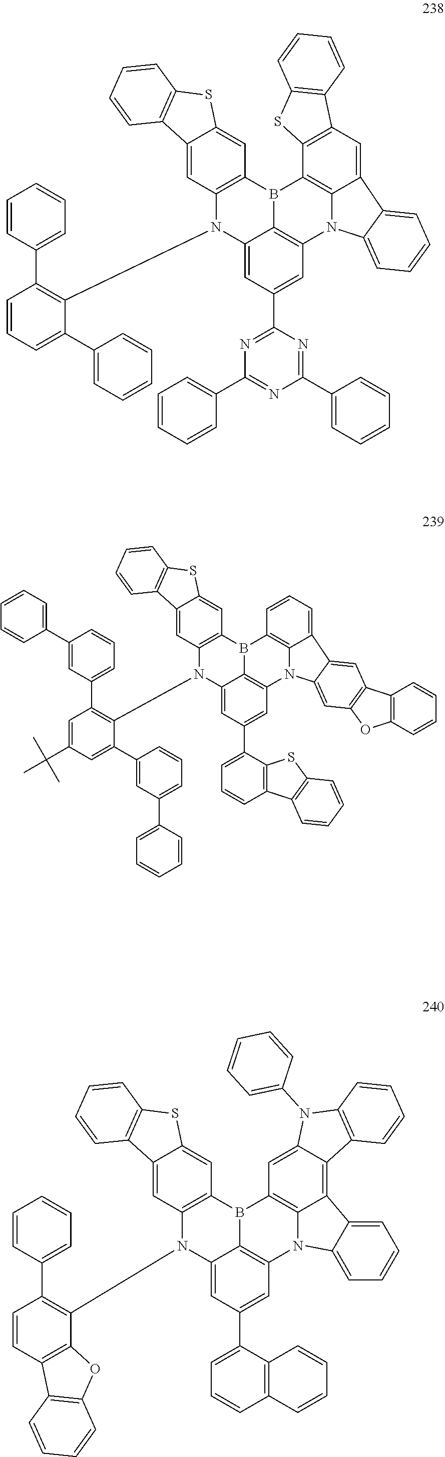 [SMILES: c1ccc(-c2nc(-c3ccccc3)nc(-c3cc4c5c(c3)-n3c6ccccc6c6cc7c(sc8ccccc87)c(c63)B5c3cc5sc6ccccc6c5cc3N4c3c(-c4ccccc4)cccc3-c3ccccc3)n2)cc1 ; CC(C)(C)c1cc(-c2cccc(-c3ccccc3)c2)c(N2c3cc4c(cc3B3c5c2cc(-c2cccc6c2sc2ccccc26)cc5-n2c5cc6oc7ccccc7c6cc5c5cccc3c52)sc2ccccc24)c(-c2cccc(-c3ccccc3)c2)c1 ; c1ccc(-c2ccc3c(oc4ccccc43)c2N2c3cc4c(cc3B3c5c2cc(-c2cccc6ccccc26)cc5-n2c5ccccc5c5c6c7ccccc7n(-c7ccccc7)c6cc3c52)sc2ccccc24)cc1] 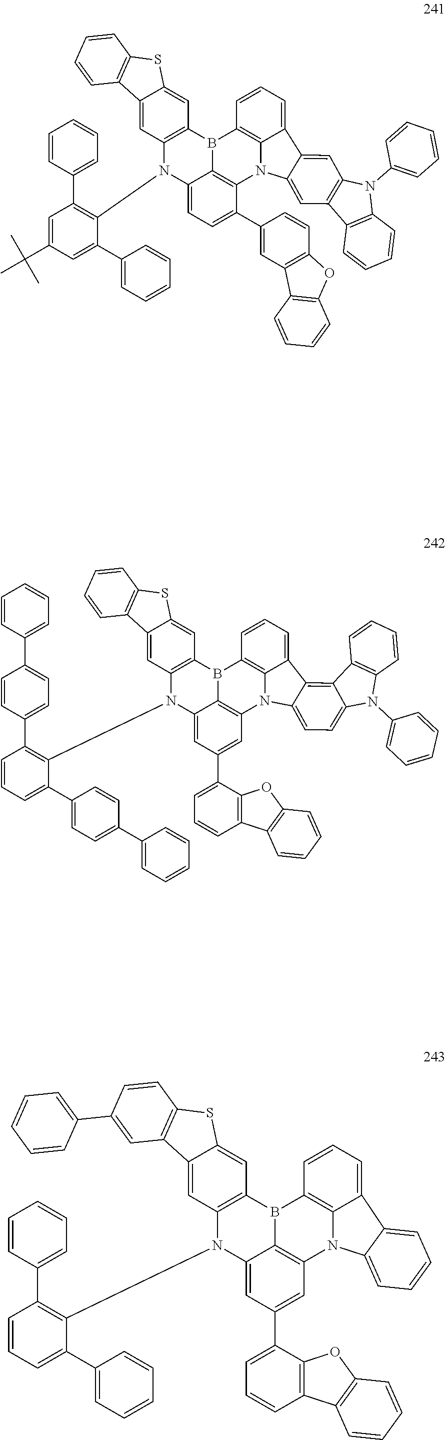 [SMILES: CC(C)(C)c1cc(-c2ccccc2)c(N2c3cc4c(cc3B3c5c2ccc(-c2ccc6oc7ccccc7c6c2)c5-n2c5cc6c7ccccc7n(-c7ccccc7)c6cc5c5cccc3c52)sc2ccccc24)c(-c2ccccc2)c1 ; c1ccc(-c2ccc(-c3cccc(-c4ccc(-c5ccccc5)cc4)c3N3c4cc5c(cc4B4c6c3cc(-c3cccc7c3oc3ccccc37)cc6-n3c6ccc7c(c8ccccc8n7-c7ccccc7)c6c6cccc4c63)sc3ccccc35)cc2)cc1 ; c1ccc(-c2ccc3sc4cc5c(cc4c3c2)N(c2c(-c3ccccc3)cccc2-c2ccccc2)c2cc(-c3cccc4c3oc3ccccc34)cc3c2B5c2cccc4c5ccccc5n-3c24)cc1] 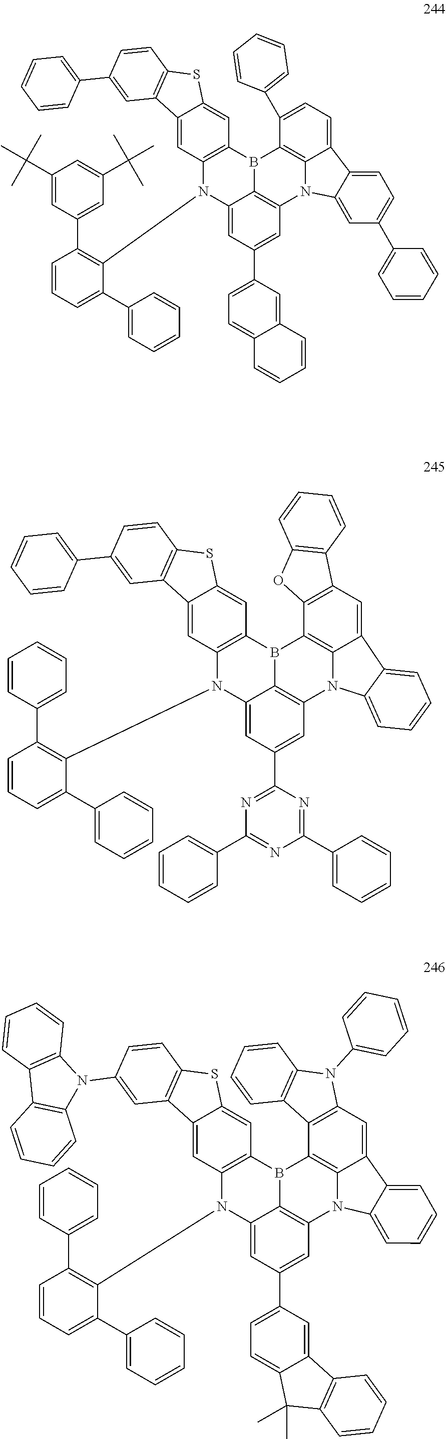 [SMILES: CC(C)(C)c1cc(-c2cccc(-c3ccccc3)c2N2c3cc4c(cc3B3c5c2cc(-c2ccc6ccccc6c2)cc5-n2c5cc(-c6ccccc6)ccc5c5ccc(-c6ccccc6)c3c52)sc2ccc(-c3ccccc3)cc24)cc(C(C)(C)C)c1 ; c1ccc(-c2ccc3sc4cc5c(cc4c3c2)N(c2c(-c3ccccc3)cccc2-c2ccccc2)c2cc(-c3nc(-c4ccccc4)nc(-c4ccccc4)n3)cc3c2B5c2c4oc5ccccc5c4cc4c5ccccc5n-3c24)cc1 ; CC1(C)c2ccccc2-c2cc(-c3cc4c5c(c3)-n3c6ccccc6c6cc7c(c(c63)B5c3cc5sc6ccc(-n8c9ccccc9c9ccccc98)cc6c5cc3N4c3c(-c4ccccc4)cccc3-c3ccccc3)c3ccccc3n7-c3ccccc3)ccc21] 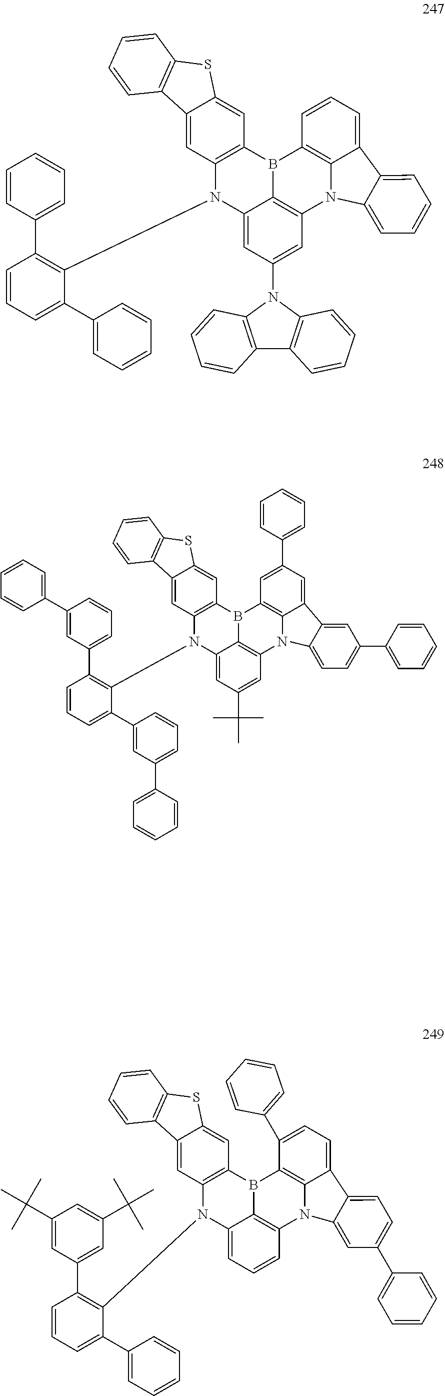 [SMILES: c1ccc(-c2cccc(-c3ccccc3)c2N2c3cc4c(cc3B3c5c2cc(-n2c6ccccc6c6ccccc62)cc5-n2c5ccccc5c5cccc3c52)sc2ccccc24)cc1 ; CC(C)(C)c1cc2c3c(c1)-n1c4ccc(-c5ccccc5)cc4c4cc(-c5ccccc5)cc(c41)B3c1cc3sc4ccccc4c3cc1N2c1c(-c2cccc(-c3ccccc3)c2)cccc1-c1cccc(-c2ccccc2)c1 ; CC(C)(C)c1cc(-c2cccc(-c3ccccc3)c2N2c3cc4c(cc3B3c5c2cccc5-n2c5cc(-c6ccccc6)ccc5c5ccc(-c6ccccc6)c3c52)sc2ccccc24)cc(C(C)(C)C)c1] 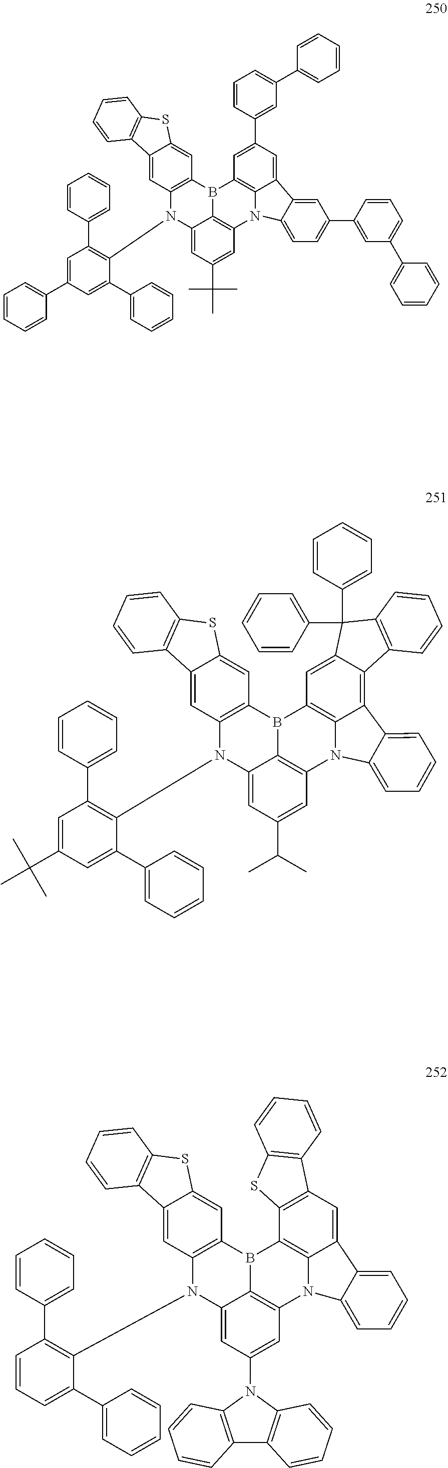 [SMILES: CC(C)(C)c1cc2c3c(c1)-n1c4ccc(-c5cccc(-c6ccccc6)c5)cc4c4cc(-c5cccc(-c6ccccc6)c5)cc(c41)B3c1cc3sc4ccccc4c3cc1N2c1c(-c2ccccc2)cc(-c2ccccc2)cc1-c1ccccc1 ; CC(C)c1cc2c3c(c1)-n1c4ccccc4c4c5c(cc(c41)B3c1cc3sc4ccccc4c3cc1N2c1c(-c2ccccc2)cc(C(C)(C)C)cc1-c1ccccc1)C(c1ccccc1)(c1ccccc1)c1ccccc1-5 ; c1ccc(-c2cccc(-c3ccccc3)c2N2c3cc4c(cc3B3c5c2cc(-n2c6ccccc6c6ccccc62)cc5-n2c5ccccc5c5cc6c(sc7ccccc76)c3c52)sc2ccccc24)cc1] 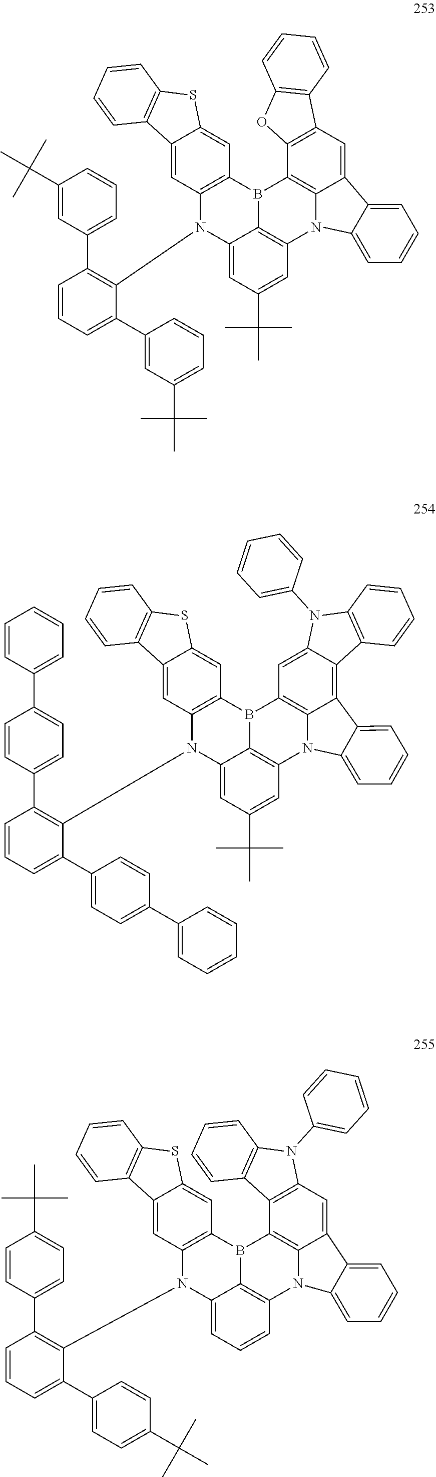 [SMILES: CC(C)(C)c1cccc(-c2cccc(-c3cccc(C(C)(C)C)c3)c2N2c3cc4c(cc3B3c5c2cc(C(C)(C)C)cc5-n2c5ccccc5c5cc6c(oc7ccccc76)c3c52)sc2ccccc24)c1 ; CC(C)(C)c1cc2c3c(c1)-n1c4ccccc4c4c5c6ccccc6n(-c6ccccc6)c5cc(c41)B3c1cc3sc4ccccc4c3cc1N2c1c(-c2ccc(-c3ccccc3)cc2)cccc1-c1ccc(-c2ccccc2)cc1 ; CC(C)(C)c1ccc(-c2cccc(-c3ccc(C(C)(C)C)cc3)c2N2c3cc4c(cc3B3c5c2cccc5-n2c5ccccc5c5cc6c(c3c52)c2ccccc2n6-c2ccccc2)sc2ccccc24)cc1] 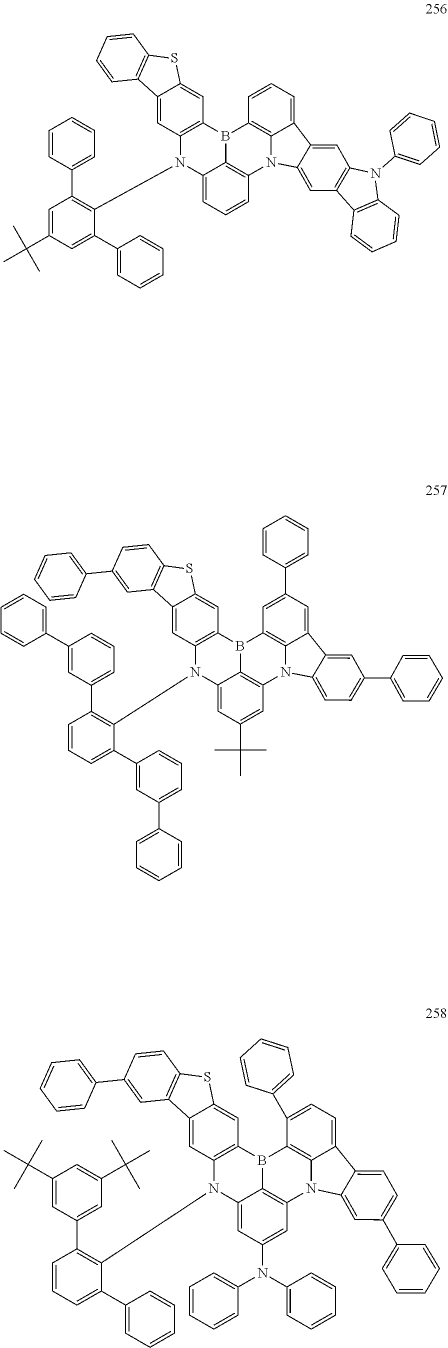 [SMILES: CC(C)(C)c1cc(-c2ccccc2)c(N2c3cc4c(cc3B3c5c2cccc5-n2c5cc6c7ccccc7n(-c7ccccc7)c6cc5c5cccc3c52)sc2ccccc24)c(-c2ccccc2)c1 ; CC(C)(C)c1cc2c3c(c1)-n1c4ccc(-c5ccccc5)cc4c4cc(-c5ccccc5)cc(c41)B3c1cc3sc4ccc(-c5ccccc5)cc4c3cc1N2c1c(-c2cccc(-c3ccccc3)c2)cccc1-c1cccc(-c2ccccc2)c1 ; CC(C)(C)c1cc(-c2cccc(-c3ccccc3)c2N2c3cc4c(cc3B3c5c2cc(N(c2ccccc2)c2ccccc2)cc5-n2c5cc(-c6ccccc6)ccc5c5ccc(-c6ccccc6)c3c52)sc2ccc(-c3ccccc3)cc24)cc(C(C)(C)C)c1]
